(19) United States
(12) Patent Application Publication
(10) Pub. No.: US 2019/0067616 A1
(43) Pub. Date: Feb. 28, 2019

(54) ORGANIC LIGHT-EMITTING DEVICE

(71) Applicants: Samsung Electronics Co., Ltd., Suwon-si (KR); Korea Advanced Institute of Science and Technology, Daejeon (KR)

(72) Inventors: Soonok JEON, Suwon-si (KR); Hiroshi MIYAZAKI, Hwaseong-si (KR); Yeonsook CHUNG, Seoul (KR); Myungsun SIM, Suwon-si (KR); Sooghang IHN, Hwaseong-si (KR); Wonchul LEE, Daejeon (KR); Heeseung LEE, Daejeon (KR); LianJin ZHANG, Daejeon (KR); Yoonchul JUNG, Daejeon (KR)

(21) Appl. No.: 16/108,994

(22) Filed: Aug. 22, 2018

(30) Foreign Application Priority Data
Aug. 23, 2017 (KR) 10-2017-0106922
Jul. 19, 2018 (KR) 10-2018-0084273

(51) Int. Cl. H01L 51/50; H01L 51/52; H01L 51/00

(52) U.S. Cl. CPC H01L 51/5024; H01L 51/5092; H01L 51/5096; H01L 51/5072; H01L 51/5221; H01L 51/0072; H01L 51/5056; H01L 51/5206

(57) ABSTRACT

An organic light-emitting device including a first electrode; a second electrode; and an organic layer disposed between the first electrode and the second electrode, wherein the organic layer comprises an emission layer, wherein the emission layer includes at least one of a condensed cyclic compound represented by Formula 1, and wherein a ratio of an emission component of thermally activated delayed fluorescence (TADF) emitted from the condensed cyclic compound to a total emission component emitted from the emission layer is about 80% or more.

### CROSS-REFERENCE TO RELATED APPLICATIONS

This application claims priority to Korean Patent Application Nos. 10-2017-0106922 and 10-2018-0084273, respectively filed on Aug. 23, 2017 and Jul. 19, 2018, in the Korean Intellectual Property Office, and all the benefits accruing therefrom under 35 U.S.C. § 119, the contents of which are incorporated herein in their entirety by reference.

### BACKGROUND

### 1. Field

One or more embodiments relate to an organic light-emitting device.

### 2. Description of the Related Art

Organic light-emitting devices (OLEDs) are self-emission devices that produce full-color images, and also have wide viewing angles, high contrast ratios, short response times, as well as excellent characteristics in terms of brightness, driving voltage, and response speed.

In an example, an organic light-emitting device includes an anode, a cathode, and an organic layer disposed between the anode and the cathode, wherein the organic layer includes an emission layer. A hole transport region may be disposed between the anode and the emission layer, and an electron transport region may be disposed between the emission layer and the cathode. Holes provided from the anode may move toward the emission layer through the hole transport region, and electrons provided from the cathode may move toward the emission layer through the electron transport region. Carriers, such as holes and electrons, recombine in an emission layer region to produce excitons. These excitons transit from an excited state to a ground state, thereby generating light.

Various types of organic light emitting devices are known. However, there still remains a need in OLEDs having low driving voltage, high efficiency, high brightness, and long lifespan.

### SUMMARY

One or more embodiments provide an organic light-emitting device.

Additional aspects will be set forth in part in the description which follows and, in part, will be apparent from the description, or may be learned by practice of the presented embodiments.

An aspect provides an organic light-emitting device including:

a first electrode;

a second electrode; and

an organic layer disposed between the first electrode and the second electrode and including an emission layer,

wherein the emission layer includes at least one of a condensed cyclic compound represented by Formula 1, and

wherein a ratio of an emission component of thermally activated delayed fluorescence (TADF) emitted from the condensed cyclic compound to a total emission component emitted from the emission layer is about 80% or more:

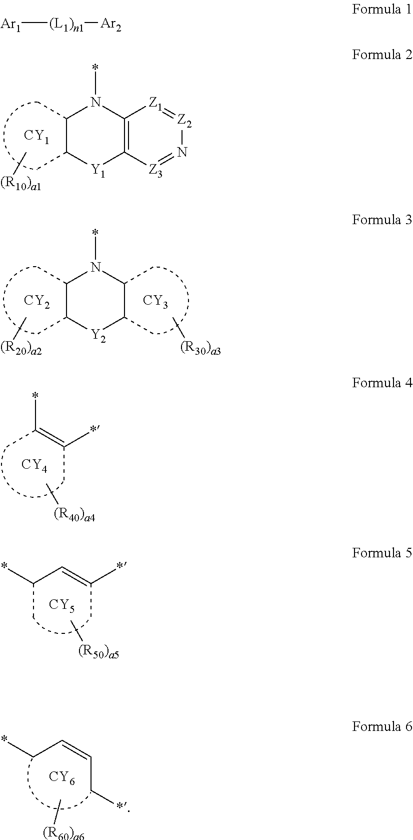

In Formulae 1 to 6,

Ar₁ may be a group represented by Formula 2,

Ar₂ may be a group represented by Formula 3 or a substituted or unsubstituted C₅-C₃₀ carbocyclic group,

L₁ may be selected from a group represented by Formula 4, a group represented by Formula 5, and a group represented by Formula 6,

n1 may be an integer of 0 to 5,

CY₁ to CY₃ may each independently be a C₅-C₃₀ carbocyclic group or a C₁-C₃₀ heterocyclic group,

CY₄ to CY₆ may each independently be a C₅-C₃₀ carbocyclic group,

Z₁ may be N or C(R₁), Z₂ may be N or C(R₂), and Z₃ may be N or C(R₃),

Y₁ may be a single bond, C(R₅)(R₆), N(R₅), O, or S,

Y₂ may be a single bond, C(R₇)(R₈), N(R₇), O, or S,

R₁ to R₃, R₅ to R₈, R₁₀, R₂₀, and R₃₀ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₄)(Q₅), and —B(Q₆)(Q₇),

R₄₀, R₅₀, and R₆₀ may each independently be selected from hydrogen, deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₄)(Q₅), and —B(Q₆)(Q₇),

a1 to a6 may each independently be an integer of 1 to 10,

at least one of groups R₁₀ in the number of a1 may be a substituted or unsubstituted carbazolyl group,

* and *′ each indicate a binding site to a neighboring atom,

at least one substituent of the substituted C₅-C₃₀ carbocyclic group, the substituted C₁-C₆₀ alkyl group, the substituted C₂-C₆₀ alkenyl group, the substituted C₂-C₆₀ alkynyl group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may be selected from:

deuterium, —CD₃, —CD₂H, —CDH₂, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from deuterium, —CD₃, —CD₂H, —CDH₂, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —N(Q₁₄)(Q₁₅), and —B(Q₁₆)(Q₁₇);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group; a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from deuterium, —CD₃, —CD₂H, —CDH₂, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —N(Q₂₄)(Q₂₅), and —B(Q₂₆)(Q₂₇); and

—Si(Q₃₁)(Q₃₂)(Q₃₃), —N(Q₃₄)(Q₃₅), and —B(Q₃₆)(Q₃₇), and

Q₁ to Q₇, Q₁₁ to Q₁₇, Q₂₁ to Q₂₇, and Q₃₁ to Q₃₇ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic cross-sectional view of an organic light-emitting device according to an embodiment; and

FIG. 2 is a graph of intensity (arbitrary units) versus wavelength (nanometers, nm) illustrating an electroluminescence spectrum of an organic light-emitting device, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein.

Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly in contact with the other element or intervening elements may be present therebetween. In contrast, when an element is referred to as being “directly on” another element, there are no intervening elements present.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section.

Thus, a first element, component, region, layer, or section discussed below could be termed a second element, component, region, layer, or section without departing from the teachings of the present embodiments.

The terminology used herein is for the purpose of describing particular embodiments only and is not intended to be limiting. As used herein, the singular forms “a,” “an,” and “the” are intended to include the plural forms as well, unless the context clearly indicates otherwise.

The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

In an embodiment, an organic light-emitting device is provided. The organic light-emitting device according to an embodiment includes:

a first electrode;

a second electrode; and

an organic layer between the first electrode and the second electrode and including an emission layer,

wherein the emission layer includes at least one of a condensed cyclic compound represented by Formula 1, and

a ratio of an emission component of thermally activated delayed fluorescence (TADF) emitted from the condensed cyclic compound to a total emission component emitted from the emission layer is about 80% or more:

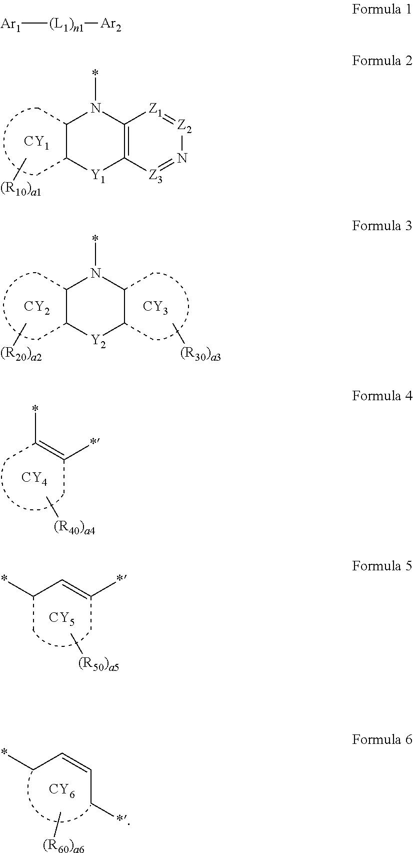

In Formula 1, Ar₁ may be a group represented by Formula 2, and Ar₂ may be a group represented by Formula 3 or a C₅-C₃₀ carbocyclic group.

In Formula 1, L₁ may be selected from a group represented by Formula 4, a group represented by Formula 5, and a group represented by Formula 6.

In Formula 1, n1 may be an integer of 0 to 5.

In an embodiment, in Formula 1, n1 may be 1 or 2, and Ar₂ may be a group represented by Formula 3, or

n1 may be 0 or 1, and Ar₂ may be a C₅-C₃₀ carbocyclic group.

In Formulae 2 and 3, CY₁ to CY₃ may each independently be a C₅-C₃₀ carbocyclic group or a C₁-C₃₀ heterocyclic group.

In an embodiment, CY₁ to CY₃ may each independently be selected from a benzene group, a fluorene group, a carbazole group, a dibenzofuran group, and a dibenzothiophene group.

For example, CY₁ may be a benzene group, but embodiments of the present disclosure are not limited thereto.

In one or more embodiments, CY₂ may be a benzene group, and

CY₃ may be selected from a benzene group, a fluorene group, a carbazole group, a dibenzofuran group, and a dibenzothiophene group.

For example, CY₂ and CY₃ may each independently be a benzene group.

In Formulae 4 and 5, CY₄ to CY₆ may each independently be a C₅-C₃₀ carbocyclic group.

In an embodiment, CY₄ to CY₆ may each independently be selected from a benzene group, a naphthalene group, and a fluorene group.

In Formula 2, Z₁ may be N or C(R₁), Z₂ may be N or C(R₂), and Z₃ may be N or C(R₃).

In an embodiment, Z₁ to Z₃ may each independently be C, or one of Z₁ to Z₃ may be N.

In one or more embodiments, Z₁ may be N, and Z₂ and Z₃ may each independently be C.

In Formulae 2 and 3, Y₁ may be a single bond, C(R₅)(R₆), N(R₅), O, or S, and Y₂ may be a single bond, C(R₇)(R₈), N(R₇), O, or S.

In an embodiment, Y₁ may be a single bond.

In one or more embodiments, Y₂ may be a single bond.

In an embodiment, Ar₁ may be a group represented by one selected from Formulae 2-1 to 2-7.

In Formulae 1 to 6, R₁ to R₃, R₅ to R₈, R₁₀, R₂₀, R₄₀, R₅₀, and R₆₀ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₄)(Q₅), and —B(Q₆)(Q₇),

a1 to a6 may each independently be an integer of 1 to 10,

at least one of groups R₁₀ in the number of a1 may be a substituted or unsubstituted carbazolyl group. That is, at least one of groups R₁₀ in the number of a1 may include a carbazolyl group.

In an embodiment, R₁ to R₃ may each independently be hydrogen.

In an embodiment, R₁₀, R₂₀, R₃₀, R₄₀, R₅₀, and R₆₀ may each independently be selected from:

hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, and a C₁-C₂₀ alkoxy group;

a C₁-C₂₀ alkyl group and a C₁-C₂₀ alkoxy group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a phenyl group, a biphenyl group, a terphenyl group, and a naphthyl group;

a cyclopentyl group, a cyclohexyl group, a cyclopentenyl group, a cyclohexenyl group, a cycloheptenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyrimidinyl group, an imidazopyridinyl group, a pyridoindolyl group, a benzofuropyridinyl group, a benzothienopyridinyl group, a pyrimidoindolyl group, a benzofuropyrimidinyl group, a benzothienopyrimidinyl group, a phenoxazinyl group, a pyridobenzoxazinyl group, and a pyridobenzothiazinyl group;

a cyclopentyl group, a cyclohexyl group, a cyclopentenyl group, a cyclohexenyl group, a cycloheptenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-fluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyrimidinyl group, an imidazopyridinyl group, a pyridoindolyl group, a benzofuropyridinyl group, a benzothienopyridinyl group, a pyrimidoindolyl group, a benzofuropyrimidinyl group, a benzothienopyrimidinyl group, a phenoxazinyl group, a pyridobenzoxazinyl group, and a pyridobenzothiazinyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₁-C₂₀ alkoxy group, a phenyl group, a biphenyl group, a terphenyl group, a naphthyl group, an anthracenyl group, a pyrenyl group, a phenanthrenyl group, a fluorenyl group, a carbazolyl group, a benzocarbazolyl group, a dibenzocarbazolyl group, a pyridinyl group, a pyrimidinyl group, a pyrazinyl group, a pyridazinyl group, a triazinyl group, a quinolinyl group, an isoquinolinyl group, a phthalazinyl group, a quinoxalinyl group, a cinnolinyl group, a quinazolinyl group, —Si(Q₃₁)(Q₃₂)(Q₃₃), —N(Q₃₄)(Q₃₅), and —B(Q₃₆)(Q₃₇); and

Si(Q₁)(Q₂)(Q₃), —N(Q₄)(Q₅), and —B(Q₆)(Q₇),

at least one R₁₀ may be selected from:

a carbazolyl group; and

a carbazolyl group substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₁-C₂₀ alkoxy group, a phenyl group, a biphenyl group, a terphenyl group, a naphthyl group, an anthracenyl group, a pyrenyl group, a phenanthrenyl group, a fluorenyl group, a carbazolyl group, a benzocarbazolyl group, a dibenzocarbazolyl group, a pyridinyl group, a pyrimidinyl group, a pyrazinyl group, a pyridazinyl group, a triazinyl group, a quinolinyl group, an isoquinolinyl group, a phthalazinyl group, a quinoxalinyl group, a cinnolinyl group, a quinazolinyl group, —Si(Q₃₁)(Q₃₂)(Q₃₃), —N(Q₃₄)(Q₃₅), and —B(Q₃₆)(Q₃₇), and

Q₁ to Q₇ and Q₃₁ to Q₃₇ may each independently be selected from hydrogen, a C₁-C₂₀ alkyl group, a C₁-C₂₀ alkoxy group, a phenyl group, a biphenyl group, a terphenyl group, a naphthyl group, a fluorenyl group, a carbazolyl group, a dibenzofuranyl group, and a dibenzothiophenyl group.

In an embodiment, Ar₁ may be a group represented by one selected from Formulae 2-1 to 2-7:

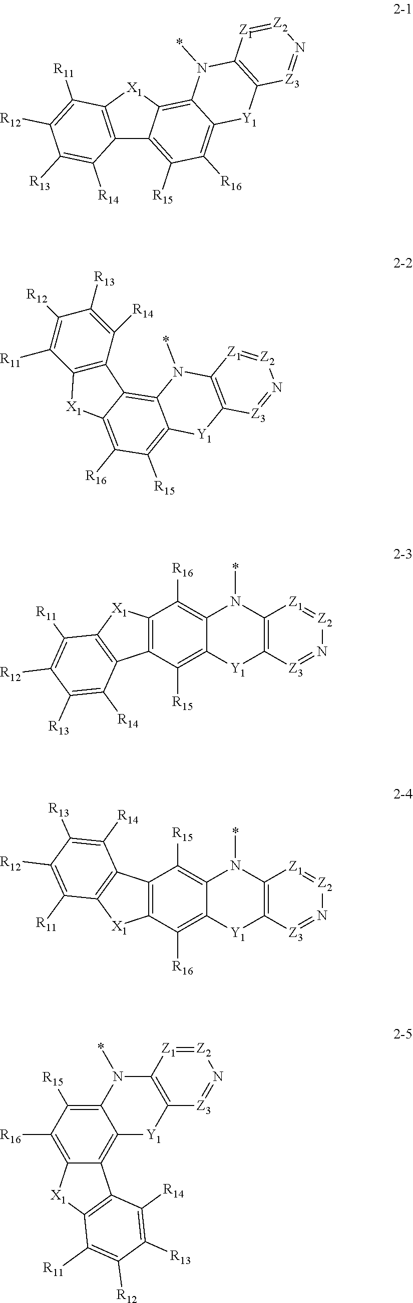

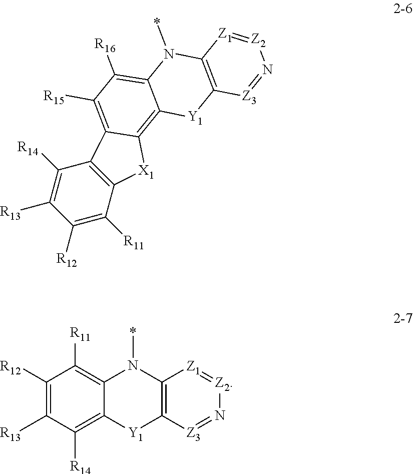

In Formulae 2-1 to 2-7,

X₁ may be C(R₁₇)(R₁₈), N(R₁₉), O, or S,

Y₁, Z₁, Z₂, and Z₃ may each independently be the same as described above,

R₁ to R₃, R₅ to R₈, and R₁₁ to R₁₉ may each independently be selected from:

hydrogen, deuterium, —F, —Cl, —Br, —I, a cyano group, a C₁-C₂₀ alkyl group, and a C₁-C₂₀ alkoxy group;

a C₁-C₂₀ alkyl group and a C₁-C₂₀ alkoxy group, each substituted with at least one selected from deuterium, a phenyl group, a biphenyl group, a terphenyl group, and a naphthyl group;

a cyclopentyl group, a cyclohexyl group, a cyclopentenyl group, a cyclohexenyl group, a cycloheptenyl group, a phenyl group, a biphenyl group, a terphenyl group, a naphthyl group, a fluorenyl group, a carbazolyl group, a dibenzofuranyl group, and a dibenzothiophenyl group;

a cyclopentyl group, a cyclohexyl group, a cyclopentenyl group, a cyclohexenyl group, a cycloheptenyl group, a phenyl group, a biphenyl group, a terphenyl group, a naphthyl group, a fluorenyl group, a carbazolyl group, a dibenzofuranyl group, and a dibenzothiophenyl group, each substituted with at least one selected from deuterium, a C₁-C₂₀ alkyl group, a C₁-C₂₀ alkoxy group, a phenyl group, a biphenyl group, a terphenyl group, a naphthyl group, a carbazolyl group, and —Si(Q₃₁)(Q₃₂)(Q₃₃); and

—Si(Q₁)(Q₂)(Q₃),

at least one selected from R₁₁ to R₁₄ may be selected from:

a carbazolyl group; and

a carbazolyl group substituted with at least one selected from deuterium, a C₁-C₂₀ alkyl group, a C₁-C₂₀ alkoxy group, a phenyl group, a biphenyl group, a terphenyl group, a naphthyl group, a carbazolyl group, and —Si(Q₃₁)(Q₃₂)(Q₃₃),

Q₁ to Q₃ and Q₃₁ to Q₃₃ may each independently be selected from hydrogen, a C₁-C₂₀ alkyl group, a C₁-C₂₀ alkoxy group, a phenyl group, a biphenyl group, a terphenyl group, and a naphthyl group, and

* indicates a binding site to a neighboring atom.

In an embodiment, Ar₂ may be a group represented by one selected from Formulae 3-1 to 3-7 and 4-1 to 4-19:

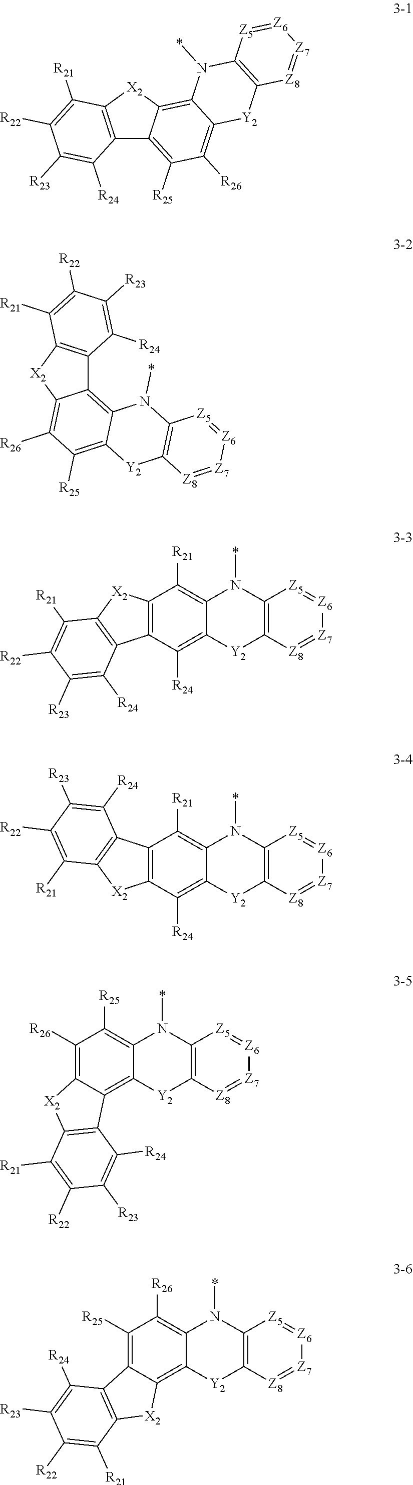

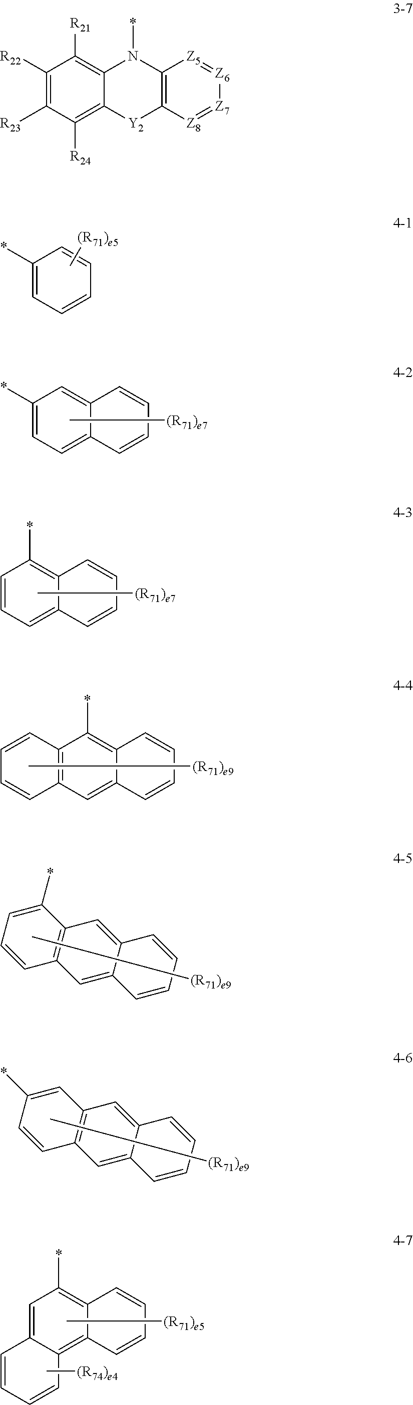

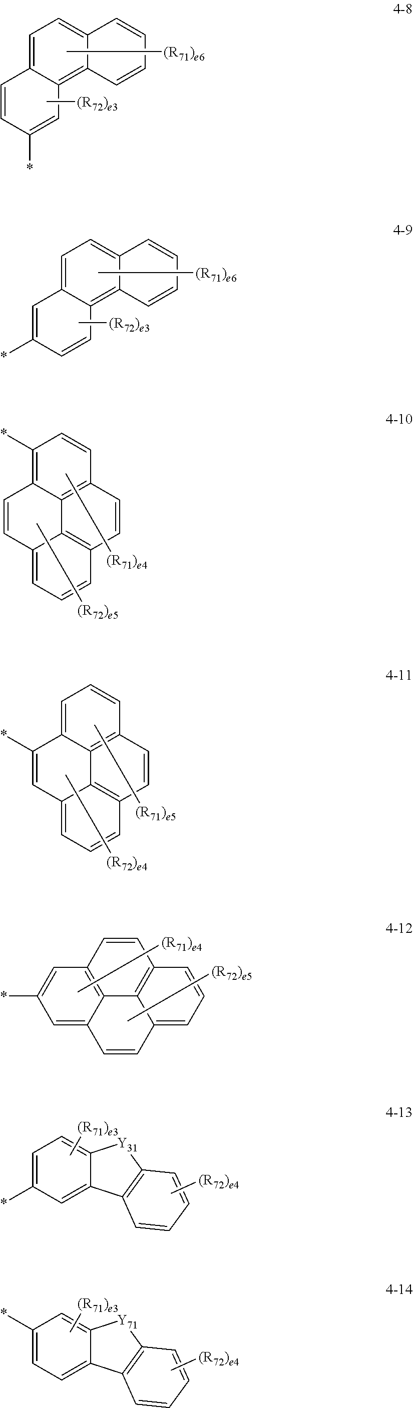

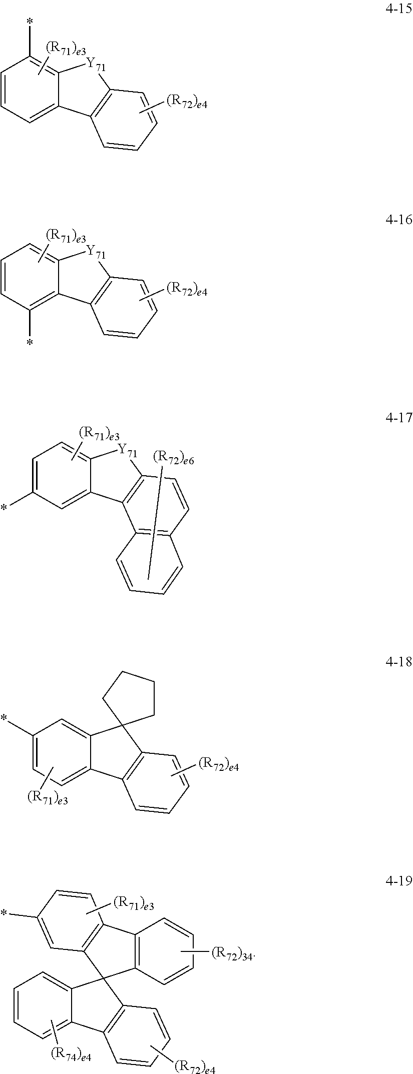

in Formulae 3-1 to 3-7 and 4-1 to 4-19:

X₂ may be C(R₂₇)(R₂₈), N(R₂₉), O, or S,

Y₂ may be the same as described above,

Z₅ may be N or C(R₃₁), Z₆ may be N or C(R₃₂), Z₇ may be N or C(R₃₃), and Z₈

may be N or C(R₃₄),

R₂₁ to R₂₉ and R₃₁ to R₃₄ may each independently be selected from: hydrogen, deuterium, —F, —Cl, —Br, —I, a cyano group, a C₁-C₂₀ alkyl group, and a C₁-C₂₀ alkoxy group;

a C₁-C₂₀ alkyl group and a C₁-C₂₀ alkoxy group, each substituted with at least one selected from deuterium, a phenyl group, a biphenyl group, a terphenyl group, and a naphthyl group;

a cyclopentyl group, a cyclohexyl group, a cyclopentenyl group, a cyclohexenyl group, a cycloheptenyl group, a phenyl group, a biphenyl group, a terphenyl group, a naphthyl group, a fluorenyl group, a carbazolyl group, a dibenzofuranyl group, and a dibenzothiophenyl group;

a cyclopentyl group, a cyclohexyl group, a cyclopentenyl group, a cyclohexenyl group, a cycloheptenyl group, a phenyl group, a biphenyl group, a terphenyl group, a naphthyl group, a fluorenyl group, a carbazolyl group, a dibenzofuranyl group, and a dibenzothiophenyl group, each substituted with at least one selected from deuterium, a C₁-C₂₀ alkyl group, a C₁-C₂₀ alkoxy group, a phenyl group, a biphenyl group, a terphenyl group, a naphthyl group, a carbazolyl group, and —Si(Q₃₁)(Q₃₂)(Q₃₃); and

—Si(Q₁)(Q₂)(Q₃),

Q₁ to Q₃ may each independently be selected from hydrogen, a C₁-C₂₀ alkyl group, a C₁-C₂₀ alkoxy group, a phenyl group, a biphenyl group, a terphenyl group, a naphthyl group, a fluorenyl group, a carbazolyl group, a dibenzofuranyl group, and a dibenzothiophenyl group,

Y₇₁ may be O, S, C(R₇₅)(R₇₆), or Si(R₇₅)(R₇₆),

R₇₁ and R₇₆ may each independently be one selected from hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, an anthracenyl group, and a phenanthrenyl group,

e2 may be an integer of 0 to 2,

e3 may be an integer of 0 to 3,

e4 may be an integer of 0 to 4,

e5 may be an integer of 0 to 5,

e6 may be an integer of 0 to 6,

e7 may be an integer of 0 to 7,

e9 may be an integer of 0 to 9, and

* indicates a binding site to a neighboring atom.

In an embodiment, in Formulae 2-1 to 2-7 and 3-1 to 3-7, R₁ to R₈, R₁₁ to R₁₉, R₂₁ to R₂₉, and R₃₁ to R₃₄ may each independently be selected from:

hydrogen, deuterium, —F, —Cl, —Br, —I, a cyano group, a C₁-C₂₀ alkyl group, and a C₁-C₂₀ alkoxy group;

a C₁-C₂₀ alkyl group and a C₁-C₂₀ alkoxy group, each substituted with at least one selected from deuterium, —F, —Cl, —Br, —I, a cyano group, a phenyl group, a biphenyl group, a terphenyl group, and a naphthyl group;

a cyclopentyl group, a cyclohexyl group, a cyclopentenyl group, a cyclohexenyl group, a cycloheptenyl group, a phenyl group, a biphenyl group, a terphenyl group, a naphthyl group, a fluorenyl group, a carbazolyl group, a dibenzofuranyl group, and a dibenzothiophenyl group;

a cyclopentyl group, a cyclohexyl group, a cyclopentenyl group, a cyclohexenyl group, a cycloheptenyl group, a phenyl group, a biphenyl group, a terphenyl group, a naphthyl group, a fluorenyl group, a carbazolyl group, a dibenzofuranyl group, and a dibenzothiophenyl group, each substituted with at least one selected from deuterium, a cyano group, a C₁-C₂₀ alkyl group, a C₁-C₂₀ alkoxy group, a phenyl group, a biphenyl group, a terphenyl group, a naphthyl group, and —Si(Q₃₁)(Q₃₂)(Q₃₃); and

—Si(Q₁)(Q₂)(Q₃), and

Q₁ to Q₃ and Q₃₁ to Q₃₃ may each independently be selected from hydrogen, a C₁-C₂₀ alkyl group, a C₁-C₂₀ alkoxy group, a phenyl group, a biphenyl group, a terphenyl group, and a naphthyl group.

In an embodiment, in Formulae 2-1 to 2-7 and 3-1 to 3-14, X₁ may be O or S.

In an embodiment, Ar₁ may be represented by Formula 2-7, and Ar₂ may be represented by Formula 3-7. However, embodiments of the present disclosure are not limited thereto.

In an embodiment, the condensed cyclic compound represented by Formula 1 may be represented by one selected from Formulae 1-1 to 1-9:

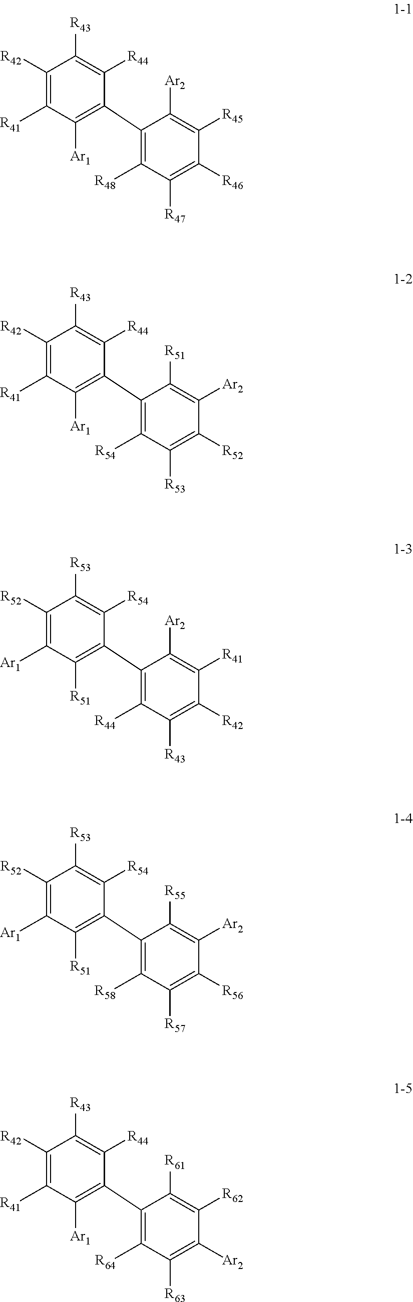

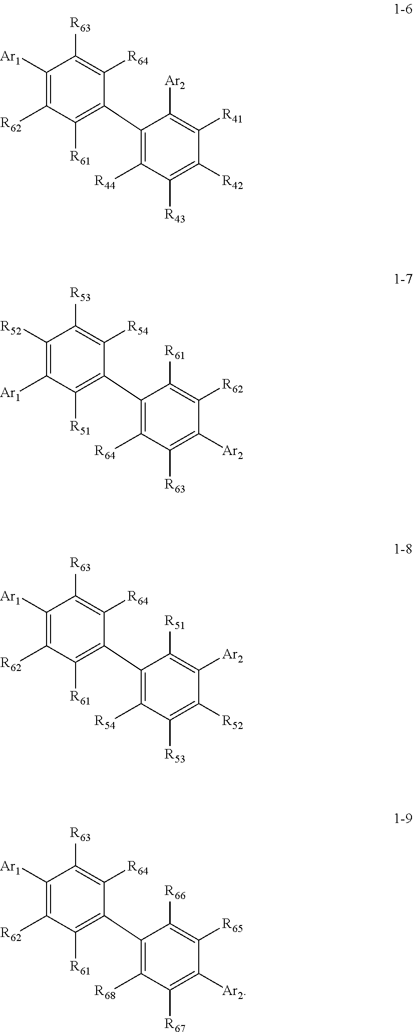

In Formulae 1-1 to 1-9,

Ar₁ and Ar₂ may each independently be the same as described above,

R₄₁ to R₄₈ may each independently have the same definition as R₄₀,

R₅₁ to R₅₈ may each independently have the same definition as R₅₀, and

R₆₁ to R₆₈ may each independently have the same definition as R₆₀.

In an embodiment, in Formulae 1-1 to 1-9, R₄₁ to R₄₈, R₅₁ to R₅₈, and R₆₁ to R₆₈ may each independently be selected from:

hydrogen, deuterium, —F, —Cl, —Br, —I, a cyano group, a C₁-C₂₀ alkyl group, and a C₁-C₂₀ alkoxy group;

a C₁-C₂₀ alkyl group and a C₁-C₂₀ alkoxy group, each substituted with at least one selected from deuterium, a phenyl group, a biphenyl group, a terphenyl group, and a naphthyl group;

a cyclopentyl group, a cyclohexyl group, a cyclopentenyl group, a cyclohexenyl group, a cycloheptenyl group, a phenyl group, a biphenyl group, a terphenyl group, a naphthyl group, a fluorenyl group, a carbazolyl group, a dibenzofuranyl group, and a dibenzothiophenyl group;

a cyclopentyl group, a cyclohexyl group, a cyclopentenyl group, a cyclohexenyl group, a cycloheptenyl group, a phenyl group, a biphenyl group, a terphenyl group, a naphthyl group, a fluorenyl group, a carbazolyl group, a dibenzofuranyl group, and a dibenzothiophenyl group, each substituted with at least one selected from deuterium, a C₁-C₂₀ alkyl group, a C₁-C₂₀ alkoxy group, a phenyl group, a biphenyl group, a terphenyl group, a naphthyl group, and —Si(Q₃₁)(Q₃₂)(Q₃₃); and

—Si(Q₁)(Q₂)(Q₃), and

Q₁ to Q₃ and Q₃₁ to Q₃₃ may each independently be selected from hydrogen, a C₁-C₂₀ alkyl group, a C₁-C₂₀ alkoxy group, a phenyl group, a biphenyl group, a terphenyl group, and a naphthyl group.

In one or more embodiments, in Formulae 1-1 to 1-9, Ar₁ may be a group represented by one selected from Formulae 2-1 to 2-7, and Ar₂ may be a group represented by one selected from Formulae 3-1 to 3-7 and 4-1 to 4-19.

In an embodiment, the number of the carbazole group included in the condensed cyclic compound represented by Formula 1 may be 1, 2, 3, or 4.

In an embodiment, the number of the carbazole group included in R₁₀ in Formula 1 may be 1 or 2.

In an embodiment, the condensed cyclic compound represented by Formula 1 may be selected from Compounds 1 to 168, but embodiments of the present disclosure are not limited thereto:

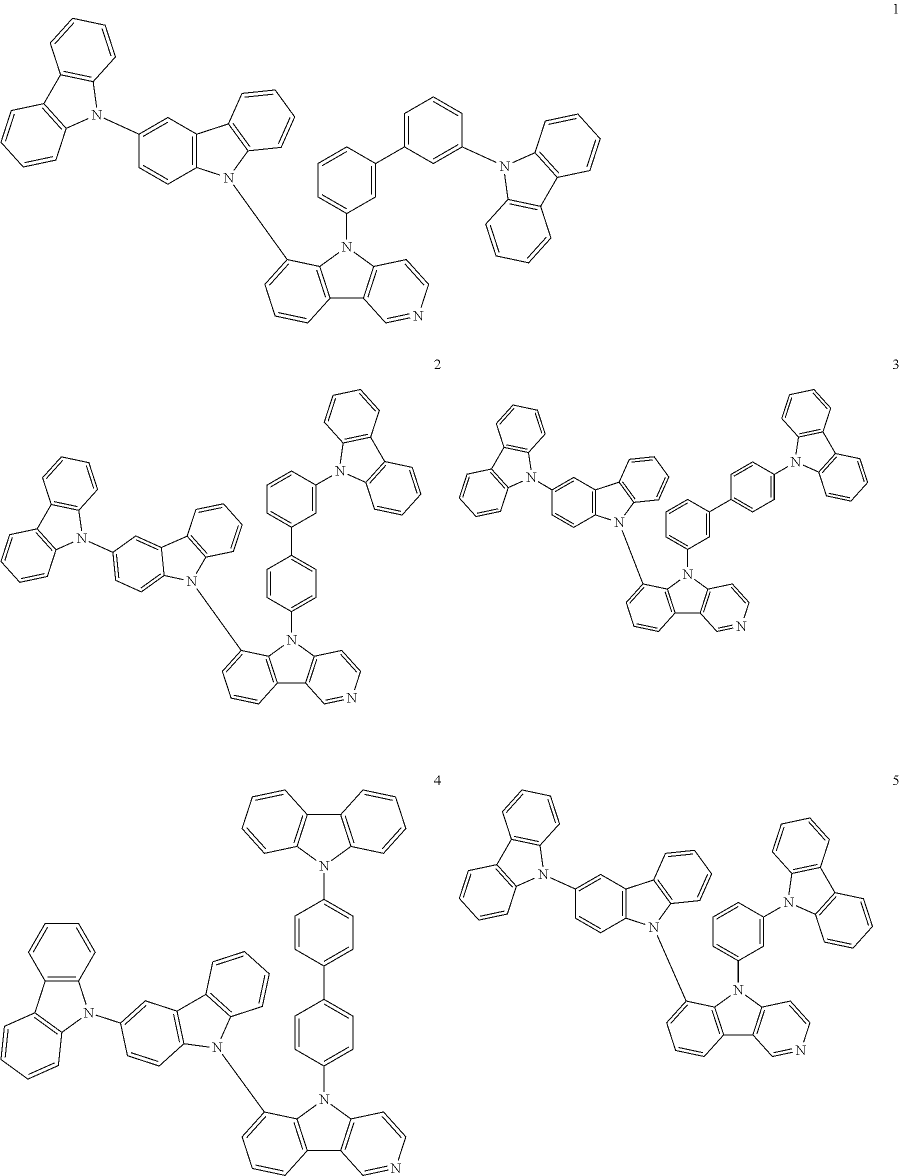

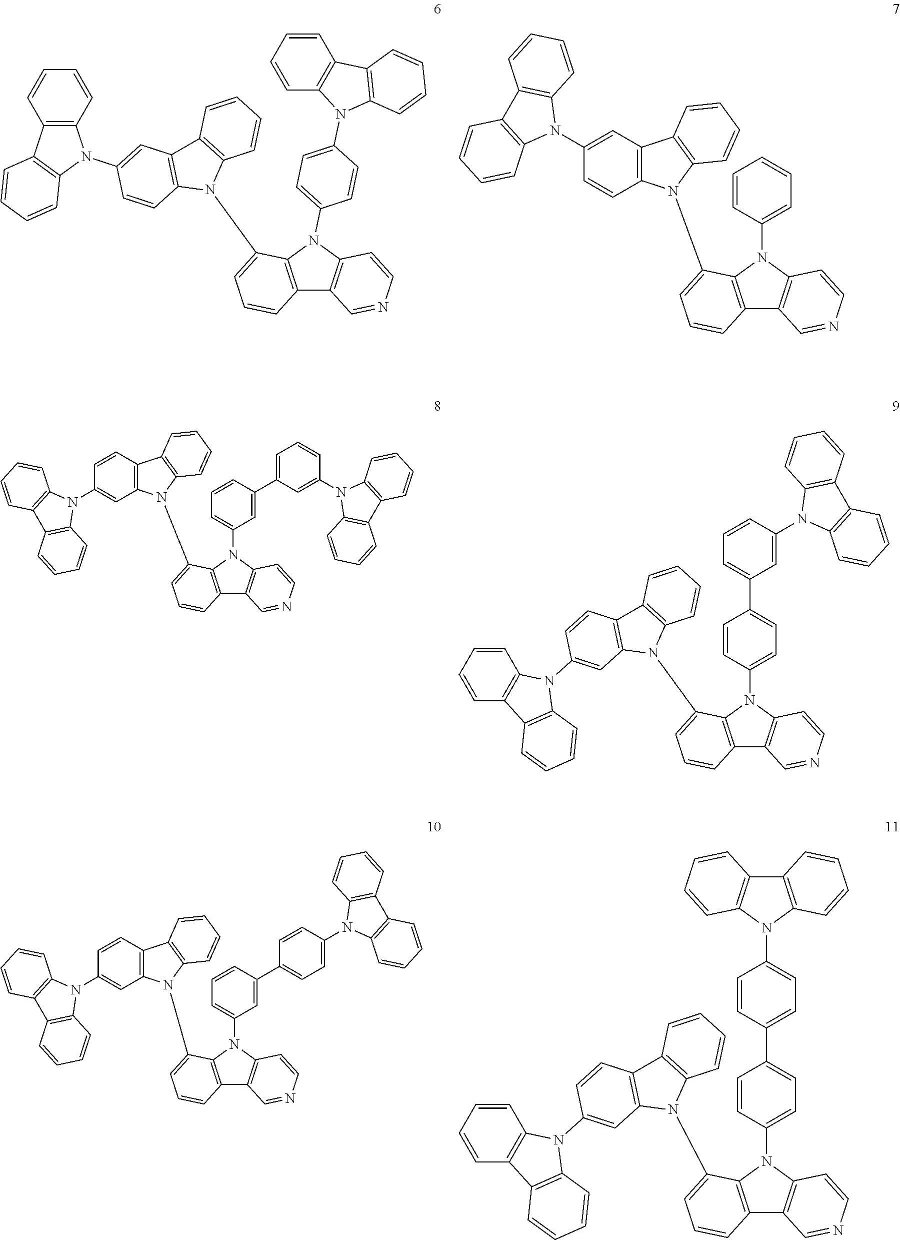

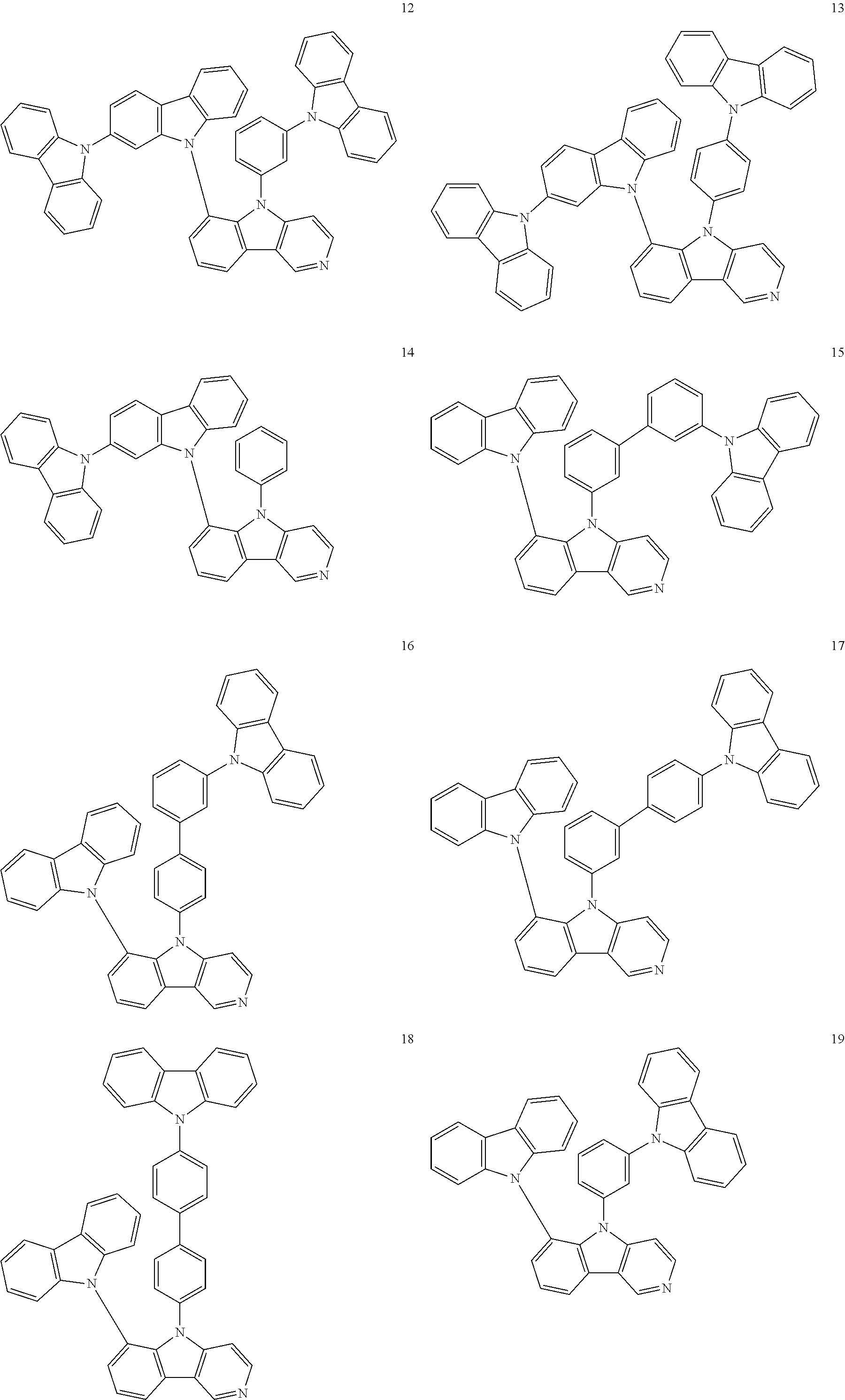

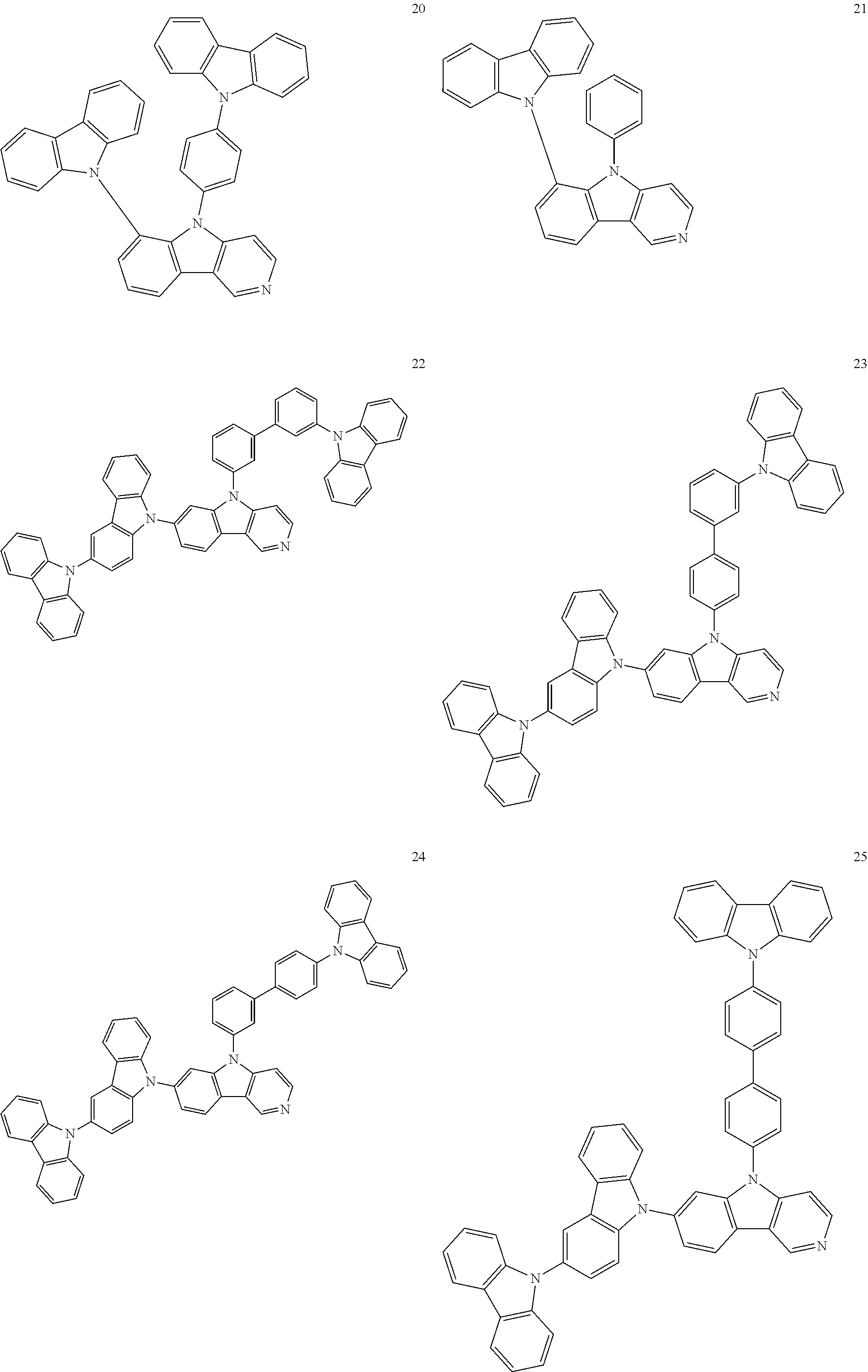

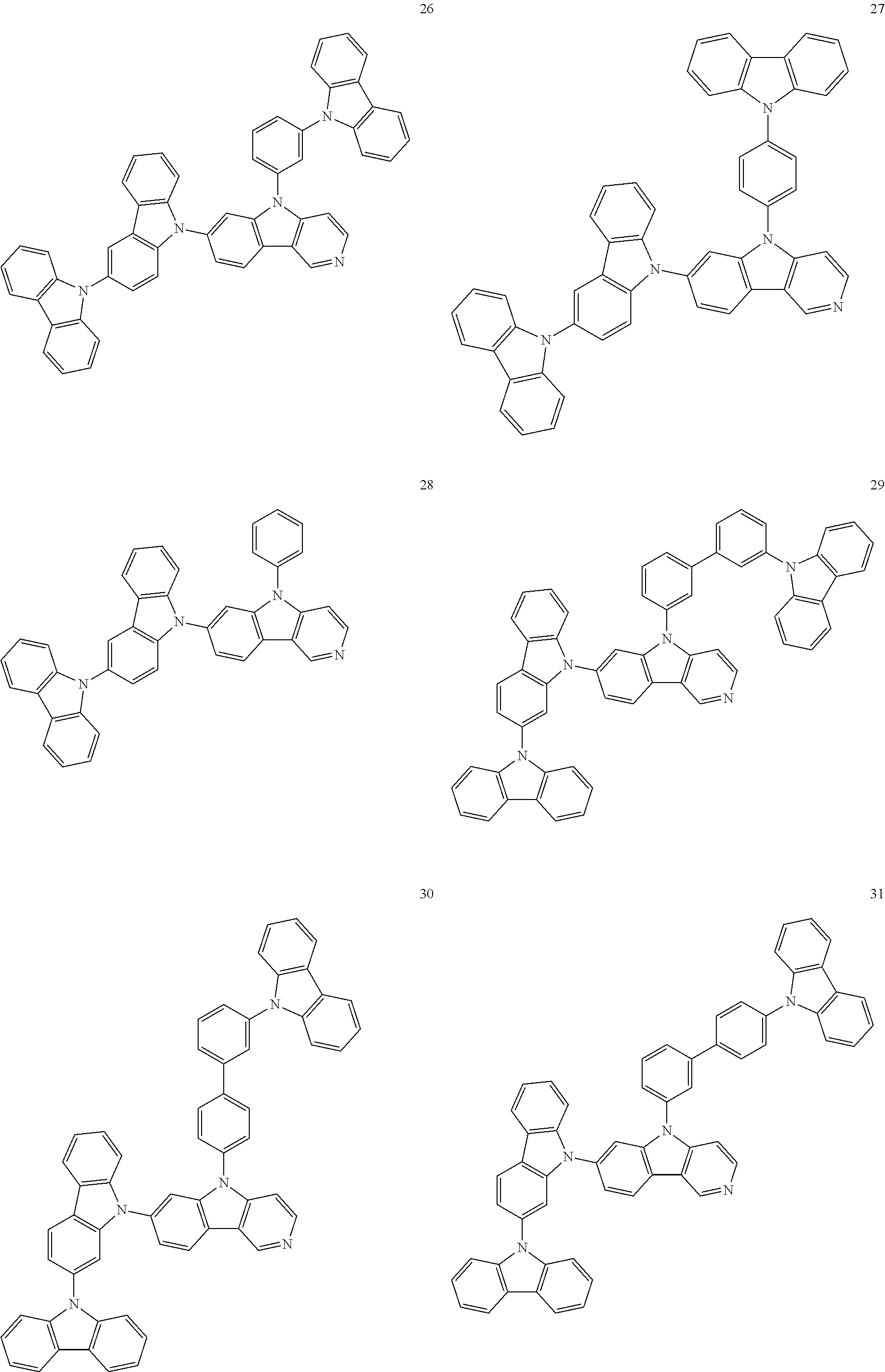

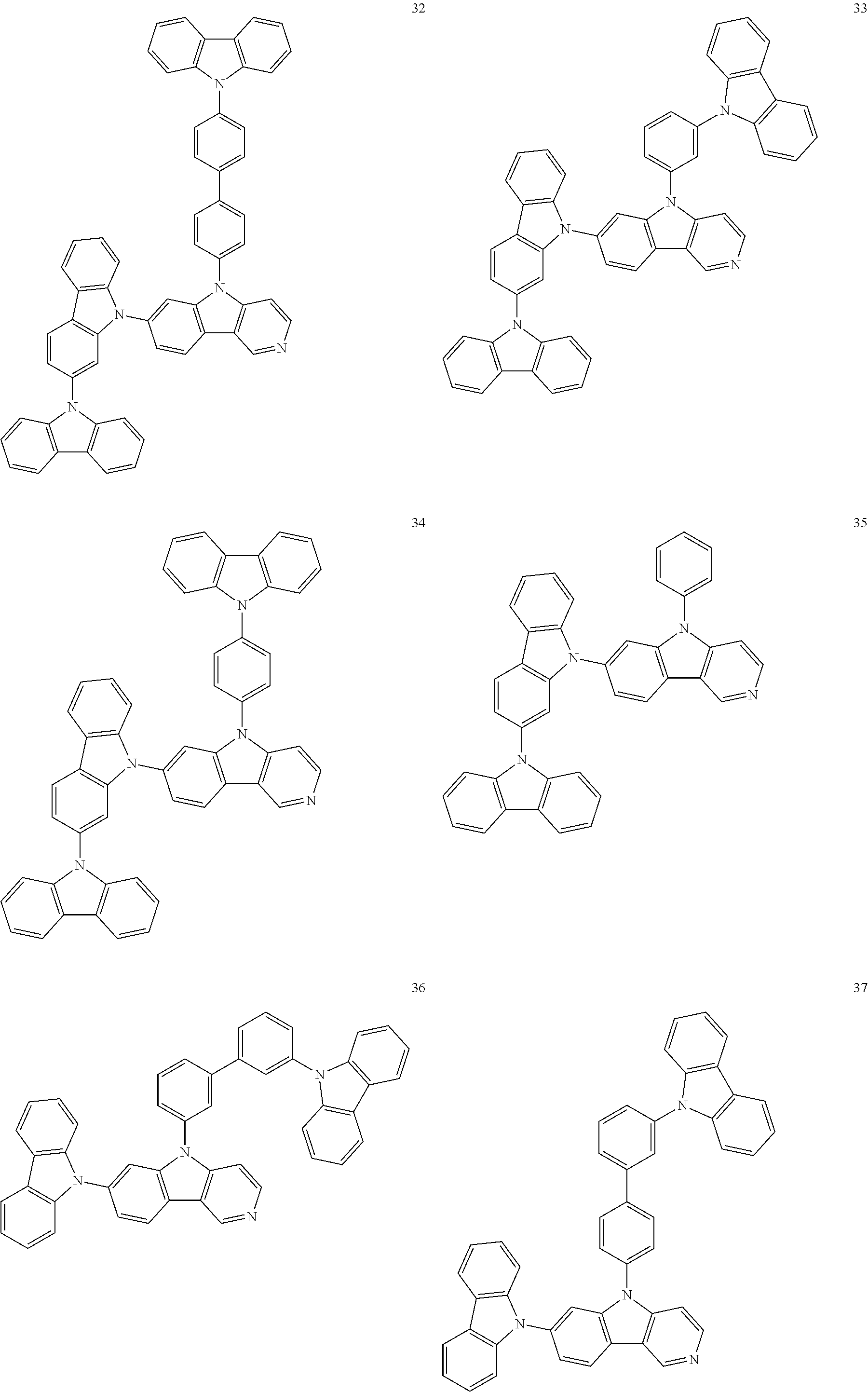

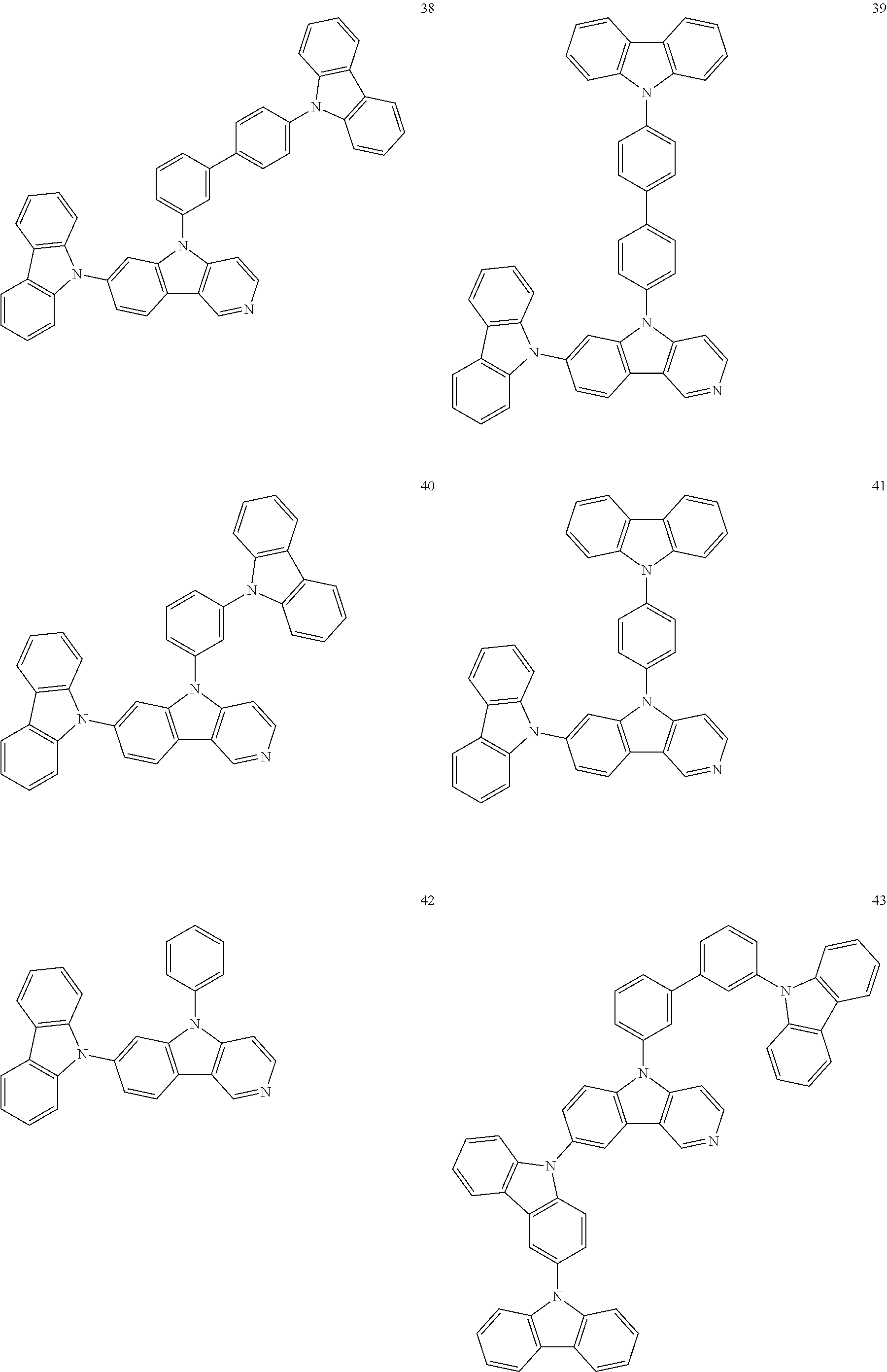 [SMILES: c1cc(-c2ccc(-n3c4ccccc4c4ccccc43)cc2)cc(-n2c3ccncc3c3ccc(-n4c5ccccc5c5ccccc54)cc32)c1 ; c1ccc2c(c1)c1ccccc1n2-c1ccc(-c2ccc(-n3c4ccncc4c4ccc(-n5c6ccccc6c6ccccc65)cc43)cc2)cc1 ; c1cc(-n2c3ccccc3c3ccccc32)cc(-n2c3ccncc3c3ccc(-n4c5ccccc5c5ccccc54)cc32)c1 ; c1ccc2c(c1)c1ccccc1n2-c1ccc(-n2c3ccncc3c3ccc(-n4c5ccccc5c5ccccc54)cc32)cc1 ; c1ccc(-n2c3ccncc3c3ccc(-n4c5ccccc5c5ccccc54)cc32)cc1 ; c1cc(-c2cccc(-n3c4ccncc4c4cc(-n5c6ccccc6c6cc(-n7c8ccccc8c8ccccc87)ccc65)ccc43)c2)cc(-n2c3ccccc3c3ccccc32)c1]

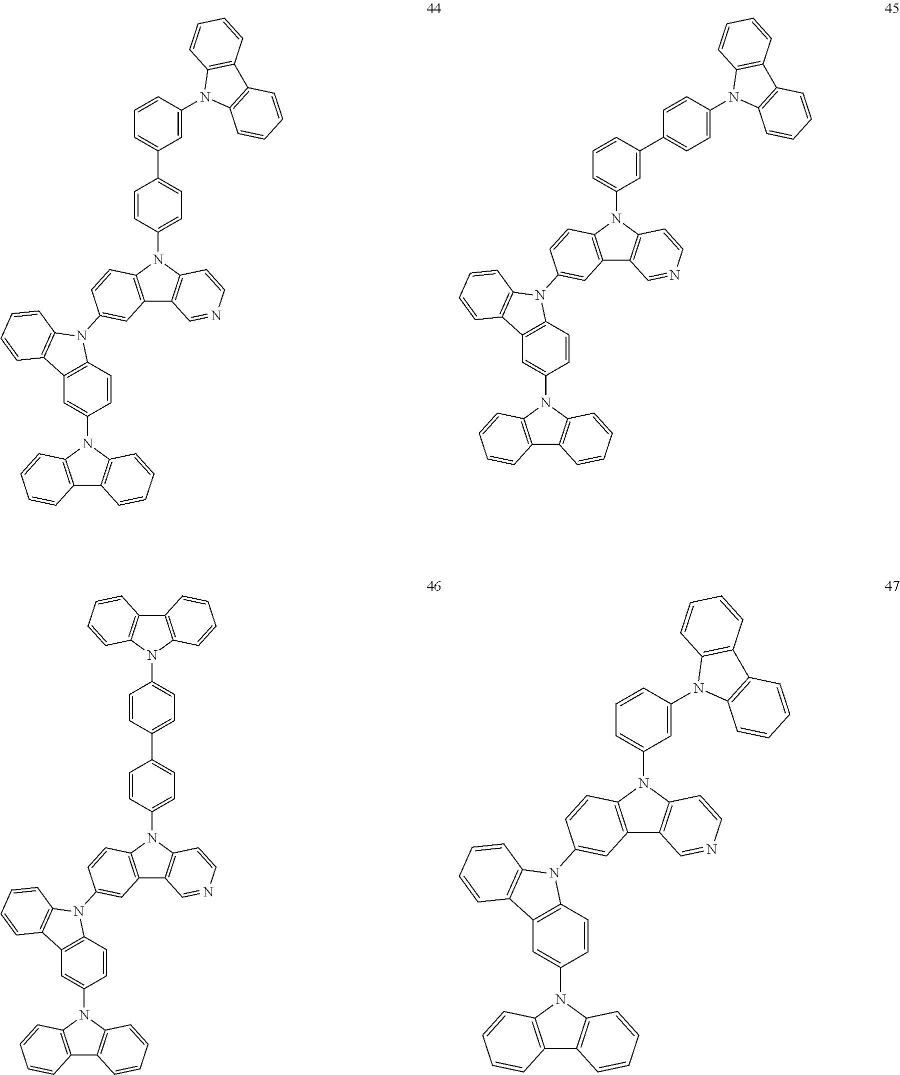 [SMILES: c1cc(-c2ccc(-n3c4ccncc4c4cc(-n5c6ccccc6c6cc(-n7c8ccccc8c8ccccc87)ccc65)ccc43)cc2)cc(-n2c3ccccc3c3ccccc32)c1 ; c1cc(-c2ccc(-n3c4ccccc4c4ccccc43)cc2)cc(-n2c3ccncc3c3cc(-n4c5ccccc5c5cc(-n6c7ccccc7c7ccccc76)ccc54)ccc32)c1 ; c1ccc2c(c1)c1ccccc1n2-c1ccc(-c2ccc(-n3c4ccncc4c4cc(-n5c6ccccc6c6cc(-n7c8ccccc8c8ccccc87)ccc65)ccc43)cc2)cc1 ; c1cc(-n2c3ccccc3c3ccccc32)cc(-n2c3ccncc3c3cc(-n4c5ccccc5c5cc(-n6c7ccccc7c7ccccc76)ccc54)ccc32)c1]

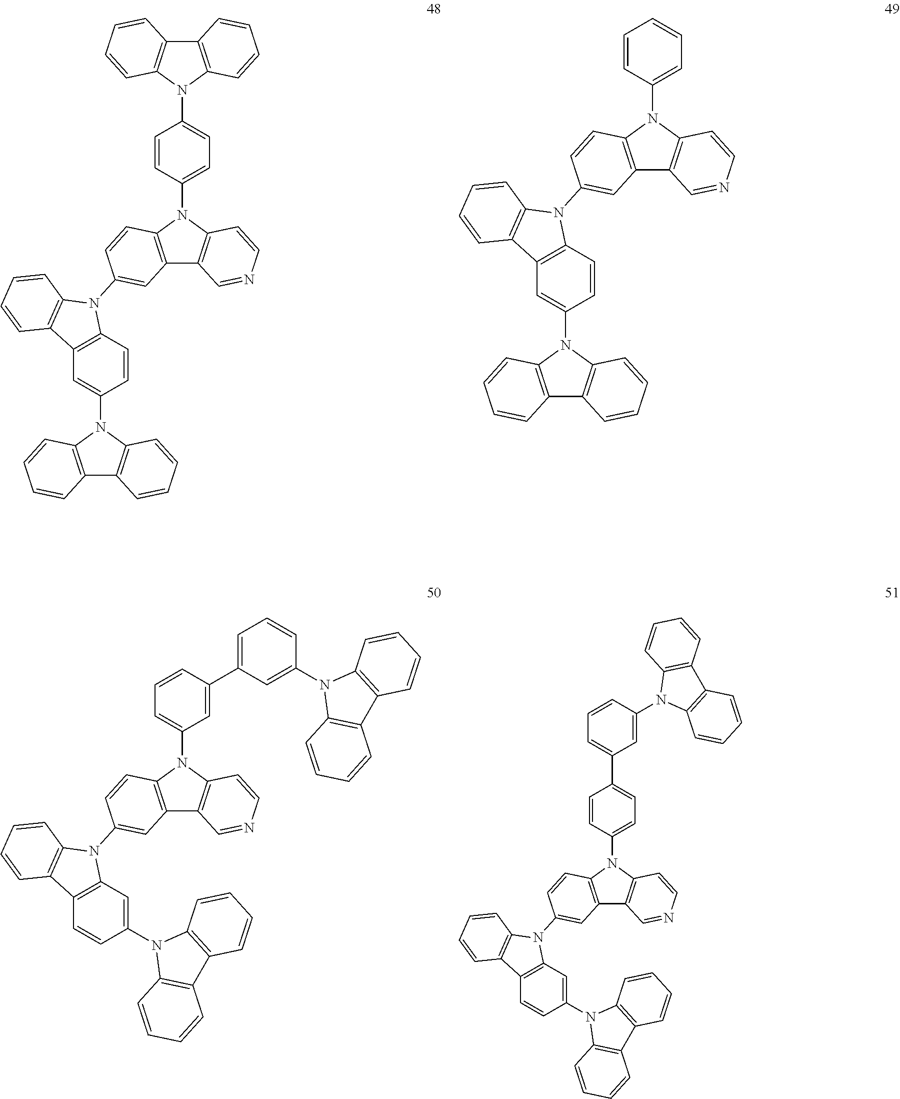 [SMILES: c1ccc2c(c1)c1ccccc1n2-c1ccc(-n2c3ccncc3c3cc(-n4c5ccccc5c5cc(-n6c7ccccc7c7ccccc76)ccc54)ccc32)cc1 ; c1ccc(-n2c3ccncc3c3cc(-n4c5ccccc5c5cc(-n6c7ccccc7c7ccccc76)ccc54)ccc32)cc1 ; c1cc(-c2cccc(-n3c4ccncc4c4cc(-n5c6ccccc6c6ccc(-n7c8ccccc8c8ccccc87)cc65)ccc43)c2)cc(-n2c3ccccc3c3ccccc32)c1 ; c1cc(-c2ccc(-n3c4ccncc4c4cc(-n5c6ccccc6c6ccc(-n7c8ccccc8c8ccccc87)cc65)ccc43)cc2)cc(-n2c3ccccc3c3ccccc32)c1]

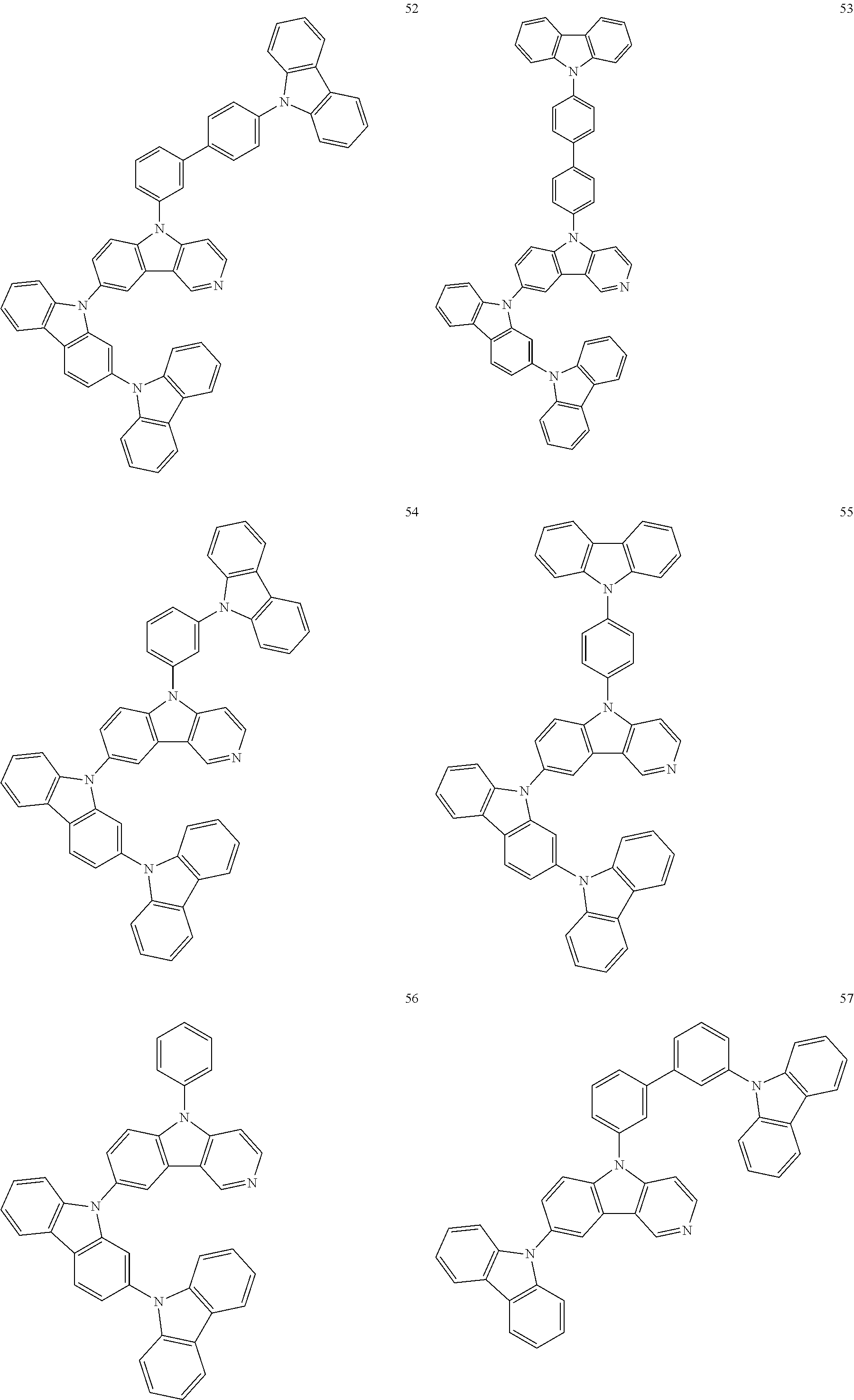

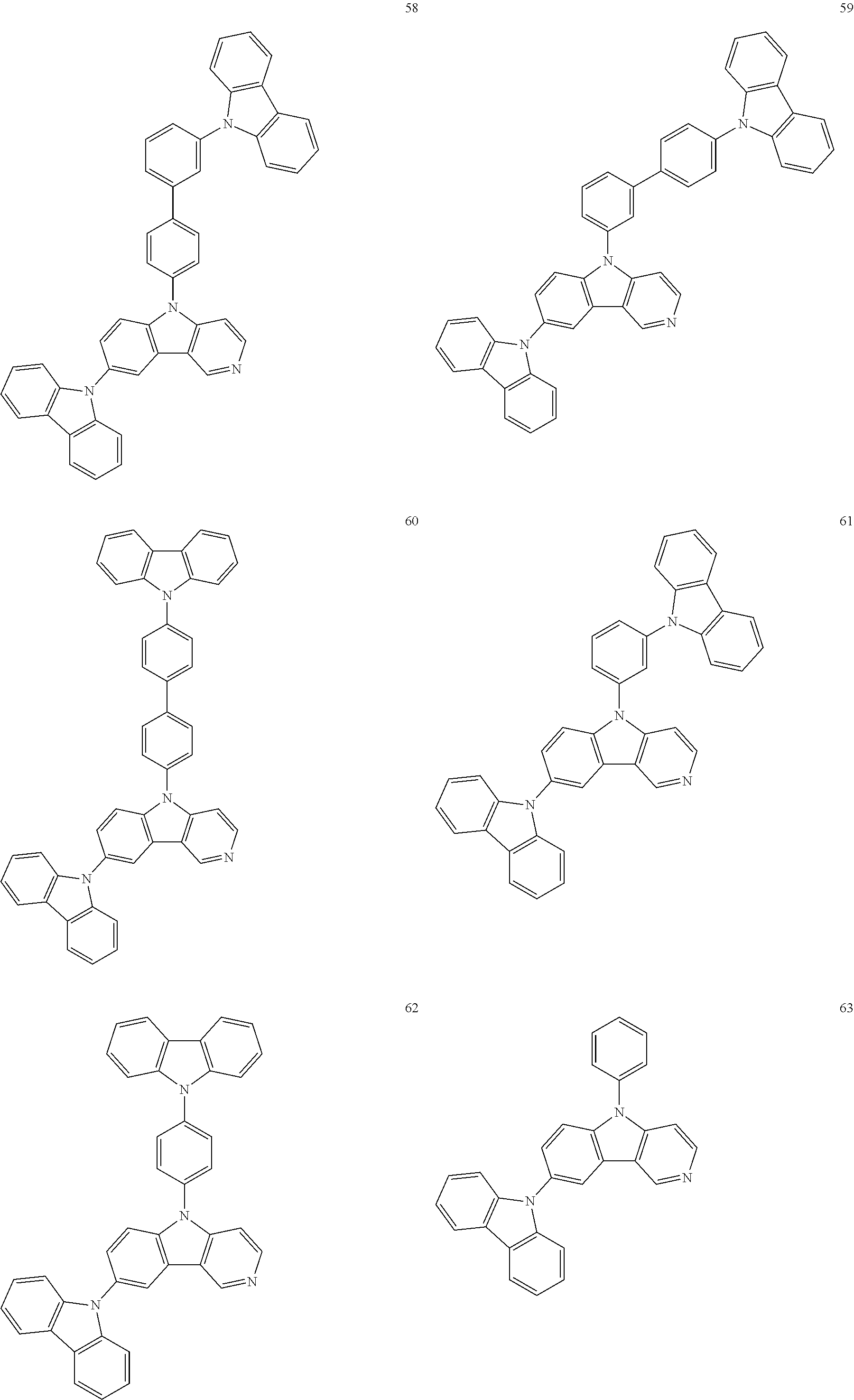 [SMILES: c1cc(-c2ccc(-n3c4ccncc4c4cc(-n5c6ccccc6c6ccccc65)ccc43)cc2)cc(-n2c3ccccc3c3ccccc32)c1 ; c1cc(-c2ccc(-n3c4ccccc4c4ccccc43)cc2)cc(-n2c3ccncc3c3cc(-n4c5ccccc5c5ccccc54)ccc32)c1 ; c1ccc2c(c1)c1ccccc1n2-c1ccc(-c2ccc(-n3c4ccncc4c4cc(-n5c6ccccc6c6ccccc65)ccc43)cc2)cc1 ; c1cc(-n2c3ccccc3c3ccccc32)cc(-n2c3ccncc3c3cc(-n4c5ccccc5c5ccccc54)ccc32)c1 ; c1ccc2c(c1)c1ccccc1n2-c1ccc(-n2c3ccncc3c3cc(-n4c5ccccc5c5ccccc54)ccc32)cc1 ; c1ccc(-n2c3ccncc3c3cc(-n4c5ccccc5c5ccccc54)ccc32)cc1]

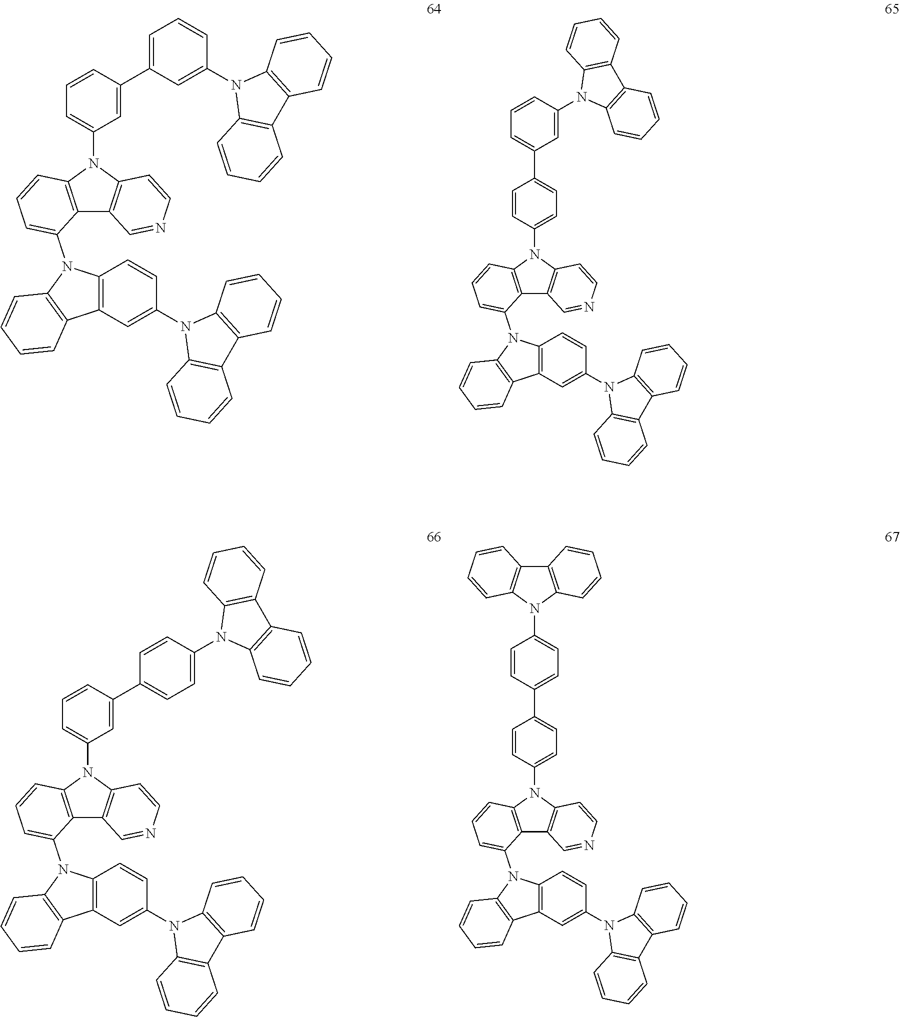 [SMILES: c1cc(-c2cccc(-n3c4ccncc4c4c(-n5c6ccccc6c6cc(-n7c8ccccc8c8ccccc87)ccc65)cccc43)c2)cc(-n2c3ccccc3c3ccccc32)c1 ; c1cc(-c2ccc(-n3c4ccncc4c4c(-n5c6ccccc6c6cc(-n7c8ccccc8c8ccccc87)ccc65)cccc43)cc2)cc(-n2c3ccccc3c3ccccc32)c1 ; c1cc(-c2ccc(-n3c4ccccc4c4ccccc43)cc2)cc(-n2c3ccncc3c3c(-n4c5ccccc5c5cc(-n6c7ccccc7c7ccccc76)ccc54)cccc32)c1 ; c1ccc2c(c1)c1ccccc1n2-c1ccc(-c2ccc(-n3c4ccncc4c4c(-n5c6ccccc6c6cc(-n7c8ccccc8c8ccccc87)ccc65)cccc43)cc2)cc1]

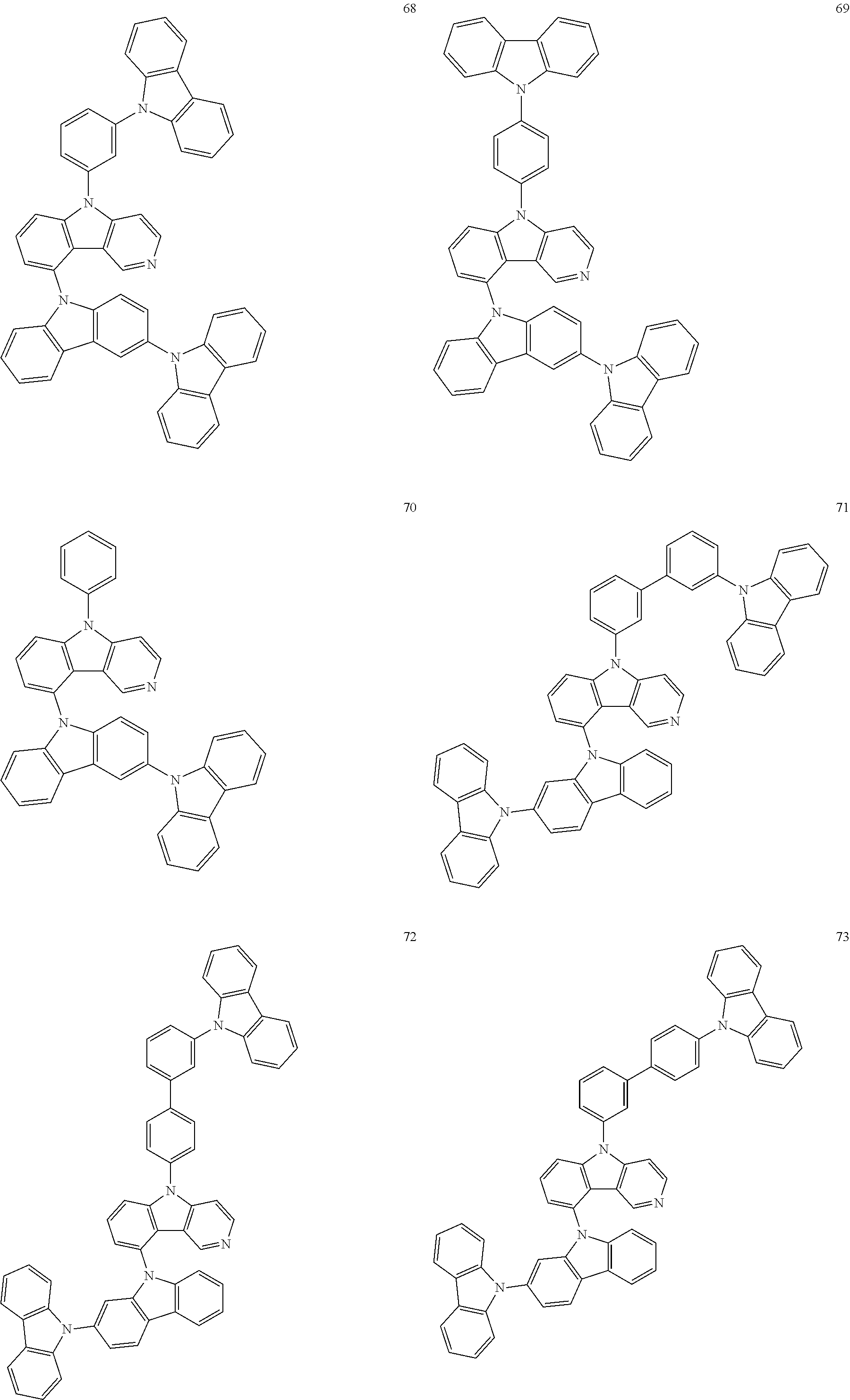

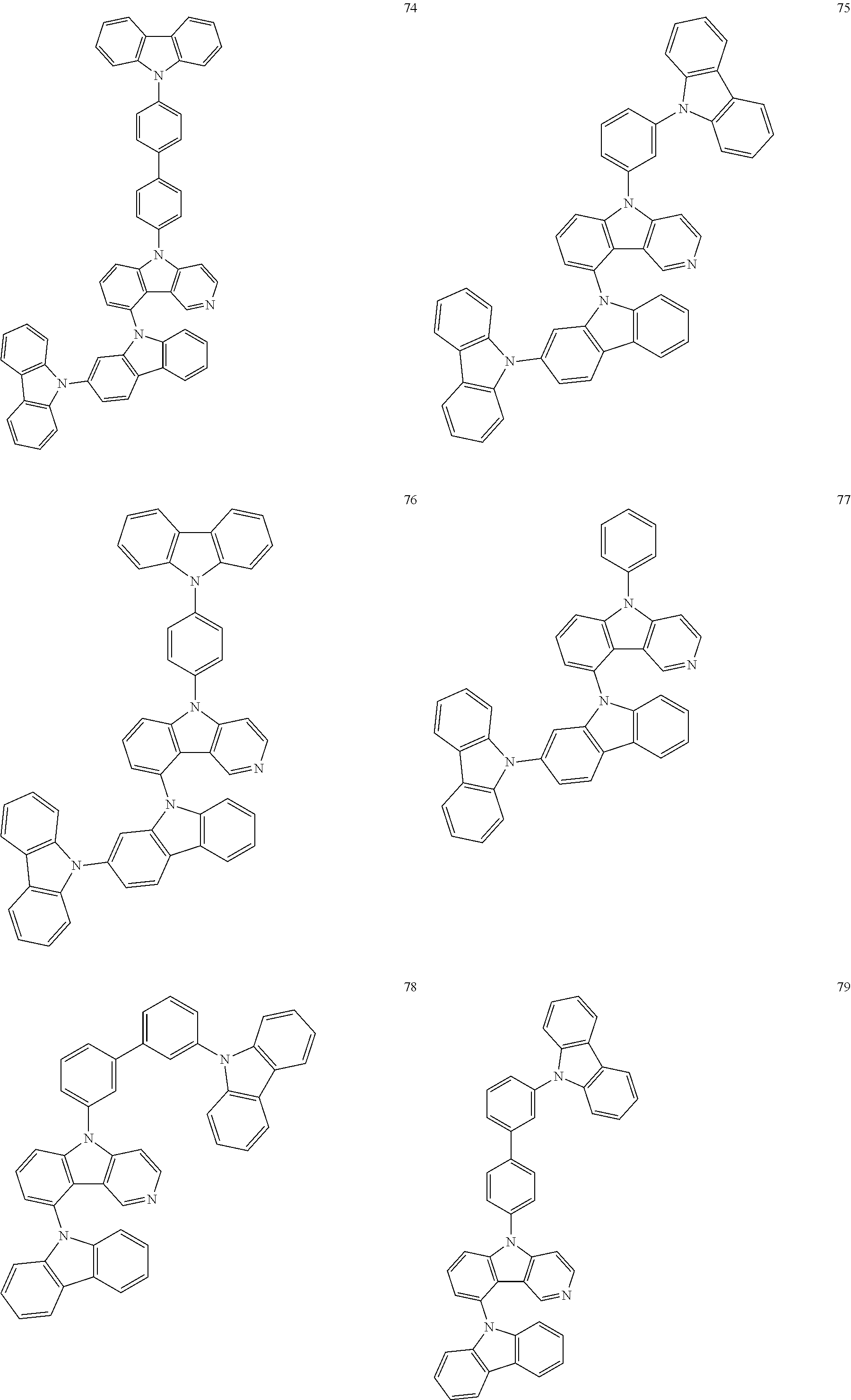

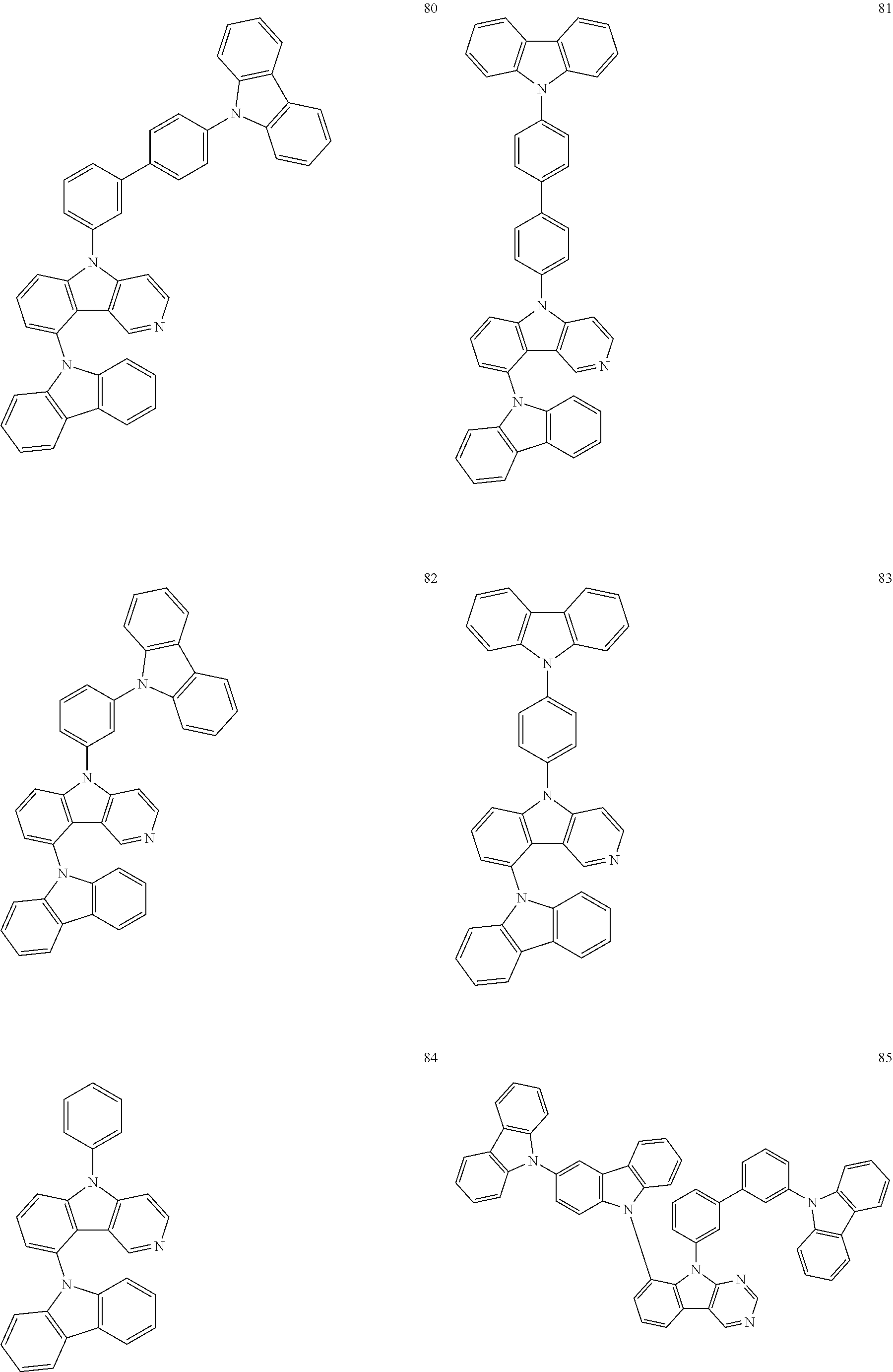 [SMILES: c1cc(-c2ccc(-n3c4ccccc4c4ccccc43)cc2)cc(-n2c3ccncc3c3c(-n4c5ccccc5c5ccccc54)cccc32)c1 ; c1ccc2c(c1)c1ccccc1n2-c1ccc(-c2ccc(-n3c4ccncc4c4c(-n5c6ccccc6c6ccccc65)cccc43)cc2)cc1 ; c1cc(-n2c3ccccc3c3ccccc32)cc(-n2c3ccncc3c3c(-n4c5ccccc5c5ccccc54)cccc32)c1 ; c1ccc2c(c1)c1ccccc1n2-c1ccc(-n2c3ccncc3c3c(-n4c5ccccc5c5ccccc54)cccc32)cc1 ; c1ccc(-n2c3ccncc3c3c(-n4c5ccccc5c5ccccc54)cccc32)cc1 ; c1cc(-c2cccc(-n3c4ncncc4c4cccc(-n5c6ccccc6c6cc(-n7c8ccccc8c8ccccc87)ccc65)c43)c2)cc(-n2c3ccccc3c3ccccc32)c1]

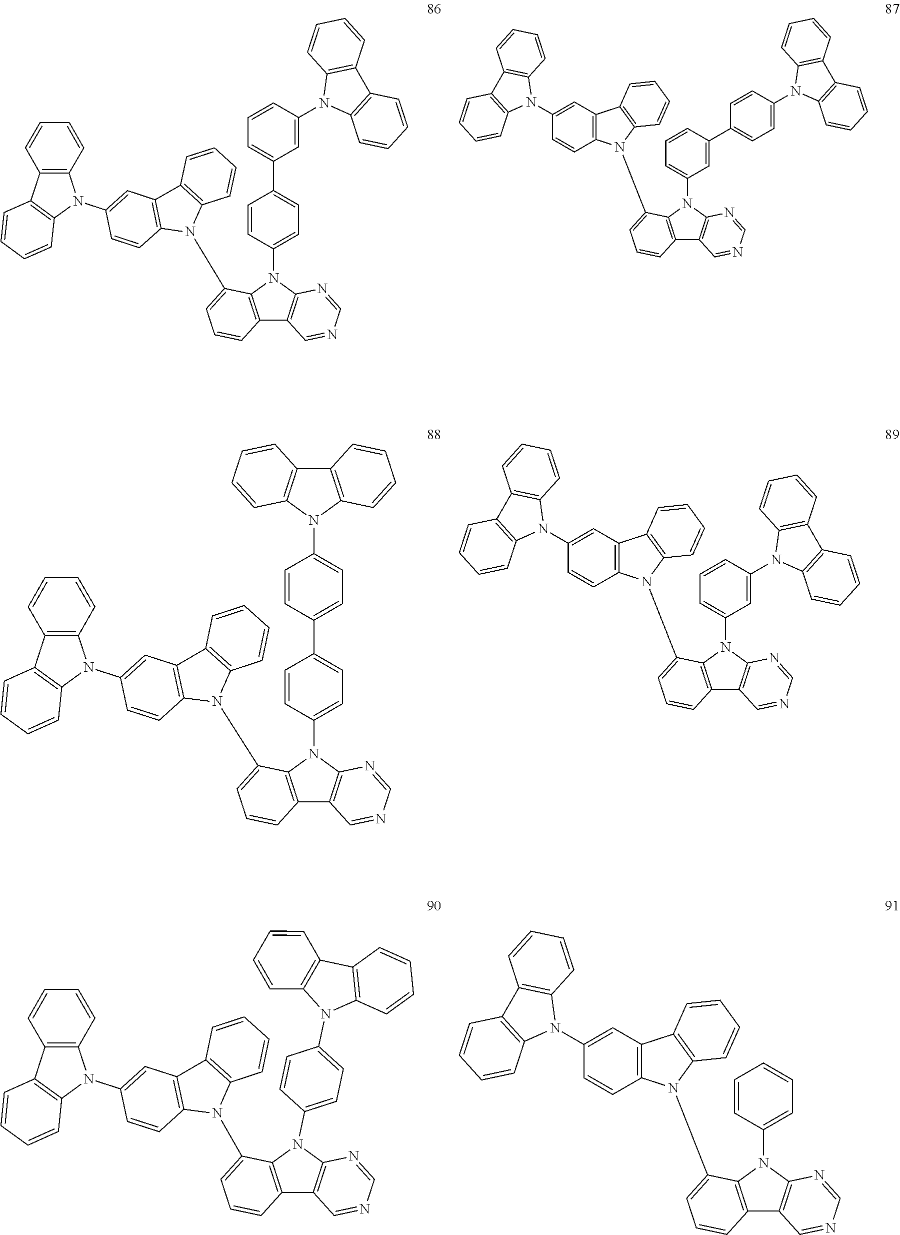

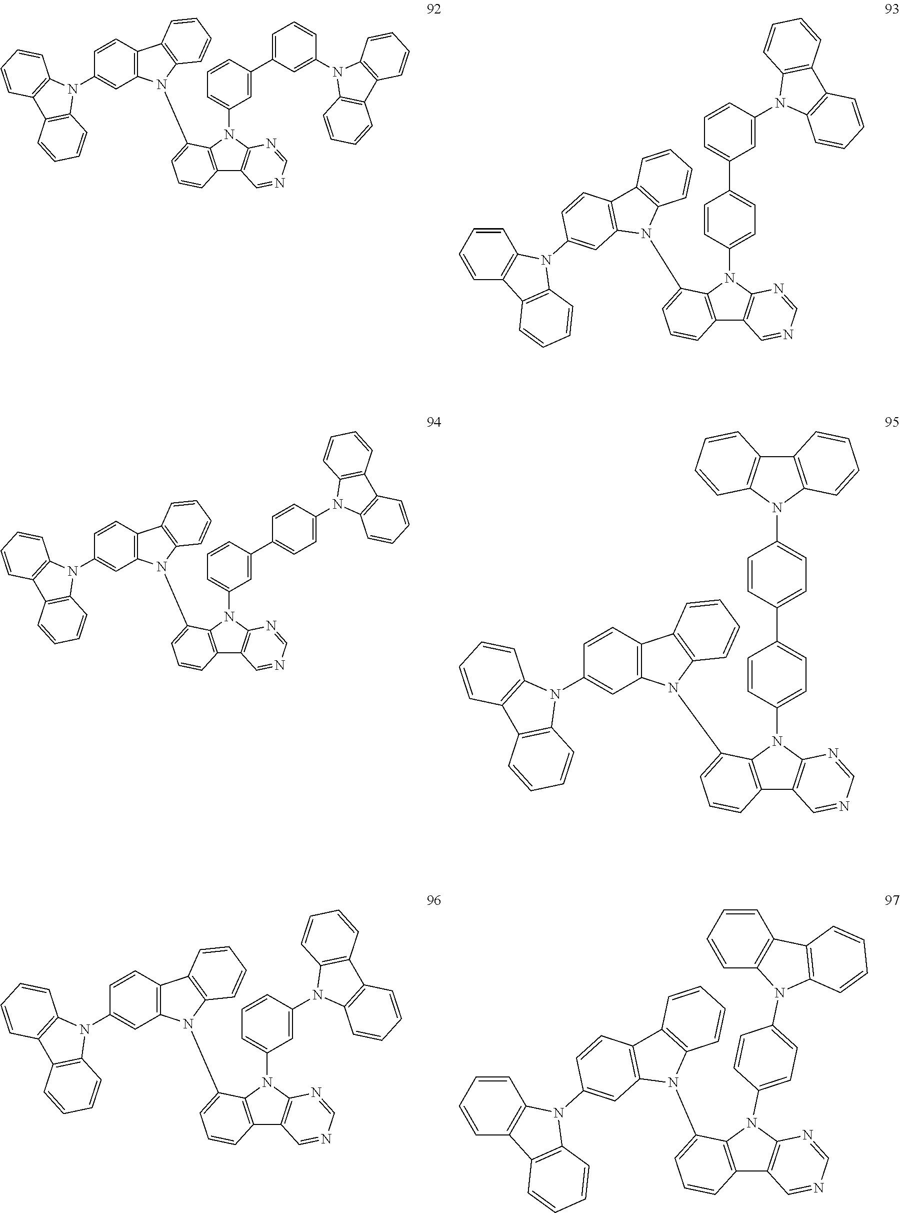

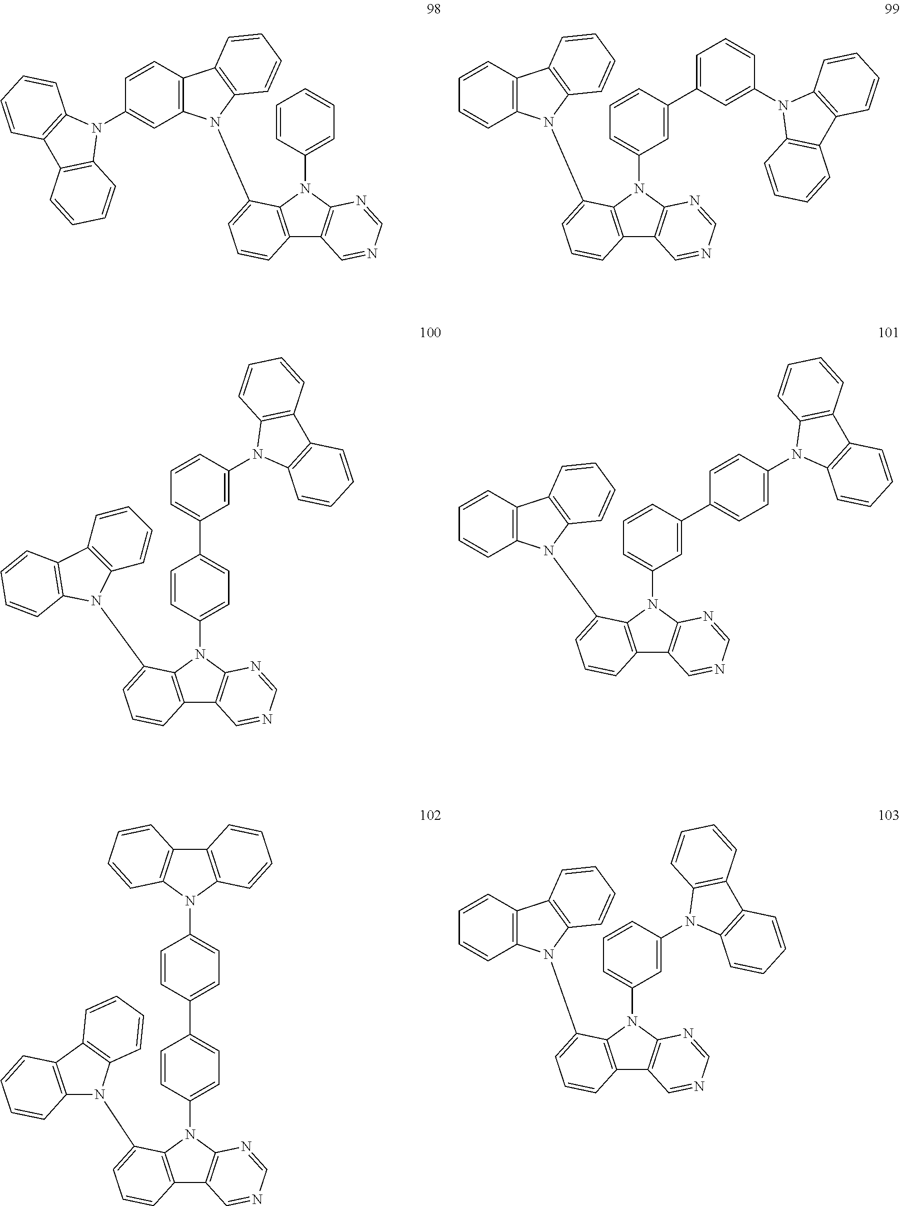

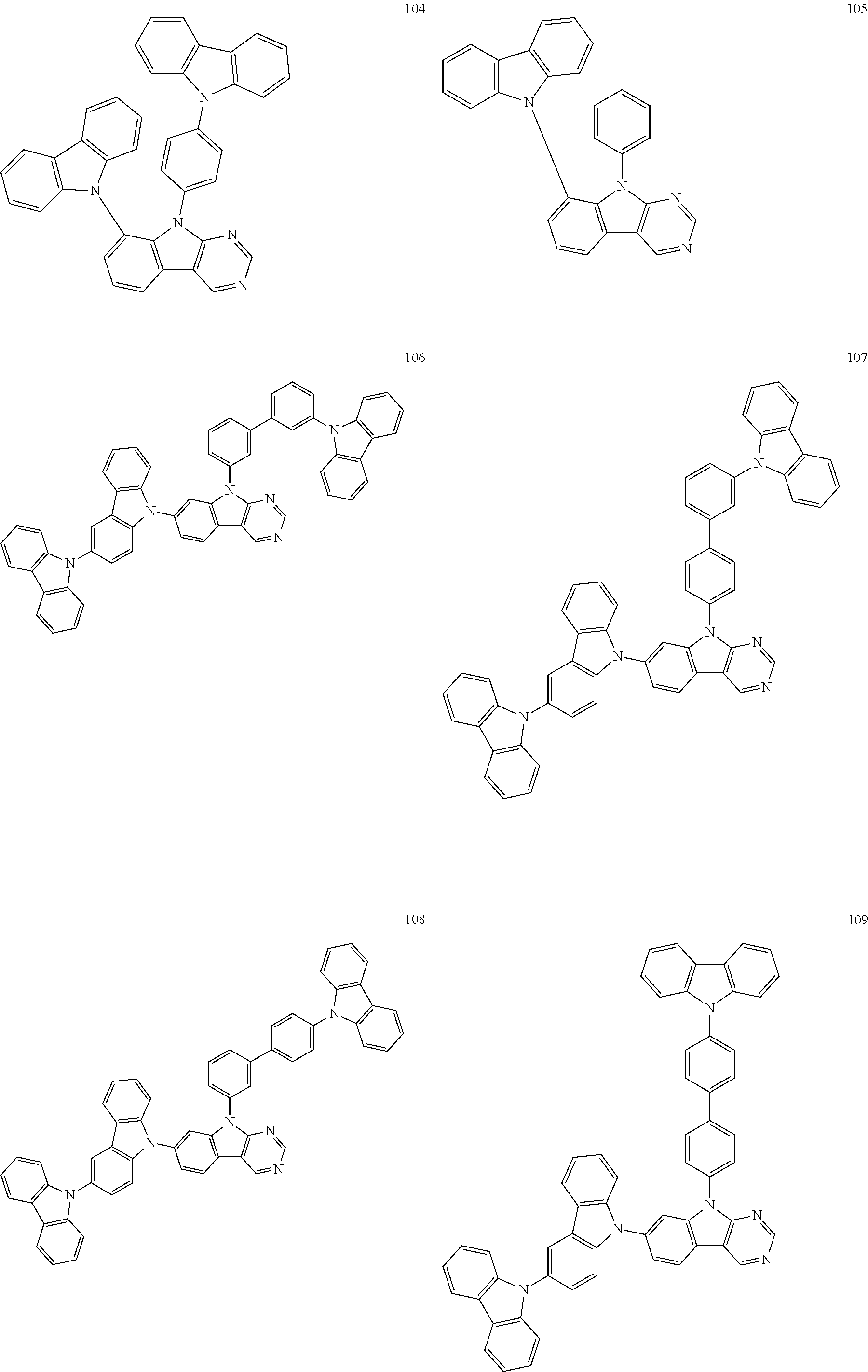

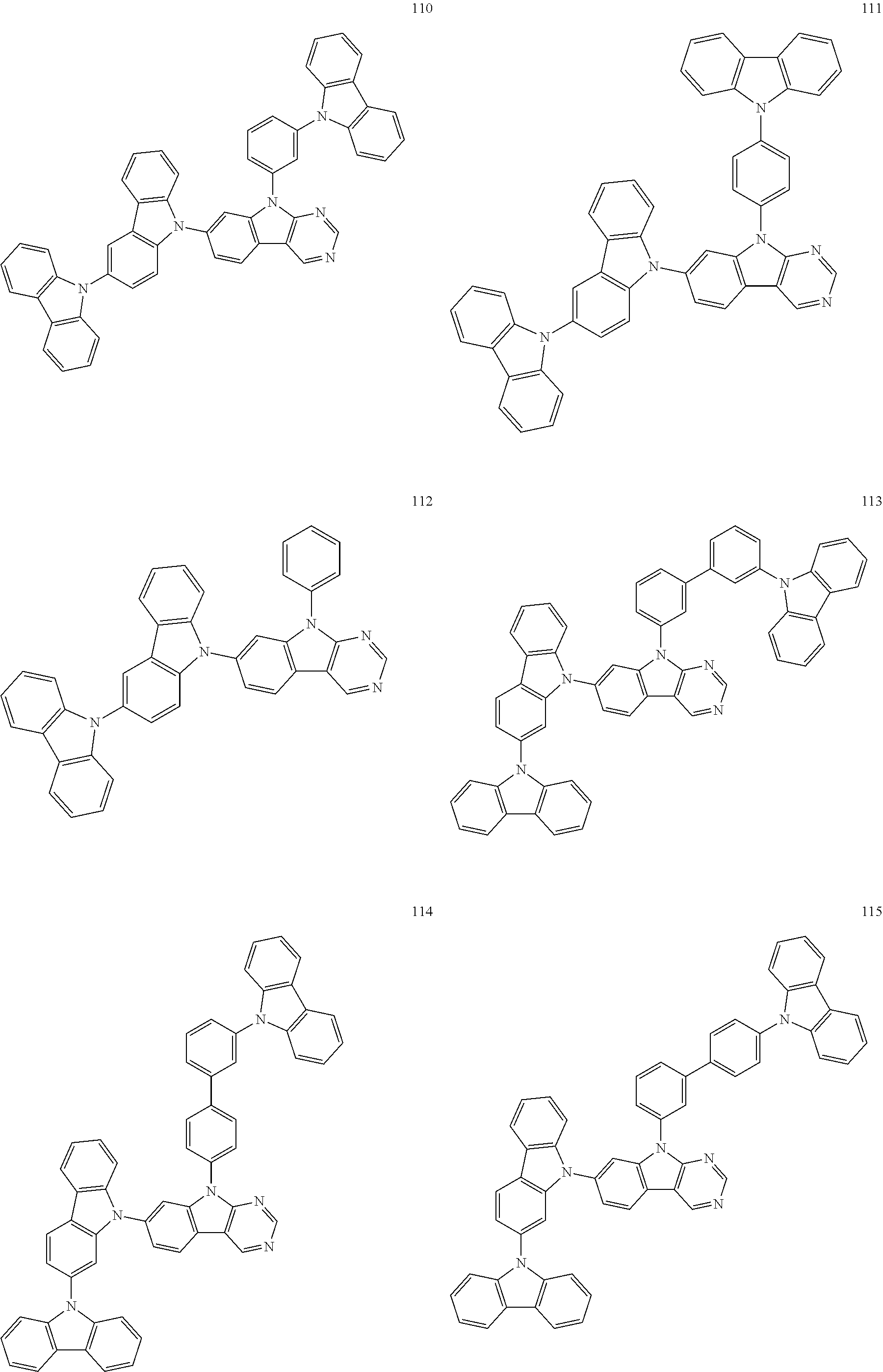

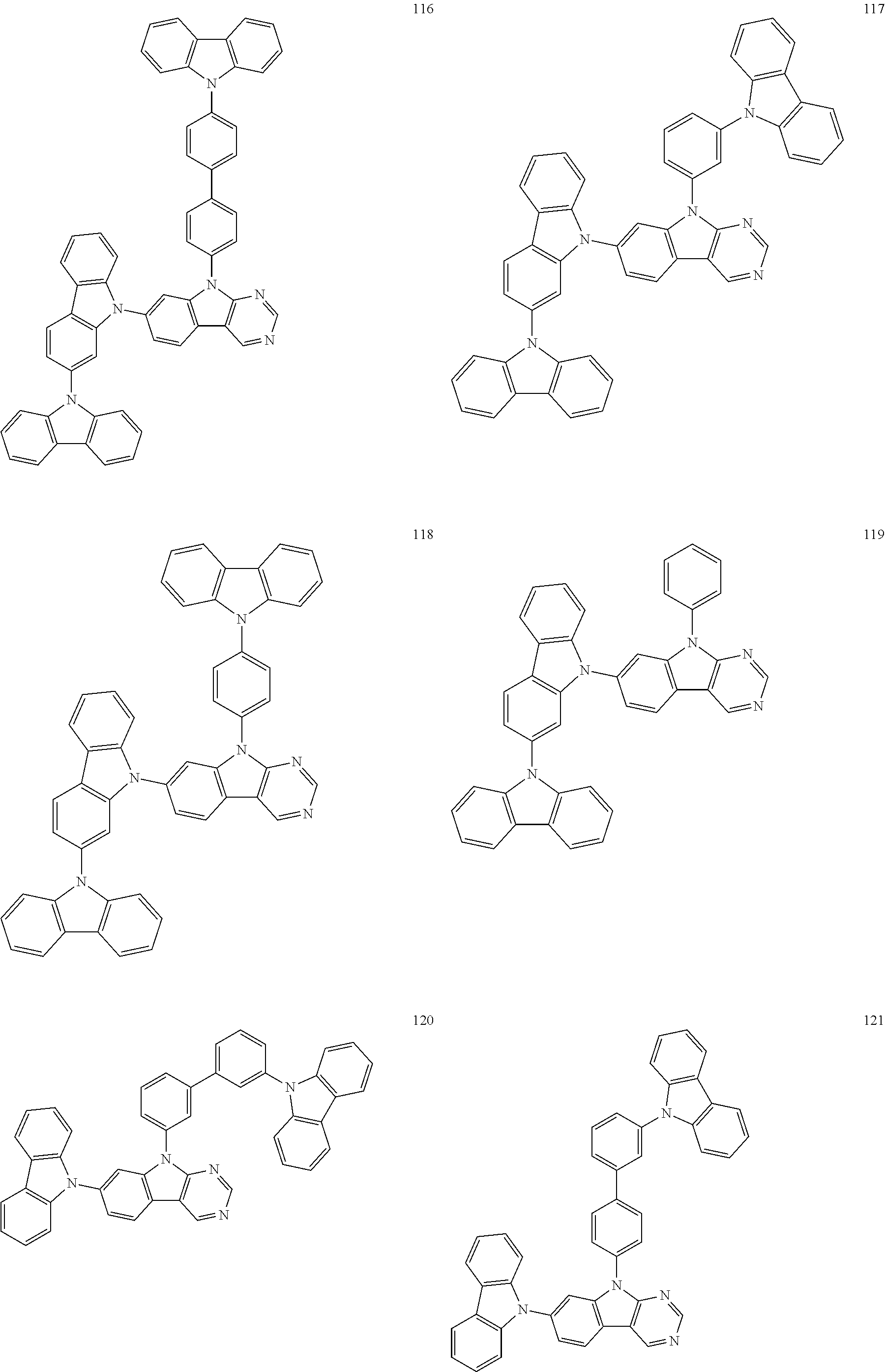

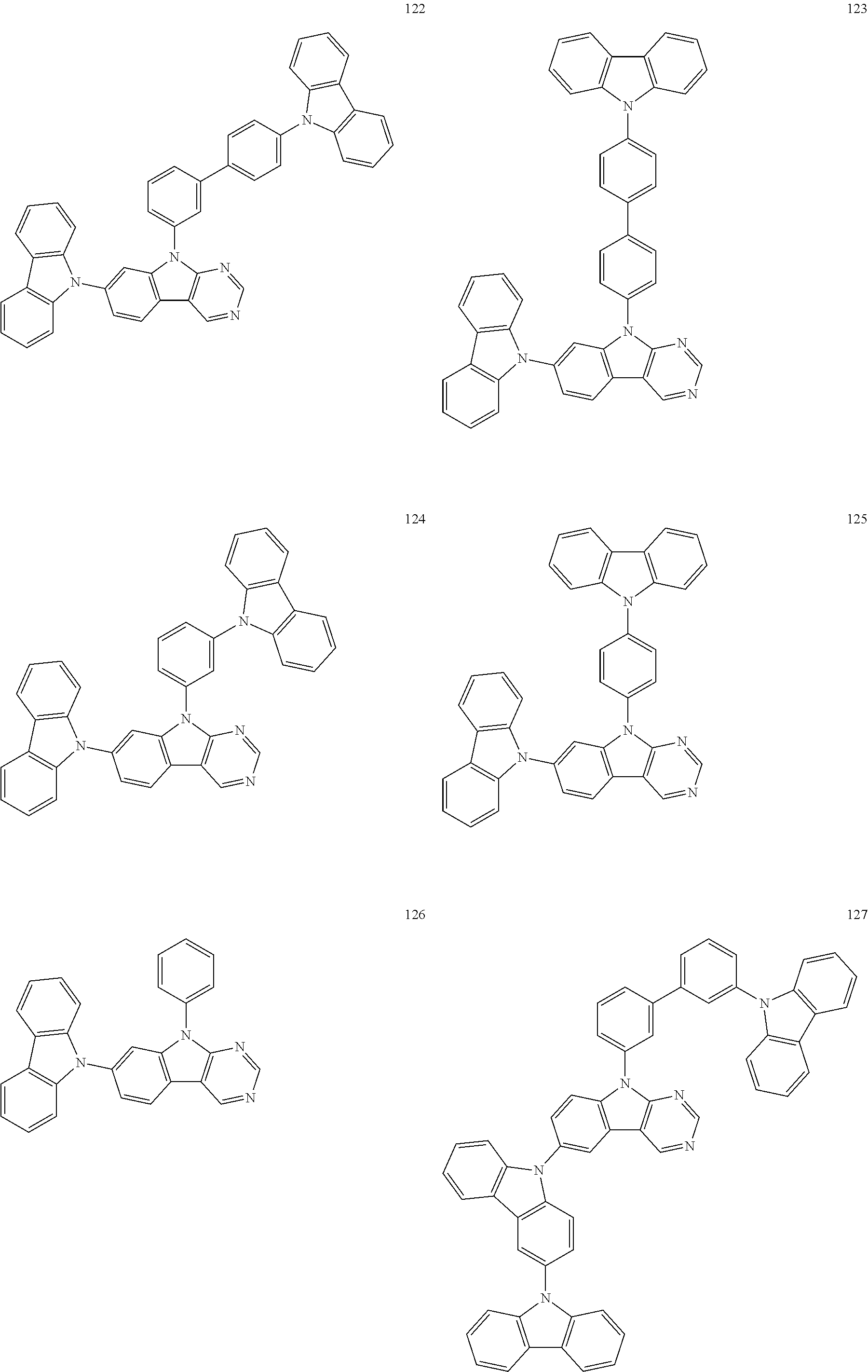 [SMILES: c1cc(-c2ccc(-n3c4ccccc4c4ccccc43)cc2)cc(-n2c3cc(-n4c5ccccc5c5ccccc54)ccc3c3cncnc32)c1 ; c1ccc2c(c1)c1ccccc1n2-c1ccc(-c2ccc(-n3c4cc(-n5c6ccccc6c6ccccc65)ccc4c4cncnc43)cc2)cc1 ; c1cc(-n2c3ccccc3c3ccccc32)cc(-n2c3cc(-n4c5ccccc5c5ccccc54)ccc3c3cncnc32)c1 ; c1ccc2c(c1)c1ccccc1n2-c1ccc(-n2c3cc(-n4c5ccccc5c5ccccc54)ccc3c3cncnc32)cc1 ; c1ccc(-n2c3cc(-n4c5ccccc5c5ccccc54)ccc3c3cncnc32)cc1 ; c1cc(-c2cccc(-n3c4ccc(-n5c6ccccc6c6cc(-n7c8ccccc8c8ccccc87)ccc65)cc4c4cncnc43)c2)cc(-n2c3ccccc3c3ccccc32)c1]

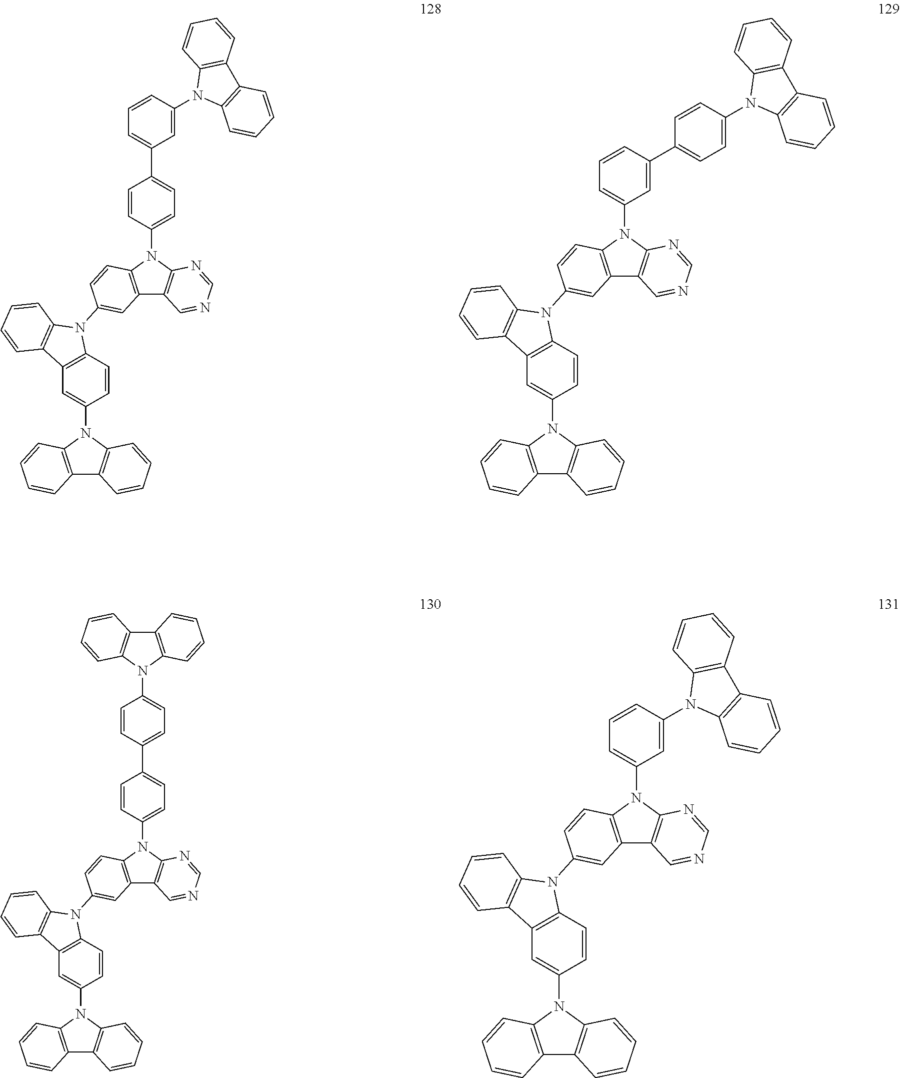 [SMILES: c1cc(-c2ccc(-n3c4ccc(-n5c6ccccc6c6cc(-n7c8ccccc8c8ccccc87)ccc65)cc4c4cncnc43)cc2)cc(-n2c3ccccc3c3ccccc32)c1 ; c1cc(-c2ccc(-n3c4ccccc4c4ccccc43)cc2)cc(-n2c3ccc(-n4c5ccccc5c5cc(-n6c7ccccc7c7ccccc76)ccc54)cc3c3cncnc32)c1 ; c1ccc2c(c1)c1ccccc1n2-c1ccc(-c2ccc(-n3c4ccc(-n5c6ccccc6c6cc(-n7c8ccccc8c8ccccc87)ccc65)cc4c4cncnc43)cc2)cc1 ; c1cc(-n2c3ccccc3c3ccccc32)cc(-n2c3ccc(-n4c5ccccc5c5cc(-n6c7ccccc7c7ccccc76)ccc54)cc3c3cncnc32)c1]

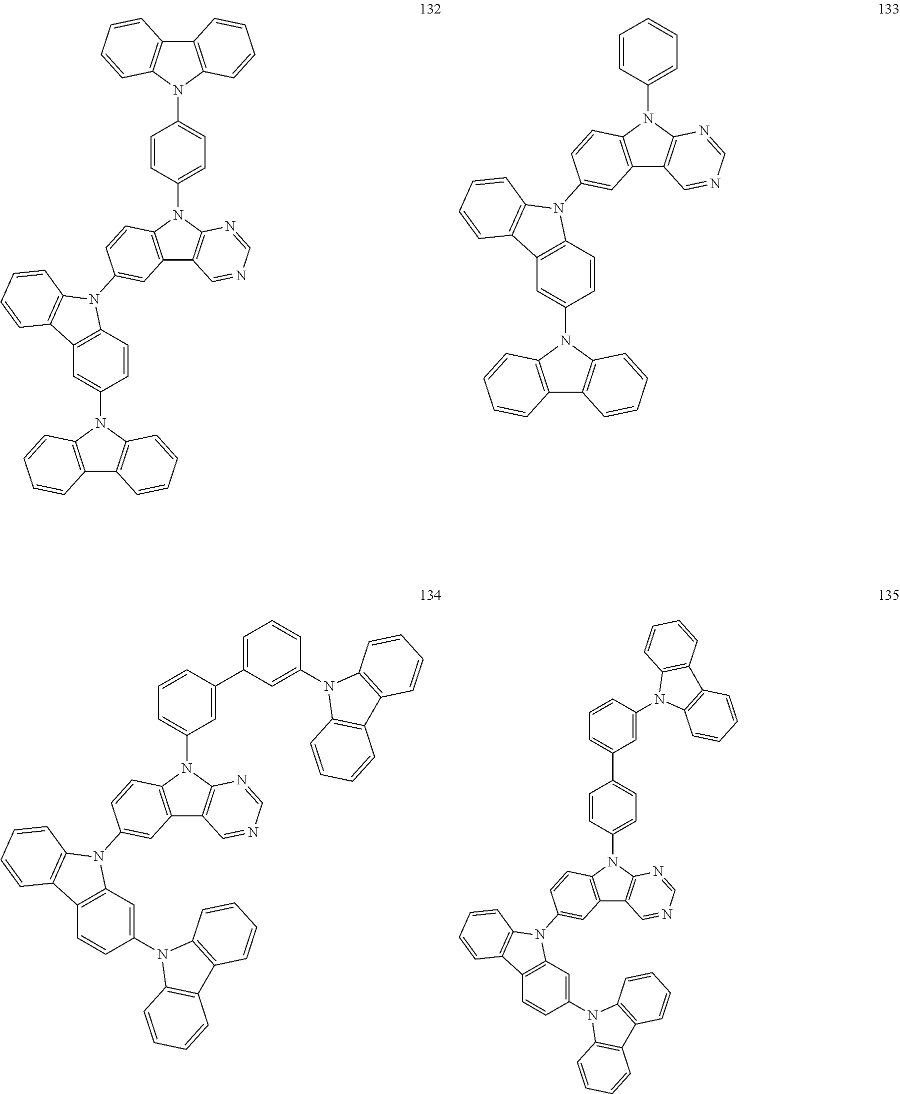 [SMILES: c1ccc2c(c1)c1ccccc1n2-c1ccc(-n2c3ccc(-n4c5ccccc5c5cc(-n6c7ccccc7c7ccccc76)ccc54)cc3c3cncnc32)cc1 ; c1ccc(-n2c3ccc(-n4c5ccccc5c5cc(-n6c7ccccc7c7ccccc76)ccc54)cc3c3cncnc32)cc1 ; c1cc(-c2cccc(-n3c4ccc(-n5c6ccccc6c6ccc(-n7c8ccccc8c8ccccc87)cc65)cc4c4cncnc43)c2)cc(-n2c3ccccc3c3ccccc32)c1 ; c1cc(-c2ccc(-n3c4ccc(-n5c6ccccc6c6ccc(-n7c8ccccc8c8ccccc87)cc65)cc4c4cncnc43)cc2)cc(-n2c3ccccc3c3ccccc32)c1]

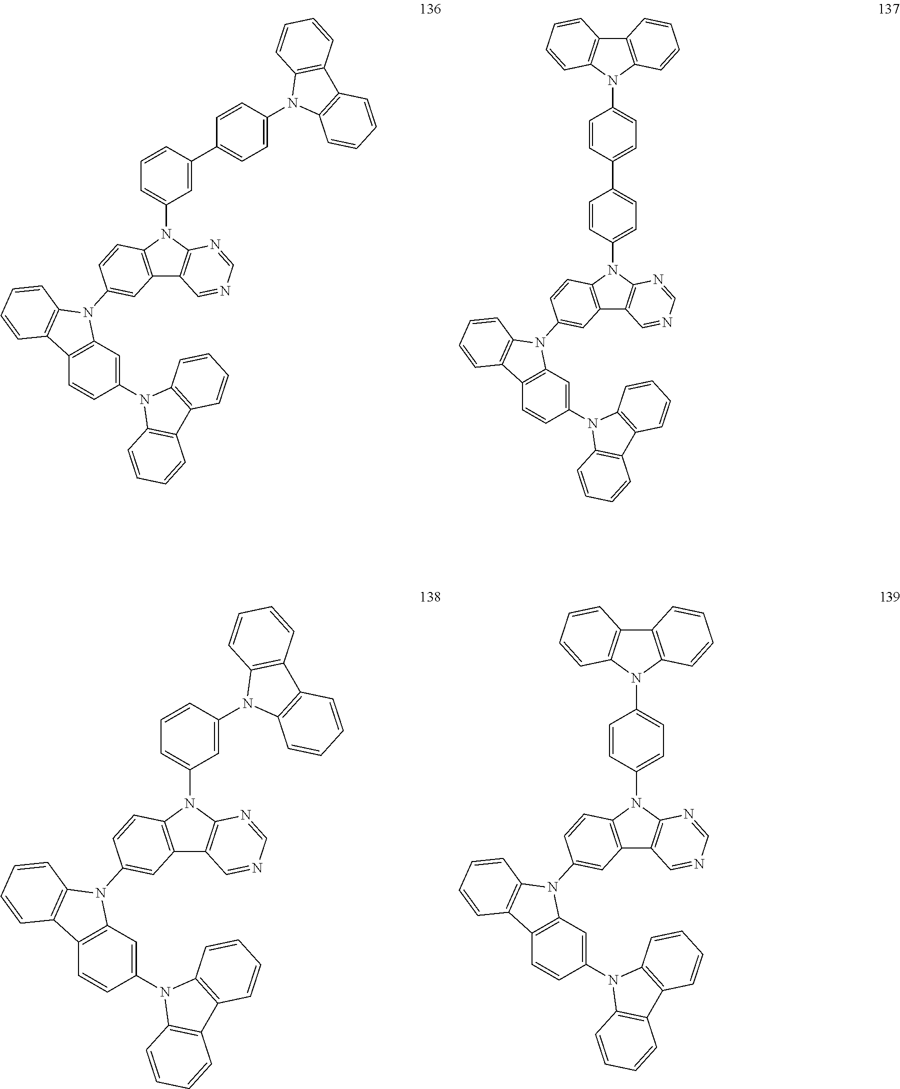 [SMILES: c1cc(-c2ccc(-n3c4ccccc4c4ccccc43)cc2)cc(-n2c3ccc(-n4c5ccccc5c5ccc(-n6c7ccccc7c7ccccc76)cc54)cc3c3cncnc32)c1 ; c1ccc2c(c1)c1ccccc1n2-c1ccc(-c2ccc(-n3c4ccc(-n5c6ccccc6c6ccc(-n7c8ccccc8c8ccccc87)cc65)cc4c4cncnc43)cc2)cc1 ; c1cc(-n2c3ccccc3c3ccccc32)cc(-n2c3ccc(-n4c5ccccc5c5ccc(-n6c7ccccc7c7ccccc76)cc54)cc3c3cncnc32)c1 ; c1ccc2c(c1)c1ccccc1n2-c1ccc(-n2c3ccc(-n4c5ccccc5c5ccc(-n6c7ccccc7c7ccccc76)cc54)cc3c3cncnc32)cc1]

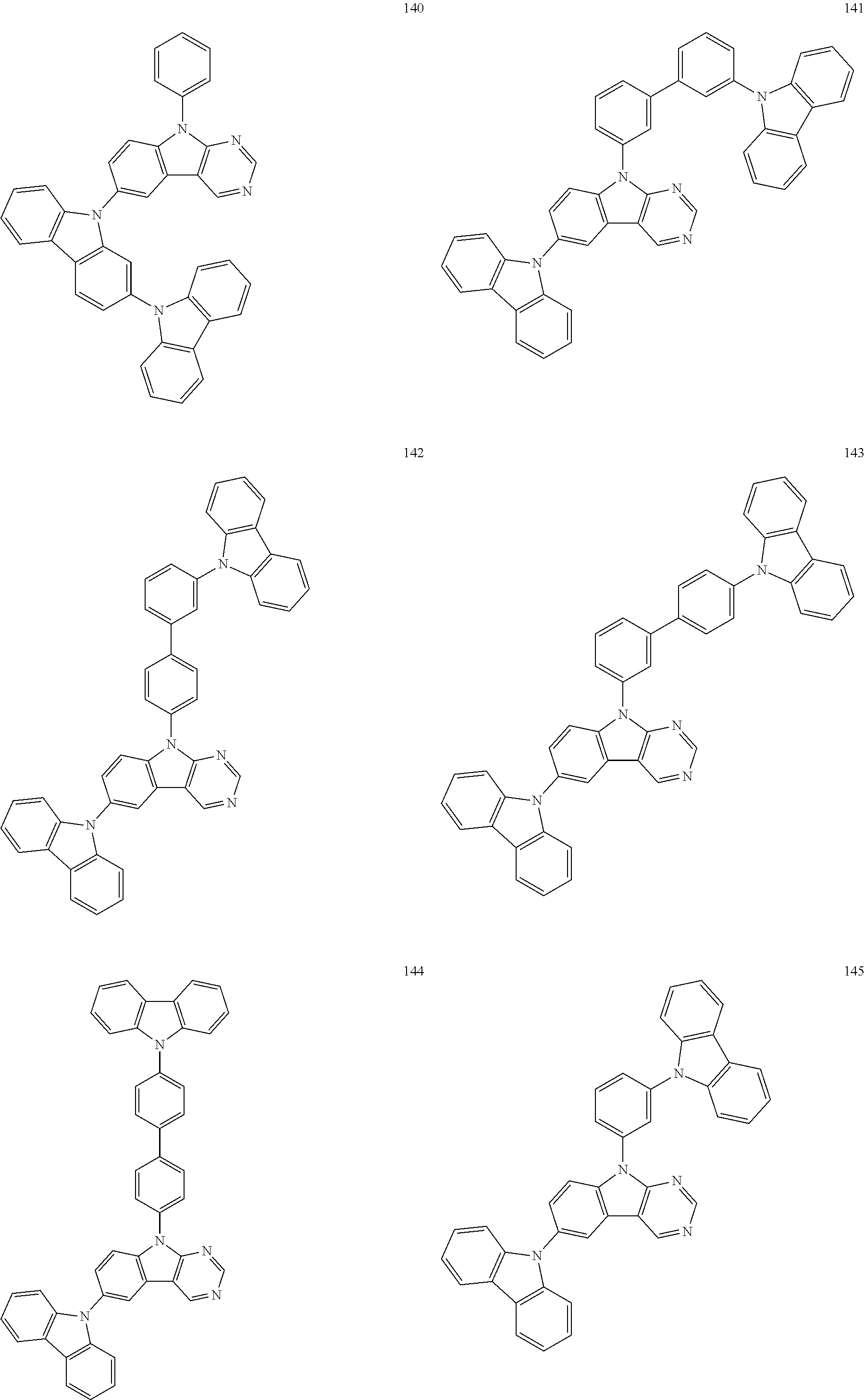

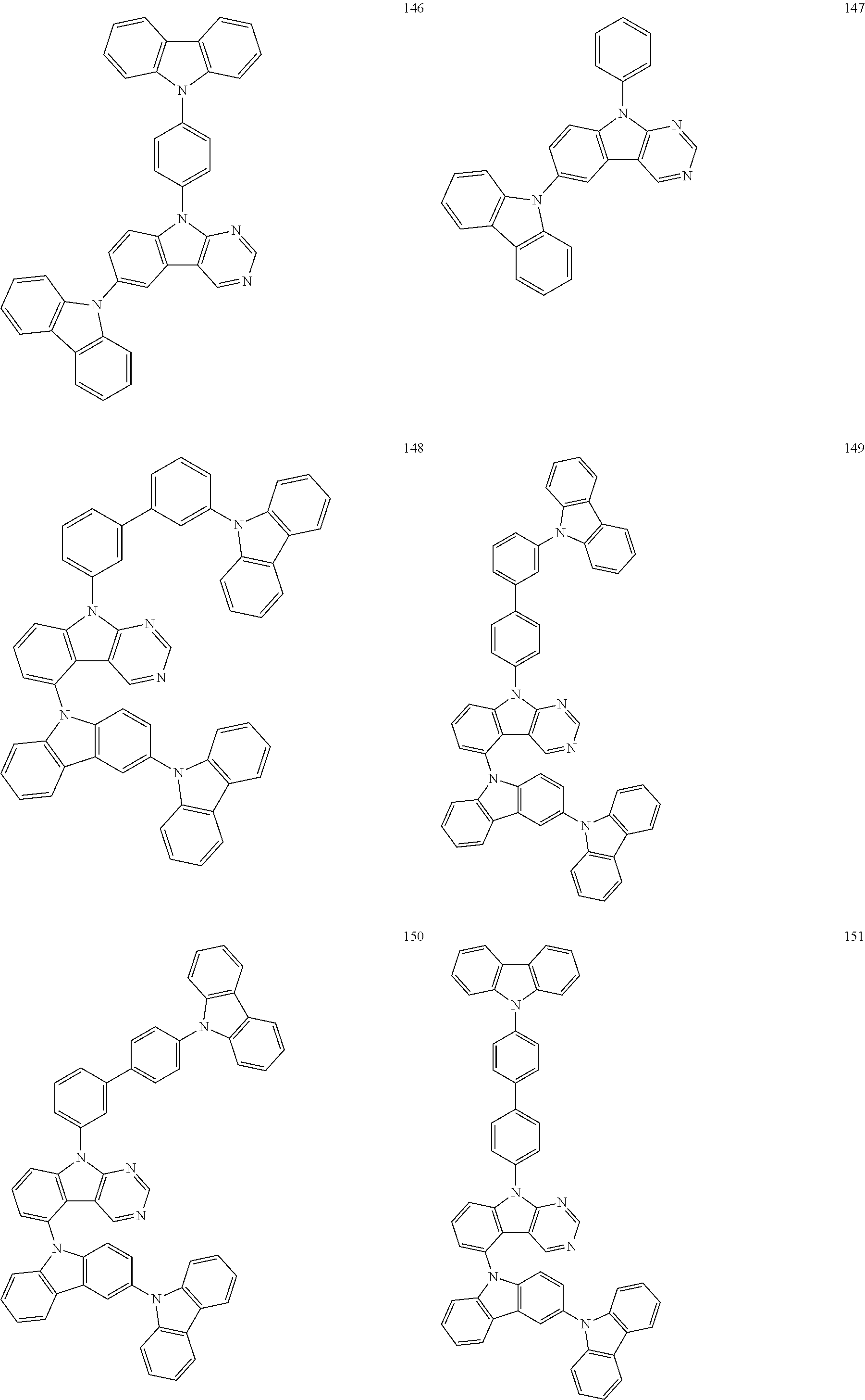

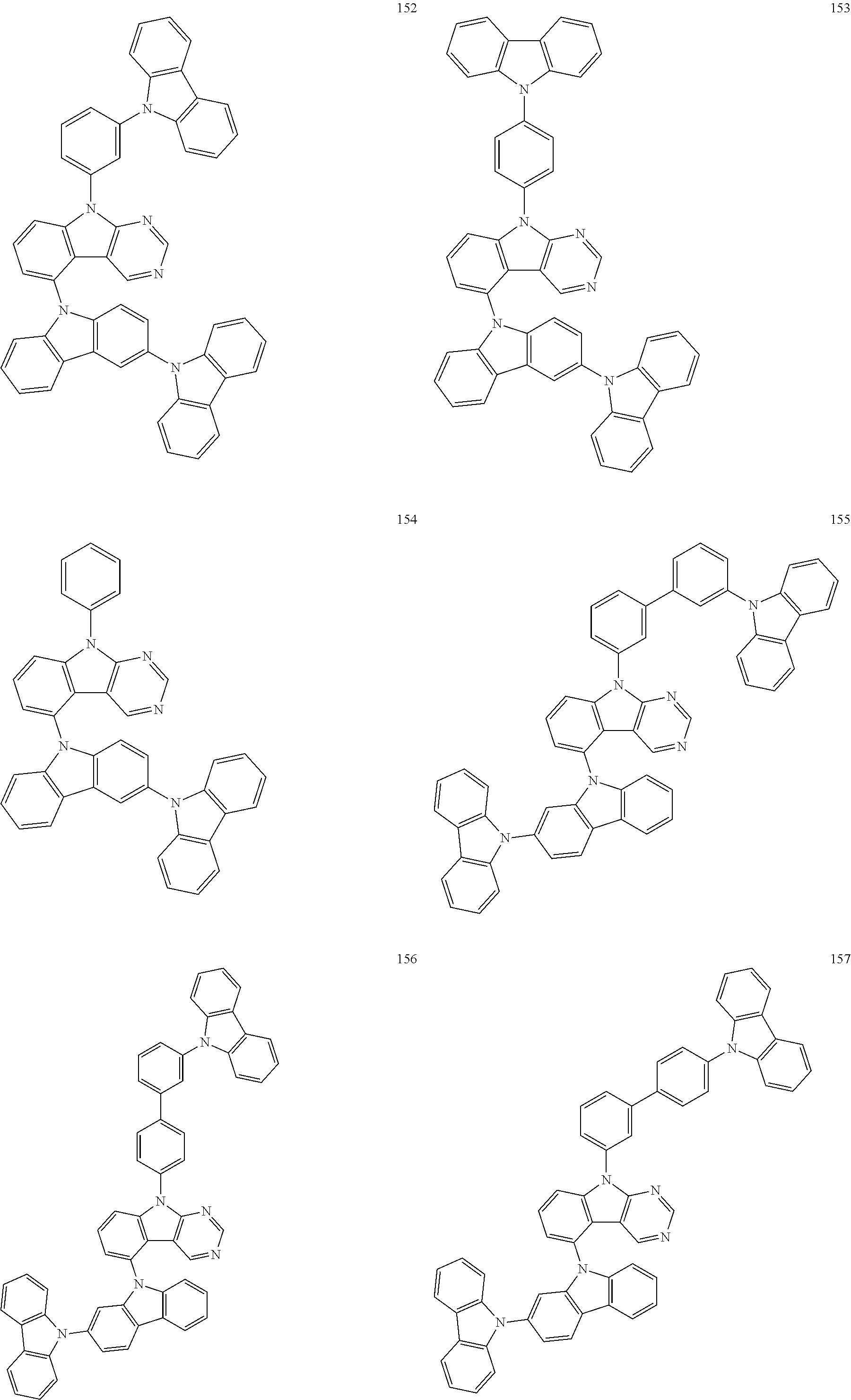

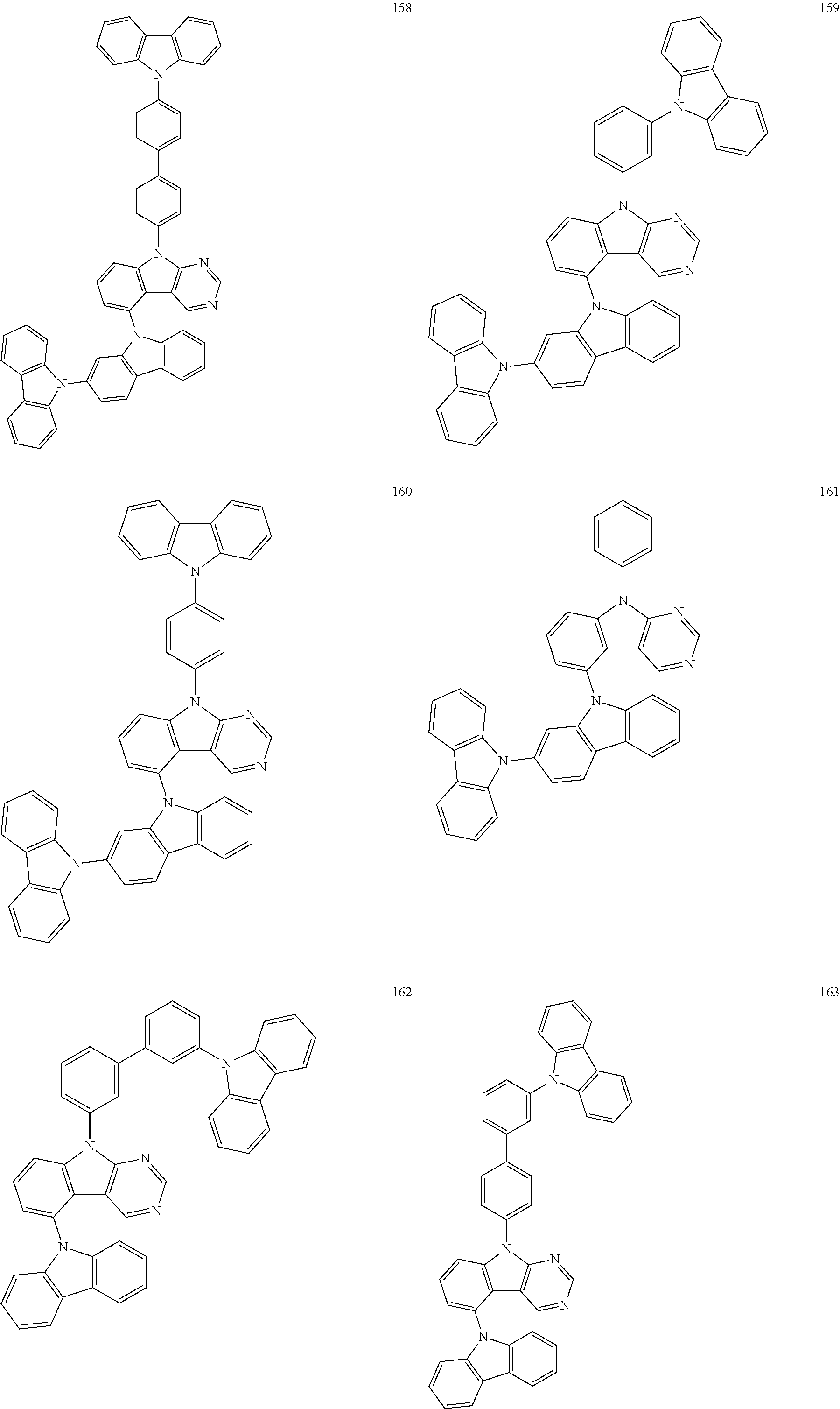

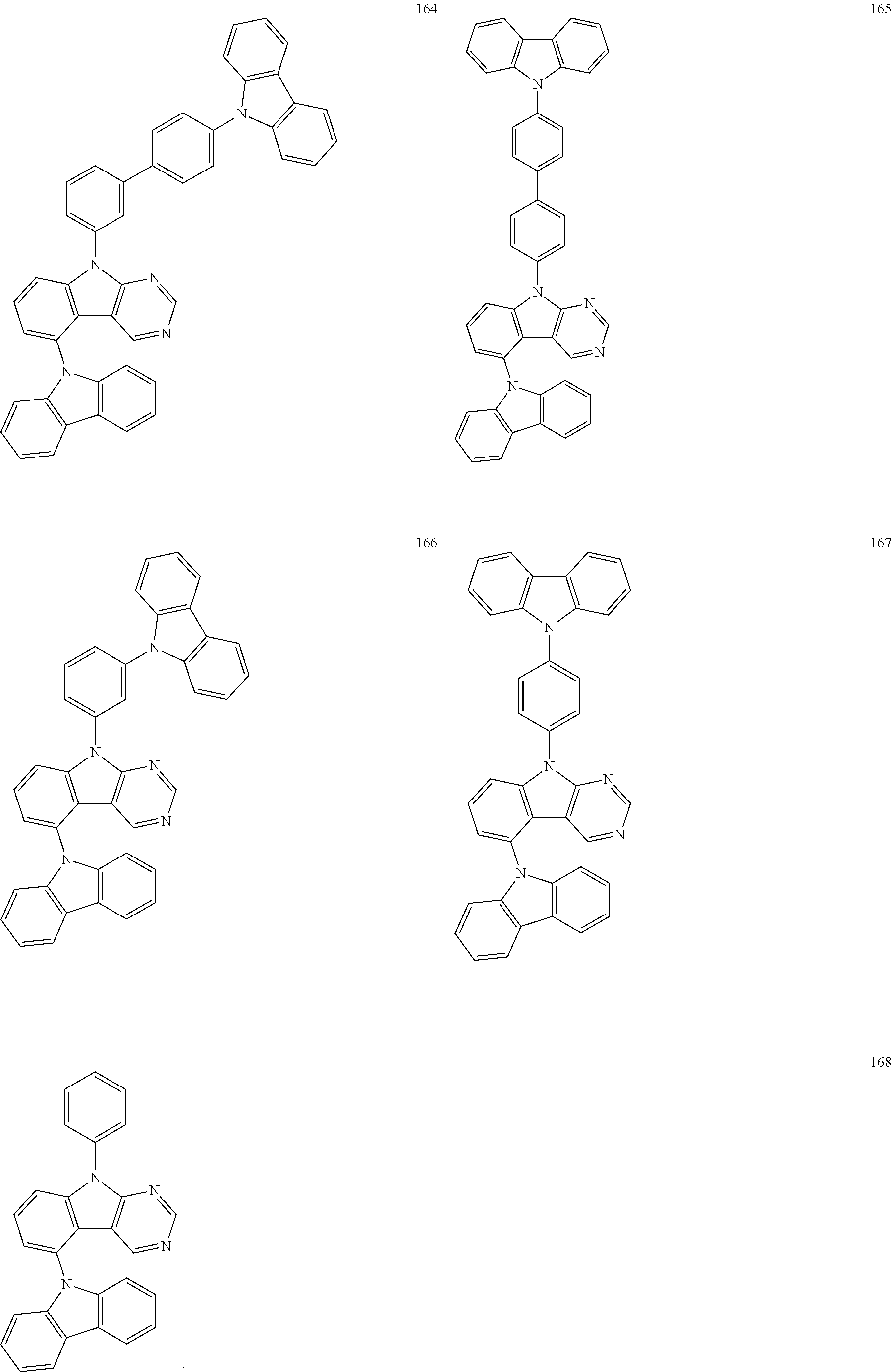 [SMILES: c1cc(-c2ccc(-n3c4ccccc4c4ccccc43)cc2)cc(-n2c3cccc(-n4c5ccccc5c5ccccc54)c3c3cncnc32)c1 ; c1ccc2c(c1)c1ccccc1n2-c1ccc(-c2ccc(-n3c4cccc(-n5c6ccccc6c6ccccc65)c4c4cncnc43)cc2)cc1 ; c1cc(-n2c3ccccc3c3ccccc32)cc(-n2c3cccc(-n4c5ccccc5c5ccccc54)c3c3cncnc32)c1 ; c1ccc2c(c1)c1ccccc1n2-c1ccc(-n2c3cccc(-n4c5ccccc5c5ccccc54)c3c3cncnc32)cc1 ; c1ccc(-n2c3cccc(-n4c5ccccc5c5ccccc54)c3c3cncnc32)cc1]

In the condensed cyclic compound represented by Formula 1, since Ar₁ is included as an electron acceptor moiety, and R₁₀ and Ar₂ that are the substituents of Ar₁ are included as a first electron donor moiety and a second electron donor moiety, the movement of electrons in the molecule easily occurs. In addition, a dipole is formed from the electron donor moiety to the electron acceptor moiety in the condensed cyclic compound represented by Formula 1, and the dipole moment in the molecule increases.

Therefore, the organic light-emitting device including the condensed cyclic compound has excellent luminescent efficiency.

In addition, the condensed cyclic compound represented by Formula 1 is a compound capable of emitting delayed fluorescence, and triplet exciton as well as singlet exciton may be used for light emission. Therefore, the organic light-emitting device including the condensed cyclic compound has excellent luminescent efficiency.

For example, highest occupied molecular orbital (HOMO), lowest unoccupied molecular orbital (LUMO), T₁ energy level, S₁ energy level, natural population analysis (NPA) charge, and dipole moment of Compounds 1 to 168 and Compounds A to E were evaluated by using a DFT method of Gaussian program (structurally optimized at a level of B3LYP, 6-31G(d,p)) and results thereof are shown in Table 1.

TABLE 1

| Compound | HOMO | LUMO | S1 | T1 | ΔE_{ST} | NPA | Dipole |
|---|---|---|---|---|---|---|---|
| No. | (eV) | (eV) | (eV) | (eV) | (eV) | charge | moment |
| 1 | −5.165 | −1.288 | 3.436 | 3.132 | 0.303 | 0.464 | 3.156 |
| 2 | −5.227 | −1.307 | 3.514 | 3.153 | 0.361 | 0.464 | 0.96 |
| 3 | −5.253 | −1.321 | 3.524 | 3.063 | 0.461 | 0.463 | 1.21 |
| 4 | −5.225 | −1.315 | 3.486 | 3.031 | 0.455 | 0.464 | 2.437 |
| 5 | −5.118 | −1.304 | 3.438 | 3.14 | 0.298 | 0.468 | 2.833 |
| 6 | −5.263 | −1.307 | 3.563 | 3.151 | 0.413 | 0.468 | 2.242 |
| 7 | −5.22 | −1.239 | 3.595 | 3.162 | 0.433 | 0.466 | 2.262 |
| 8 | −5.224 | −1.263 | 3.532 | 3.022 | 0.51 | 0.465 | 4.493 |
| 9 | −5.267 | −1.309 | 3.553 | 3.033 | 0.52 | 0.464 | 2.471 |
| 10 | −5.303 | −1.271 | 3.554 | 3.026 | 0.528 | 0.465 | 3.608 |
| 11 | −5.29 | −1.337 | 3.57 | 3.021 | 0.549 | 0.464 | 2.445 |
| 12 | −5.161 | −1.283 | 3.484 | 2.98 | 0.503 | 0.469 | 3.737 |
| 13 | −5.301 | −1.28 | 3.623 | 3.019 | 0.604 | 0.468 | 2.336 |
| 14 | −5.267 | −1.195 | 3.672 | 3.034 | 0.638 | 0.467 | 3.2 |
| 15 | −5.386 | −1.2 | 3.654 | 3.179 | 0.476 | 0.462 | 3.275 |
| 16 | −5.428 | −1.229 | 3.661 | 3.18 | 0.481 | 0.462 | 1.923 |
| 17 | −5.395 | −1.221 | 3.668 | 3.078 | 0.59 | 0.463 | 2.462 |
| 18 | −5.388 | −1.246 | 3.625 | 3.051 | 0.574 | 0.463 | 1.41 |
| 19 | −5.459 | −1.22 | 3.734 | 3.176 | 0.557 | 0.468 | 2.348 |
| 20 | −5.448 | −1.208 | 3.753 | 3.178 | 0.576 | 0.468 | 1.641 |
| 21 | −5.474 | −1.114 | 3.75 | 3.182 | 0.568 | 0.466 | 2.45 |
| 22 | −5.16 | −1.348 | 3.467 | 3.029 | 0.438 | 0.466 | 3.986 |
| 23 | −5.141 | −1.46 | 3.382 | 3.055 | 0.327 | 0.465 | 3.756 |
| 24 | −5.235 | −1.374 | 3.469 | 2.964 | 0.505 | 0.466 | 3.003 |
| 25 | −5.175 | −1.478 | 3.391 | 2.98 | 0.411 | 0.466 | 2.433 |
| 26 | −5.197 | −1.355 | 3.46 | 3.044 | 0.416 | 0.469 | 1.835 |
| 27 | −5.175 | −1.355 | 3.442 | 3.037 | 0.406 | 0.469 | 2.374 |
| 28 | −5.168 | −1.286 | 3.496 | 3.053 | 0.443 | 0.469 | 3.056 |
| 29 | −5.235 | −1.329 | 3.535 | 3.04 | 0.495 | 0.467 | 2.743 |
| 30 | −5.196 | −1.397 | 3.434 | 3.024 | 0.41 | 0.466 | 3.571 |
| 31 | −5.242 | −1.392 | 3.54 | 3.008 | 0.532 | 0.467 | 3.566 |
| 32 | −5.255 | −1.455 | 3.429 | 2.98 | 0.449 | 0.467 | 2.122 |
| 33 | −5.258 | −1.311 | 3.549 | 3.026 | 0.523 | 0.47 | 1.758 |
| 34 | −5.306 | −1.282 | 3.622 | 3.033 | 0.589 | 0.47 | 2.046 |
| 35 | −5.225 | −1.251 | 3.576 | 3.021 | 0.555 | 0.47 | 2.939 |
| 36 | −5.364 | −1.288 | 3.617 | 3.02 | 0.597 | 0.465 | 2.172 |
| 37 | −5.362 | −1.427 | 3.534 | 3.033 | 0.5 | 0.465 | 2.855 |
| 38 | −5.342 | −1.379 | 3.558 | 3.025 | 0.533 | 0.465 | 2.899 |
| 39 | −5.373 | −1.441 | 3.52 | 2.975 | 0.545 | 0.465 | 2.037 |
| 40 | −5.382 | −1.234 | 3.613 | 3.023 | 0.59 | 0.471 | 2.709 |
| 41 | −5.396 | −1.245 | 3.611 | 3.028 | 0.584 | 0.47 | 1.976 |
| 42 | −5.338 | −1.164 | 3.637 | 3.04 | 0.597 | 0.469 | 3.313 |
| 43 | −5.1 | −1.457 | 3.404 | 3.152 | 0.252 | 0.465 | 7.164 |
| 44 | −5.111 | −1.497 | 3.38 | 3.122 | 0.258 | 0.465 | 6.551 |
| 45 | −5.105 | −1.474 | 3.395 | 3.028 | 0.366 | 0.465 | 7.148 |
| 46 | −5.119 | −1.519 | 3.362 | 2.971 | 0.391 | 0.465 | 5.375 |
| 47 | −5.101 | −1.34 | 3.38 | 3.149 | 0.231 | 0.469 | 6.809 |
| 48 | −5.113 | −1.349 | 3.382 | 3.151 | 0.231 | 0.468 | 6.157 |
| 49 | −5.108 | −1.275 | 3.45 | 3.154 | 0.295 | 0.468 | 6.388 |
| 50 | −5.192 | −1.44 | 3.487 | 3.03 | 0.457 | 0.466 | 4.912 |
| 51 | −5.178 | −1.476 | 3.454 | 3.029 | 0.425 | 0.466 | 5.108 |
| 52 | −5.168 | −1.446 | 3.463 | 3.03 | 0.433 | 0.465 | 5.825 |
| 53 | −5.175 | −1.487 | 3.447 | 2.974 | 0.473 | 0.466 | 5.12 |
| 54 | −5.178 | −1.297 | 3.482 | 3.026 | 0.456 | 0.47 | 5.777 |
| 55 | −5.184 | −1.306 | 3.479 | 3.027 | 0.452 | 0.469 | 4.974 |
| 56 | −5.208 | −1.235 | 3.591 | 3.038 | 0.553 | 0.469 | 4.62 |
| 57 | −5.266 | −1.414 | 3.51 | 3.154 | 0.356 | 0.464 | 5.629 |
| 58 | −5.277 | −1.458 | 3.475 | 3.088 | 0.387 | 0.464 | 4.626 |
| 59 | −5.286 | −1.438 | 3.509 | 3.017 | 0.492 | 0.464 | 4.556 |
| 60 | −5.284 | −1.471 | 3.453 | 2.966 | 0.488 | 0.464 | 3.804 |
| 61 | −5.284 | −1.231 | 3.495 | 3.167 | 0.329 | 0.469 | 4.322 |
| 62 | −5.302 | −1.247 | 3.498 | 3.164 | 0.335 | 0.469 | 3.717 |
| 63 | −5.253 | −1.159 | 3.535 | 3.173 | 0.361 | 0.469 | 5.145 |
| 64 | −5.09 | −1.443 | 3.385 | 3.156 | 0.229 | 0.466 | 7.216 |
| 65 | −5.079 | −1.481 | 3.366 | 3.126 | 0.24 | 0.466 | 7.687 |
| 66 | −5.08 | −1.475 | 3.365 | 3.004 | 0.361 | 0.466 | 7.754 |
| 67 | −5.082 | −1.497 | 3.354 | 2.994 | 0.36 | 0.466 | 6.885 |
| 68 | −5.084 | −1.312 | 3.352 | 3.148 | 0.204 | 0.47 | 7.532 |
| 69 | −5.095 | −1.319 | 3.353 | 3.148 | 0.206 | 0.47 | 6.714 |
| 70 | −5.068 | −1.245 | 3.397 | 3.156 | 0.241 | 0.47 | 7.965 |
| 71 | −5.172 | −1.361 | 3.498 | 3.031 | 0.467 | 0.467 | 6.444 |
| 72 | −5.149 | −1.441 | 3.437 | 3.026 | 0.411 | 0.467 | 4.853 |
| 73 | −5.135 | −1.419 | 3.429 | 3.013 | 0.416 | 0.467 | 5.945 |
| 74 | −5.146 | −1.465 | 3.415 | 2.981 | 0.435 | 0.467 | 4.981 |
| 75 | −5.144 | −1.262 | 3.438 | 3.019 | 0.419 | 0.472 | 5.253 |
| 76 | −5.159 | −1.279 | 3.438 | 3.025 | 0.413 | 0.471 | 4.81 |
| 77 | −5.161 | −1.203 | 3.539 | 3.033 | 0.506 | 0.471 | 5.975 |
| 78 | −5.356 | −1.387 | 3.562 | 3.152 | 0.41 | 0.466 | 4.853 |
| 79 | −5.351 | −1.434 | 3.551 | 3.099 | 0.452 | 0.465 | 5.124 |
| 80 | −5.356 | −1.413 | 3.544 | 3.036 | 0.508 | 0.466 | 4.933 |
| 81 | −5.359 | −1.457 | 3.519 | 2.976 | 0.543 | 0.466 | 4.497 |
| 82 | −5.368 | −1.18 | 3.546 | 3.146 | 0.4 | 0.47 | 5.122 |
| 83 | −5.378 | −1.188 | 3.544 | 3.153 | 0.392 | 0.471 | 4.382 |
| 84 | −5.326 | −1.106 | 3.576 | 3.155 | 0.421 | 0.471 | 5.665 |
| 85 | −5.257 | −1.616 | 3.287 | 3.149 | 0.139 | 0.471 | 2.301 |
| 86 | −5.215 | −1.599 | 3.259 | 3.149 | 0.11 | 0.471 | 2.221 |
| 87 | −5.255 | −1.629 | 3.275 | 3.107 | 0.168 | 0.471 | 2.759 |
| 88 | −5.229 | −1.626 | 3.252 | 3.05 | 0.203 | 0.471 | 3.391 |
| 89 | −5.12 | −1.649 | 3.128 | 3.08 | 0.048 | 0.477 | 3.41 |
| 90 | −5.179 | −1.665 | 3.177 | 3.106 | 0.071 | 0.476 | 3.391 |
| 91 | −5.21 | −1.577 | 3.278 | 3.132 | 0.146 | 0.477 | 2.175 |
| 92 | −5.221 | −1.591 | 3.253 | 3.031 | 0.221 | 0.472 | 4.687 |
| 93 | −5.301 | −1.588 | 3.345 | 3.029 | 0.316 | 0.472 | 1.489 |
| 94 | −5.261 | −1.582 | 3.363 | 3.025 | 0.338 | 0.472 | 3.864 |
| 95 | −5.307 | −1.599 | 3.34 | 3.02 | 0.32 | 0.472 | 2.775 |
| 96 | −5.188 | −1.619 | 3.208 | 3.02 | 0.188 | 0.477 | 3.135 |
| 97 | −5.319 | −1.641 | 3.311 | 3.016 | 0.295 | 0.477 | 2.873 |
| 98 | −5.258 | −1.528 | 3.341 | 3.03 | 0.311 | 0.479 | 3.316 |
| 99 | −5.373 | −1.486 | 3.463 | 3.178 | 0.285 | 0.473 | 2.144 |
| 100 | −5.373 | −1.51 | 3.456 | 3.147 | 0.309 | 0.472 | 2.382 |
| 101 | −5.312 | −1.525 | 3.5 | 3.127 | 0.373 | 0.472 | 3.358 |
| 102 | −5.327 | −1.543 | 3.474 | 3.06 | 0.414 | 0.472 | 2.817 |
| 103 | −5.355 | −1.546 | 3.402 | 3.155 | 0.247 | 0.479 | 2.3 |
| 104 | −5.348 | −1.57 | 3.427 | 3.143 | 0.284 | 0.479 | 2.957 |
| 105 | −5.494 | −1.466 | 3.473 | 3.143 | 0.33 | 0.481 | 2.051 |
| 106 | −5.203 | −1.662 | 3.203 | 2.923 | 0.281 | 0.473 | 2.019 |
| 107 | −5.176 | −1.671 | 3.166 | 2.937 | 0.229 | 0.473 | 2.744 |
| 108 | −5.253 | −1.669 | 3.237 | 2.969 | 0.267 | 0.474 | 2.795 |
| 109 | −5.213 | −1.669 | 3.2 | 2.927 | 0.273 | 0.473 | 2.283 |
| 110 | −5.189 | −1.684 | 3.165 | 2.907 | 0.258 | 0.478 | 1.45 |
| 111 | −5.218 | −1.697 | 3.173 | 2.9 | 0.274 | 0.478 | 2.234 |
| 112 | −5.205 | −1.626 | 3.233 | 2.945 | 0.288 | 0.48 | 1.754 |
| 113 | −5.193 | −1.601 | 3.236 | 2.998 | 0.238 | 0.474 | 4.528 |
| 114 | −5.254 | −1.59 | 3.295 | 2.957 | 0.338 | 0.475 | 2.211 |
| 115 | −5.332 | −1.631 | 3.325 | 2.973 | 0.352 | 0.474 | 2.647 |
| 116 | −5.271 | −1.647 | 3.257 | 2.99 | 0.267 | 0.474 | 2.116 |
| 117 | −5.302 | −1.629 | 3.295 | 2.971 | 0.324 | 0.479 | 3.6 |
| 118 | −5.322 | −1.641 | 3.306 | 2.982 | 0.324 | 0.479 | 2.838 |
| 119 | −5.237 | −1.591 | 3.27 | 2.986 | 0.285 | 0.482 | 2.277 |
| 120 | −5.405 | −1.529 | 3.446 | 2.918 | 0.528 | 0.475 | 0.47 |
| 121 | −5.428 | −1.566 | 3.403 | 2.935 | 0.468 | 0.475 | 1.88 |
| 122 | −5.383 | −1.593 | 3.417 | 2.957 | 0.46 | 0.475 | 1.257 |
| 123 | −5.389 | −1.574 | 3.407 | 2.931 | 0.476 | 0.475 | 1.276 |
| 124 | −5.466 | −1.613 | 3.353 | 2.957 | 0.396 | 0.481 | 1.239 |
| 125 | −5.461 | −1.606 | 3.397 | 2.92 | 0.477 | 0.481 | 1.349 |
| 126 | −5.429 | −1.514 | 3.424 | 2.94 | 0.483 | 0.485 | 1.686 |
| 127 | −5.151 | −1.651 | 3.149 | 3.054 | 0.095 | 0.472 | 4.111 |
| 128 | −5.169 | −1.679 | 3.136 | 3.054 | 0.082 | 0.473 | 4.051 |
| 129 | −5.167 | −1.676 | 3.143 | 3.051 | 0.092 | 0.472 | 3.292 |
| 130 | −5.168 | −1.685 | 3.126 | 2.989 | 0.137 | 0.473 | 3.825 |
| 131 | −5.173 | −1.727 | 3.092 | 3.015 | 0.077 | 0.478 | 3.986 |
| 132 | −5.183 | −1.724 | 3.114 | 3.03 | 0.084 | 0.477 | 2.705 |
| 133 | −5.153 | −1.636 | 3.167 | 3.066 | 0.101 | 0.479 | 4.064 |
| 134 | −5.245 | −1.632 | 3.23 | 3.023 | 0.207 | 0.473 | 2.881 |
| 135 | −5.231 | −1.632 | 3.216 | 3.019 | 0.197 | 0.473 | 4.555 |
| 136 | −5.243 | −1.637 | 3.245 | 3.018 | 0.227 | 0.473 | 3.003 |
| 137 | −5.245 | −1.636 | 3.221 | 2.993 | 0.228 | 0.474 | 3.445 |
| 138 | −5.235 | −1.667 | 3.182 | 3.025 | 0.156 | 0.479 | 3.96 |
| 139 | −5.26 | −1.674 | 3.198 | 3.025 | 0.173 | 0.478 | 3.432 |
| 140 | −5.221 | −1.586 | 3.246 | 3.026 | 0.22 | 0.48 | 4.514 |
| 141 | −5.38 | −1.564 | 3.284 | 3.067 | 0.217 | 0.473 | 3.735 |
| 142 | −5.385 | −1.578 | 3.275 | 3.065 | 0.211 | 0.474 | 2.74 |
| 143 | −5.389 | −1.579 | 3.277 | 3.041 | 0.235 | 0.473 | 2.394 |
| 144 | −5.378 | −1.583 | 3.272 | 2.989 | 0.284 | 0.474 | 1.839 |
| 145 | −5.408 | −1.646 | 3.238 | 3.035 | 0.202 | 0.481 | 2.692 |
| 146 | −5.396 | −1.623 | 3.249 | 3.042 | 0.207 | 0.48 | 1.77 |
| 147 | −5.356 | −1.525 | 3.296 | 3.075 | 0.221 | 0.484 | 3.16 |
| 148 | −5.147 | −1.599 | 3.139 | 3.044 | 0.095 | 0.474 | 6.996 |
| 149 | −5.182 | −1.613 | 3.176 | 3.035 | 0.141 | 0.474 | 4.675 |
| 150 | −5.162 | −1.617 | 3.132 | 3.043 | 0.09 | 0.474 | 4.977 |
| 151 | −5.162 | −1.627 | 3.122 | 2.992 | 0.13 | 0.474 | 5.129 |
| 152 | −5.178 | −1.665 | 3.103 | 3.026 | 0.077 | 0.479 | 4.593 |
| 153 | −5.171 | −1.668 | 3.092 | 3.011 | 0.081 | 0.478 | 5.044 |
| 154 | −5.143 | −1.573 | 3.158 | 3.04 | 0.118 | 0.481 | 6.253 |
| 155 | −5.258 | −1.588 | 3.256 | 3.005 | 0.25 | 0.475 | 4.689 |
| 156 | −5.209 | −1.571 | 3.193 | 3.002 | 0.192 | 0.475 | 4.882 |
| 157 | −5.217 | −1.565 | 3.206 | 3.004 | 0.202 | 0.475 | 4.232 |
| 158 | −5.222 | −1.576 | 3.202 | 3.005 | 0.197 | 0.475 | 3.912 |
| 159 | −5.235 | −1.62 | 3.169 | 3.003 | 0.166 | 0.48 | 2.977 |
| 160 | −5.262 | −1.633 | 3.226 | 3.009 | 0.217 | 0.48 | 3.033 |
| 161 | −5.197 | −1.523 | 3.23 | 3.013 | 0.217 | 0.482 | 4.702 |
| 162 | −5.474 | −1.489 | 3.381 | 3.071 | 0.31 | 0.476 | 2.682 |
| 163 | −5.441 | −1.492 | 3.378 | 3.065 | 0.313 | 0.475 | 3.717 |
| 164 | −5.438 | −1.498 | 3.369 | 3.057 | 0.312 | 0.475 | 3.173 |
| 165 | −5.407 | −1.498 | 3.377 | 2.994 | 0.383 | 0.476 | 3.087 |
| 166 | −5.441 | −1.56 | 3.345 | 3.054 | 0.291 | 0.483 | 3.947 |
| 167 | −5.471 | −1.541 | 3.359 | 3.056 | 0.303 | 0.482 | 2.993 |
| 168 | −5.457 | −1.441 | 3.396 | 3.077 | 0.319 | 0.486 | 4.105 |

Referring to Table 1, it is confirmed that the condensed cyclic compound represented by Formula 1 has excellent electric characteristics. For example, it is confirmed that the condensed cyclic compound represented by Formula 1 has a high Si energy level, a high T₁ energy level, and a large NPA charge. Therefore, the condensed cyclic compound represented by Formula 1 is advantageous in terms of the stability of the material itself and the stability of the device when applied to the device, and is suitably used as a material for forming an emission layer of an electronic device, for example, an organic light-emitting device.

Synthesis methods of the condensed cyclic compound represented by Formula 1 may be understood by those of ordinary skill in the art by referring to Synthesis Examples provided below.

The organic light-emitting device according to the embodiment is an organic light-emitting device using delayed fluorescence emitted from the condensed cyclic compound and may have high efficiency and a long lifespan.

In an embodiment, the emission layer included in the organic light-emitting device may emit blue light having a maximum emission wavelength of about 380 nanometers (nm) to about 475 nm.

The organic light-emitting device may have, due to the inclusion of an organic layer including the condensed cyclic compound represented by Formula 1, high efficiency and long lifespan.

In one or more embodiments, the condensed cyclic compound included in the emission layer of the organic light-emitting device may be a delayed fluorescent emitter.

In one or more embodiments, the emission layer may consist of the condensed cyclic compound only.

In one or more embodiments, the emission layer may further include a host, and an amount of the host may be larger than an amount of the condensed cyclic compound.

In an embodiment, the emission layer may include a host and a dopant (wherein an amount of the host is larger than an amount of the dopant), and the host may include the condensed cyclic compound represented by Formula 1. The condensed cyclic compound acting as a dopant may emit delayed fluorescence due to a delayed fluorescence emission mechanism. The host may be selected from any known dopants.

In an embodiment, the emission layer may include the condensed cyclic compound. At this time, a ratio of a fluorescence component to a total emission component emitted from the emission layer may be about 90% or more, for example, about 95% or more (for example, about 98% or more). In addition, the emission layer includes the condensed cyclic compound represented by Formula 1, and may not include a phosphorescence emission compound (for example, an organometallic compound including a heavy metal). Therefore, the emission layer may be clearly distinguished from a phosphorescent emission layer including a phosphorescent dopant, wherein a ratio of a phosphorescence component to a total emission component is, for example, about 80% or more.

According to an embodiment in which the condensed cyclic compound included in the emission layer is used as a fluorescent emitter, a ratio of an emission component emitted from the condensed cyclic compound to a total emission component emitted from the emission layer is about 80% or more, for example, about 90% or more. For example, a ratio of an emission component emitted from the condensed cyclic compound to a total emission component emitted from the emission layer may be about 95% or more. The emission component of the condensed cyclic compound is the sum of the prompt emission component of the condensed cyclic compound and the delayed fluorescence component due to the reverse intersystem crossing of the condensed cyclic compound.

In an embodiment, the emission layer may consist of the condensed cyclic compound only; or the emission layer may further include a host (the host is different from the condensed cyclic compound).

When the emission layer further includes, in addition to the condensed cyclic compound, a host, an amount of the condensed cyclic compound may be in a range of about 50 parts by weight or less, for example, about 30 parts by weight or less, based on 100 parts by weight of the emission layer, and an amount of the host in the emission layer may be in a range of about 50 parts by weight or more, for example, about 70 parts by weight or more, based on 100 parts by weight of the emission layer, but embodiments of the present disclosure are not limited thereto.

In addition, according to another embodiment in which the condensed cyclic compound included in the emission layer is used as a fluorescent host, the emission layer includes a host and a fluorescent dopant, wherein the host includes the condensed cyclic compound, and a ratio of an emission component of the fluorescent dopant to a total emission component emitted from the emission layer may be about 80% or more, for example, about 90% or more (for example, about 95% or more).

In this embodiment, an amount of the fluorescent dopant in the emission layer may be in a range of about 50 parts by weight or less, for example, about 30 parts by weight or less, based on 100 parts by weight of the emission layer, and an amount of the host in the emission layer may be in a range of about 50 parts by weight or more, for example, about 70 parts by weight or more, based on 100 parts by weight of the emission layer, but the present disclosure is not limited thereto.

When the condensed cyclic compound included in the emission layer is used as a fluorescent host, the fluorescent host may consist of the condensed cyclic compound only, or may further include a known other host.

In an embodiment, the emission layer may include a host, an auxiliary dopant, and a fluorescent dopant, the auxiliary dopant may include the condensed cyclic compound, and the emission layer may satisfy Equations 3 and 4 below:

E_{T1(HOST)}−E_{T1(AD)}>0.05 eV Equation 3

E_{S1(FD)}−E_{S1(AD)}<0 eV. Equation 4

In Equation 3, E_{T1(HOST)} is triplet energy (electron volts, eV) of the host, and E_{T1(AD)} is triplet energy (eV) of the auxiliary dopant,

in Equation 4, E_{S1(FD)} is singlet energy (eV) of the fluorescent dopant, and E_{S1(AD)} is singlet energy (eV) of the auxiliary dopant, and

E_{T1(HOST)}, E_{T1(AD)}, and E_{S1(FD)} are evaluated by using a DFT method of Gaussian program structurally optimized at a level of B3LYP/6-31 G(d,p).

The term “organic layer” as used herein refers to a single layer and/or a plurality of layers disposed between the first electrode and the second electrode of the organic light-emitting device. The “organic layer” may include, in addition to an organic compound, an organometallic complex including metal.

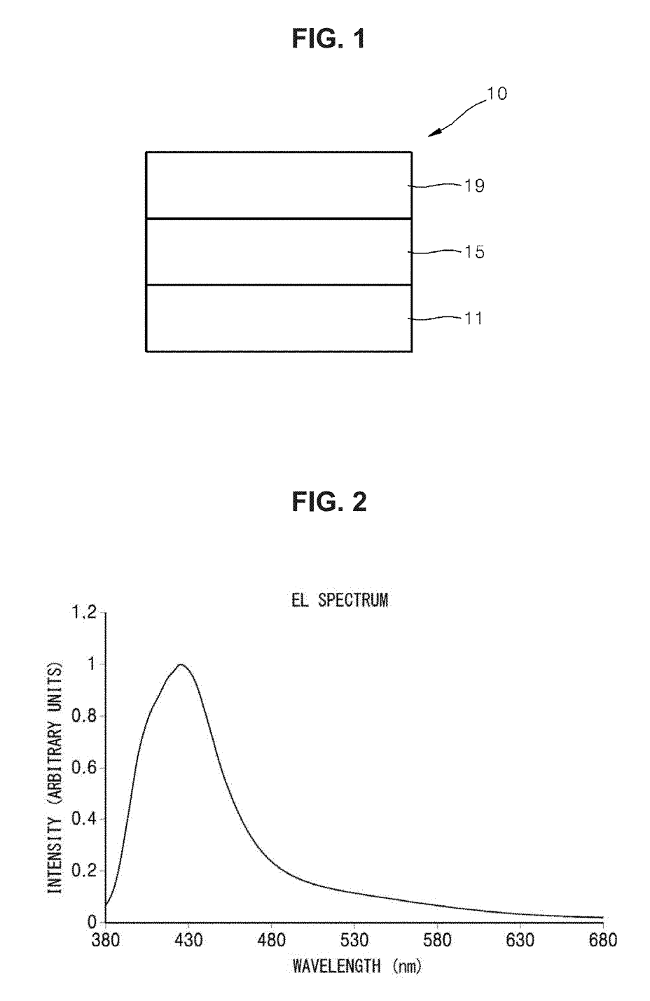

FIG. 1 is a schematic view of an organic light-emitting device 10 according to an embodiment. Hereinafter, the structure of an organic light-emitting device according to an embodiment and a method of manufacturing an organic light-emitting device according to an embodiment will be described in connection with FIG. 1. The organic light-emitting device 10 includes a first electrode 11, an organic layer 15, and a second electrode 19, which are sequentially stacked.

A substrate may be additionally disposed under the first electrode 11 or above the second electrode 19. For use as the substrate, any substrate that is used in general organic light-emitting devices may be used, and the substrate may be a glass substrate or a transparent plastic substrate, each having excellent mechanical strength, thermal stability, transparency, surface smoothness, ease of handling, and water resistance.

In one or more embodiments, the first electrode 11 may be formed by depositing or sputtering a material for forming the first electrode 11 on the substrate. The first electrode 11 may be an anode. The material for forming the first electrode 11 may be selected from materials with a high work function to facilitate hole injection. The first electrode 11 may be a reflective electrode, a semi-transmissive electrode, or a transmissive electrode. The material for forming the first electrode 11 may be indium tin oxide (ITO), indium zinc oxide (IZO), tin oxide (SnO₂), or zinc oxide (ZnO). In one or more embodiments, the material for forming the first electrode 11 may be metal, such as magnesium (Mg), aluminum (Al), aluminum-lithium (Al—Li), calcium (Ca), magnesium-indium (Mg—In), or magnesium-silver (Mg—Ag).

The first electrode 11 may have a single-layered structure or a multi-layered structure including two or more layers. For example, the first electrode 11 may have a three-layered structure of ITO/Ag/ITO, but the structure of the first electrode 110 is not limited thereto.

The organic layer 15 is disposed on the first electrode 11.

The organic layer 15 may include a hole transport region, an emission layer, and an electron transport region.

The hole transport region may be disposed between the first electrode 11 and the emission layer.

The hole transport region may include at least one selected from a hole injection layer, a hole transport layer, an electron blocking layer, and a buffer layer.

The hole transport region may include only either a hole injection layer or a hole transport layer. In one or more embodiments, the hole transport region may have a hole injection layer/hole transport layer structure or a hole injection layer/hole transport layer/electron blocking layer structure, which are sequentially stacked in this stated order from the first electrode 11.

When the hole transport region includes a hole injection layer (HIL), the hole injection layer may be formed on the first electrode 11 by using one or more suitable methods, for example, vacuum deposition, spin coating, casting, and/or Langmuir-Blodgett (LB) deposition.

When a hole injection layer is formed by vacuum deposition, the deposition conditions may vary according to a material that is used to form the hole injection layer, and the structure and thermal characteristics of the hole injection layer. For example, the deposition conditions may include a deposition temperature of about 100 to about 500° C., a vacuum pressure of about 10⁻⁸ torr to about 10⁻³ torr, and a deposition rate of about 0.01 Angstroms per second (A/sec) to about 100 Å/sec. However, the deposition conditions are not limited thereto, but embodiments of the present disclosure are not limited thereto.

When the hole injection layer is formed using spin coating, coating conditions may vary according to the material used to form the hole injection layer, and the structure and thermal properties of the hole injection layer. For example, a coating speed may be from about 2,000 revolutions per minute (rpm) to about 5,000 rpm, and a temperature at which a heat treatment is performed to remove a solvent after coating may be from about 80° C. to about 200° C. However, the coating conditions are not limited thereto.

Conditions for forming a hole transport layer and an electron blocking layer may be understood by referring to conditions for forming the hole injection layer.

The hole transport region may include at least one selected from m-MTDATA, TDATA, 2-TNATA, NPB, p-NPB, TPD, Spiro-TPD, Spiro-NPB, methylated-NPB, TAPC, HMTPD, 4,4′,4″-tris(N-carbazolyl)triphenylamine (TCTA), polyaniline/dodecylbenzene sulfonic acid (PANI/DBSA), poly(3,4-ethylenedioxythiophene)/poly(4-styrene sulfonate) (PEDOT/PSS), polyaniline/camphor sulfonic acid (PANI/CSA), polyaniline/poly(4-styrene sulfonate) (PANI/PSS), a compound represented by Formula 201 below, and a compound represented by Formula 202 below:

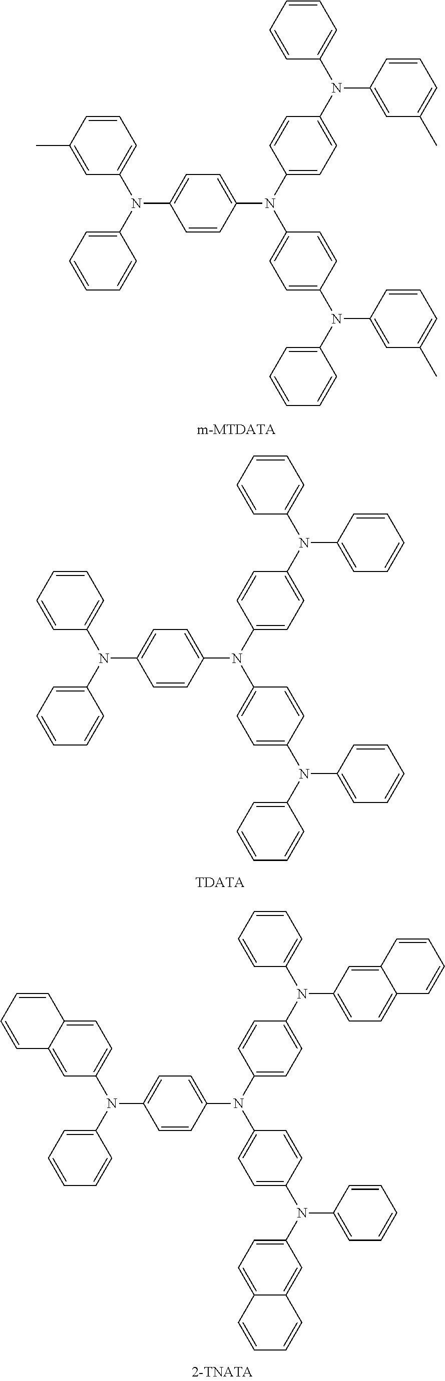

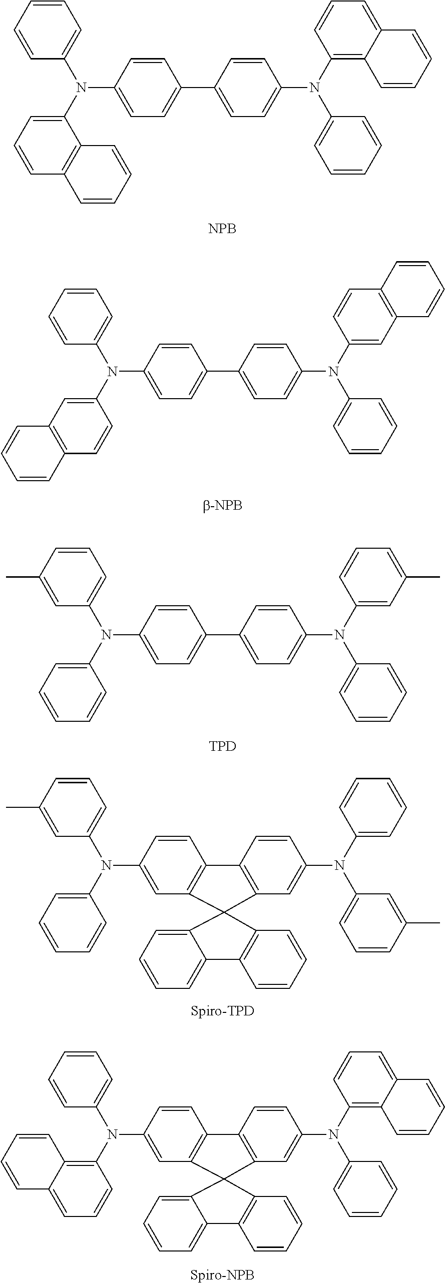

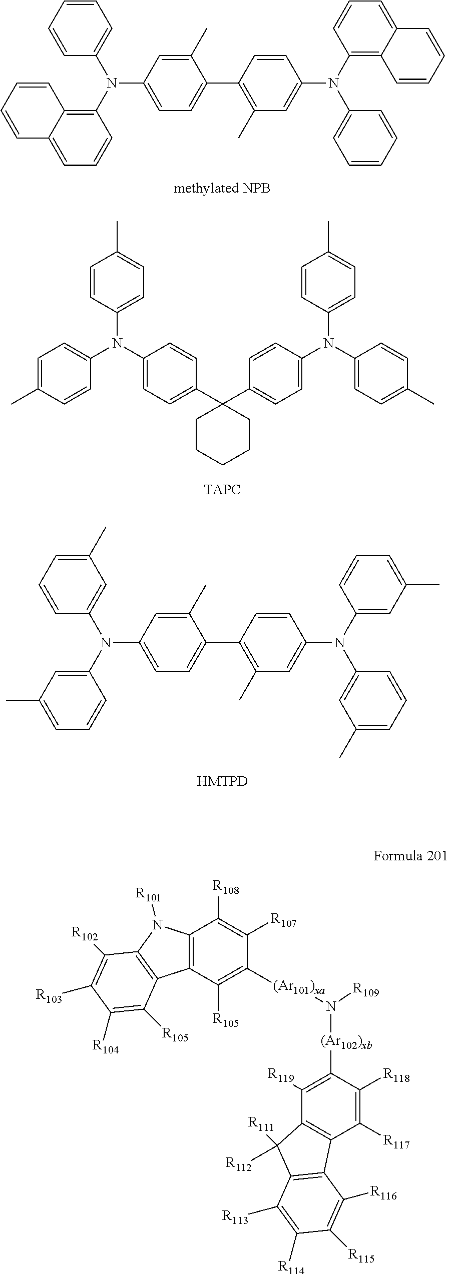

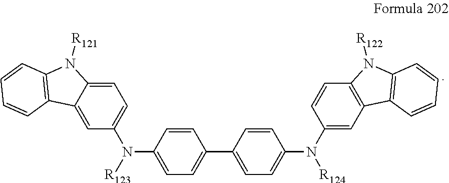

Ar₁₀₁ and Ar₁₀₂ in Formula 201 may each independently be selected from: a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, and a pentacenylene group; and

a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, and a pentacenylene group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group.

xa and xb in Formula 201 may each independently be an integer from 0 to 5, or 0, 1 or 2. For example, xa may be 1 and xb may be 0, but xa and xb are not limited thereto.

In Formulae 201 and 202, R₁₀₁ to R₁₀₈, R₁₁₁ to R₁₁₉, and R₁₂₁ to R₁₂₄ may each independently be selected from:

hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (for example, a methyl group, an ethyl group, a propyl group, a butyl group, a pentyl group, a hexyl group, and so on), and a C₁-C₁₀ alkoxy group (for example, a methoxy group, an ethoxy group, a propoxy group, a butoxy group, a pentoxy group, and so on);

a C₁-C₁₀ alkyl group and a C₁-C₁₀ alkoxy group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof;

a phenyl group, a naphthyl group, an anthracenyl group, a fluorenyl group, or a pyrenyl group; or

a phenyl group, a naphthyl group, an anthracenyl group, a fluorenyl group, and a pyrenyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, and a C₁-C₁₀ alkoxy group,

but embodiments of the present disclosure are not limited thereto, and

R₁₀₉ in Formula 201 may be selected from:

a phenyl group, a naphthyl group, an anthracenyl group, and a pyridinyl group; and

a phenyl group, a naphthyl group, an anthracenyl group, and a pyridinyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, and a pyridinyl group.

In an embodiment, the compound represented by Formula 201 may be represented by Formula 201A, but embodiments of the present disclosure are not limited thereto:

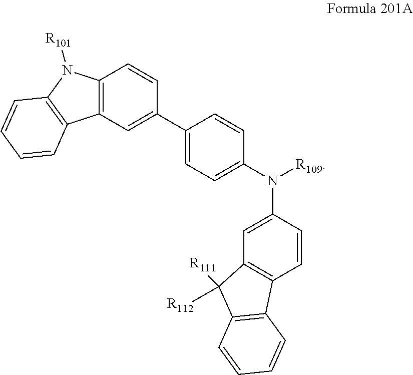

In Formula 201A, R₁₀₁, R₁₁₁, R₁₁₂, and R₁₀₉ may each independently be the same as described above.

For example, the compound represented by Formula 201, and the compound represented by Formula 202 may include compounds HT1 to HT20 illustrated below, but are not limited thereto:

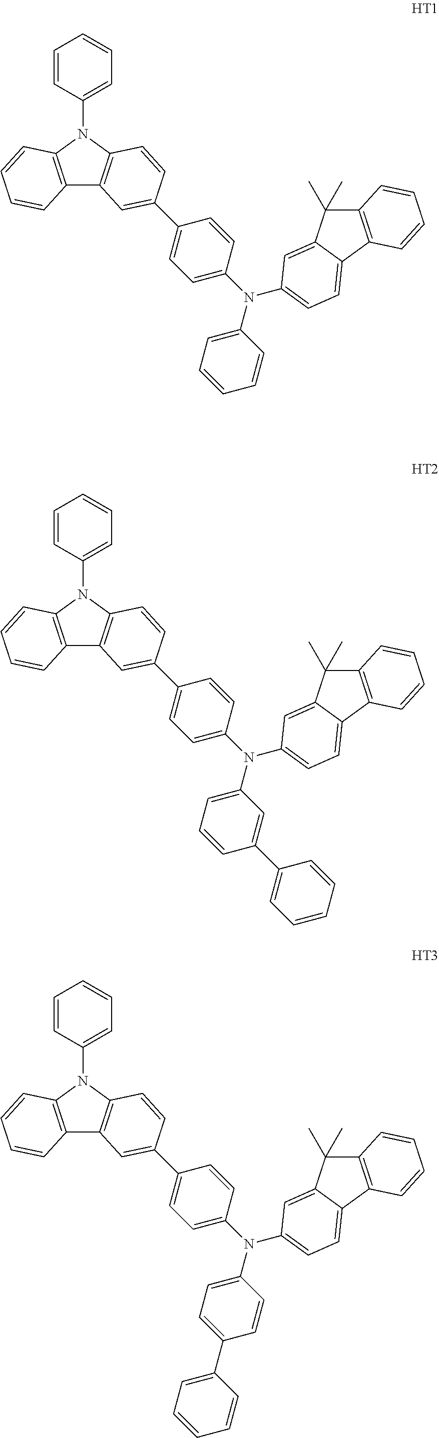 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

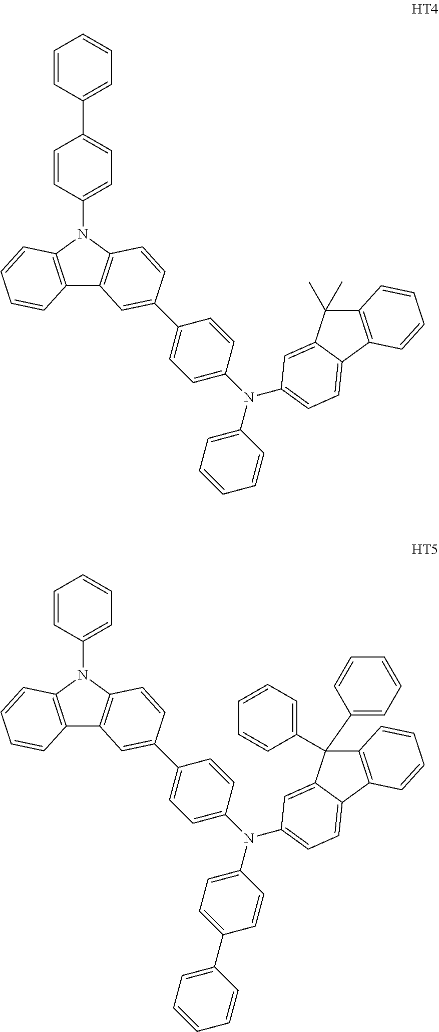 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

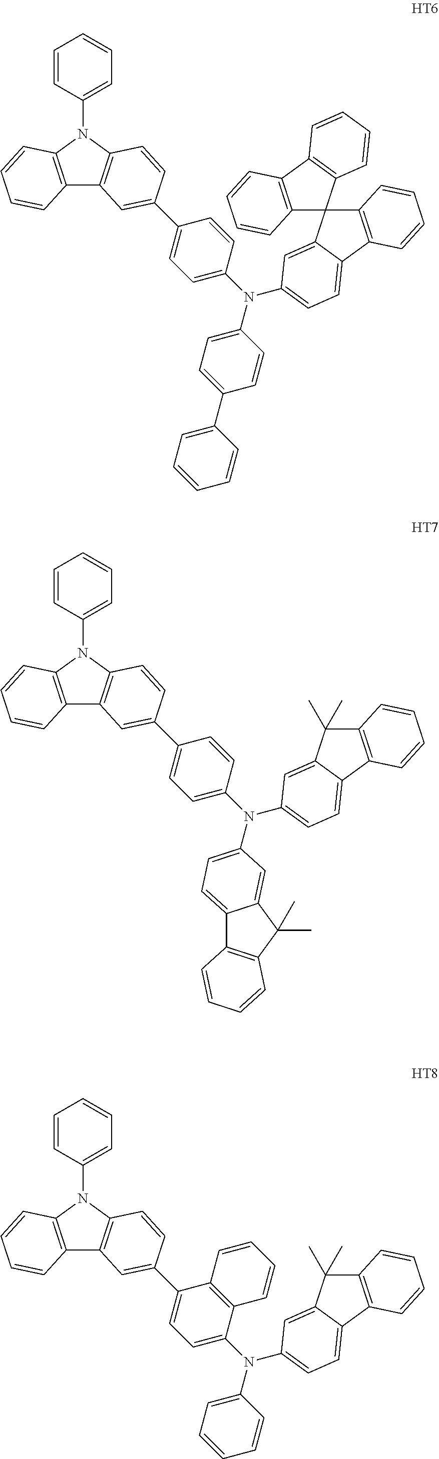 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21]

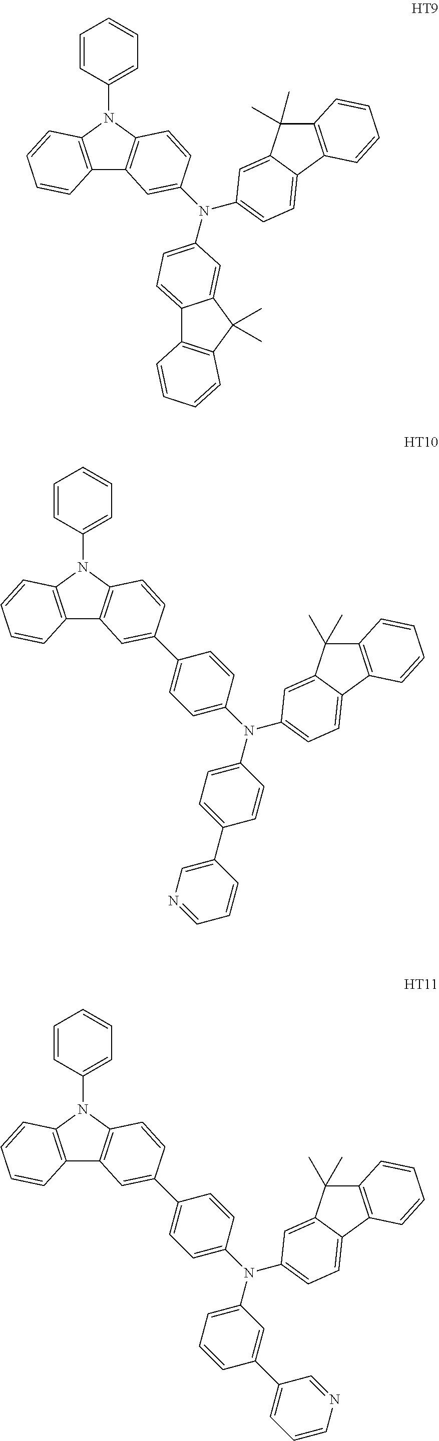 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

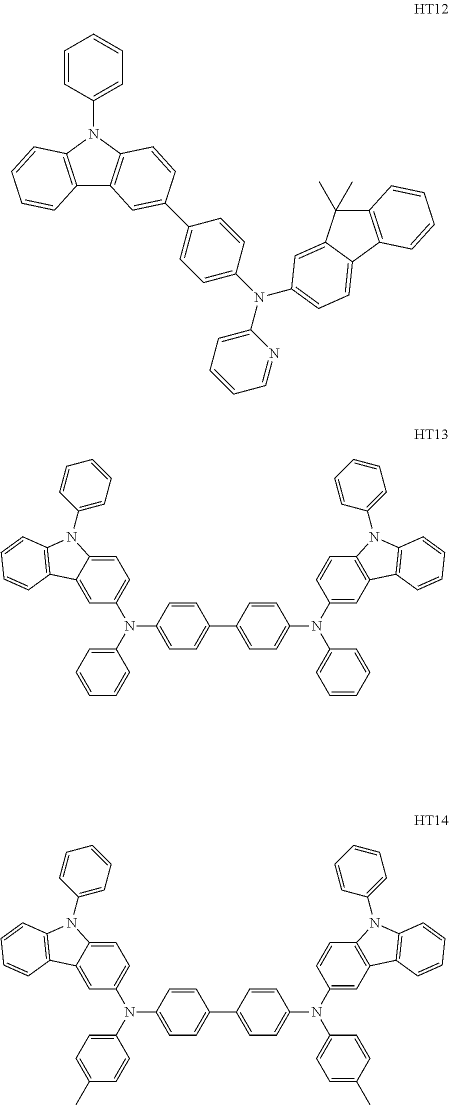 [SMILES: CC1(C)c2ccccc2-c2ccc(N(c3ccc(-c4ccc5c(c4)c4ccccc4n5-c4ccccc4)cc3)c3ccccn3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1]

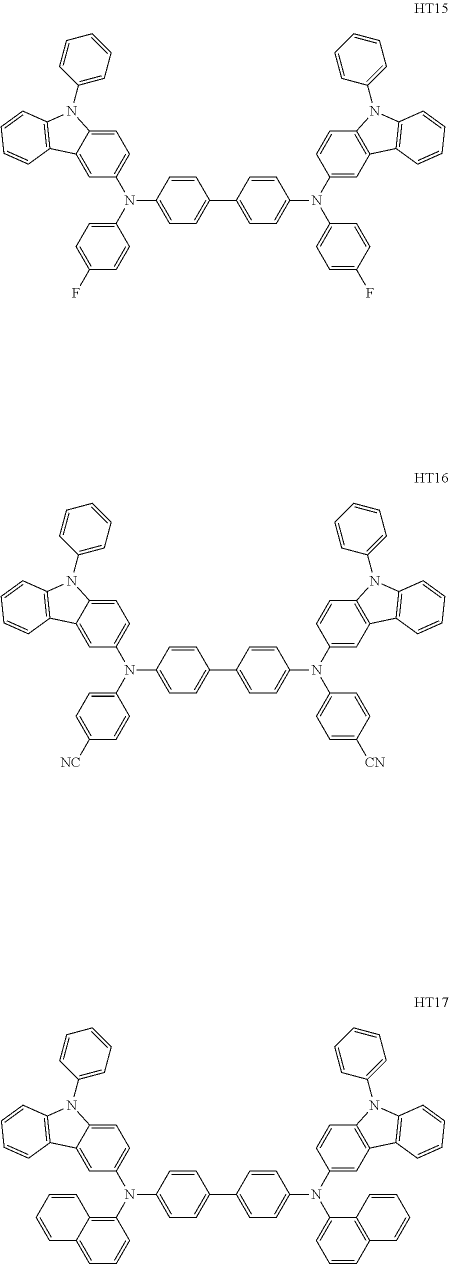 [SMILES: Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1]

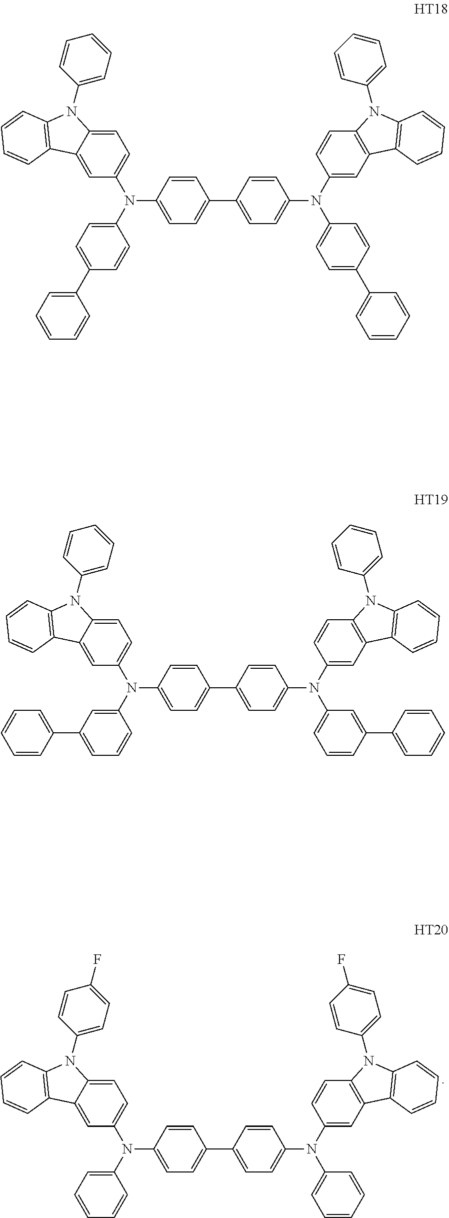 [SMILES: c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

The hole transport layer may include the condensed cyclic compound represented by Formula 1.

A thickness of the hole transport region may be in a range of about 100 Angstroms (Å) to about 10,000 Å, for example, about 100 Å to about 1,000 Å. When the hole transport region includes at least one of a hole injection layer and a hole transport layer, a thickness of the hole injection layer may be in a range of about 100 Å to about 10,000 Å, for example, about 100 Å to about 1,000 Å, and a thickness of the hole transport layer may be in a range of about 50 Å to about 2,000 Å, for example about 100 Å to about 1,500 Å. While not wishing to be bound by theory, it is understood that when the thicknesses of the hole transport region, the hole injection layer, and the hole transport layer are within these ranges, satisfactory hole transporting characteristics may be obtained without a substantial increase in driving voltage.

The hole transport region may further include, in addition to these materials, a charge-generation material for the improvement of conductive properties. The charge-generation material may be homogeneously or non-homogeneously dispersed in the hole transport region.

The charge-generation material may be, for example, a p-dopant. The p-dopant may be one selected from a quinone derivative, a metal oxide, and a cyano group-containing compound, but embodiments of the present disclosure are not limited thereto. Non-limiting examples of the p-dopant are a quinone derivative, such as tetracyanoquinonedimethane (TCNQ) or 2,3,5,6-tetrafluoro-tetracyano-1,4-benzoquinonedimethane (F4-TCNQ); a metal oxide, such as a tungsten oxide or a molybdenium oxide; and a cyano group-containing compound, such as Compound HT-D1 or HP-1, but are not limited thereto:

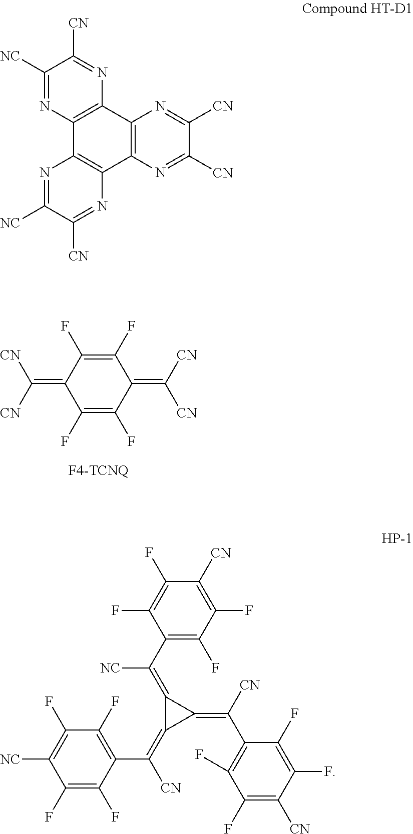

The hole transport region may include a buffer layer.

Also, the buffer layer may compensate for an optical resonance distance according to a wavelength of light emitted from the emission layer, and thus, efficiency of a formed organic light-emitting device may be improved.

Then, an emission layer may be formed on the hole transport region by vacuum deposition, spin coating, casting, LB deposition, or the like. When the emission layer is formed by vacuum deposition or spin coating, the deposition or coating conditions may be similar to those applied in forming the hole injection layer although the deposition or coating conditions may vary according to a compound that is used to form the emission layer.

The electron transport region may further include an electron blocking layer. The electron blocking layer may include, for example, mCP, but a material therefor is not limited thereto.

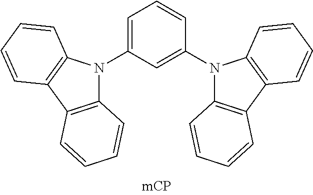 [SMILES: c1cc(-n2c3ccccc3c3ccccc32)cc(-n2c3ccccc3c3ccccc32)c1]

For example, the hole transport region may include the electron blocking layer, wherein the electron blocking layer includes the condensed cyclic compound represented by Formula 1.

A thickness of the electron blocking layer may be in a range of about 50 Å to about 1,000 Å, for example, about 70 Å to about 500 Å. While not wishing to be bound by theory, it is understood that when the thickness of the electron blocking layer is within the range described above, the electron blocking layer may have satisfactory electron blocking characteristics without a substantial increase in driving voltage.

When the organic light-emitting device is a full-color organic light-emitting device, the emission layer may be patterned into a red emission layer, a green emission layer, and a blue emission layer. In one or more embodiments, due to a stacked structure including a red emission layer, a green emission layer, and/or a blue emission layer, the emission layer may emit white light.

The emission layer may include the condensed cyclic compound represented by Formula 1. For example, the emission layer may include the compound represented by Formula 1 alone. In one or more embodiment, the emission layer may include a host and a dopant, and the host may include the condensed cyclic compound represented by Formula 1. In one or more embodiment, the emission layer may include a host and a dopant, and the dopant may include the condensed cyclic compound represented by Formula 1.

In one or more embodiment, the emission layer may further include a phosphorescent dopant, and the phosphorescent dopant may include an organometallic compound represented by Formula 81:

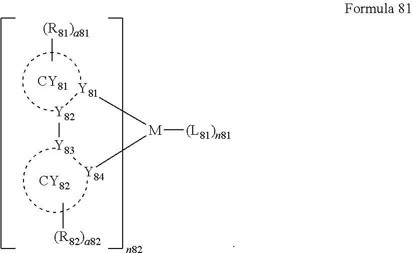

In Formula 81,

M may be selected from iridium (Ir), platinum (Pt), osmium (Os), titanium (Ti), zirconium (Zr), hafnium (Hf), europium (Eu), terbium (Tb), thulium (Tm), rhenium (Re), and rhodium (Rh),

Y₈₁ to Y₈₄ may each independently be C or N,

Y₈₁ and Y₈₂ may be linked each other via a single bond or a double bond, and Y₈₃ and Y₈₄ may be linked each other via a single bond or a double bond,

CY₈₁ and CY₈₂ may each independently be selected from a benzene group, a naphthalene group, a fluorene group, a spiro-bifluorene group, an indene group, a pyrrole group, a thiophene group, a furan group, an imidazole group, a pyrazole group, a thiazole group, an isothiazole group, an oxazole group, an isoxazole group, a pyridine group, a pyrazine group, a pyrimidine group, a pyridazine group, a quinoline group, an isoquinoline group, a benzoquinoline group, a quinoxaline group, a quinazoline group, a carbazole group, a benzimidazole group, a benzofuran group, a benzothiophene group, an isobenzothiophene group, a benzoxazole group, an isobenzoxazole group, a triazole group, a tetrazole group, an oxadiazole group, a triazine group, a dibenzofuran group, or a dibenzothiophene group, and CY₈₁ and CY₈₂ may optionally be further linked via an organic linking group,

R₈₁ and R₈₂ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), and —B(Q₆)(Q₇),

a81 and a82 may each independently be an integer of 1 to 5,

n81 may be an integer of 0 to 4,

n82 may be 1, 2, or 3,

L₈₁ may be a monovalent, divalent, or trivalent organic ligand, and

Q₁ to Q₇ may each independently have the same definition as Q₁ to Q₃ of —Si(Q₁)(Q₂)(Q₃) in Formula 1, and

R₈₁ and R₈₂ may each independently have the same definition as R₁₁.

The phosphorescent dopant may include at least one selected from Compounds PD1 to PD78 and FIr6, but embodiments of the present disclosure are not limited thereto:

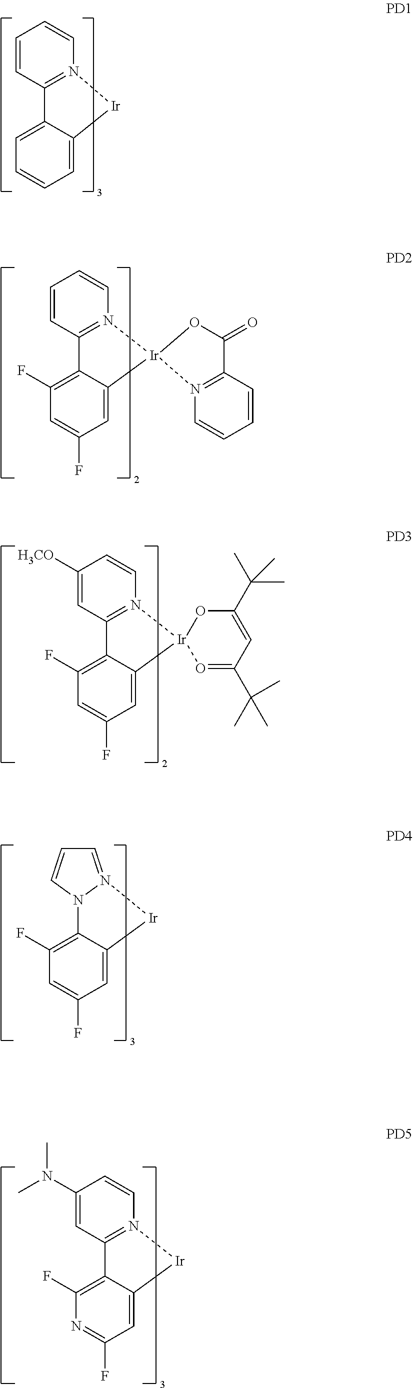

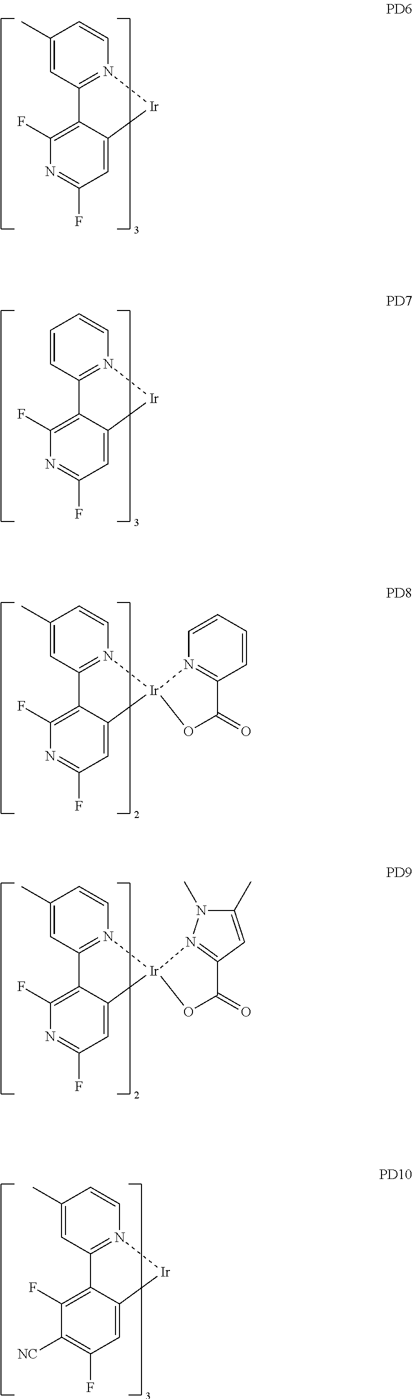

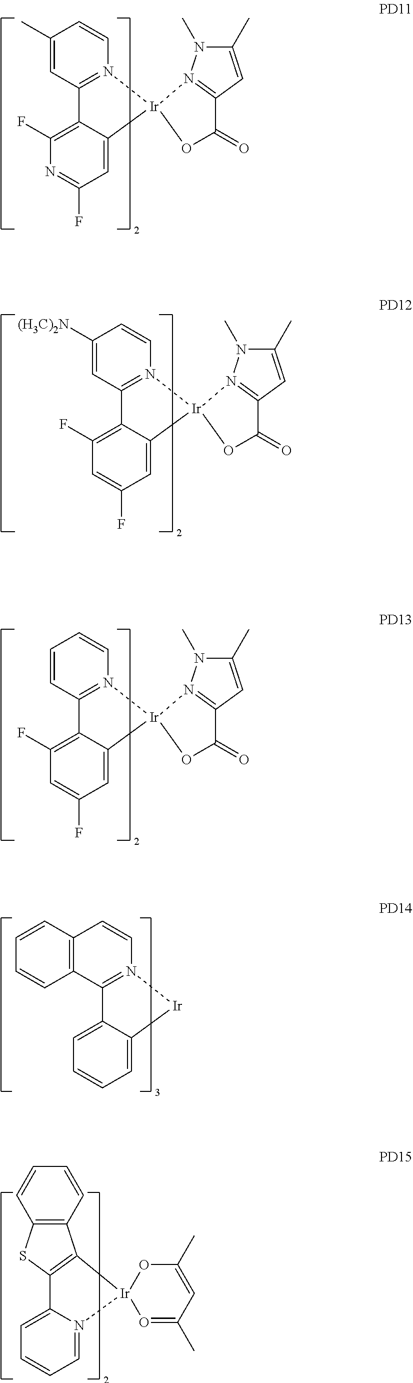

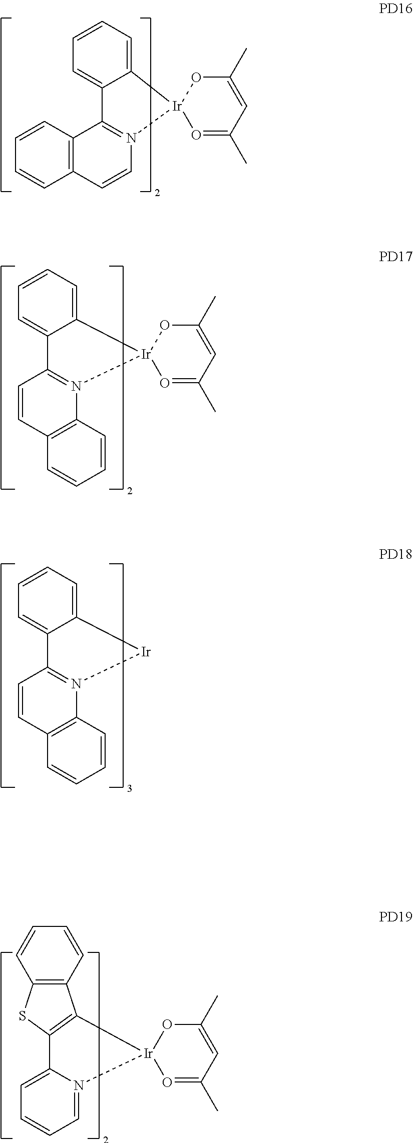

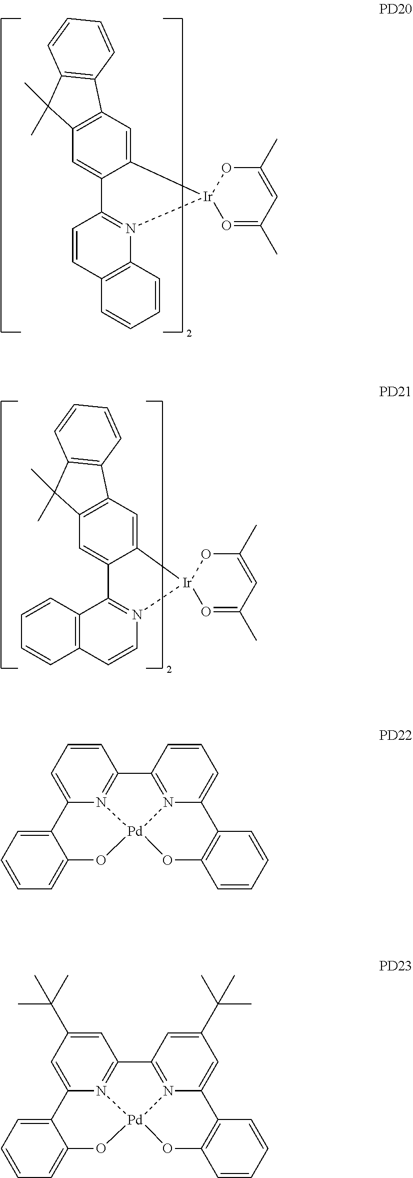

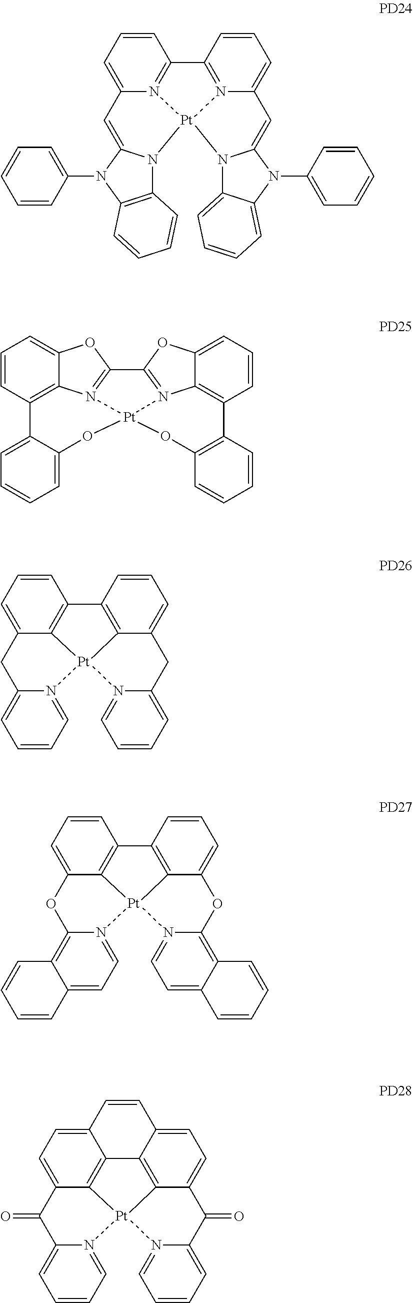

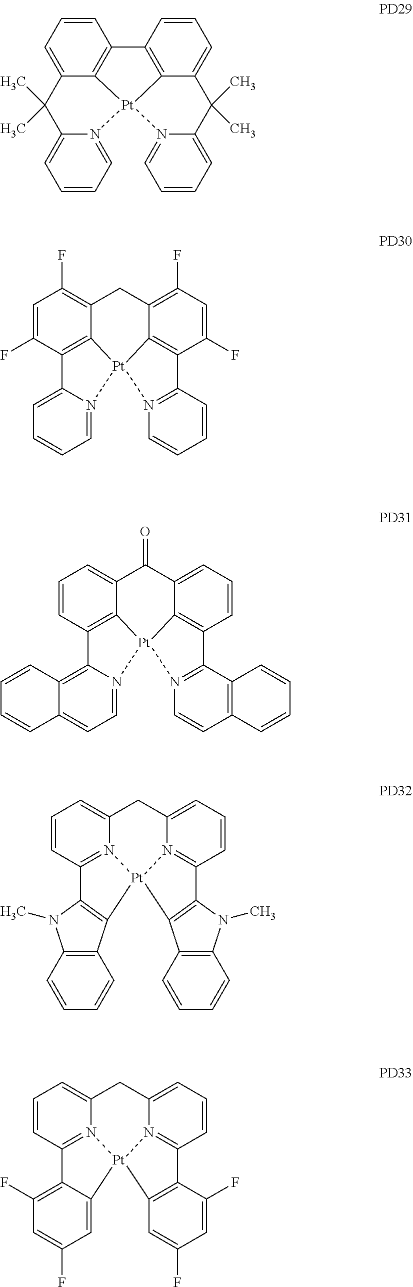

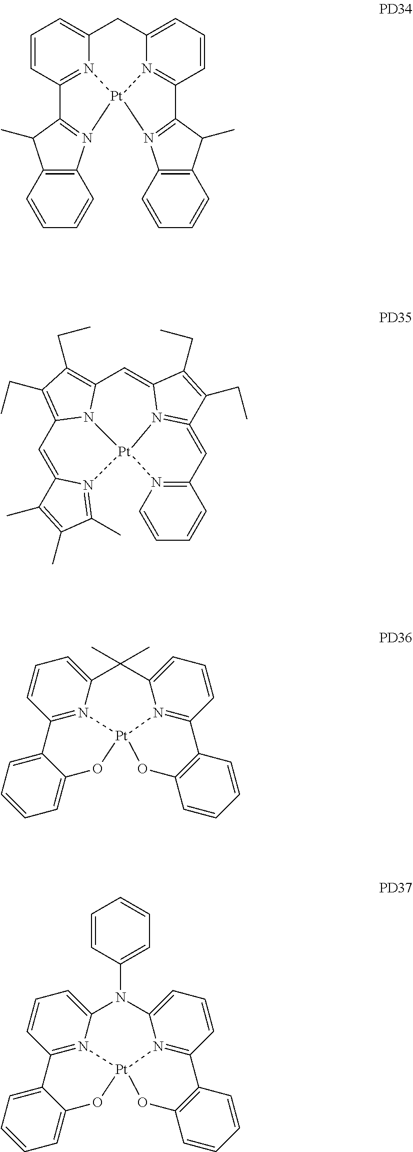

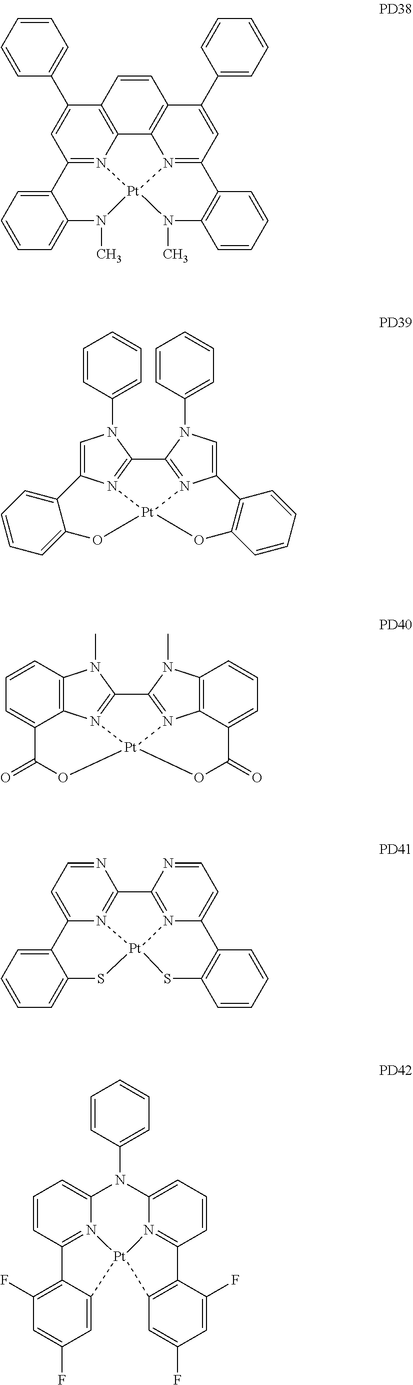

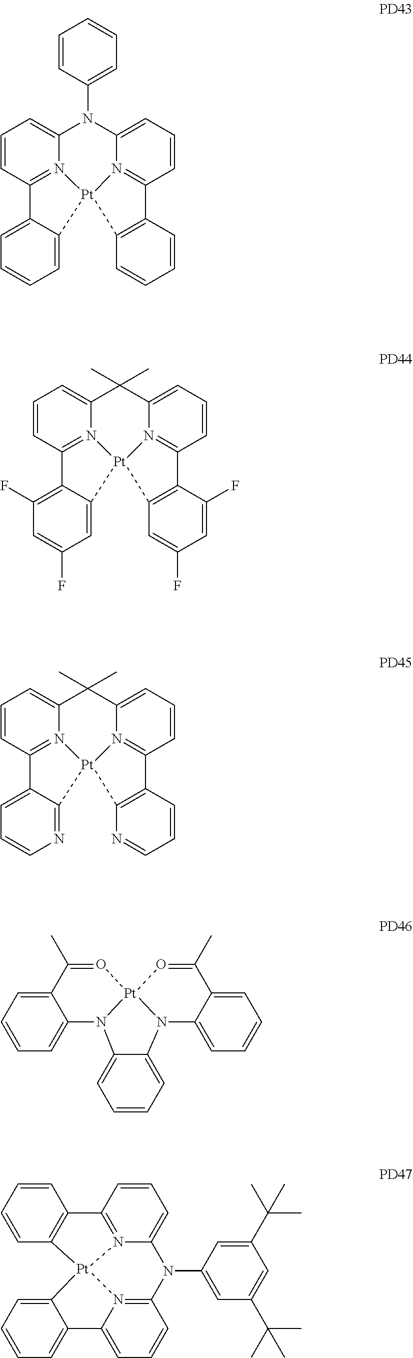

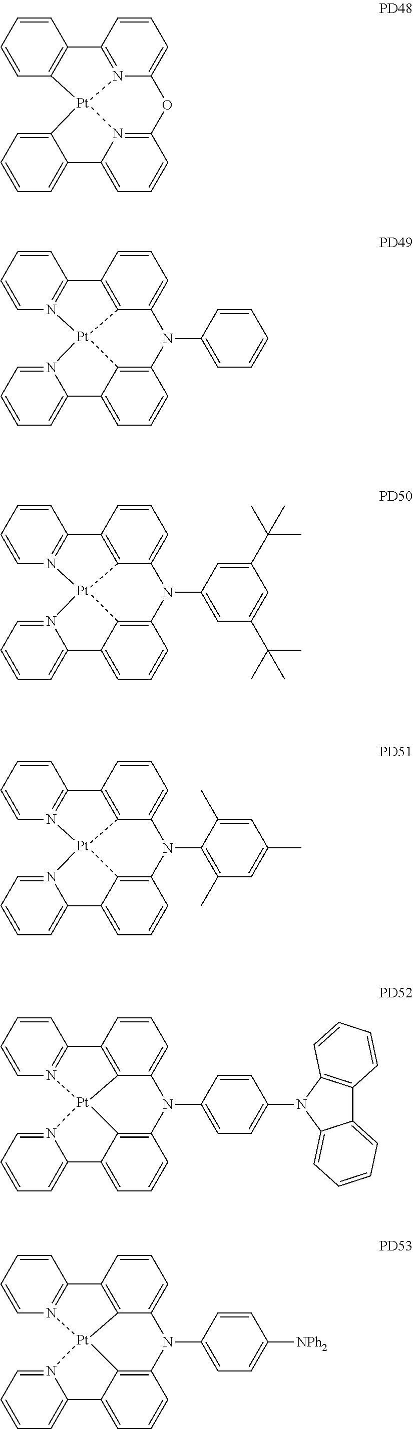

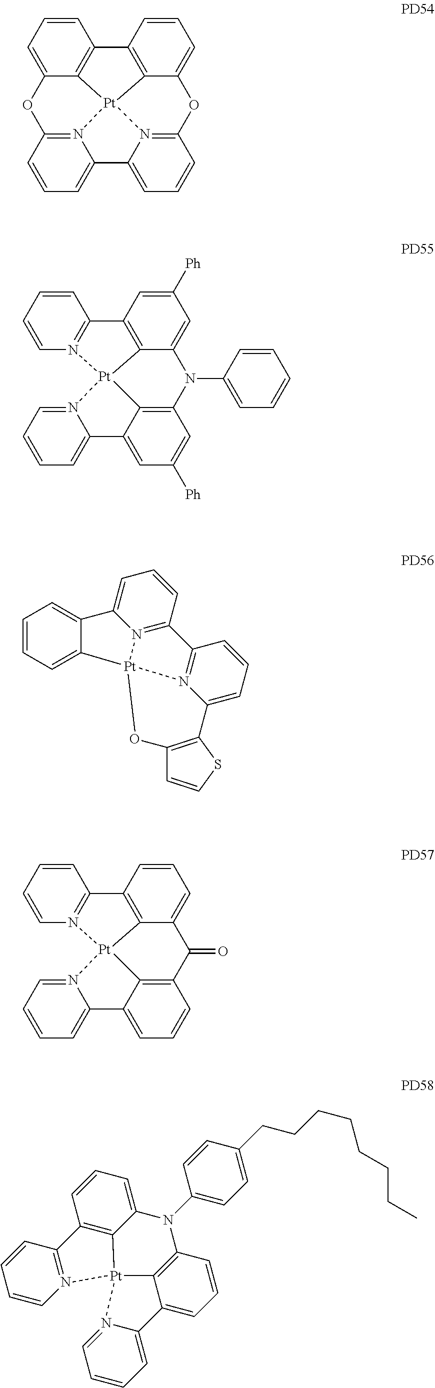

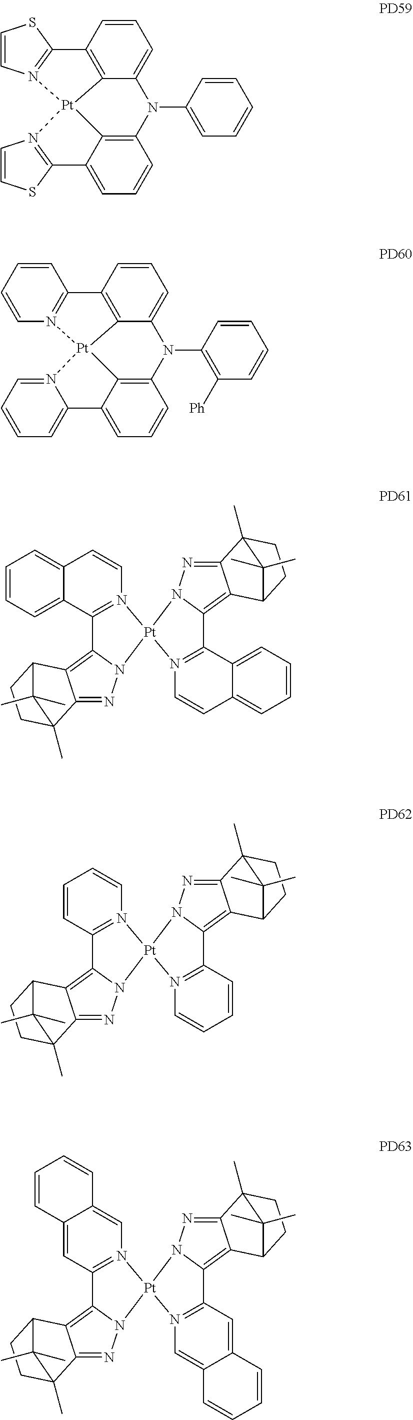

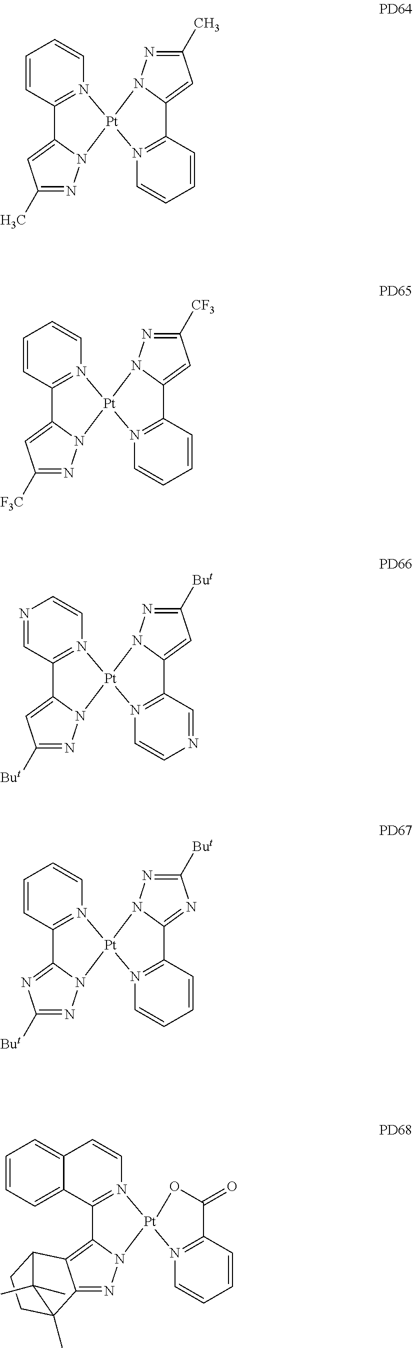

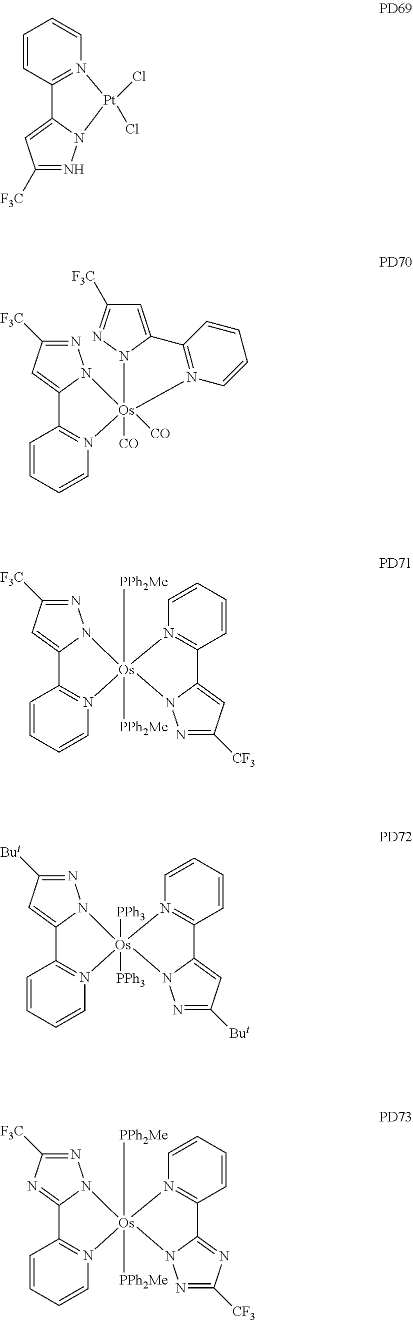

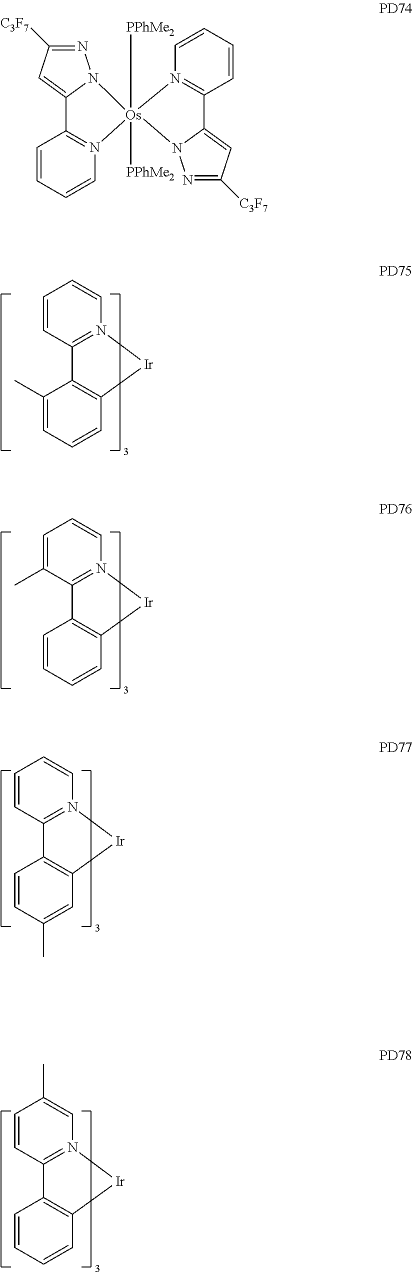

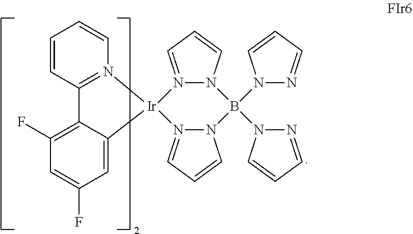

In one or more embodiments, the phosphorescent dopant may include PtOEP:

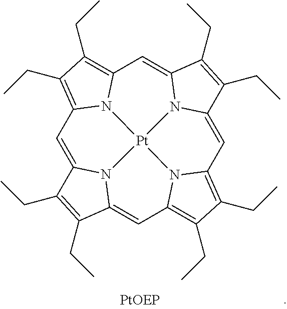

When the emission layer includes a host and a dopant, an amount of the dopant may be in a range of about 0.01 parts to about 20 parts by weight based on 100 parts by weight of the host, but embodiments of the present disclosure are not limited thereto.

A thickness of the emission layer may be in a range of about 100 Å to about 1,000 Å, for example, about 200 Å to about 600 Å. While not wishing to be bound by theory, it is understood that when the thickness of the emission layer is within this range, excellent light-emission characteristics may be obtained without a substantial increase in driving voltage.

Then, an electron transport region may be disposed on the emission layer.

The electron transport region may include at least one selected from a hole blocking layer, an electron transport layer, and an electron injection layer.

For example, the electron transport region may have a hole blocking layer/electron transport layer/electron injection layer structure or an electron transport layer/electron injection layer structure, but the structure of the electron transport region is not limited thereto. The electron transport layer may have a single-layered structure or a multi-layered structure including two or more different materials.

Conditions for forming the hole blocking layer, the electron transport layer, and the electron injection layer which constitute the electron transport region may be understood by referring to the conditions for forming the hole injection layer.

When the electron transport region includes a hole blocking layer, the hole blocking layer may include, for example, at least one of BCP and Bphen, but may also include other materials:

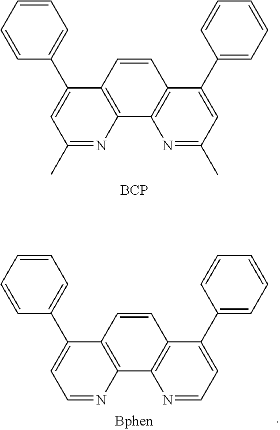

A thickness of the hole blocking layer may be in a range of about 20 Å to about 1,000 Å, for example, about 30 Å to about 300 Å. While not wishing to be bound by theory, it is understood that when the thickness of the hole blocking layer is within these ranges, the hole blocking layer may have excellent hole blocking characteristics without a substantial increase in driving voltage.

The electron transport layer may further include, in addition to the organometallic compound represented by Formula 1, at least one selected from BCP, Bphen, Alq₃, BAlq, TAZ, and NTAZ:

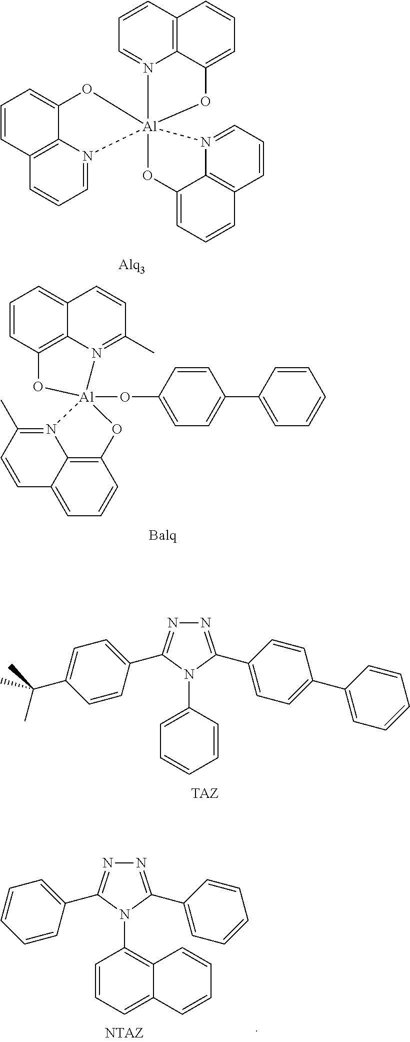

In one or more embodiments, the electron transport layer may include at least one selected from Compounds ET1, ET2, and ET3, but embodiments of the present disclosure are not limited thereto:

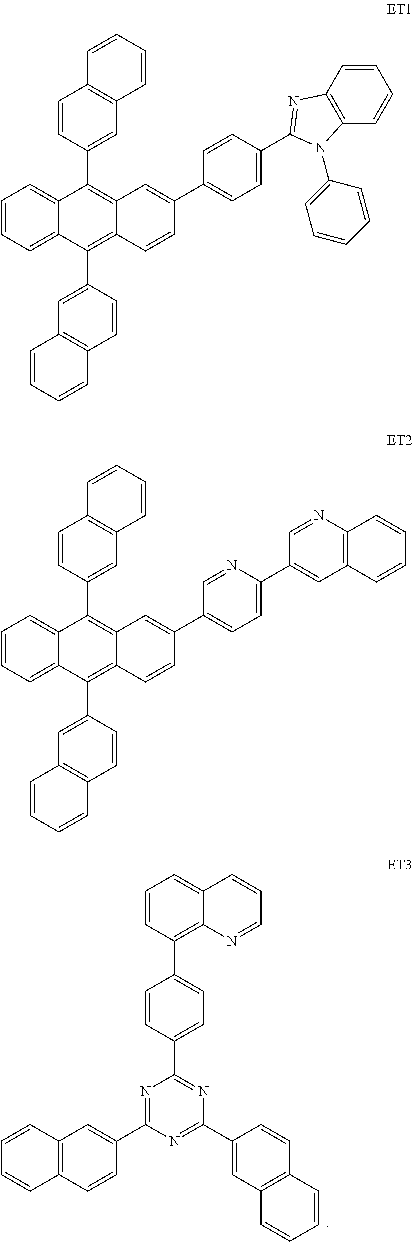 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

A thickness of the electron transport layer may be in a range of about 100 Å to about 1,000 Å, for example, about 150 Å to about 500 Å. While not wishing to be bound by theory, it is understood that when the thickness of the electron transport layer is within the range described above, the electron transport layer may have satisfactory electron transport characteristics without a substantial increase in driving voltage.

Also, the electron transport layer may further include, in addition to the materials described above, a metal-containing material.

The metal-containing material may include a Li complex. The Li complex may include, for example, Compound ET-D1 (lithium 8-hydroxyquinolate, LiQ) or ET-D2:

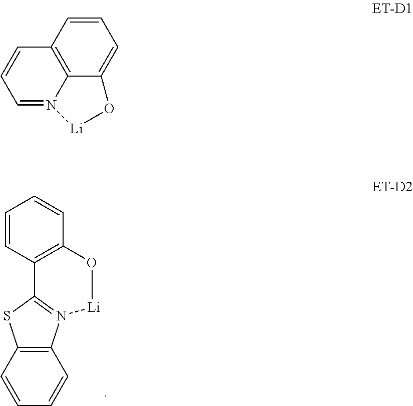

The electron transport region may include an electron injection layer (EIL) that promotes flow of electrons from the second electrode 19 thereinto.

The electron injection layer may include at least one selected from LiQ, LiF, NaCl, CsF, Li₂O, and BaO.

A thickness of the electron injection layer may be in a range of about 1 Å to about 100 Å, for example, about 3 Å to about 90 Å. While not wishing to be bound by theory, it is understood that when the thickness of the electron injection layer is within the range described above, the electron injection layer may have satisfactory electron injection characteristics without a substantial increase in driving voltage.

The second electrode 19 is disposed on the organic layer 15. The second electrode 19 may be a cathode. A material for forming the second electrode 19 may be metal, an alloy, an electrically conductive compound, or a combination thereof, which have a relatively low work function. For example, lithium (Li), magnesium (Mg), aluminum (Al), aluminum-lithium (Al—Li), calcium (Ca), magnesium-indium (Mg—In), or magnesium-silver (Mg—Ag) may be formed as the material for forming the second electrode 19. To manufacture a top-emission type light-emitting device, a transmissive electrode formed using ITO or IZO may be used as the second electrode 19.

In an embodiment, the organic layer 15 of the organic light-emitting device may include a hole transport region and an emission layer, and the hole transport region and the emission layer may include the condensed cyclic compound represented by Formula 1. Here, the condensed cyclic compound represented by Formula 1 included in the hole transport region may be identical to the condensed cyclic compound represented by Formula 1 included in the emission layer.

In one or more embodiments, the organic layer 15 of the organic light-emitting device may include a hole transport region and an emission layer, and the hole transport region and the emission layer may include the condensed cyclic compound represented by Formula 1. Here, the condensed cyclic compound represented by Formula 1 included in the hole transport region may be different from the condensed cyclic compound represented by Formula 1 included in the emission layer.

The hole transport region may include at least one selected from a hole transport layer and an electron blocking layer, and the condensed cyclic compound represented by Formula 1 may be included in i) a hole transport layer, ii) an electron blocking layer, or iii) both in a hole transport layer and an electron blocking layer. The electron blocking layer may directly contact the emission layer.

Hereinbefore, the organic light-emitting device according to an embodiment has been described in connection with FIG. 1, but embodiments of the present disclosure are not limited thereto.

The term “C₁-C₆₀ alkyl group” as used herein refers to a linear or branched aliphatic saturated hydrocarbon monovalent group having 1 to 60 carbon atoms, and examples thereof include a methyl group, an ethyl group, a propyl group, an iso-butyl group, a sec-butyl group, a tert-butyl group, a pentyl group, an iso-amyl group, and a hexyl group. The term “C₁-C₆₀ alkylene group” as used herein refers to a divalent group having the same structure as the C₁-C₆₀ alkyl group.

The term “C₁-C₆₀ alkoxy group” as used herein refers to a monovalent group represented by —OA₁₀₁ (wherein A₁₀₁ is the C₁-C₆₀ alkyl group), and examples thereof include a methoxy group, an ethoxy group, and an iso-propyloxy group.

The term “C₂-C₆₀ alkenyl group” as used herein refers to a hydrocarbon group having at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group having at least one carbon-carbon triple bond in the middle or at the terminus of the C₂-C₆₀ alkyl group, and examples thereof include an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon monocyclic group having 3 to 10 carbon atoms, and examples thereof include a cyclopropyl group, a cyclobutyl group, a cyclopentyl group, a cyclohexyl group, and a cycloheptyl group. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent saturated monocyclic group having at least one heteroatom selected from N, O, P, Si and S as a ring-forming atom and 1 to 10 carbon atoms, and non-limiting examples thereof include a tetrahydrofuranyl group, and a tetrahydrothiophenyl group. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent monocyclic group that has 3 to 10 carbon atoms and at least one carbon-carbon double bond in the ring thereof and no aromaticity, and non-limiting examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that has at least one heteroatom selected from N, O, P, Si, and S as a ring-forming atom, 1 to 10 carbon atoms, and at least one carbon-carbon double bond in its ring. Non-limiting examples of the C₂-C₁₀ heterocycloalkenyl group include a 2,3-dihydrofuranyl group, and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Non-limiting examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

The term “C₁-C₆₀ heteroaryl group,” used herein, refers to a monovalent group having a carbocyclic aromatic system that has at least one heteroatom selected from N, O, P, and S as a ring-forming atom, in addition to 1 to 60 carbon atoms. A C₁-C₆₀ heteroarylene group used herein refers to a divalent group having a carbocyclic aromatic system that has at least one heteroatom selected from N, O, P, and S as a ring-forming atom, in addition to 1 to 60 carbon atoms. Examples of the C₁-C₆₀ heteroaryl group are a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include two or more rings, the rings may be fused to each other.

The term “C₆-C₆₀ aryloxy group” as used herein refers to —OA₁₀₂ (wherein A₁₀₂ is the C₆-C₆₀ aryl group), and a C₆-C₆₀ arylthio group used herein indicates —SA₁₀₃ (wherein A₁₀₃ is the C₆-C₆₀ aryl group).

The term “monovalent non-aromatic condensed polycyclic group” as used herein refers to a monovalent group having two or more rings condensed to each other, only carbon atoms (for example, the number of carbon atoms may be in a range of 8 to 60) as a ring-forming atom, and no aromaticity in its entire molecular structure. Non-limiting examples of the monovalent non-aromatic condensed polycyclic group include a fluorenyl group. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group having two or more rings condensed to each other, a heteroatom selected from N, O, P, Si, and S, other than carbon atoms (for example, the number of carbon atoms may be in a range of 2 to 60), as a ring-forming atom, and no aromaticity in its entire molecular structure. Non-limiting examples of the monovalent non-aromatic condensed heteropolycyclic group include a carbazolyl group. The term “divalent non-aromatic condensed heteropolycyclic group” as used herein refers to a divalent group having the same structure as the monovalent non-aromatic condensed heteropolycyclic group.

In the specification, in Formula 1, at least one substituent of the substituted C₁-C₆₀ alkyl group, the substituted C₂-C₆₀ alkenyl group, the substituted C₂-C₆₀ alkynyl group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may be selected from:

deuterium, —CD₃, —CD₂H, —CDH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from deuterium, —CD₃, —CD₂H, —CDH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —N(Q₁₄)(Q₁₅), and —B(Q₁₆)(Q₁₇);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from deuterium, —CD₃, —CD₂H, —CDH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —N(Q₂₄)(Q₂₅), and —B(Q₂₆)(Q₂₇); and

—Si(Q₃₁)(Q₃₂)(Q₃₃), —N(Q₃₄)(Q₃₅), and —B(Q₃₆)(Q₃₇), and

Q₁ to Q₇, Q₁₁ to Q₁₇, Q₂₁ to Q₂₇, and Q₃₁ to Q₃₇ may each independently be selected from hydrogen, deuterium, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group.

The term “biphenyl group” refers to a monovalent group in which two benzene groups are linked via a single bond.

The term “terphenyl group” refers to a monovalent group in which two benzene groups are linked via a single bond.

Hereinafter, a compound and an organic light-emitting device according to embodiments are described in detail with reference to Synthesis Example and Examples. However, the organic light-emitting device is not limited thereto. The wording “‘B’ was used instead of ‘A’” used in describing Synthesis Examples means that a molar equivalent of ‘A’ was identical to a molar equivalent of ‘B’.

### EXAMPLES

### Synthesis Example 1: Synthesis of Compound 43

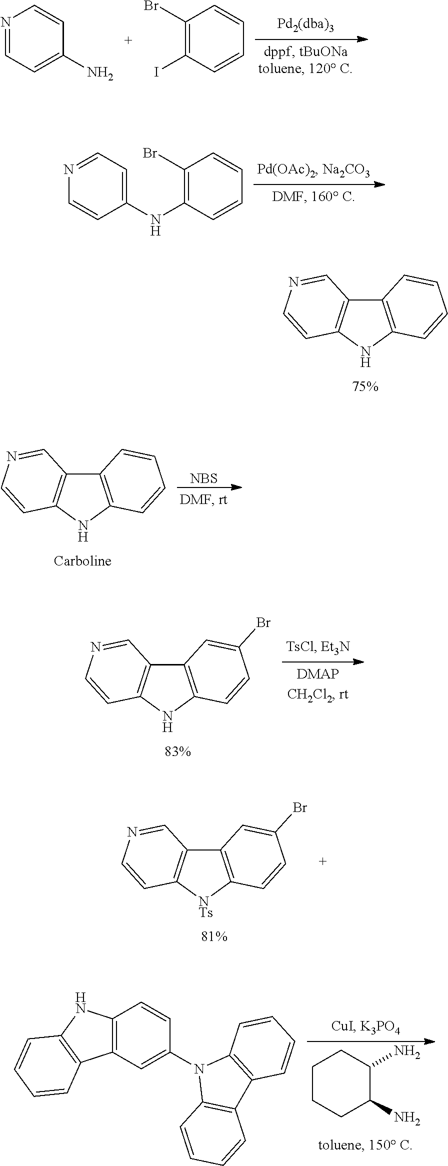

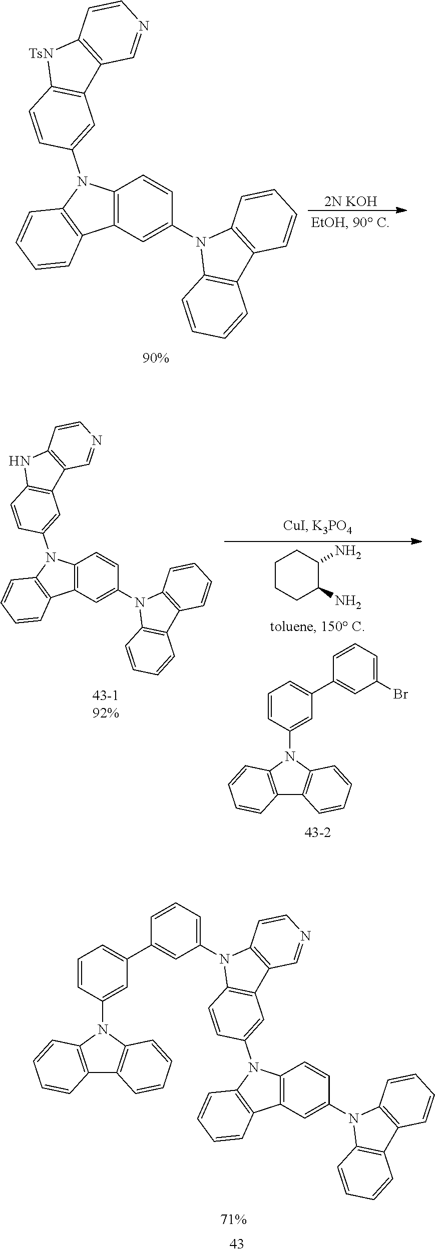

### (1) Synthesis of Intermediate 43-2

### (i) Synthesis of 9-(3-Iodophenyl)-9H-Carbazole

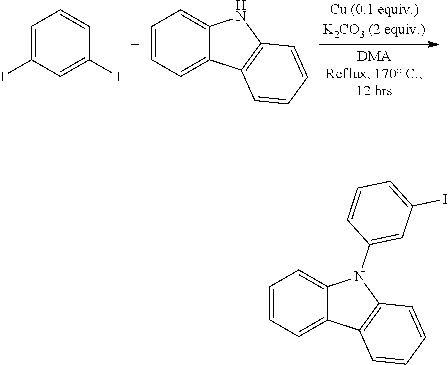

7.10 grams (g) (21.5 millimoles, mmol) of 1,3-diiodobenzene, 0.060 g (0.900 mmol) of copper powder, and 4.95 g (35.9 mmol) of potassium carbonate were added to a solution in which 3.00 g (17.9 mmol) of 9H-carbazole was stirred in 60 milliliters (mL) of N,N-dimethylacetamide. The generated solution was heated for 12 hours at a temperature of 170° C. under nitrogen stream. The reaction solution was cooled to room temperature, filtered through a celite pad, and washed with EtOAc. The mixed filtrate was repeatedly washed with water, dried by using anhydrous magnesium sulfate, filtered, and concentrated under reduced pressure. The oily material obtained therefrom was purified by silica gel column chromatography (Hexane:EtOAc=9:1) to obtain 2.78 g (yield of 42%) of 9-(3-iodophenyl)-9H-carbazole.

White solid, yield of 42%; R_{f} 0.5 (Hexane/EtOAc:9/1); ¹H NMR (400 MHz, CDCl₃) δ 8.20-8.15 (m, 2H), 7.98 (t, J=1.9 Hz, 1H), 7.82 (ddt, J=7.9, 1.5, 0.7 Hz, 1H), 7.60-7.55 (m, 1H), 7.48-7.42 (m, 4H), 7.38-7.31 (m, 3H).

### (ii) Synthesis of 9-(3-(4,4,5,5-tetramethyl-1,3,2-dioxaborolan-2-yl)phenyl)-9H-carbazole

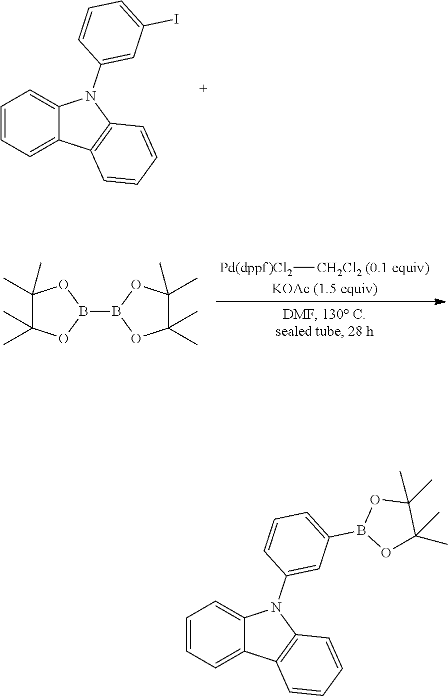

A sealed tube equipped with a magnetic stir bar was filled with a solution of 2.70 g (7.00 mmol) of aryl iodide, 2.79 g (11.0 mmol) of bis(pinacolato)diboron, 0.600 g (0.730 mmol) of PdCl₂(dppf)₂-CH₂Cl₂, and 1.08 g (11.0 mmol) of KOAc in 60 mL (DMF).

The generated mixture was stirred at a temperature of 130° C. for 24 hours. The reaction mixture was cooled to the ambient temperature. The mixture was filtered through a celite pad and washed with CH₂Cl₂. The filtrate was concentrated in vacuum and the residue was purified by column chromatography (Hexane:Toluene=1:2) to provide 1.94 g (yield of 72%) of a boronate product.

White solid, yield of 72%; R_{f} 0.5 (Hexane/Toluene: 1/2); ¹H NMR (400 MHz, CDCl₃) δ 8.14 (dt, J=7.8, 1.0 Hz, 2H), 7.99 (dt, J=1.9, 0.8 Hz, 1H), 7.91 (ddd, J=6.8, 1.8, 1.1 Hz, 1H), 7.67-7.58 (m, 2H), 7.43-7.35 (m, 4H), 7.28 (ddd, J=8.0, 6.6, 1.6 Hz, 2H), 1.35 (s, 12H); ¹³C NMR (101 MHz, CDCl₃) δ 141.01, 137.19, 133.78, 133.47, 130.07, 129.25, 128.18, 125.79, 123.23, 120.18, 119.71, 109.78, 84.06, 77.30, 76.98, 76.66, 24.86.

### (iii) Synthesis of Intermediate 43-2

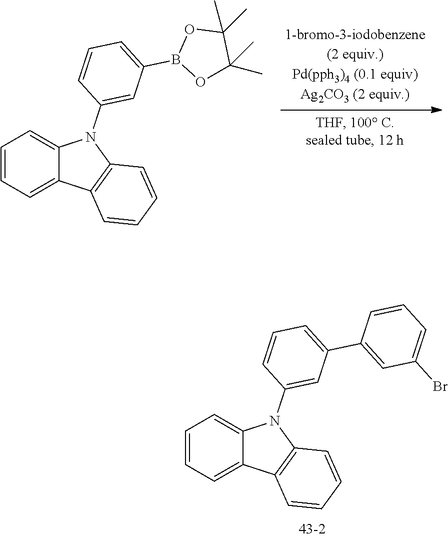 [SMILES: CC1(C)OB(c2cccc(-n3c4ccccc4c4ccccc43)c2)OC1(C)C ; Brc1cccc(-c2cccc(-n3c4ccccc4c4ccccc43)c2)c1]

2.00 g (5.40 mmol) of boronate ester, 1.38 mL (10.8 mmol) of 3-bromoiodobenzene, 0.630 g (0.540 mmol) of tetrakis(triphenylphosphine)palladium(0), 2.99 g (10.8 mmol) of Ag₂CO₃, and 90 mL of tetrahydrofuran were added to a 150-mL dual-wall pressure vessel. The mixture was heated and stirred at a temperature of 100° C. for 12 hours. The reaction solution was cooled to room temperature and filtered through celite. The filtrate was concentrated in vacuum and the residue was purified by column chromatography (Hexane:Toluene=4:1) to provide 1.61 g (yield of 75%) of Intermediate 43-2 (9-(3′-bromo-[1,1′-biphenyl]-3-yl)-9H-carbazole).

White solid, yield of 75%; R_{f} 0.5 (Hexane/Toluene: 4/1); ¹H NMR (400 MHz, CDCl₃) δ 8.18 (dt, J=7.8, 1.0 Hz, 2H), 7.83-7.76 (m, 2H), 7.71-7.64 (m, 2H), 7.61-7.54 (m, 2H), 7.54-7.41 (m, 5H), 7.33 (ddt, J=7.9, 6.5, 1.7 Hz, 3H); ¹³C NMR (101 MHz, CDCl₃) δ 142.17, 141.59, 140.76, 138.33, 130.77, 130.46, 130.44, 130.20, 129.03, 128.22, 126.43, 126.07, 126.03, 125.78, 125.67, 125.30, 123.41, 123.07, 120.39, 120.06, 109.70.

### (2) Synthesis of Intermediate 43-1

### (i) Synthesis of 4-(2′-bromoanilino)pyridine

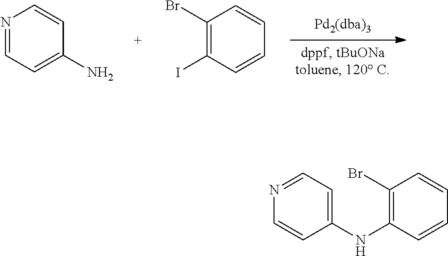 [SMILES: Nc1ccncc1 ; Brc1ccccc1I ; Brc1ccccc1Nc1ccncc1]

944 milligrams (mg) (10.0 mmol) of 4-aminopyridine, 1.14 g (11.9 mmol) of t-BuONa, 137 mg (0.150 mmol) of tris(dibenzylideneacetone)-dipalladium, and 200 mg (0.361 mmol) of 1,10-bis(diphenylphosphino)ferrocene were added to a sealed tube equipped with a magnetic stir bar. The generated mixture was stirred at a temperature of 120° C. for 18 hours. The reaction mixture was cooled to the ambient temperature.

The mixture was filtered through a celite pad and washed with CH₂Cl₂. The filtrate was concentrated in vacuum, and the residue was purified by column chromatography (3% MeOH in CH₂Cl₂, then 10% MeOH in CH₂Cl₂) to provide 2.48 g (yield of 99%) of 4-(2′-bromoanilino)pyridine.

### (ii) Synthesis of 5H-pyrido[4,3-b]indole

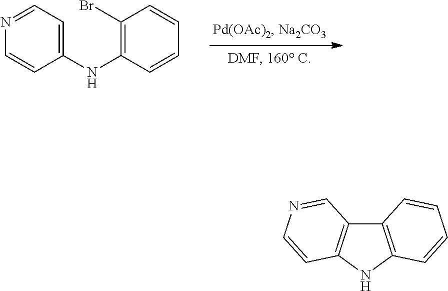 [SMILES: Brc1ccccc1Nc1ccncc1 ; c1ccc2c(c1)[nH]c1ccncc12]

2.48 g (9.96 mmol) of 4-(2′-bromoanilino)pyridine, 112 mg (4.98 mmol) of Pd(OAc)₂, and 1.48 g (13.9 mmol) of Na₂CO₃ were added to a sealed tube equipped with a magnetic stir bar. The mixture was purged with nitrogen and 20 mL of DMF was added thereto. The generated mixture was stirred at a temperature of 160° C. for 20 hours. The reaction mixture was cooled to the ambient temperature. The mixture was filtered through a celite pad and washed with CH₂Cl₂. The filtrate was concentrated in vacuum, the residue was diluted with 12 mL of H₂O, extracted with EtOAc (20 mL×6), dried by using MgSO₄, and concentrated in vacuum. The residue was purified by flash column chromatography (5% MeOH in CH₂Cl₂, then 15% MeOH in CH₂Cl₂) to provide 1.26 g (yield of 75%) of 5H-pyrido[4,3-b]indole.

### (iii) Synthesis of 8-bromo-5H-pyrido[4,3-b]indole

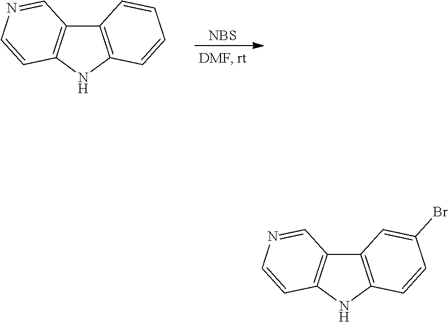

1.60 g (8.99 mmol) of N-bromosuccinimide (NBS) was added by small portions to 1.26 g (7.49 mmol) of the starting material (SM) solution in 20 mL of DMF (20 mL) at room temperature. The reaction mixture was stirred at room temperature for 12 hours and diluted with 20 mL of H₂O. The aqueous layer was extracted therefrom by using EtOAc (30 mL×4) and evaporated in vacuum. The residue was purified by column chromatography (5% MeOH in CH₂Cl₂) to generate 1.53 g (83%) of bromide.

### (iv) Synthesis of 8-bromo-5-tosyl-5H-pyrido[4,3-b]indole

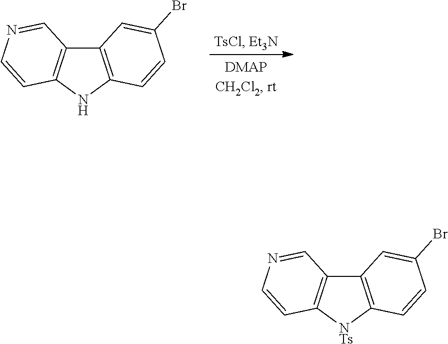

1.3 mL (9.29 mmol) of Et₃N, 1.42 g (7.43 mmol) of p-toluenesulfonyl chloride (TsCl), and 76 mg (0.62 mmol) of 4-dimethylaminopyridine (DMAP) were added to 1.53 g (6.19 mmol) of SM solution in 30 mL of CH₂Cl₂ at room temperature. The reaction mixture was stirred at room temperature for 2 hours and quenched by using 30 mL of saturated aqueous NaHCO₃. The combined organic layer was extracted therefrom by using EtOAc (30 mL×3), dried by using MgSO₄, and concentrated in vacuum. The residue was purified by flash column chromatography (Hexane:EtOAc=1:1 then 1:3) to provide 2.03 g (81%) of 8-bromo-5-tosyl-5H-pyrido[4,3-b]indole.

### (v) Synthesis of 9-(5-tosyl-5H-pyrido[4,3-b]indol-8-yl)-9H-3,9′-bicarbazole

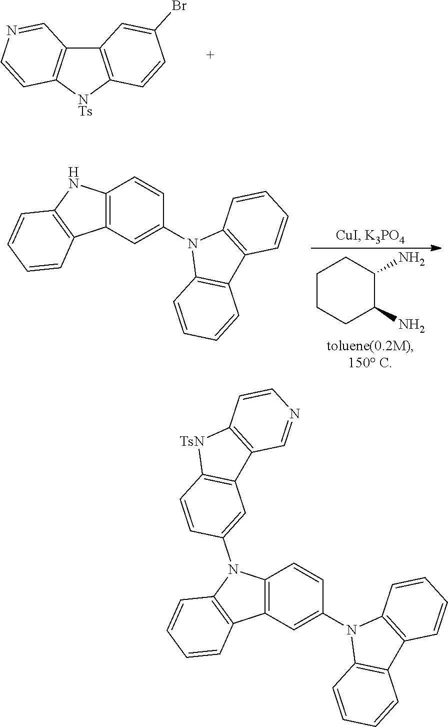

A sealed tube equipped with a magnetic stir bar was filled with 1.5 g (3.74 mmol) of 8-bromo-5-tosyl-5H-pyrido[4,3-b]indole, 1.37 g (4.11 mmol) of 9H-3,9′-bicarbazole, 214 mg (1.12 mmol) of CuI, and 2.38 g (11.2 mmol) of K₃PO₄. The mixture was purged with nitrogen, 19 mL of dry toluene was added thereto, and 128 mg (11.2 mmol) of (±)-trans-1,2-diaminocyclohexane was added thereto. The generated mixture was stirred at a temperature of 150° C. for 16 hours. The reaction mixture was cooled to the ambient temperature. The mixture was filtered through a celite pad and washed with CH₂Cl₂. The filtrate was concentrated in vacuum, and the residue was purified by column chromatography (acetone:CH₂Cl₂=1:30) to provide 2.18 g (yield of 89%) of 9-(5-tosyl-5H-pyrido[4,3-b]indol-8-yl)-9H-3,9′-bicarbazole.

### (vi) Synthesis of Intermediate 43-1

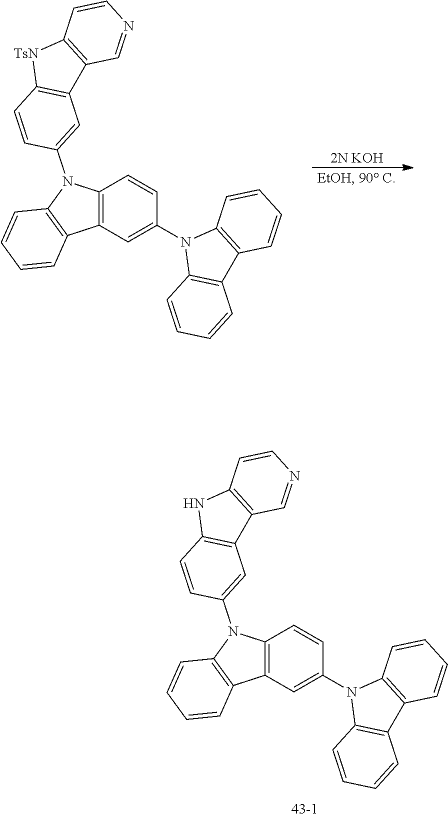 [SMILES: Cc1ccc(S(=O)(=O)n2c3ccncc3c3cc(-n4c5ccccc5c5cc(-n6c7ccccc7c7ccccc76)ccc54)ccc32)cc1 ; "2N KOH" ; "EtOH, 90° C." ; c1ccc2c(c1)c1ccccc1n2-c1ccc2c(c1)c1ccccc1n2-c1ccc2[nH]c3ccncc3c2c1]

16 mL of 2N KOH (2 normal potassium hydroxide solution) was added to 2.18 g (3.34 mmol) of SM solution in 60 mL of ethanol (EtOH). The reaction mixture was stirred at a temperature of 90° C. for 2 hours, cooled to 0° C., and diluted with 12 mL of 2N HCl (2 normal hydrogen chloride solution). The remaining EtOH was evaporated and discarded, and the aqueous layer was extracted therefrom by using CH₂Cl₂ (30 mL×3), dried over MgSO₄, and concentrated in vacuum. The residue was purified by flash column chromatography (acetone:CH₂Cl₂=1:20 then 5% MeOH in CH₂Cl₂) to provide 1.40 g (84%) of Intermediate 43-1.

### (3) Synthesis of Compound 43

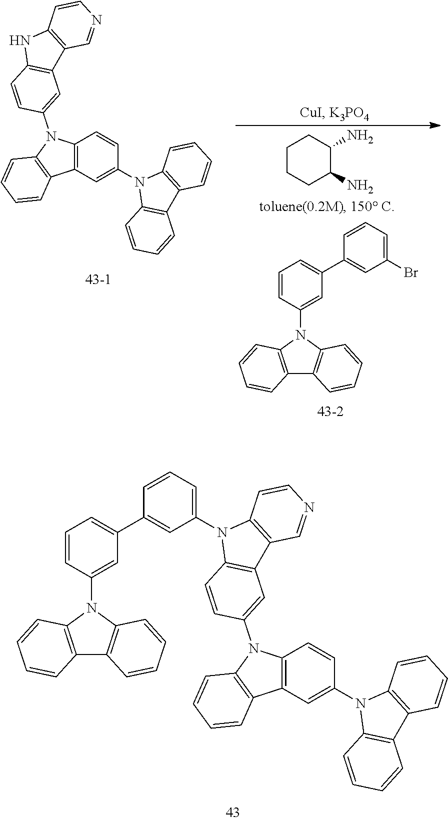

A sealed tube equipped with a magnetic bar was filled with 850 mg (1.70 mmol) of Intermediate 43-1, 747 mg (1.88 mmol) of Intermediate 43-2, 97 mg (0.51 mmol) of CuI, and 1.09 g (5.11 mmol) of K₃PO₄. The reaction mixture was purged with nitrogen and 8.5 mL of dry toluene, and 58 mg (0.51 mmol) of (±)-trans-1,2-diaminocyclohexane was added thereto. The obtained mixture was stirred at a temperature of 150° C. for 40 hours. The reaction mixture was cooled to room temperature. The mixture was filtered through a celite pad and washed with CH₂Cl₂. The filtrate was concentrated in vacuum, and the residue was purified by column chromatography (acetone:CH₂Cl₂=1:15) to provide 924 mg (yield of 66%) of Compound 43.

LC-Mass (Calcd: 815.98 g/mol, Found: 816.08 g/mol (M+1)).

### Synthesis Example 2: Synthesis of Compound 64

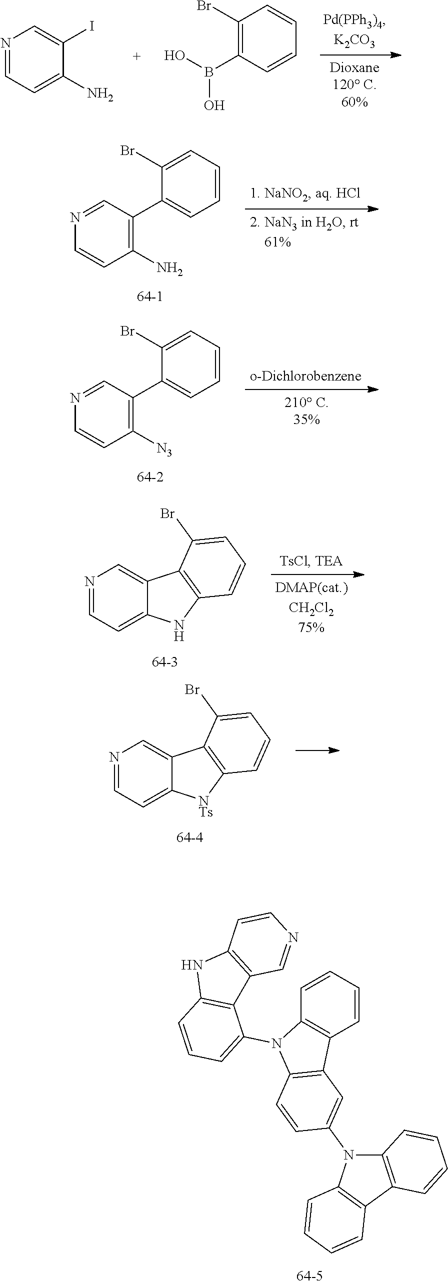

### (1) Synthesis of Intermediate 64-1

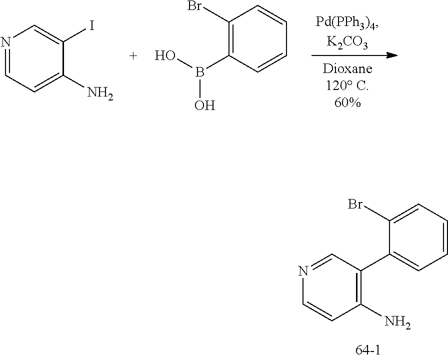 [SMILES: Nc1ccncc1I ; OB(O)c1ccccc1Br ; Nc1ccncc1-c1ccccc1Br]

4.0 g (18.18 mmol) of 3-iodopyridin-4-amine, 4.38 g (21.82 mmol) of (2-bromophenyl)boronic acid, 1.05 g (0.91 mmol) of palladium tetrakis(triphenylphosphine) (Pd(PPh₃)₄), and 4.67 g (36.36 mmol) of potassium carbonate (K₂CO₃) were added to 36 mL of dioxane and heated under reflux. After the reaction was completed, the reaction product was cooled to room temperature, and the organic layer was extracted therefrom by using dichloromethane and water and filtered through silica gel. The obtained organic layer was concentrated and precipitated by pouring methanol, and 3.78 g (yield of 83%) of a white solid, Intermediate 64-1, was synthesized.

GC-Mass (Calcd: 249.11 g/mol, Found: 249.1 g/mol (M+0)).

### (2) Synthesis of Intermediate 64-2

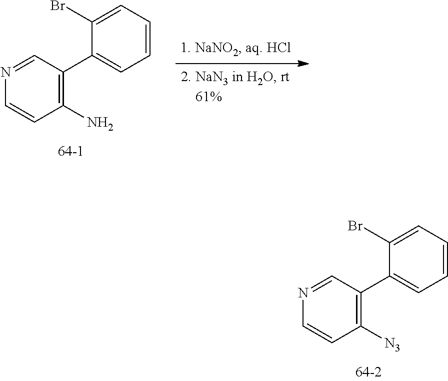 [SMILES: Nc1ccncc1-c1ccccc1Br ; [N-]=[N+]=Nc1ccncc1-c1ccccc1Br]

3.5 g (14.05 mmol) of 3-(2-bromophenyl)pyridin-4-amine and 1.94 g (28.10 mmol) of sodium nitrite (NaNO₂) was added and stirred at room temperature. 200 mL of aqueous hydrochloric acid solution was added to the generated mixture, which was further stirred for about 1 hour. After the reaction was completed, an aqueous solution was made by using 1.83 g (28.10 mmol) of sodium azide (NaN₃), added to a reaction vessel, and the mixture was additionally stirred at room temperature for 4 hours. After the reaction was completed, only the organic layer was extracted therefrom by using an organic solvent, and a solvent was concentrated. 2.35 g (61%) of Intermediate 64-2 was obtained without purification.

GC-Mass (Calcd: 275.11 g/mol, Found: 275.1 g/mol (M+0)).

### (3) Synthesis of Intermediate 64-3

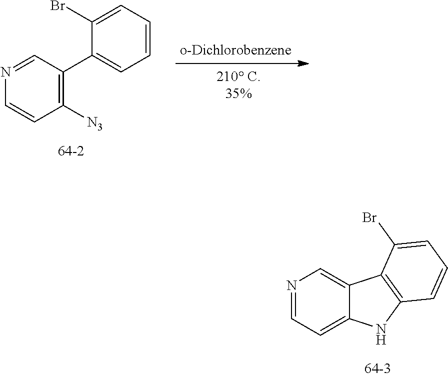 [SMILES: [N-]=[N+]=Nc1ccncc1-c1ccccc1Br ; Brc1cccc2[nH]c3ccncc3c12]

2.35 g (8.54 mmol) of 4-azido-3-(2-bromophenyl)pyridine and 50 mL of o-dichlorobenzene were added and stirred at a temperature of 210° C. for 12 hours. After the reaction was completed, methanol was added thereto, and the mixture was filtered through silica gel. The obtained organic layer was concentrated, dissolved again in toluene, filtered through silica gel, and then concentrated. The residue was recrystallized in toluene to provide 0.74 g (yield of 35%) of a yellow solid, Intermediate 64-3.

GC-Mass (Calcd: 247.1 g/mol, Found: 247.1 g/mol (M+0)).

### (4) Synthesis of Intermediate 64-4

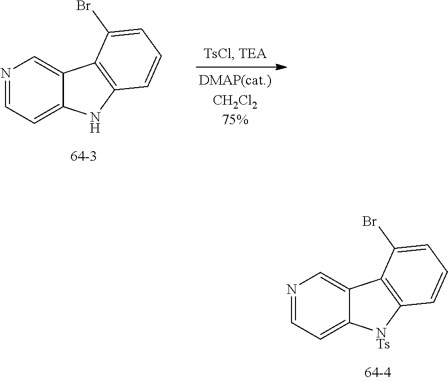 [SMILES: Brc1cccc2[nH]c3ccncc3c12 ; Cc1ccc(S(=O)(=O)n2c3ccncc3c3c(Br)cccc32)cc1]

900 mg (yield of 75%) of Intermediate 64-4 was synthesized in the same manner as in step (iv) of Synthesis Example 1, except that Intermediate 9-bromo-5H-pyrido[4,3-b]indole was used instead of Intermediate 8-bromo-5H-pyrido[4,3-b]indole.

LC-Mass (Calcd: 401.28 g/mol, Found: 401.38 g/mol (M+1)).

### (5) Synthesis of Intermediate 64-5

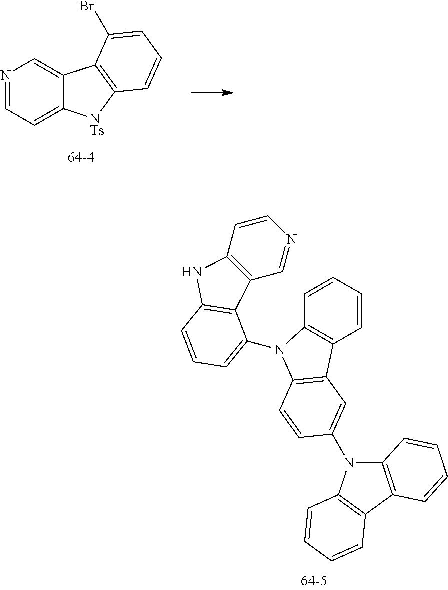 [SMILES: Cc1ccc(S(=O)(=O)n2c3ccncc3c3c(Br)cccc32)cc1 ; c1cc(-n2c3ccccc3c3cc(-n4c5ccccc5c5ccccc54)ccc32)c2c(c1)[nH]c1ccncc12]

2.3 g (yield of 88%) of Intermediate 5 was synthesized in the same manner as in step (v) of Synthesis Example 1, except that Intermediate 9-bromo-5-tosyl-5H-pyrido[4,3-b]indole was used instead of Intermediate 8-bromo-5-tosyl-5H-pyrido[4,3-b]indole.

LC-Mass (Calcd: 498.59 g/mol, Found: 498.69 g/mol (M+1)).

### (6) Synthesis of Compound 64

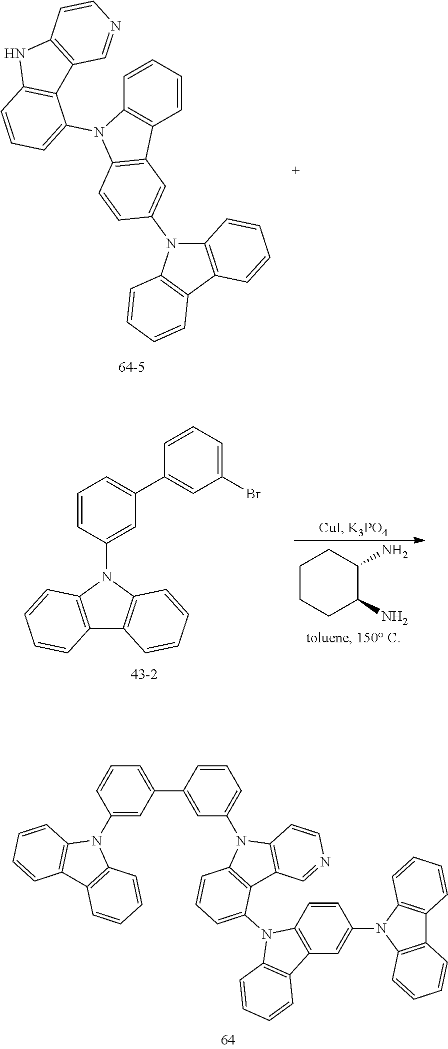

2.2 g (yield of 58%) of Compound 64 was synthesized in the same manner as used to synthesize Compound 43 of Synthesis Example 1, except that Intermediate 64-5 was used instead of Intermediate 43-1.

LC-Mass (Calcd: 815.98 g/mol, Found: 816.08 g/mol (M+1)).

### Example 1

A glass substrate, on which a 1,500 Angstroms (Å) ITO electrode (first electrode, anode) was formed, was washed by distilled water sonication. When the washing with distilled water was completed, sonification washing was performed using a solvent, such as iso-propyl alcohol, acetone, or methanol. The resulting substrate was dried and then transferred to a plasma washer, where it was washed with oxygen plasma for 5 minutes and then, transferred to a vacuum depositing device.

Compound HT3 was vacuum-deposited on the ITO electrode of the glass substrate to form a hole injection layer having a thickness of 100 Å, and Compound HT13 was deposited on the hole injection layer to form a hole transport layer having a thickness of 1,300 Å, thereby forming a hole transport region.

Compound 43 (host) and Compound DPEPO (dopant, 15 weight %) were deposited on the hole transport region to form an emission layer having a thickness of 300 Å.

ET3 and LiQ were co-deposited on the emission layer to form an electron transport layer having a thickness of 250 Å, LiQ was deposited on the electron transport layer to form an electron injection layer having a thickness of 5 Å, and Al was deposited on the electron injection layer to form an Al second electrode (cathode) having a thickness of 1,000 Å, thereby completing the manufacture of an organic light-emitting device.

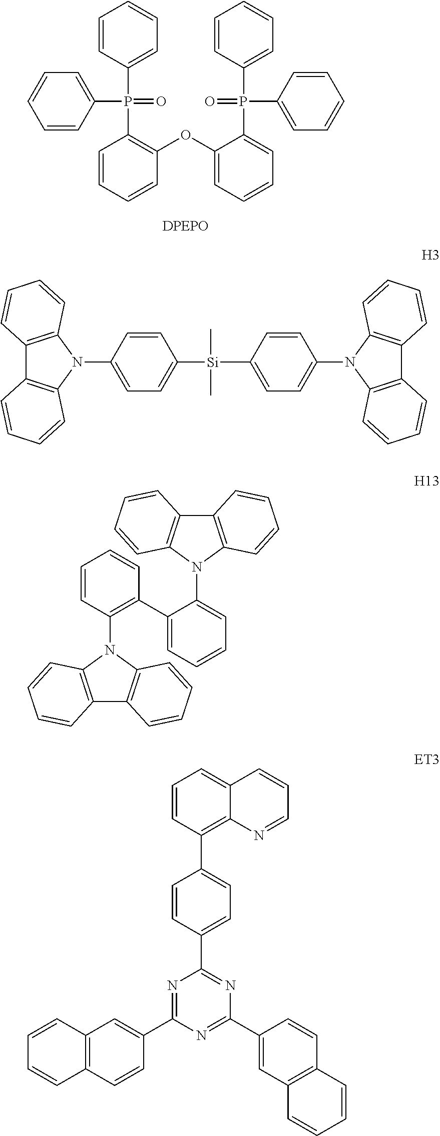 [SMILES: O=P(c1ccccc1)(c1ccccc1)c1ccccc1Oc1ccccc1P(=O)(c1ccccc1)c1ccccc1 ; C[Si](C)(c1ccc(-n2c3ccccc3c3ccccc32)cc1)c1ccc(-n2c3ccccc3c3ccccc32)cc1 ; c1ccc(-n2c3ccccc3c3ccccc32)c(-c2ccccc2-n2c3ccccc3c3ccccc32)c1 ; c1ccc2cc(-c3nc(-c4ccc(-c5cccc6cccnc56)cc4)nc(-c4ccc5ccccc5c4)n3)ccc2c1]

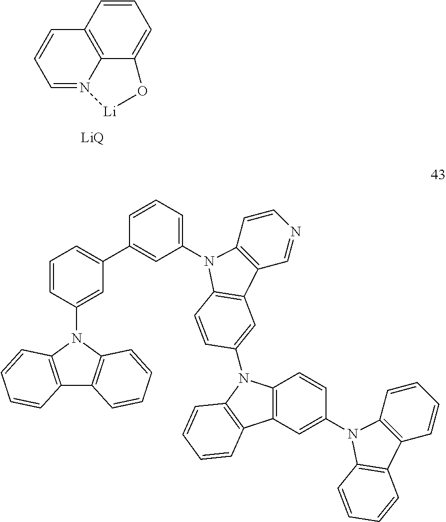

### Example 2 and Comparative Examples 1 to 5

Organic light-emitting devices were manufactured in the same manner as in Example 1, except that Compounds shown in Table 2 were each used instead of Compound 43 as a host in forming an emission layer.

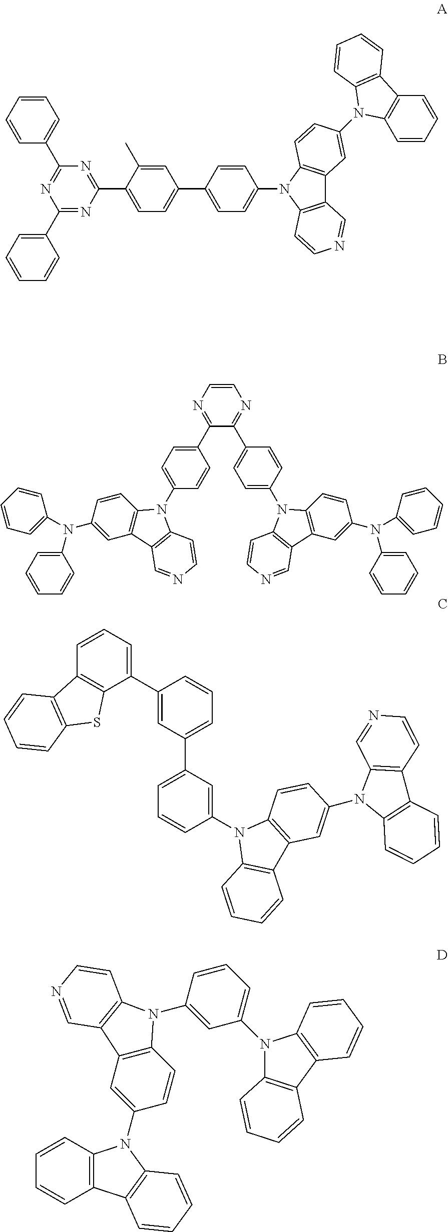 [SMILES: Cc1cc(-c2ccc(-n3c4ccncc4c4cc(-n5c6ccccc6c6ccccc65)ccc43)cc2)ccc1-c1nc(-c2ccccc2)nc(-c2ccccc2)n1 ; c1ccc(N(c2ccccc2)c2ccc3c(c2)c2cnccc2n3-c2ccc(-c3nccnc3-c3ccc(-n4c5ccncc5c5cc(N(c6ccccc6)c6ccccc6)ccc54)cc3)cc2)cc1 ; c1cc(-c2cccc(-n3c4ccccc4c4cc(-n5c6ccccc6c6ccncc65)ccc43)c2)cc(-c2cccc3c2sc2ccccc23)c1 ; c1cc(-n2c3ccccc3c3ccccc32)cc(-n2c3ccncc3c3cc(-n4c5ccccc5c5ccccc54)ccc32)c1]

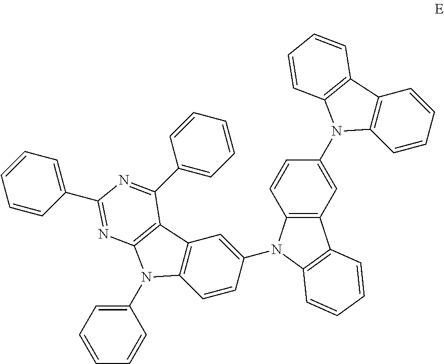 [SMILES: c1ccc(-c2nc(-c3ccccc3)c3c4cc(-n5c6ccccc6c6cc(-n7c8ccccc8c8ccccc87)ccc65)ccc4n(-c4ccccc4)c3n2)cc1]

### Evaluation Example 1: Evaluation of Characteristics of Organic Light-Emitting Devices

A change in current density, a change in luminance, and luminescent efficiency according to a voltage in the organic light-emitting devices manufactured according to Examples 1 and 2 and Comparative Examples 1 to 5 were measured. A specific measurement method was as follows, and results thereof are shown in Table 2. In addition, the electroluminescent (EL) spectrum of the organic light-emitting device of Example 1 is shown in FIG. 2.

### (1) Change in Current Density According to Voltage

Regarding the manufactured organic light-emitting device, a current flowing in a unit device was measured by using a current-voltage meter while a voltage was raised from 0 volts (V) to 10 V, and the measured current value was divided by an area.

### (2) Change in Luminance According to Voltage

Regarding the manufactured organic light-emitting device, luminance was measured by using Minolta Cs-1,000A while a voltage was raised from 0 V to 10 V.

### (3) Measurement of Luminescent Efficiency

The current efficiency (candelas per ampere, cd/A) at the same current density (10 milliamperes per square centimeter, mA/cm²) was calculated by using the luminance measured by the above (1) and (2), the current density, and the voltage.

### (4) Measurement of Durability

The time that lapsed until luminance was 95% of initial luminance (100%) was evaluated.

TABLE 2

| | Com- | Driving | Emission | Quantum | |
|---|---|---|---|---|---|
| | pound | voltage | wavelength | efficiency | Lifespan |
| | No. | (V) | (nm) | (%) | (%) |
| Example 1 | 43 | 7.75 | 432 | 100 | 100 |
| Example 2 | 64 | 7.72 | 431 | 97.8 | 114.7 |
| Comparative | A | 8.25 | 479 | 83.34 | 29.4 |
| Example 1 | | | | | |
| Comparative | B | 12.23 | 525 | 94.5 | 94.1 |
| Example 2 | | | | | |
| Comparative | C | 6.33 | 399 | 1.11 | 2.95 |
| Example 3 | | | | | |
| Comparative | D | 6.23 | 418 | 2.22 | 2.95 |
| Example 4 | | | | | |
| Comparative | E | 9.25 | 489 | 1.11 | 2.95 |
| Example 5 | | | | | |

Referring to Table 2, it is confirmed that the organic light-emitting devices of Examples 1 and 2 have excellent quantum efficiency and lifespan characteristics, as compared with Comparative Examples 1 to 5. In particular, the organic light-emitting devices of Examples 1 and 2 had a low driving voltage and emitted deep blue light in terms of emission wavelength, as compared with the organic light-emitting devices of Comparative Examples 1, 2, and 5. In addition, the organic light-emitting devices of Comparative Examples 3 and 4 do not emit delayed fluorescence, and are remarkably low in terms of quantum efficiency and lifespan, as compared with the organic light-emitting devices of Examples 1 and 2.

In addition, referring to FIG. 2, it is confirmed that the organic light-emitting device of Example 1 emits deep blue light having a maximum emission wavelength of 380 nanometers (nm) to 475 nm.

The organic light-emitting device may emit delayed fluorescence by using the condensed cyclic compound having excellent electric characteristics and thermal stability and having facilitated energy level adjustment, and may have high efficiency, long lifespan, and high color purity characteristics.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the present description as defined by the following claims.

What is claimed is:

1. An organic light-emitting device comprising:
a first electrode;
a second electrode; and
an organic layer disposed between the first electrode and the second electrode, wherein the organic layer comprises an emission layer,
wherein the emission layer comprises at least one of a condensed cyclic compound represented by Formula 1, and
wherein a ratio of an emission component of thermally activated delayed fluorescence (TADF) emitted from the condensed cyclic compound to a total emission component emitted from the emission layer is about 80% or more: 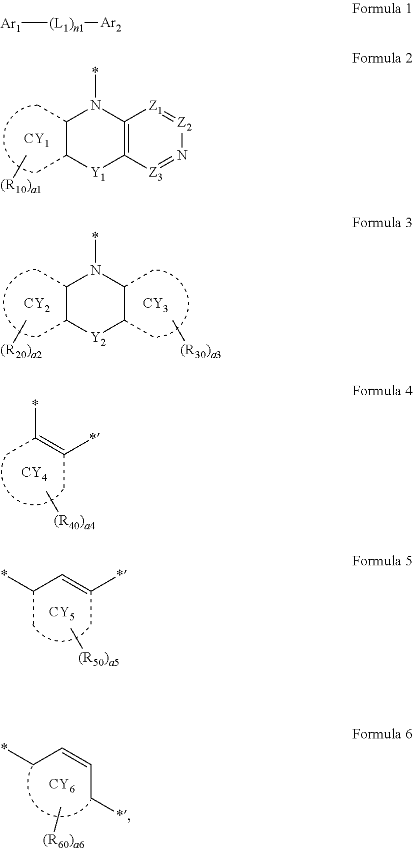
wherein, in Formulae 1 to 6,
Ar₁ is a group represented by Formula 2,
Ar₂ is a group represented by Formula 3 or a substituted or unsubstituted C₅-C₃₀ carbocyclic group,
L₁ is selected from a group represented by Formula 4, a group represented by Formula 5, and a group represented by Formula 6,
n1 is an integer of 0 to 5,
CY₁ to CY₃ are each independently a C₅-C₃₀ carbocyclic group or a C₁-C₃₀ heterocyclic group,
CY₄ to CY₆ are each a C₅-C₃₀ carbocyclic group,
Z₁ is N or C(R₁), Z₂ is N or C(R₂), and Z₃ is N or C(R₃),
Y₁ is a single bond, C(R₅)(R₆), N(R₅), O, or S,
Y₂ is a single bond, C(R₇)(R₈), N(R₇), O, or S,
R₁ to R₃, R₅ to R₈, R₁₀, R₂₀, R₄₀, R₅₀, and R₆₀ are each independently selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₄)(Q₅), and —B(Q₆)(Q₇),
a1 to a6 are each independently an integer of 1 to 10,
at least one of groups R₁₀ in the number of a1 is a substituted or unsubstituted carbazolyl group,
* and *′ each indicate a binding site to a neighboring atom,
at least one substituent of the C₅-C₃₀ carbocyclic group, the substituted C₁-C₆₀ alkyl group, the substituted C₂-C₆₀ alkenyl group, the substituted C₂-C₆₀ alkynyl group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group is selected from:
deuterium, —CD₃, —CD₂H, —CDH₂, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;
a C₁-C₆₀ alkyl group, a C₂-C₆₀ alkenyl group, a C₂-C₆₀ alkynyl group, and a C₁-C₆₀ alkoxy group, each substituted with at least one selected from deuterium, —CD₃, —CD₂H, —CDH₂, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —N(Q₁₄)(Q₁₅), and —B(Q₁₆)(Q₁₇);
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from deuterium, —CD₃, —CD₂H, —CDH₂, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —N(Q₂₄)(Q₂₅), and —B(Q₂₆)(Q₂₇); and
—Si(Q₃₁)(Q₃₂)(Q₃₃), —N(Q₃₄)(Q₃₅), and —B(Q₃₆)(Q₃₇), and
Q₁ to Q₇, Q₁₁ to Q₁₇, Q₂₁ to Q₂₇, and Q₃₁ to Q₃₇ are each independently selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group.

2. The organic light-emitting device of claim 1, wherein
n1 is 1 or 2, and Ar₂ is a group represented by Formula 3, or
n1 is 0 or 1, and Ar₂ is a C₅-C₃₀ carbocyclic group.

3. The organic light-emitting device of claim 1, wherein
CY₁ to CY₃ are each independently selected from a benzene group, a fluorene group, a carbazole group, a dibenzofuran group, and a dibenzothiophene group.

4. The organic light-emitting device of claim 1, wherein
CY₄ to CY₆ are each independently selected from a benzene group, a naphthalene group, and a fluorene group.

5. The organic light-emitting device of claim 1, wherein
Z₁ to Z₃ are each independently C, or
at least one of Z₁ to Z₃ is N.

6. The organic light-emitting device of claim 1, wherein
Y₁ and Y₂ are each independently a single bond.

7. The organic light-emitting device of claim 1, wherein
R₁ to R₃ are each independently hydrogen,
R₁₀, R₂₀, R₃₀, R₄₀, R₅₀, and R₆₀ are each independently selected from:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, and a C₁-C₂₀ alkoxy group;
a C₁-C₂₀ alkyl group and a C₁-C₂₀ alkoxy group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a phenyl group, a biphenyl group, a terphenyl group, and a naphthyl group;
a cyclopentyl group, a cyclohexyl group, a cyclopentenyl group, a cyclohexenyl group, a cycloheptenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyrimidinyl group, an imidazopyridinyl group, a pyridoindolyl group, a benzofuropyridinyl group, a benzothienopyridinyl group, a pyrimidoindolyl group, a benzofuropyrimidinyl group, a benzothienopyrimidinyl group, a phenoxazinyl group, a pyridobenzoxazinyl group, and a pyridobenzothiazinyl group;
a cyclopentyl group, a cyclohexyl group, a cyclopentenyl group, a cyclohexenyl group, a cycloheptenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-fluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyrimidinyl group, an imidazopyridinyl group, a pyridoindolyl group, a benzofuropyridinyl group, a benzothienopyridinyl group, a pyrimidoindolyl group, a benzofuropyrimidinyl group, a benzothienopyrimidinyl group, a phenoxazinyl group, a pyridobenzoxazinyl group, and a pyridobenzothiazinyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₁-C₂₀ alkoxy group, a phenyl group, a biphenyl group, a terphenyl group, a naphthyl group, an anthracenyl group, a pyrenyl group, a phenanthrenyl group, a fluorenyl group, a carbazolyl group, a benzocarbazolyl group, a dibenzocarbazolyl group, a pyridinyl group, a pyrimidinyl group, a pyrazinyl group, a pyridazinyl group, a triazinyl group, a quinolinyl group, an isoquinolinyl group, a phthalazinyl group, a quinoxalinyl group, a cinnolinyl group, a quinazolinyl group, —Si(Q₃₁)(Q₃₂)(Q₃₃), —N(Q₃₄)(Q₃₅), and —B(Q₃₆)(Q₃₇); and
—Si(Q₁)(Q₂)(Q₃), —N(Q₄)(Q₅) and —B(Q₆)(Q₇),
at least one R₁₀ is selected from:
a carbazolyl group; and
a carbazolyl group substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₂-C₂₀ alkynyl group, a C₁-C₂₀ alkoxy group, a phenyl group, a biphenyl group, a terphenyl group, a naphthyl group, an anthracenyl group, a pyrenyl group, a phenanthrenyl group, a fluorenyl group, a carbazolyl group, a benzocarbazolyl group, a dibenzocarbazolyl group, a pyridinyl group, a pyrimidinyl group, a pyrazinyl group, a pyridazinyl group, a triazinyl group, a quinolinyl group, an isoquinolinyl group, a phthalazinyl group, a quinoxalinyl group, a cinnolinyl group, a quinazolinyl group, —Si(Q₃₁)(Q₃₂)(Q₃₃), —N(Q₃₄)(Q₃₅), and —B(Q₃₆)(Q₃₇), and
Q₁ to Q₇ and Q₃₁ to Q₃₇ are each independently selected from hydrogen, a C₁-C₂₀ alkyl group, a C₁-C₂₀ alkoxy group, a phenyl group, a biphenyl group, a terphenyl group, a naphthyl group, a fluorenyl group, a carbazolyl group, a dibenzofuranyl group, and a dibenzothiophenyl group.

8. The organic light-emitting device of claim 1, wherein
Ar₁ is a group represented by one selected from Formulae 2-1 to 2-7: 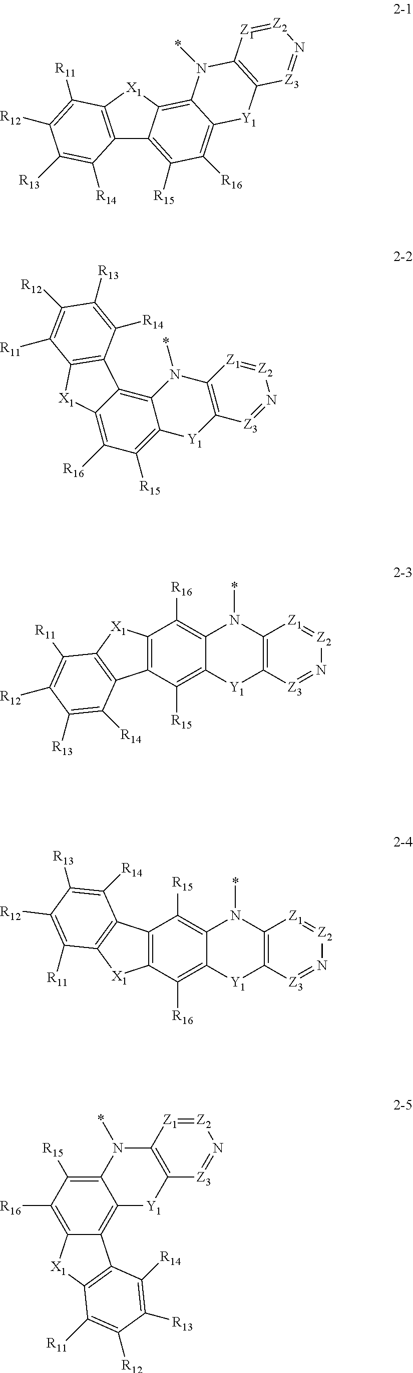 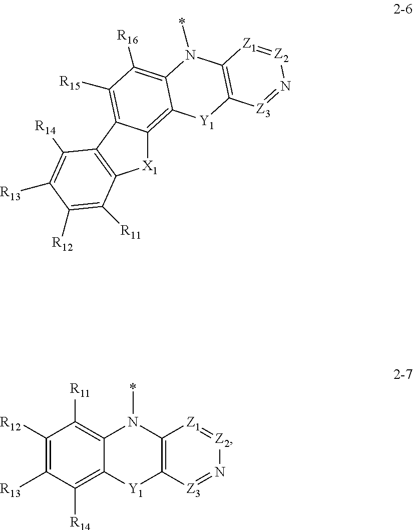
wherein, in Formulae 2-1 to 2-7,
X₁ is C(R₁₇)(R₁), N(R₁₉), O, or S,
Y₁, Z₁, Z₂, and Z₃ are each independently the same as described in claim 1,
R₁ to R₃, R₅ to R₈, and R₁₁ to R₁₉ are each independently selected from:
hydrogen, deuterium, —F, —Cl, —Br, —I, a cyano group, a C₁-C₂₀ alkyl group, and a C₁-C₂₀ alkoxy group;
a C₀₁-C₂₀ alkyl group and a C₁-C₂₀ alkoxy group, each substituted with at least one selected from deuterium, a phenyl group, a biphenyl group, a terphenyl group, and a naphthyl group;
a cyclopentyl group, a cyclohexyl group, a cyclopentenyl group, a cyclohexenyl group, a cycloheptenyl group, a phenyl group, a biphenyl group, a terphenyl group, a naphthyl group, a fluorenyl group, a carbazolyl group, a dibenzofuranyl group, and a dibenzothiophenyl group;
a cyclopentyl group, a cyclohexyl group, a cyclopentenyl group, a cyclohexenyl group, a cycloheptenyl group, a phenyl group, a biphenyl group, a terphenyl group, a naphthyl group, a fluorenyl group, a carbazolyl group, a dibenzofuranyl group, and a dibenzothiophenyl group, each substituted with at least one selected from deuterium, a C₁-C₂₀ alkyl group, a C₁-C₂₀ alkoxy group, a phenyl group, a biphenyl group, a terphenyl group, a naphthyl group, a carbazolyl group, and —Si(Q₃₁)(Q₃₂)(Q₃₃); and
—Si(Q₁)(Q₂)(Q₃),
at least one of R₁₁ to R₁₄ is selected from:
a carbazolyl group; and
a carbazolyl group substituted with at least one selected from deuterium, a C₁-C₂₀ alkyl group, a C₁-C₂₀ alkoxy group, a phenyl group, a biphenyl group, a terphenyl group, a naphthyl group, a carbazolyl group, and —Si(Q₃₁)(Q₃₂)(Q₃₃),
Q₁ to Q₃ and Q₃₁ to Q₃₃ are each independently selected from hydrogen, a C₁-C₂₀ alkyl group, a C₁-C₂₀ alkoxy group, a phenyl group, a biphenyl group, a terphenyl group, and a naphthyl group, and
* indicates a binding site to a neighboring atom.

9. The organic light-emitting device of claim 1, wherein
Ar₂ is a group represented by one selected from Formulae 3-1 to 3-7 and 4-1 to 4-19: 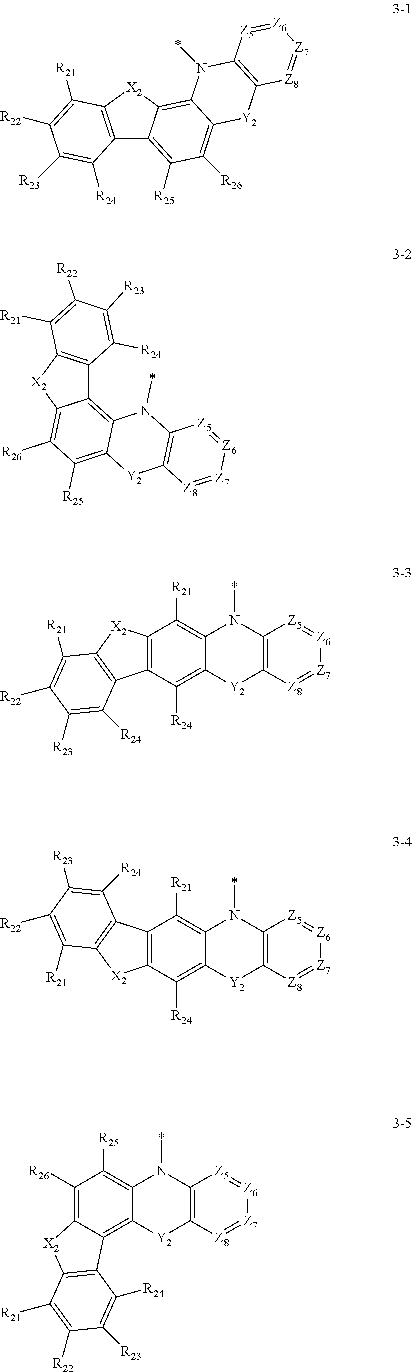 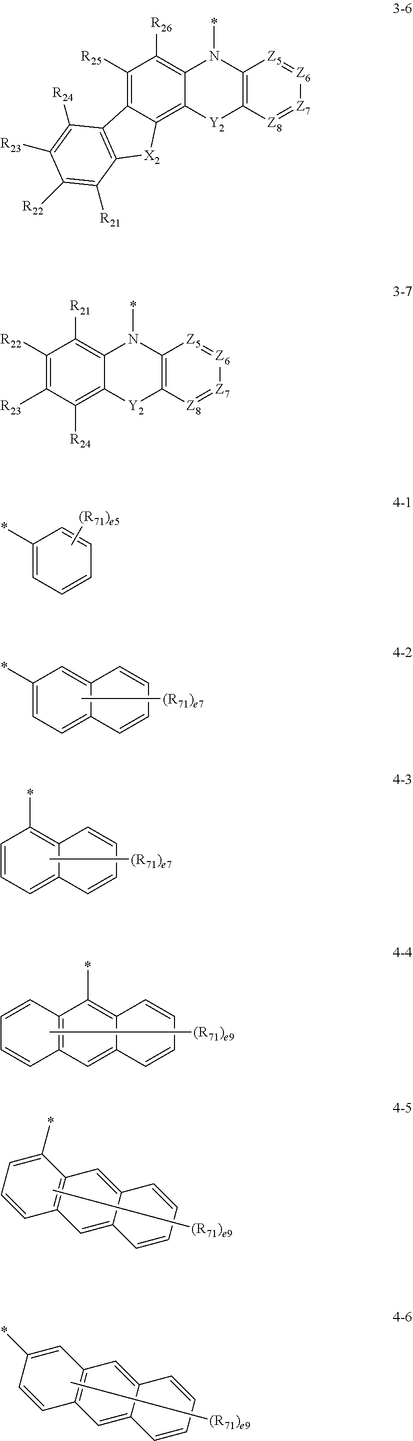 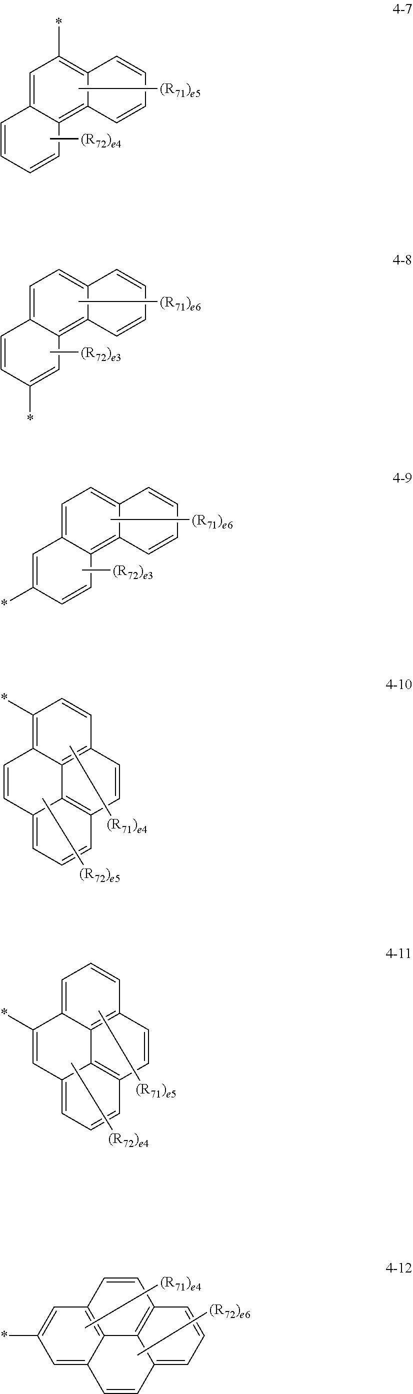 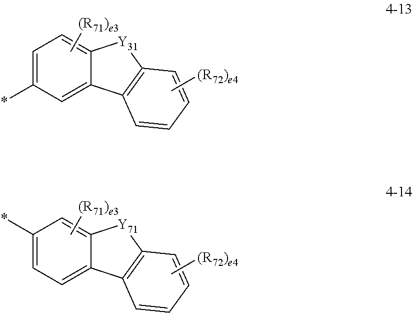 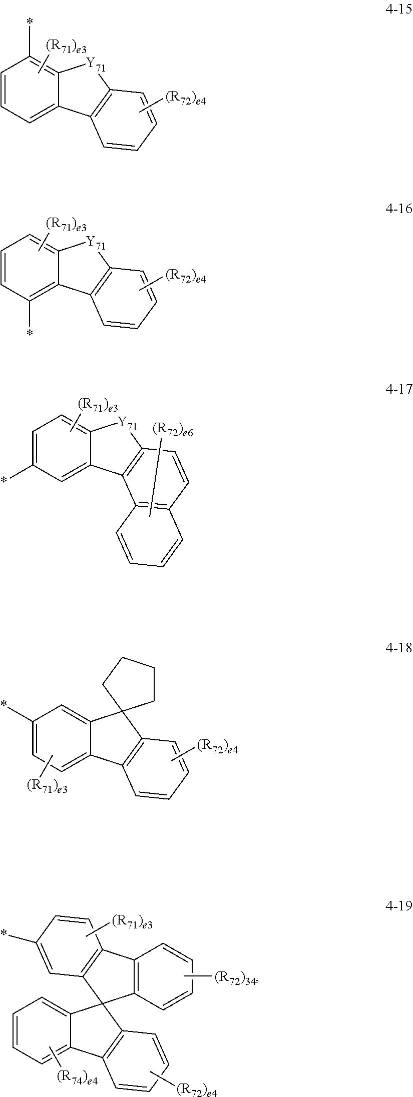
wherein, in Formulae 3-1 to 3-7 and 4-1 to 4-19:
X₂ is C(R₂₇)(R₂₈), N(R₂₉), O, or S,
Y₂ is the same as described in claim 1,
Z₅ is N or C(R₃₁), Z₆ is N or C(R₃₂), Z₇ is N or C(R₃₃), and Z₈ is N or C(R₃₄),
R₂₁ to R₂₉ and R₃₁ to R₃₄ are each independently selected from:
hydrogen, deuterium, —F, —Cl, —Br, —I, a cyano group, a C₁-C₂₀ alkyl group, and a C₁-C₂₀ alkoxy group;
a C₁-C₂₀ alkyl group and a C₁-C₂₀ alkoxy group, each substituted with at least one selected from deuterium, a phenyl group, a biphenyl group, a terphenyl group, and a naphthyl group;
a cyclopentyl group, a cyclohexyl group, a cyclopentenyl group, a cyclohexenyl group, a cycloheptenyl group, a phenyl group, a biphenyl group, a terphenyl group, a naphthyl group, a fluorenyl group, a carbazolyl group, a dibenzofuranyl group, and a dibenzothiophenyl group;
a cyclopentyl group, a cyclohexyl group, a cyclopentenyl group, a cyclohexenyl group, a cycloheptenyl group, a phenyl group, a biphenyl group, a terphenyl group, a naphthyl group, a fluorenyl group, a carbazolyl group, a dibenzofuranyl group, and a dibenzothiophenyl group, each substituted with at least one selected from deuterium, a C₁-C₂₀ alkyl group, a C₁-C₂₀ alkoxy group, a phenyl group, a biphenyl group, a terphenyl group, a naphthyl group, a carbazolyl group, and —Si(Q₃₁)(Q₃₂)(Q₃₃); and
—Si(Q₁)(Q₂)(Q₃),
Q₁ to Q₃ are each independently selected from hydrogen, a C₁-C₂₀ alkyl group, a C₁-C₂₀ alkoxy group, a phenyl group, a biphenyl group, a terphenyl group, a naphthyl group, a fluorenyl group, a carbazolyl group, a dibenzofuranyl group, and a dibenzothiophenyl group,
Y₇₁ is O, S, C(R₇₅)(R₇₆), or Si(R₇₅)(R₇₆),
R₇₁ and R₇₆ are each independently selected from hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, an anthracenyl group, and a phenanthrenyl group,
e2 is an integer of 0 to 2,
e3 is an integer of 0 to 3,
e4 is an integer of 0 to 4,
e5 is an integer of 0 to 5,
e6 is an integer of 0 to 6,
e7 is an integer of 0 to 7,
e9 is an integer of 0 to 9, and
* indicates a binding site to a neighboring atom.

10. The organic light-emitting device of claim 1, wherein
the condensed cyclic compound represented by Formula 1 is represented by one selected from Formulae 1-1 to 1-9: 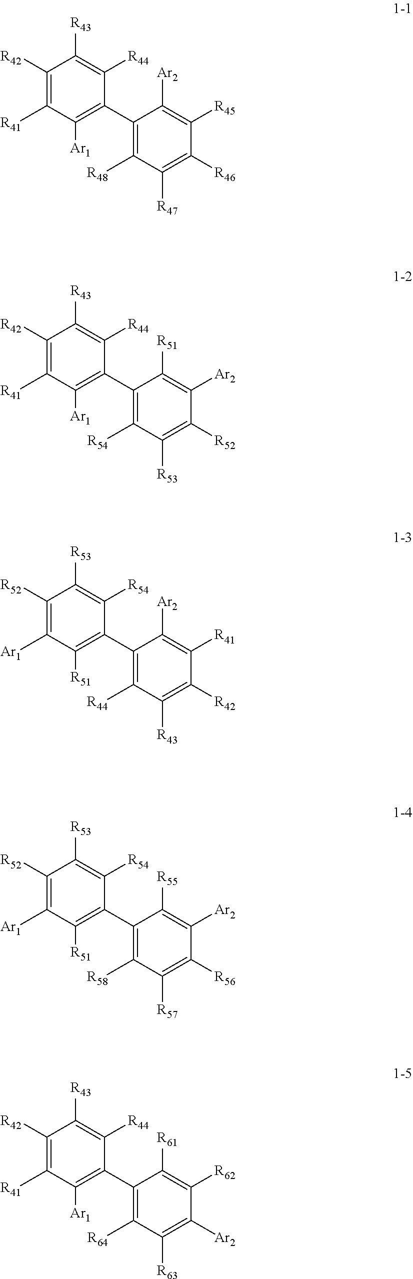 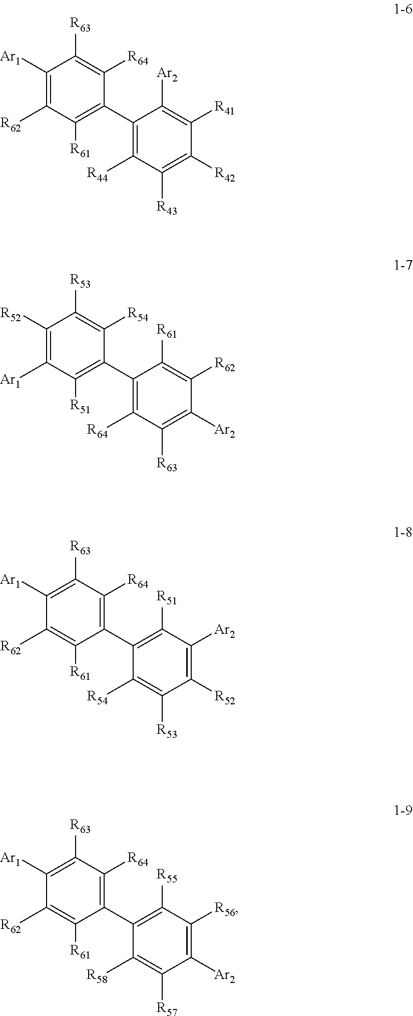
wherein, in Formulae 1-1 to 1-9,
Ar₁ and Ar₂ are each independently the same as described in claim 1,
R₄₁ to R₄₈ each independently have the same definition as R₄₀ in claim 1,
R₅₁ to R₅₈ each independently have the same definition as R₅₀ in claim 1, and
R₆₁ to R₆₈ each independently have the same definition as R₆₀ in claim 1.

11. The organic light-emitting device of claim 10, wherein
R₄₁ to R₄₈, R₅₁ to R₅₈, and R₆₁ to R₆₈ are each independently selected from:
hydrogen, deuterium, —F, —Cl, —Br, —I, a cyano group, a C₁-C₂₀ alkyl group, and a C₁-C₂₀ alkoxy group;
a C₁-C₂₀ alkyl group and a C₁-C₂₀ alkoxy group, each substituted with at least one selected from deuterium, a phenyl group, a biphenyl group, a terphenyl group, and a naphthyl group;
a cyclopentyl group, a cyclohexyl group, a cyclopentenyl group, a cyclohexenyl group, a cycloheptenyl group, a phenyl group, a biphenyl group, a terphenyl group, a naphthyl group, a fluorenyl group, a carbazolyl group, a dibenzofuranyl group, and a dibenzothiophenyl group;
a cyclopentyl group, a cyclohexyl group, a cyclopentenyl group, a cyclohexenyl group, a cycloheptenyl group, a phenyl group, a biphenyl group, a terphenyl group, a naphthyl group, a fluorenyl group, a carbazolyl group, a dibenzofuranyl group, and a dibenzothiophenyl group, each substituted with at least one selected from deuterium, a C₁-C₂₀ alkyl group, a C₁-C₂₀ alkoxy group, a phenyl group, a biphenyl group, a terphenyl group, a naphthyl group, and —Si(Q₃₁)(Q₃₂)(Q₃₃); and
—Si(Q₁)(Q₂)(Q₃), and
Q₁ to Q₃ and Q₃₁ to Q₃₃ are each independently selected from hydrogen, a C₁-C₂₀ alkyl group, a C₁-C₂₀ alkoxy group, a phenyl group, a biphenyl group, a terphenyl group, and a naphthyl group.

12. The organic light-emitting device of claim 1, wherein
the number of carbazole groups comprised in the condensed cyclic compound represented by Formula 1 is 1, 2, 3, or 4.

13. The organic light-emitting device of claim 1, wherein
the number of carbazole groups comprised in R₁₀ in Formula 1 is 1 or 2.

14. The organic light-emitting device of claim 1, wherein
the condensed cyclic compound represented by Formula 1 is selected from Compounds 1 to 168:

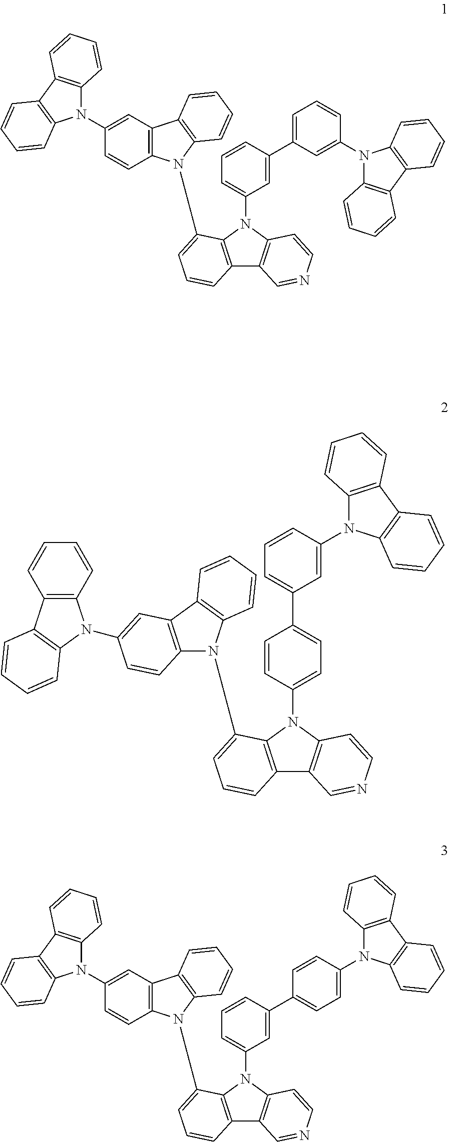 [SMILES: c1cc(-c2cccc(-n3c4ccncc4c4cccc(-n5c6ccccc6c6cc(-n7c8ccccc8c8ccccc87)ccc65)c43)c2)cc(-n2c3ccccc3c3ccccc32)c1 ; c1cc(-c2ccc(-n3c4ccncc4c4cccc(-n5c6ccccc6c6cc(-n7c8ccccc8c8ccccc87)ccc65)c43)cc2)cc(-n2c3ccccc3c3ccccc32)c1 ; c1cc(-c2ccc(-n3c4ccccc4c4ccccc43)cc2)cc(-n2c3ccncc3c3cccc(-n4c5ccccc5c5cc(-n6c7ccccc7c7ccccc76)ccc54)c32)c1]

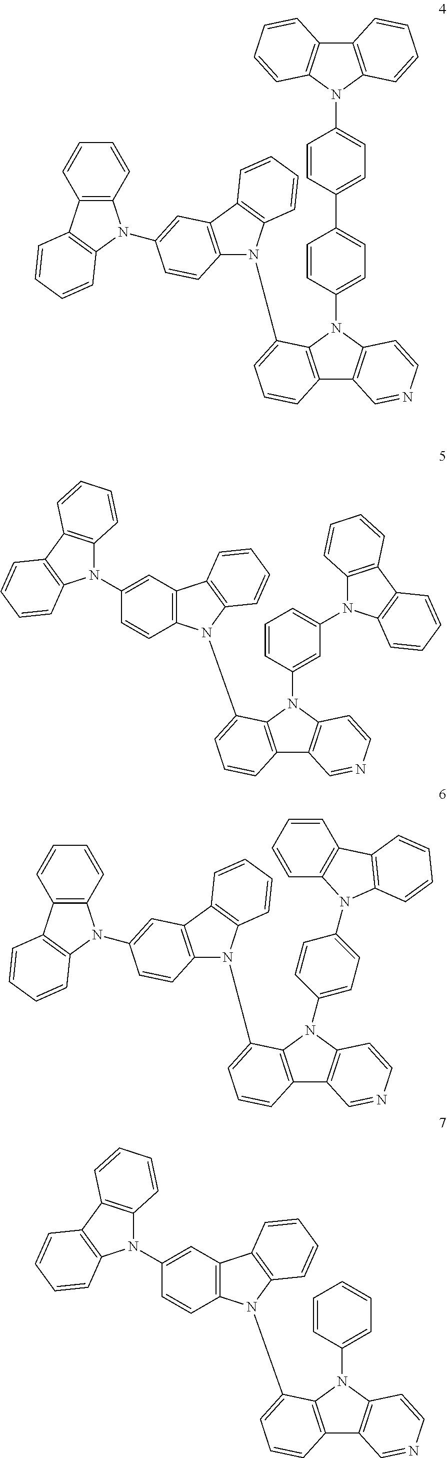

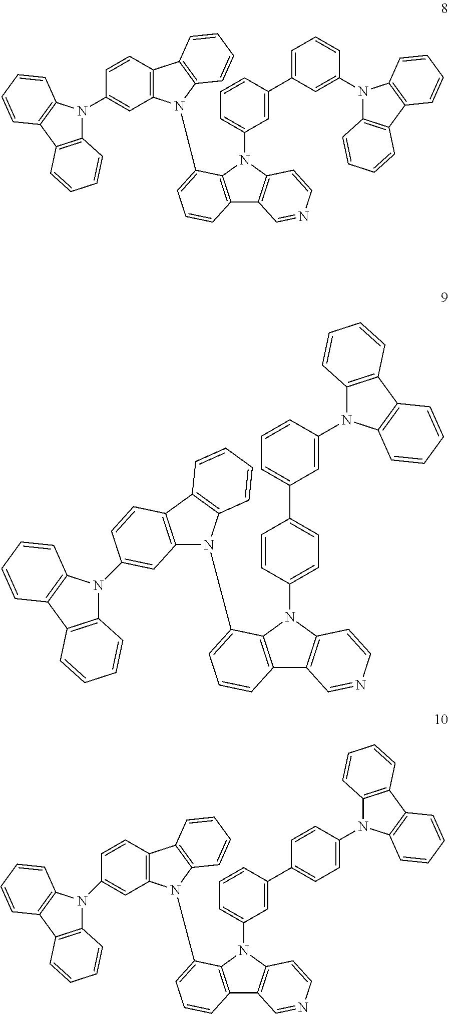 [SMILES: c1cc(-c2cccc(-n3c4ccncc4c4cccc(-n5c6ccccc6c6ccc(-n7c8ccccc8c8ccccc87)cc65)c43)c2)cc(-n2c3ccccc3c3ccccc32)c1 ; c1cc(-c2ccc(-n3c4ccncc4c4cccc(-n5c6ccccc6c6ccc(-n7c8ccccc8c8ccccc87)cc65)c43)cc2)cc(-n2c3ccccc3c3ccccc32)c1 ; c1cc(-c2ccc(-n3c4ccccc4c4ccccc43)cc2)cc(-n2c3ccncc3c3cccc(-n4c5ccccc5c5ccc(-n6c7ccccc7c7ccccc76)cc54)c32)c1]

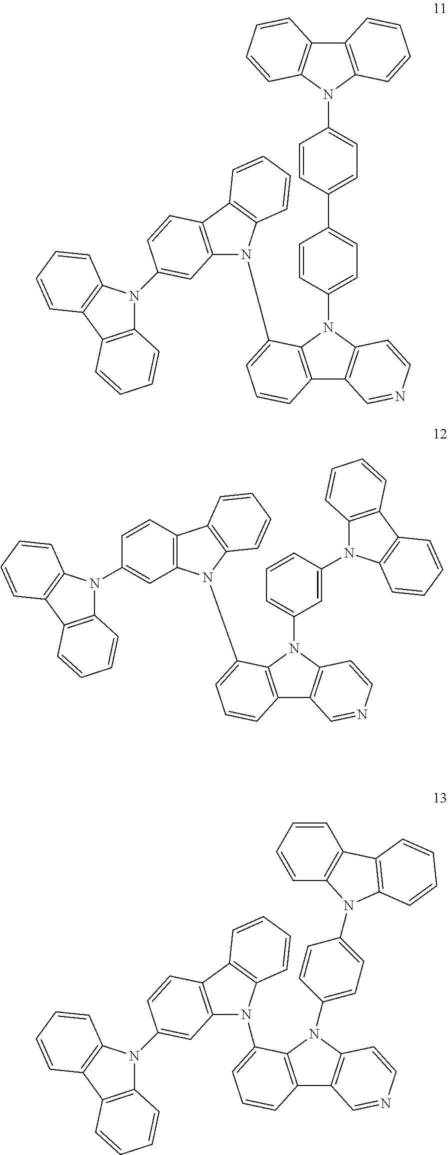 [SMILES: c1ccc2c(c1)c1ccccc1n2-c1ccc(-c2ccc(-n3c4ccncc4c4cccc(-n5c6ccccc6c6ccc(-n7c8ccccc8c8ccccc87)cc65)c43)cc2)cc1 ; c1cc(-n2c3ccccc3c3ccccc32)cc(-n2c3ccncc3c3cccc(-n4c5ccccc5c5ccc(-n6c7ccccc7c7ccccc76)cc54)c32)c1 ; c1ccc2c(c1)c1ccccc1n2-c1ccc(-n2c3ccncc3c3cccc(-n4c5ccccc5c5ccc(-n6c7ccccc7c7ccccc76)cc54)c32)cc1]

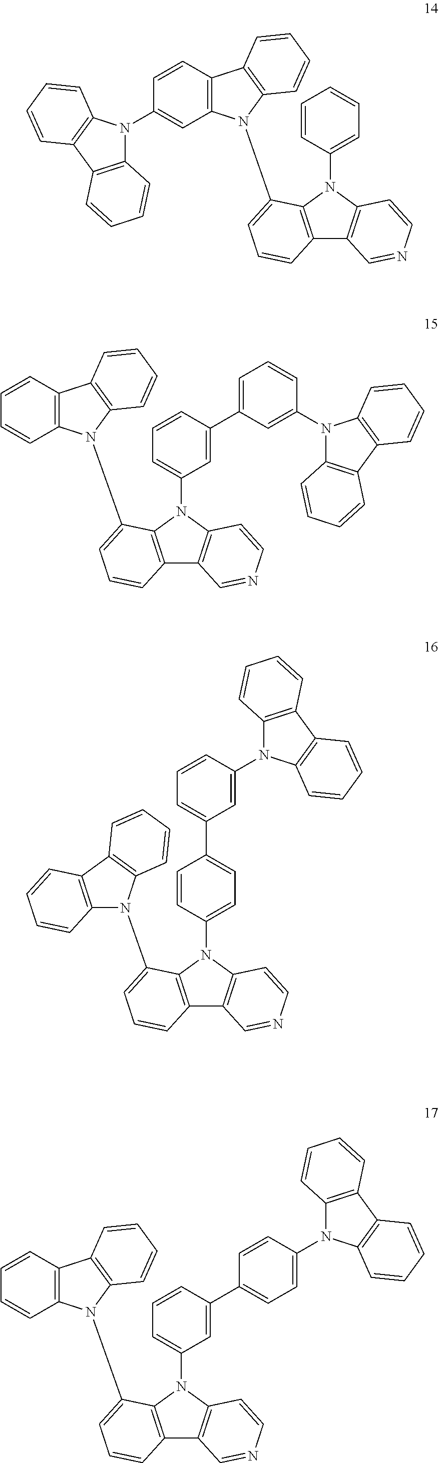 [SMILES: c1ccc(-n2c3ccncc3c3cccc(-n4c5ccccc5c5ccc(-n6c7ccccc7c7ccccc76)cc54)c32)cc1 ; c1cc(-c2cccc(-n3c4ccncc4c4cccc(-n5c6ccccc6c6ccccc65)c43)c2)cc(-n2c3ccccc3c3ccccc32)c1 ; c1cc(-c2ccc(-n3c4ccncc4c4cccc(-n5c6ccccc6c6ccccc65)c43)cc2)cc(-n2c3ccccc3c3ccccc32)c1 ; c1cc(-c2ccc(-n3c4ccccc4c4ccccc43)cc2)cc(-n2c3ccncc3c3cccc(-n4c5ccccc5c5ccccc54)c32)c1]

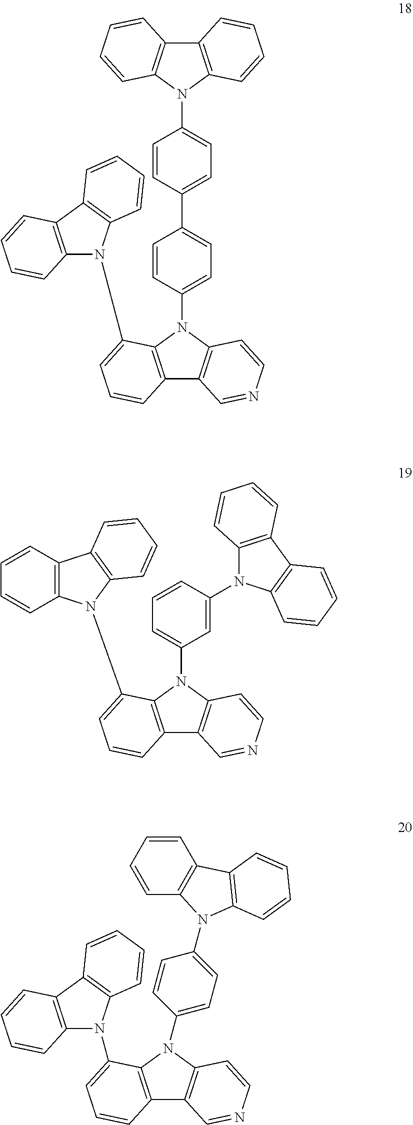 [SMILES: c1ccc2c(c1)c1ccccc1n2-c1ccc(-c2ccc(-n3c4ccncc4c4cccc(-n5c6ccccc6c6ccccc65)c43)cc2)cc1 ; c1cc(-n2c3ccccc3c3ccccc32)cc(-n2c3ccncc3c3cccc(-n4c5ccccc5c5ccccc54)c32)c1 ; c1ccc2c(c1)c1ccccc1n2-c1ccc(-n2c3ccncc3c3cccc(-n4c5ccccc5c5ccccc54)c32)cc1]

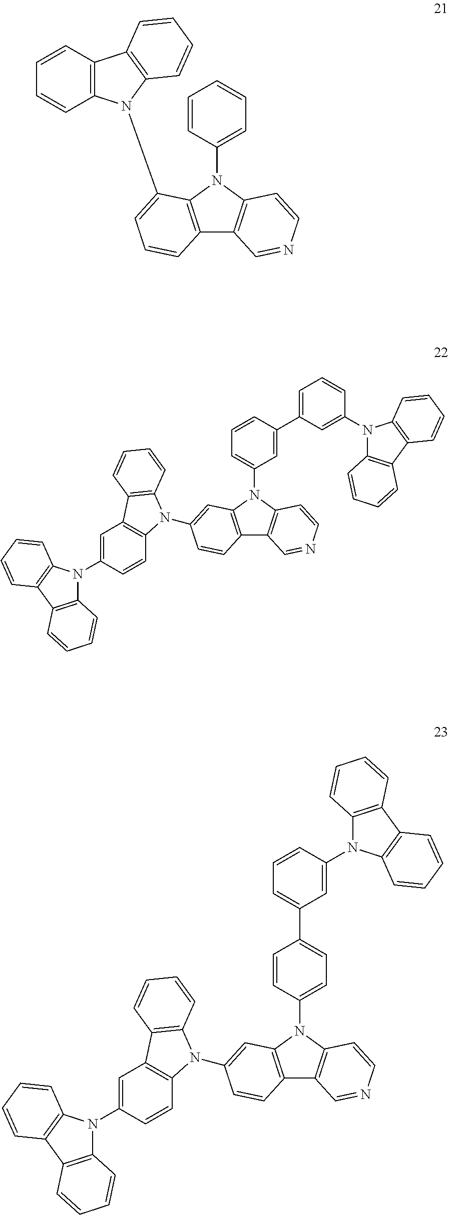 [SMILES: c1ccc(-n2c3ccncc3c3cccc(-n4c5ccccc5c5ccccc54)c32)cc1 ; c1cc(-c2cccc(-n3c4ccncc4c4ccc(-n5c6ccccc6c6cc(-n7c8ccccc8c8ccccc87)ccc65)cc43)c2)cc(-n2c3ccccc3c3ccccc32)c1 ; c1cc(-c2ccc(-n3c4ccncc4c4ccc(-n5c6ccccc6c6cc(-n7c8ccccc8c8ccccc87)ccc65)cc43)cc2)cc(-n2c3ccccc3c3ccccc32)c1]

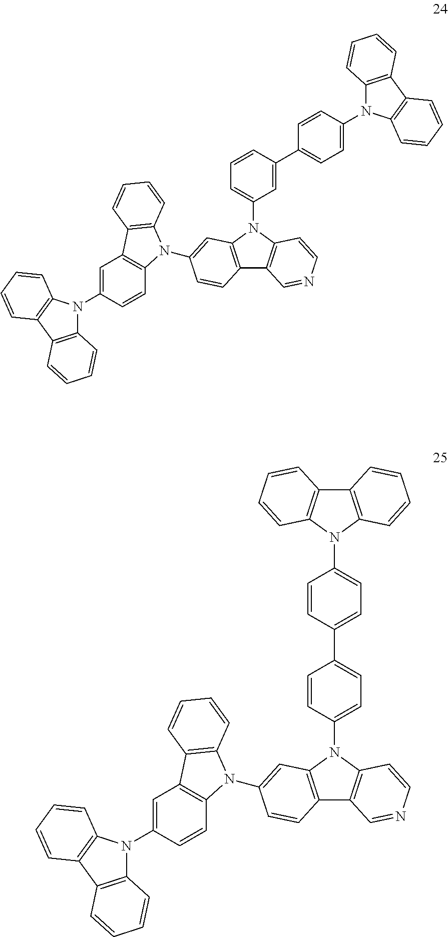 [SMILES: c1cc(-c2ccc(-n3c4ccccc4c4ccccc43)cc2)cc(-n2c3ccncc3c3ccc(-n4c5ccccc5c5cc(-n6c7ccccc7c7ccccc76)ccc54)cc32)c1 ; c1ccc2c(c1)c1ccccc1n2-c1ccc(-c2ccc(-n3c4ccncc4c4ccc(-n5c6ccccc6c6cc(-n7c8ccccc8c8ccccc87)ccc65)cc43)cc2)cc1]

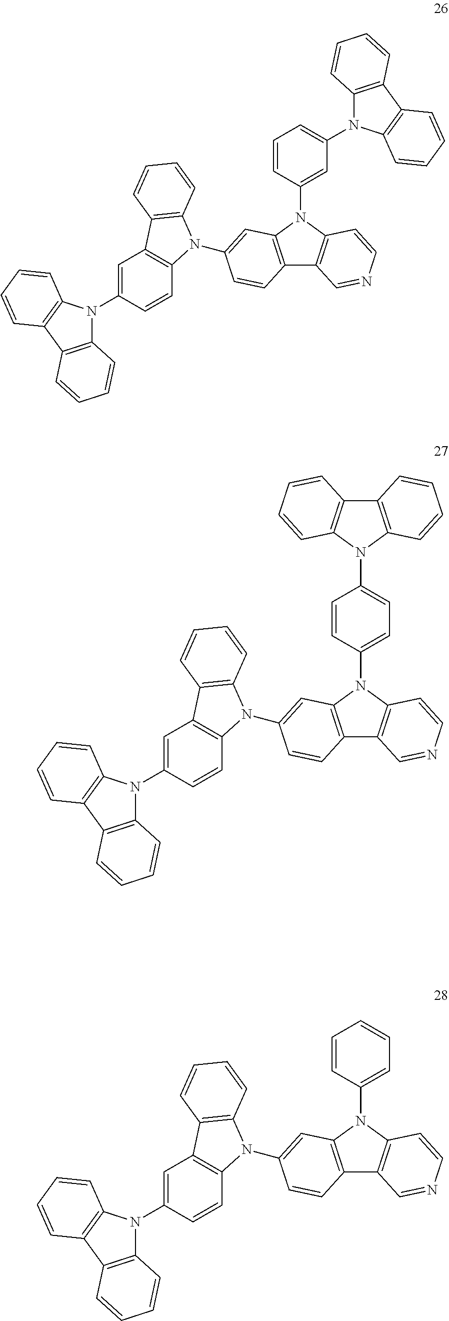 [SMILES: c1cc(-n2c3ccccc3c3ccccc32)cc(-n2c3ccncc3c3ccc(-n4c5ccccc5c5cc(-n6c7ccccc7c7ccccc76)ccc54)cc32)c1 ; c1ccc2c(c1)c1ccccc1n2-c1ccc(-n2c3ccncc3c3ccc(-n4c5ccccc5c5cc(-n6c7ccccc7c7ccccc76)ccc54)cc32)cc1 ; c1ccc(-n2c3ccncc3c3ccc(-n4c5ccccc5c5cc(-n6c7ccccc7c7ccccc76)ccc54)cc32)cc1]

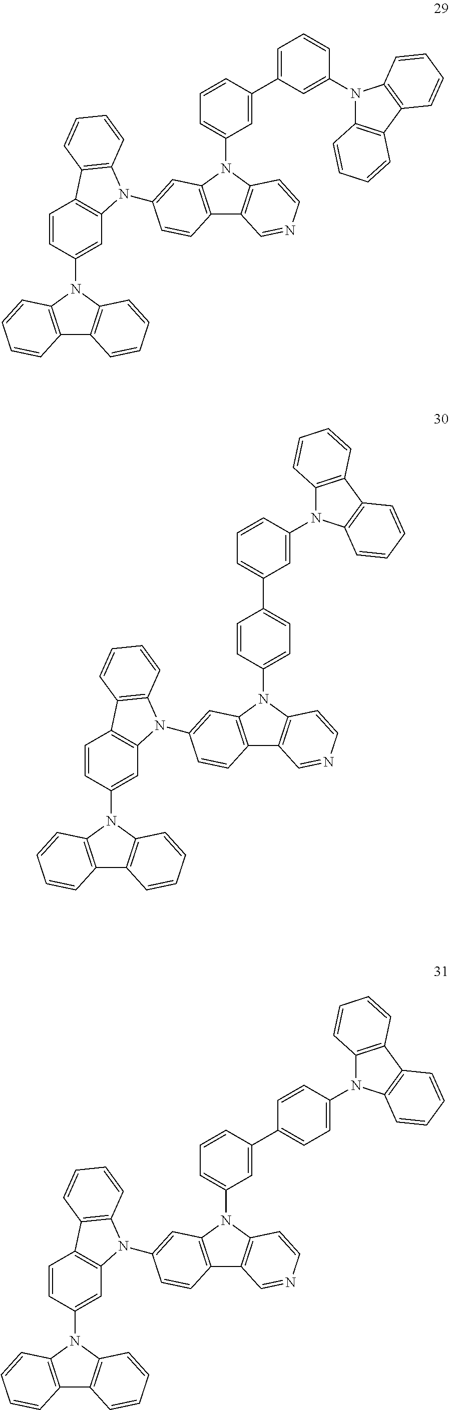 [SMILES: c1cc(-c2cccc(-n3c4ccncc4c4ccc(-n5c6ccccc6c6ccc(-n7c8ccccc8c8ccccc87)cc65)cc43)c2)cc(-n2c3ccccc3c3ccccc32)c1 ; c1cc(-c2ccc(-n3c4ccncc4c4ccc(-n5c6ccccc6c6ccc(-n7c8ccccc8c8ccccc87)cc65)cc43)cc2)cc(-n2c3ccccc3c3ccccc32)c1 ; c1cc(-c2ccc(-n3c4ccccc4c4ccccc43)cc2)cc(-n2c3ccncc3c3ccc(-n4c5ccccc5c5ccc(-n6c7ccccc7c7ccccc76)cc54)cc32)c1]

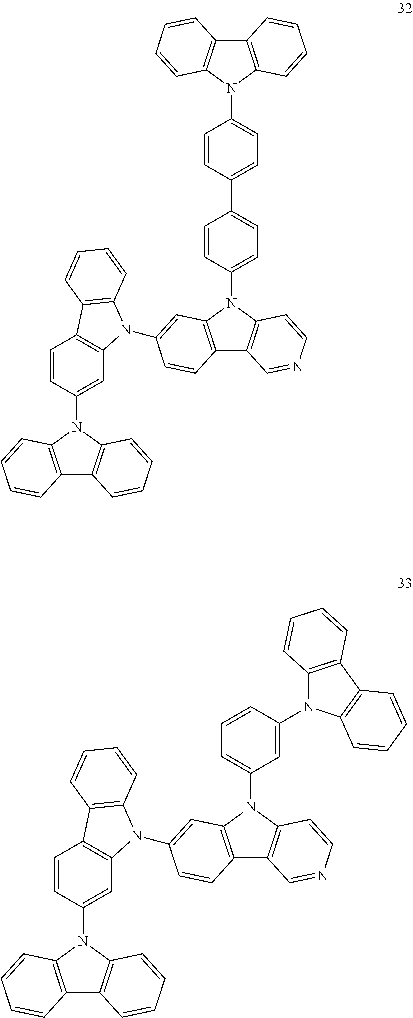 [SMILES: c1ccc2c(c1)c1ccccc1n2-c1ccc(-c2ccc(-n3c4ccncc4c4ccc(-n5c6ccccc6c6ccc(-n7c8ccccc8c8ccccc87)cc65)cc43)cc2)cc1 ; c1cc(-n2c3ccccc3c3ccccc32)cc(-n2c3ccncc3c3ccc(-n4c5ccccc5c5ccc(-n6c7ccccc7c7ccccc76)cc54)cc32)c1]

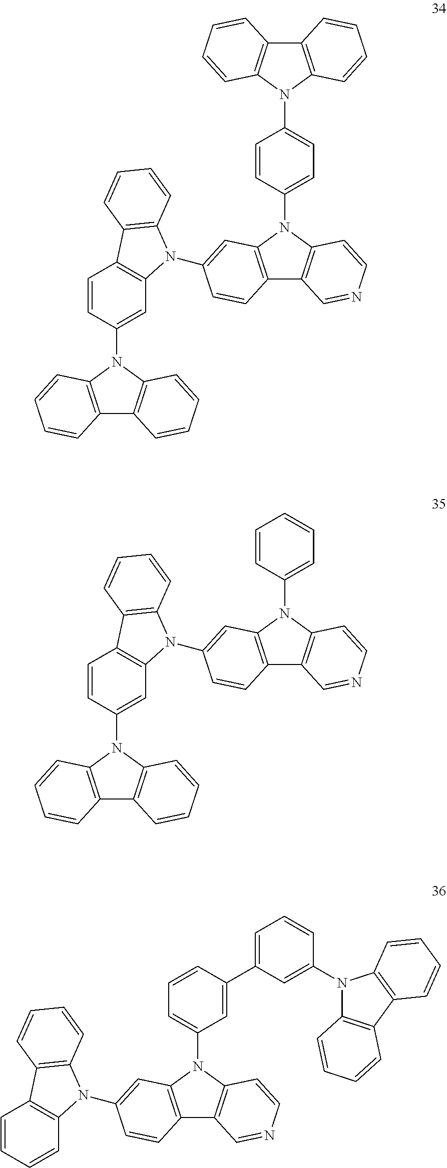 [SMILES: c1ccc2c(c1)c1ccccc1n2-c1ccc(-n2c3ccncc3c3ccc(-n4c5ccccc5c5ccc(-n6c7ccccc7c7ccccc76)cc54)cc32)cc1 ; c1ccc(-n2c3ccncc3c3ccc(-n4c5ccccc5c5ccc(-n6c7ccccc7c7ccccc76)cc54)cc32)cc1 ; c1cc(-c2cccc(-n3c4ccncc4c4ccc(-n5c6ccccc6c6ccccc65)cc43)c2)cc(-n2c3ccccc3c3ccccc32)c1]

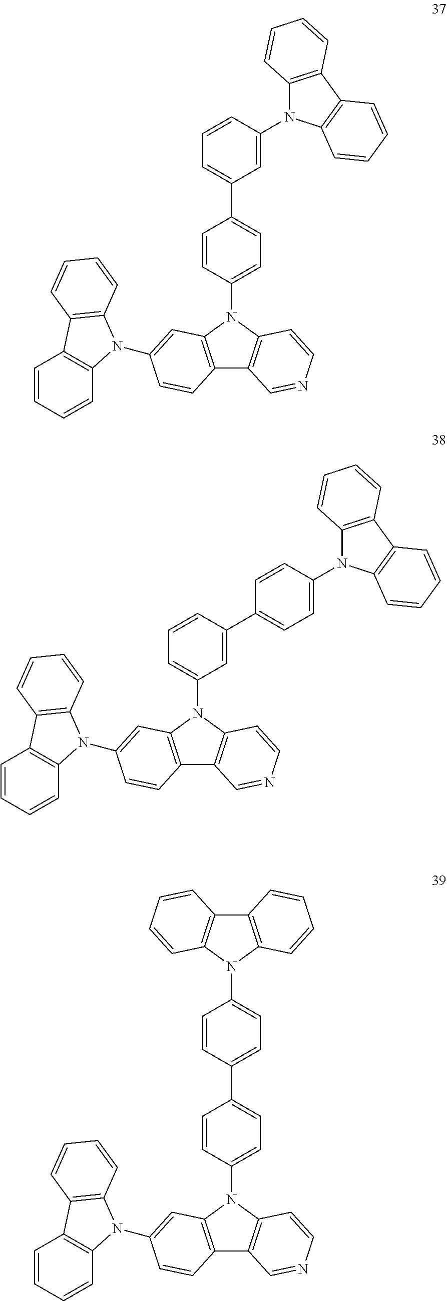 [SMILES: c1cc(-c2ccc(-n3c4ccncc4c4ccc(-n5c6ccccc6c6ccccc65)cc43)cc2)cc(-n2c3ccccc3c3ccccc32)c1 ; c1cc(-c2ccc(-n3c4ccccc4c4ccccc43)cc2)cc(-n2c3ccncc3c3ccc(-n4c5ccccc5c5ccccc54)cc32)c1 ; c1ccc2c(c1)c1ccccc1n2-c1ccc(-c2ccc(-n3c4ccncc4c4ccc(-n5c6ccccc6c6ccccc65)cc43)cc2)cc1]

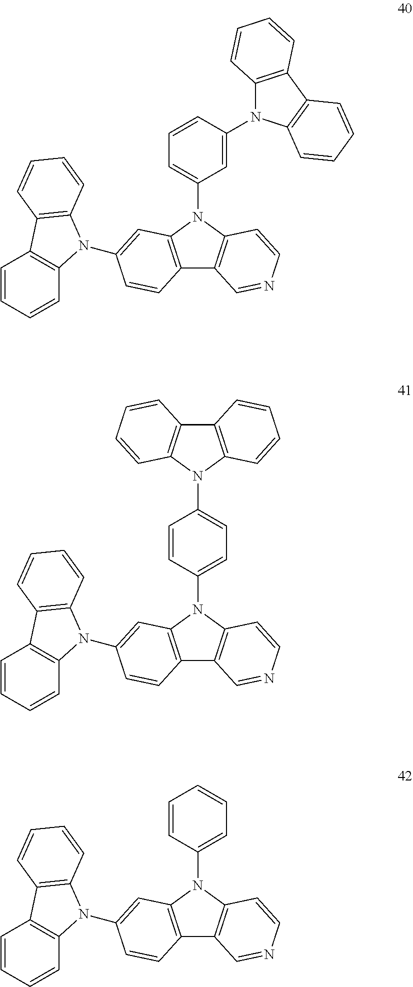 [SMILES: c1cc(-n2c3ccccc3c3ccccc32)cc(-n2c3ccncc3c3ccc(-n4c5ccccc5c5ccccc54)cc32)c1 ; c1ccc2c(c1)c1ccccc1n2-c1ccc(-n2c3ccncc3c3ccc(-n4c5ccccc5c5ccccc54)cc32)cc1 ; c1ccc(-n2c3ccncc3c3ccc(-n4c5ccccc5c5ccccc54)cc32)cc1]

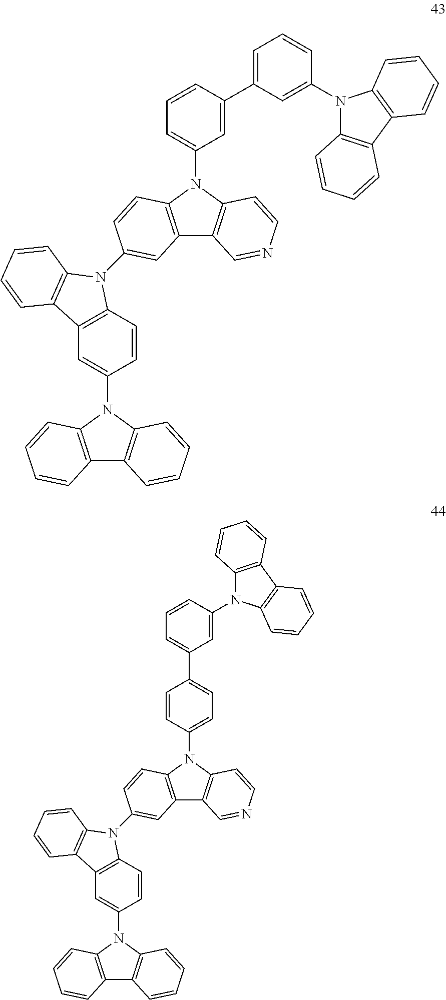 [SMILES: c1cc(-c2cccc(-n3c4ccncc4c4cc(-n5c6ccccc6c6cc(-n7c8ccccc8c8ccccc87)ccc65)ccc43)c2)cc(-n2c3ccccc3c3ccccc32)c1 ; c1cc(-c2ccc(-n3c4ccncc4c4cc(-n5c6ccccc6c6cc(-n7c8ccccc8c8ccccc87)ccc65)ccc43)cc2)cc(-n2c3ccccc3c3ccccc32)c1]

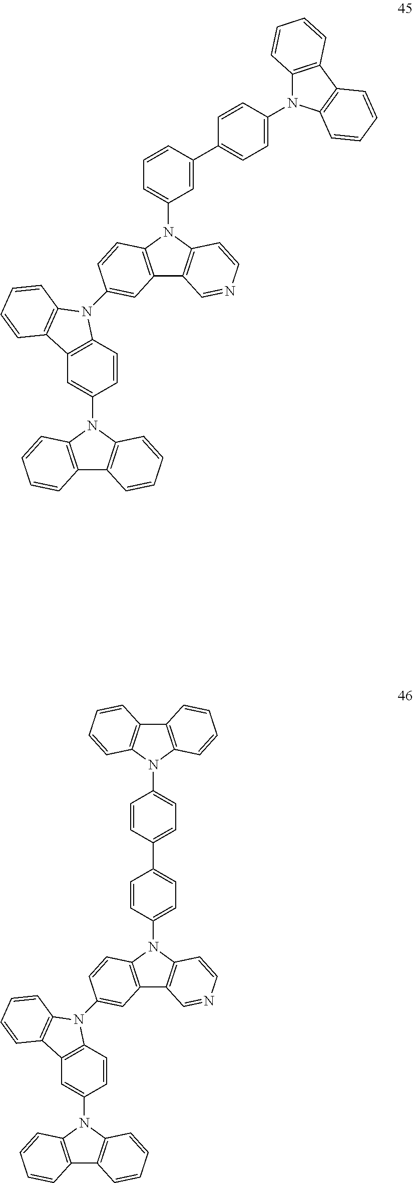 [SMILES: c1cc(-c2ccc(-n3c4ccccc4c4ccccc43)cc2)cc(-n2c3ccncc3c3cc(-n4c5ccccc5c5cc(-n6c7ccccc7c7ccccc76)ccc54)ccc32)c1 ; c1ccc2c(c1)c1ccccc1n2-c1ccc(-c2ccc(-n3c4ccncc4c4cc(-n5c6ccccc6c6cc(-n7c8ccccc8c8ccccc87)ccc65)ccc43)cc2)cc1]

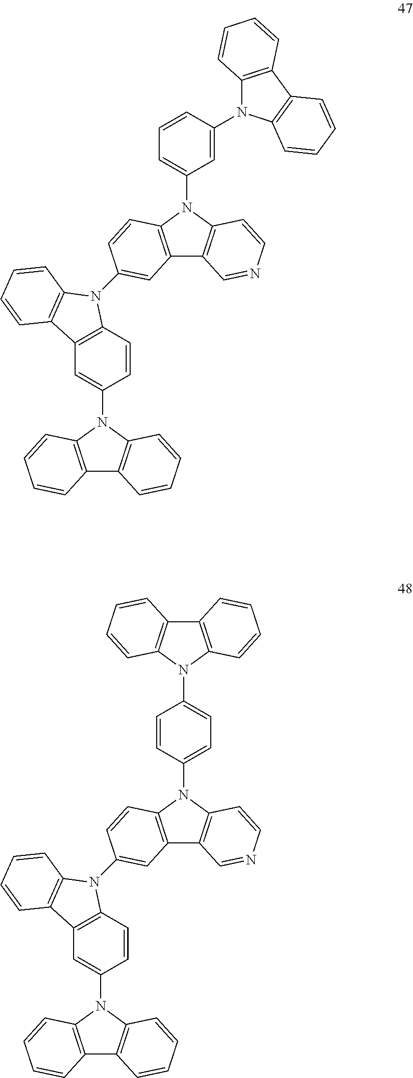 [SMILES: c1cc(-n2c3ccccc3c3ccccc32)cc(-n2c3ccncc3c3cc(-n4c5ccccc5c5cc(-n6c7ccccc7c7ccccc76)ccc54)ccc32)c1 ; c1ccc2c(c1)c1ccccc1n2-c1ccc(-n2c3ccncc3c3cc(-n4c5ccccc5c5cc(-n6c7ccccc7c7ccccc76)ccc54)ccc32)cc1]

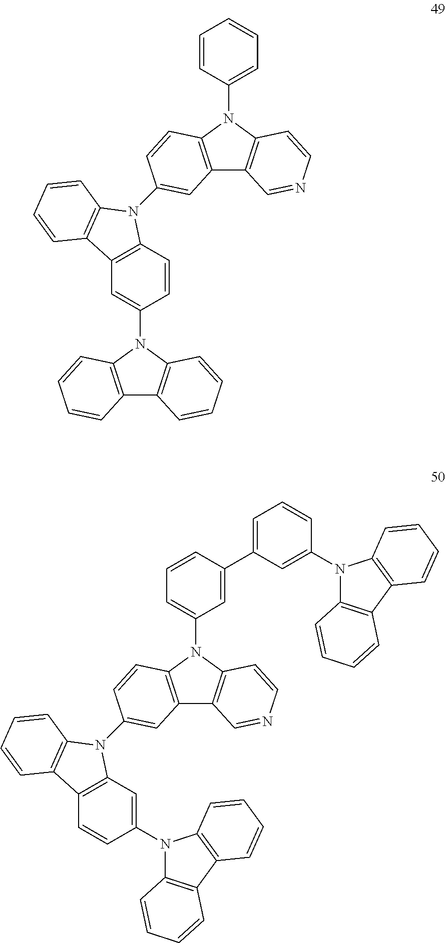 [SMILES: c1ccc(-n2c3ccncc3c3cc(-n4c5ccccc5c5cc(-n6c7ccccc7c7ccccc76)ccc54)ccc32)cc1 ; c1cc(-c2cccc(-n3c4ccncc4c4cc(-n5c6ccccc6c6ccc(-n7c8ccccc8c8ccccc87)cc65)ccc43)c2)cc(-n2c3ccccc3c3ccccc32)c1]

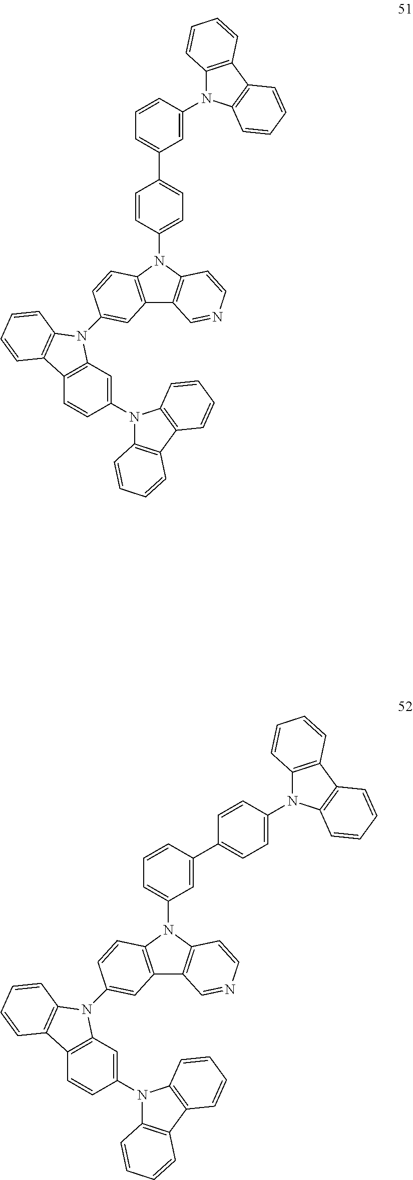 [SMILES: c1cc(-c2ccc(-n3c4ccncc4c4cc(-n5c6ccccc6c6ccc(-n7c8ccccc8c8ccccc87)cc65)ccc43)cc2)cc(-n2c3ccccc3c3ccccc32)c1 ; c1cc(-c2ccc(-n3c4ccccc4c4ccccc43)cc2)cc(-n2c3ccncc3c3cc(-n4c5ccccc5c5ccc(-n6c7ccccc7c7ccccc76)cc54)ccc32)c1]

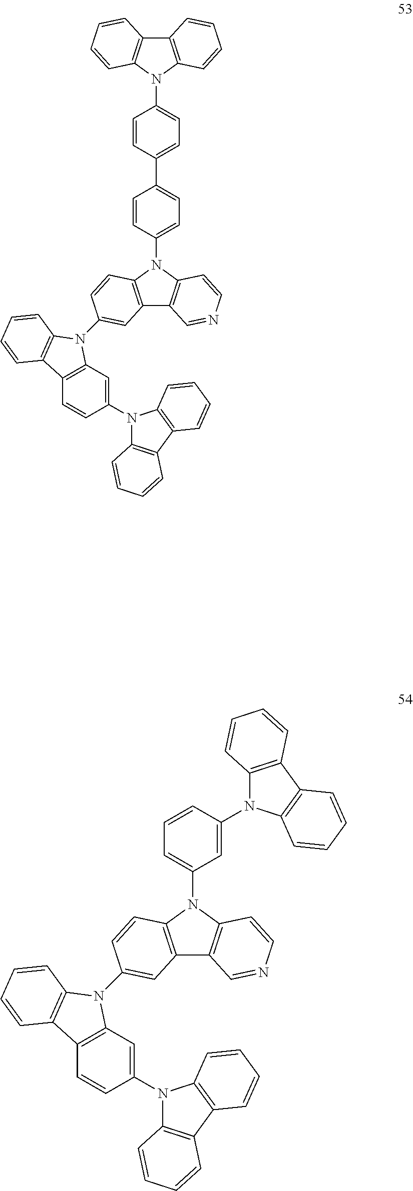 [SMILES: c1ccc2c(c1)c1ccccc1n2-c1ccc(-c2ccc(-n3c4ccncc4c4cc(-n5c6ccccc6c6ccc(-n7c8ccccc8c8ccccc87)cc65)ccc43)cc2)cc1 ; c1cc(-n2c3ccccc3c3ccccc32)cc(-n2c3ccncc3c3cc(-n4c5ccccc5c5ccc(-n6c7ccccc7c7ccccc76)cc54)ccc32)c1]

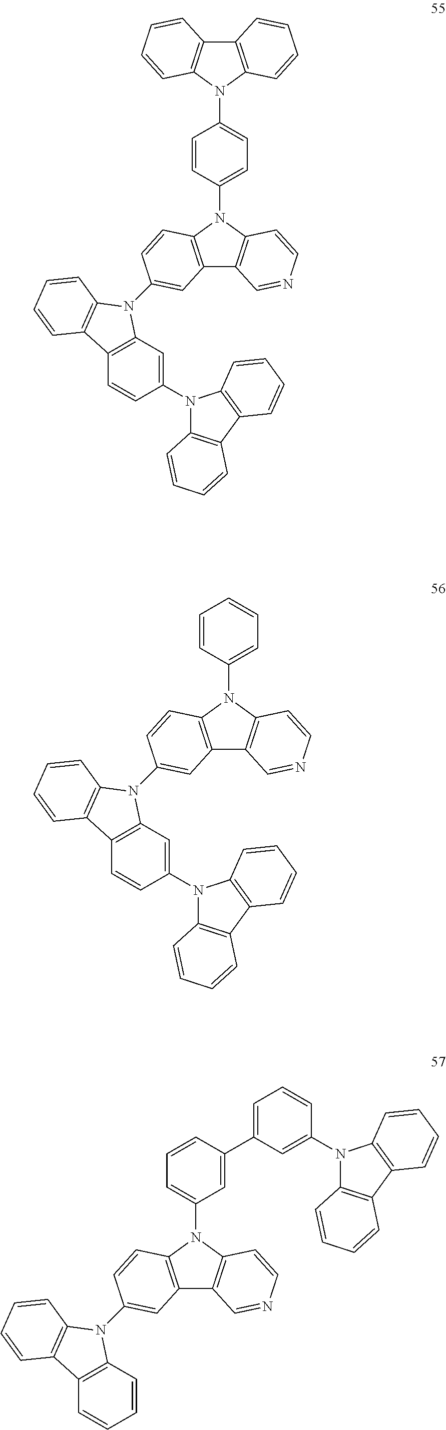 [SMILES: c1ccc2c(c1)c1ccccc1n2-c1ccc(-n2c3ccncc3c3cc(-n4c5ccccc5c5ccc(-n6c7ccccc7c7ccccc76)cc54)ccc32)cc1 ; c1ccc(-n2c3ccncc3c3cc(-n4c5ccccc5c5ccc(-n6c7ccccc7c7ccccc76)cc54)ccc32)cc1 ; c1cc(-c2cccc(-n3c4ccncc4c4cc(-n5c6ccccc6c6ccccc65)ccc43)c2)cc(-n2c3ccccc3c3ccccc32)c1]

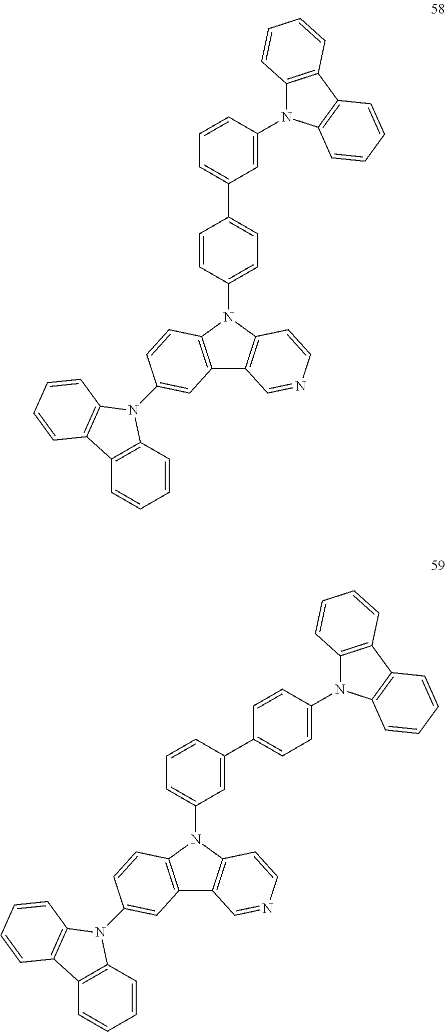 [SMILES: c1cc(-c2ccc(-n3c4ccncc4c4cc(-n5c6ccccc6c6ccccc65)ccc43)cc2)cc(-n2c3ccccc3c3ccccc32)c1 ; c1cc(-c2ccc(-n3c4ccccc4c4ccccc43)cc2)cc(-n2c3ccncc3c3cc(-n4c5ccccc5c5ccccc54)ccc32)c1]

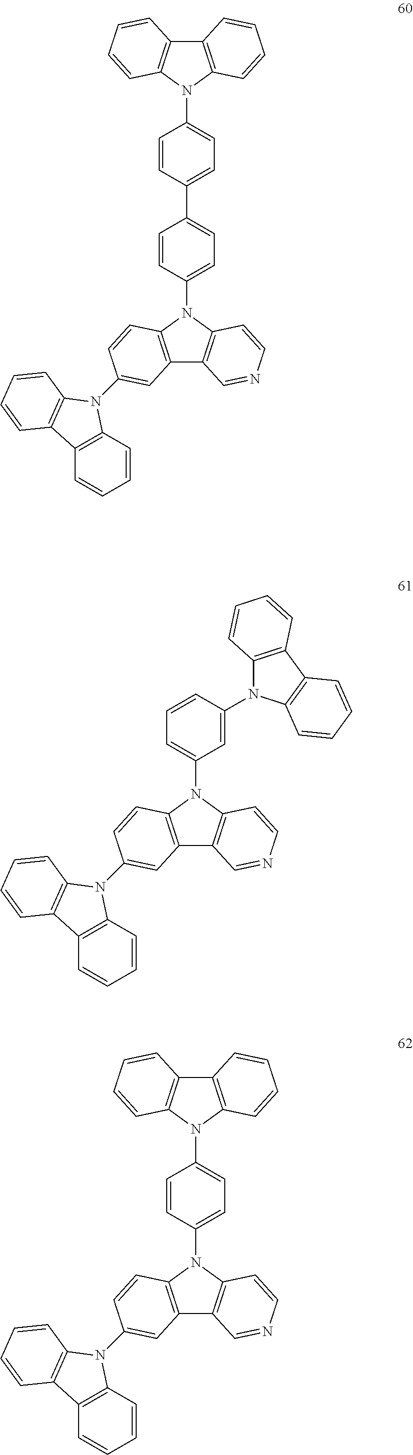 [SMILES: c1ccc2c(c1)c1ccccc1n2-c1ccc(-c2ccc(-n3c4ccncc4c4cc(-n5c6ccccc6c6ccccc65)ccc43)cc2)cc1 ; c1cc(-n2c3ccccc3c3ccccc32)cc(-n2c3ccncc3c3cc(-n4c5ccccc5c5ccccc54)ccc32)c1 ; c1ccc2c(c1)c1ccccc1n2-c1ccc(-n2c3ccncc3c3cc(-n4c5ccccc5c5ccccc54)ccc32)cc1]

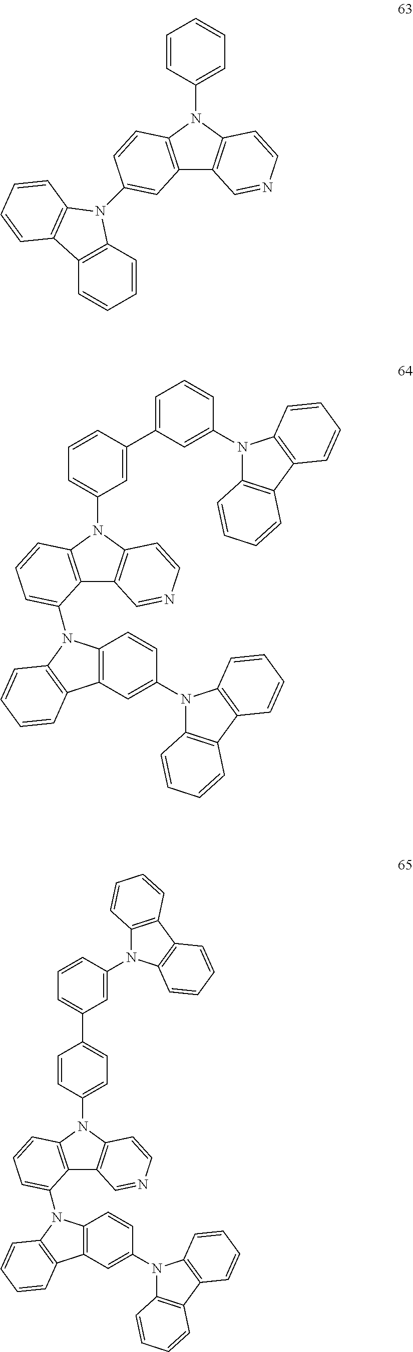 [SMILES: c1ccc(-n2c3ccncc3c3cc(-n4c5ccccc5c5ccccc54)ccc32)cc1 ; c1cc(-c2cccc(-n3c4ccncc4c4c(-n5c6ccccc6c6cc(-n7c8ccccc8c8ccccc87)ccc65)cccc43)c2)cc(-n2c3ccccc3c3ccccc32)c1 ; c1cc(-c2ccc(-n3c4ccncc4c4c(-n5c6ccccc6c6cc(-n7c8ccccc8c8ccccc87)ccc65)cccc43)cc2)cc(-n2c3ccccc3c3ccccc32)c1]

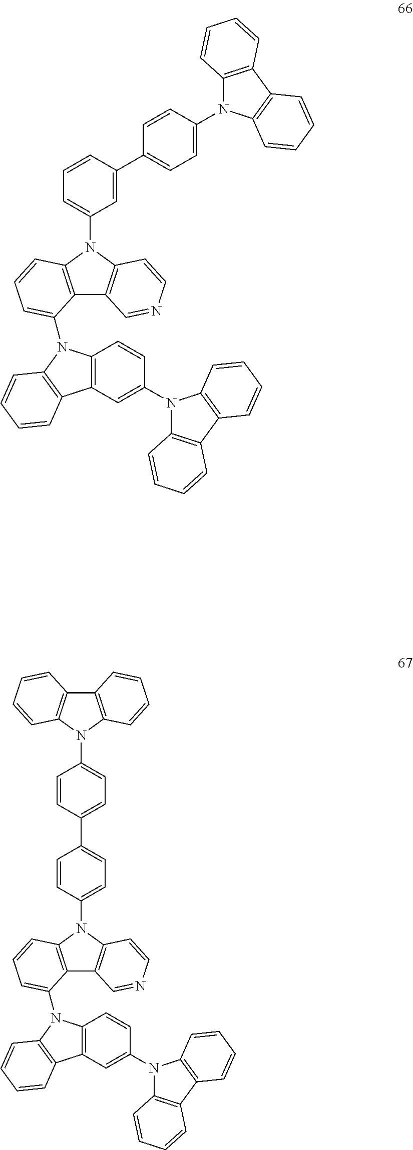 [SMILES: c1cc(-c2ccc(-n3c4ccccc4c4ccccc43)cc2)cc(-n2c3ccncc3c3c(-n4c5ccccc5c5cc(-n6c7ccccc7c7ccccc76)ccc54)cccc32)c1 ; c1ccc2c(c1)c1ccccc1n2-c1ccc(-c2ccc(-n3c4ccncc4c4c(-n5c6ccccc6c6cc(-n7c8ccccc8c8ccccc87)ccc65)cccc43)cc2)cc1]

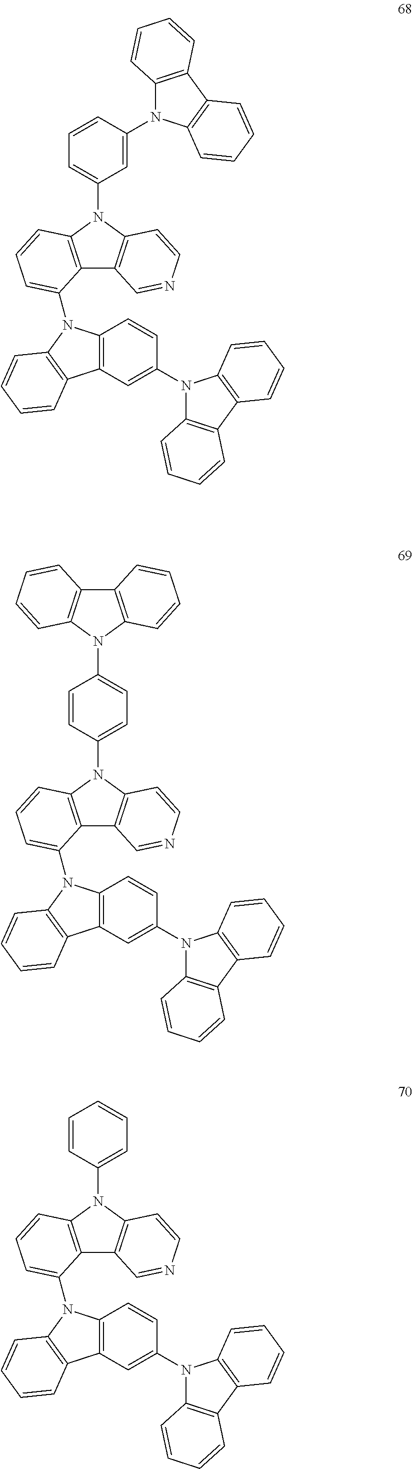 [SMILES: c1cc(-n2c3ccccc3c3ccccc32)cc(-n2c3ccncc3c3c(-n4c5ccccc5c5cc(-n6c7ccccc7c7ccccc76)ccc54)cccc32)c1 ; c1ccc2c(c1)c1ccccc1n2-c1ccc(-n2c3ccncc3c3c(-n4c5ccccc5c5cc(-n6c7ccccc7c7ccccc76)ccc54)cccc32)cc1 ; c1ccc(-n2c3ccncc3c3c(-n4c5ccccc5c5cc(-n6c7ccccc7c7ccccc76)ccc54)cccc32)cc1]

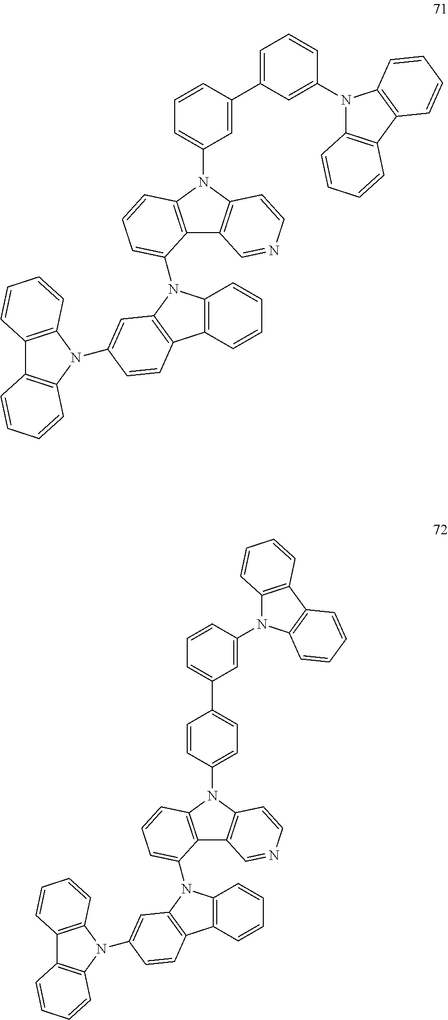 [SMILES: c1cc(-c2cccc(-n3c4ccncc4c4c(-n5c6ccccc6c6ccc(-n7c8ccccc8c8ccccc87)cc65)cccc43)c2)cc(-n2c3ccccc3c3ccccc32)c1 ; c1cc(-c2ccc(-n3c4ccncc4c4c(-n5c6ccccc6c6ccc(-n7c8ccccc8c8ccccc87)cc65)cccc43)cc2)cc(-n2c3ccccc3c3ccccc32)c1]

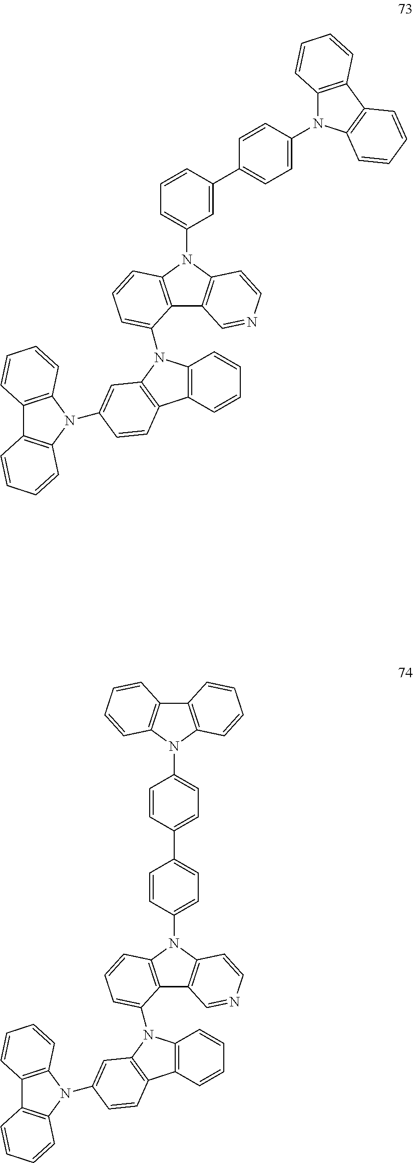 [SMILES: c1cc(-c2ccc(-n3c4ccccc4c4ccccc43)cc2)cc(-n2c3ccncc3c3c(-n4c5ccccc5c5ccc(-n6c7ccccc7c7ccccc76)cc54)cccc32)c1 ; c1ccc2c(c1)c1ccccc1n2-c1ccc(-c2ccc(-n3c4ccncc4c4c(-n5c6ccccc6c6ccc(-n7c8ccccc8c8ccccc87)cc65)cccc43)cc2)cc1]

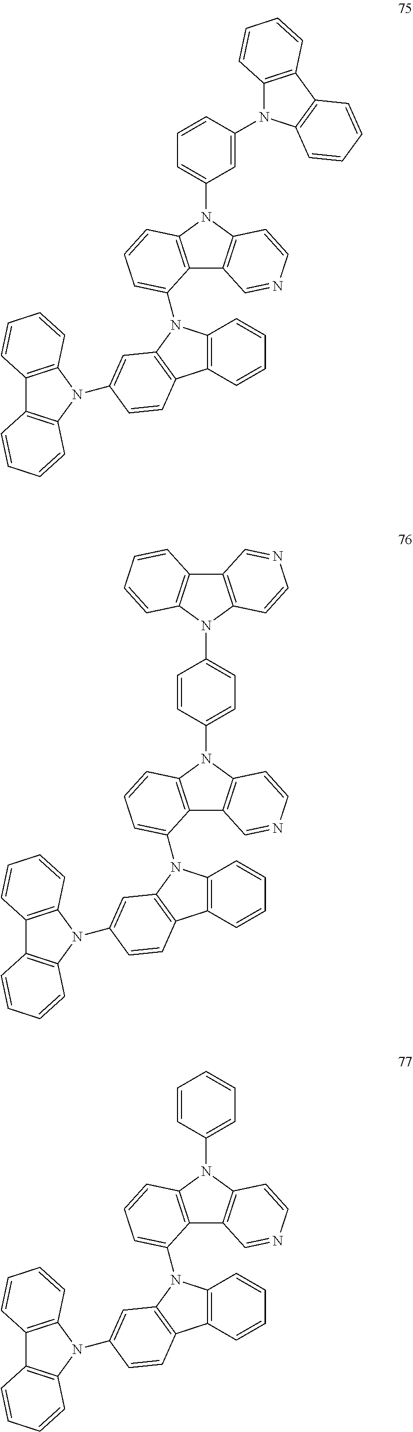 [SMILES: c1cc(-n2c3ccccc3c3ccccc32)cc(-n2c3ccncc3c3c(-n4c5ccccc5c5ccc(-n6c7ccccc7c7ccccc76)cc54)cccc32)c1 ; c1ccc2c(c1)c1ccccc1n2-c1ccc2c3ccccc3n(-c3cccc4c3c3cnccc3n4-c3ccc(-n4c5ccccc5c5cnccc54)cc3)c2c1 ; c1ccc(-n2c3ccncc3c3c(-n4c5ccccc5c5ccc(-n6c7ccccc7c7ccccc76)cc54)cccc32)cc1]

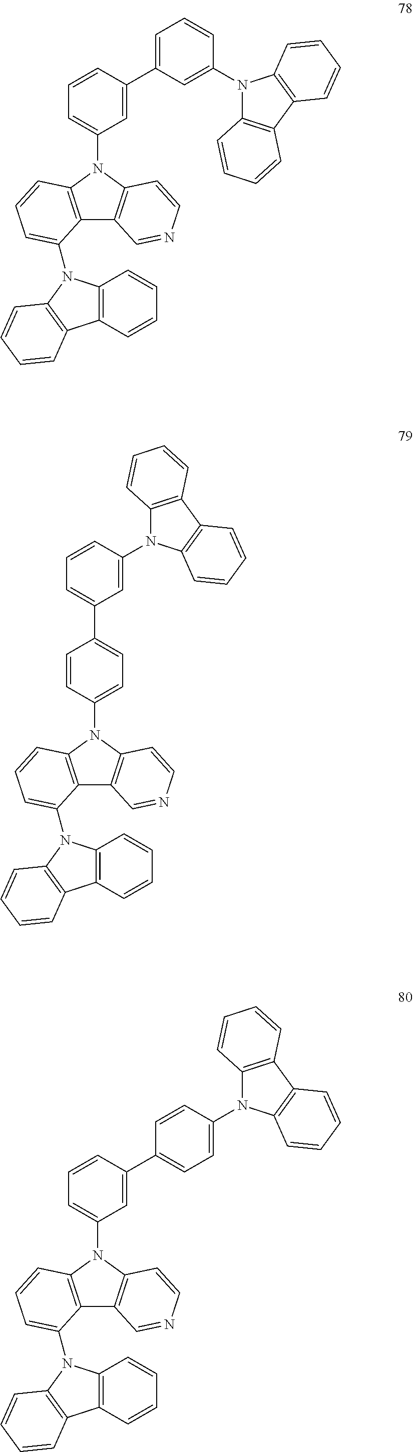 [SMILES: c1cc(-c2cccc(-n3c4ccncc4c4c(-n5c6ccccc6c6ccccc65)cccc43)c2)cc(-n2c3ccccc3c3ccccc32)c1 ; c1cc(-c2ccc(-n3c4ccncc4c4c(-n5c6ccccc6c6ccccc65)cccc43)cc2)cc(-n2c3ccccc3c3ccccc32)c1 ; c1cc(-c2ccc(-n3c4ccccc4c4ccccc43)cc2)cc(-n2c3ccncc3c3c(-n4c5ccccc5c5ccccc54)cccc32)c1]

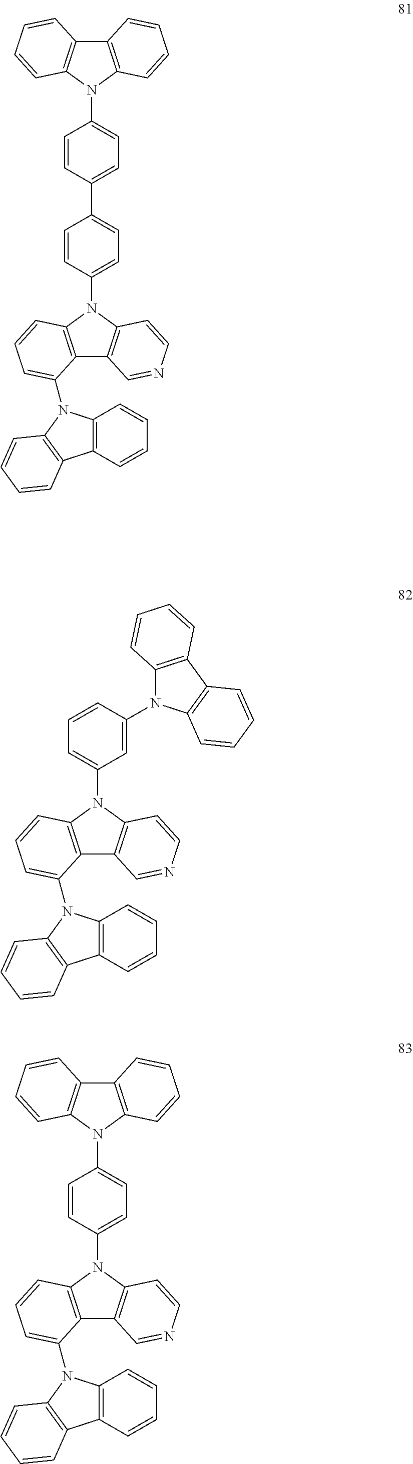 [SMILES: c1ccc2c(c1)c1ccccc1n2-c1ccc(-c2ccc(-n3c4ccncc4c4c(-n5c6ccccc6c6ccccc65)cccc43)cc2)cc1 ; c1cc(-n2c3ccccc3c3ccccc32)cc(-n2c3ccncc3c3c(-n4c5ccccc5c5ccccc54)cccc32)c1 ; c1ccc2c(c1)c1ccccc1n2-c1ccc(-n2c3ccncc3c3c(-n4c5ccccc5c5ccccc54)cccc32)cc1]

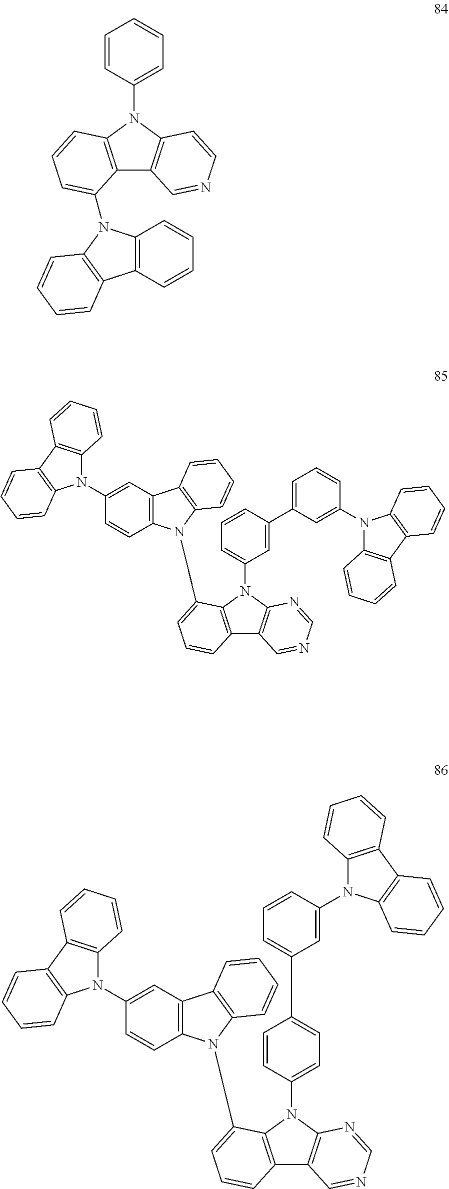 [SMILES: c1ccc(-n2c3ccncc3c3c(-n4c5ccccc5c5ccccc54)cccc32)cc1 ; c1cc(-c2cccc(-n3c4ncncc4c4cccc(-n5c6ccccc6c6cc(-n7c8ccccc8c8ccccc87)ccc65)c43)c2)cc(-n2c3ccccc3c3ccccc32)c1 ; c1cc(-c2ccc(-n3c4ncncc4c4cccc(-n5c6ccccc6c6cc(-n7c8ccccc8c8ccccc87)ccc65)c43)cc2)cc(-n2c3ccccc3c3ccccc32)c1]

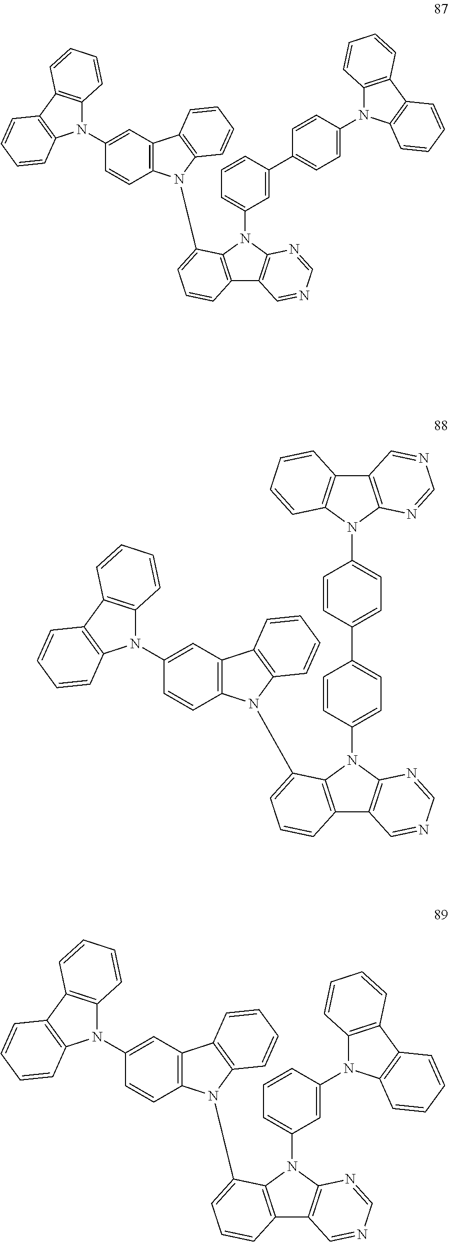 [SMILES: c1cc(-c2ccc(-n3c4ccccc4c4ccccc43)cc2)cc(-n2c3ncncc3c3cccc(-n4c5ccccc5c5cc(-n6c7ccccc7c7ccccc76)ccc54)c32)c1 ; c1ccc2c(c1)c1ccccc1n2-c1ccc2c(c1)c1ccccc1n2-c1cccc2c3cncnc3n(-c3ccc(-c4ccc(-n5c6ccccc6c6cncnc65)cc4)cc3)c12 ; c1cc(-n2c3ccccc3c3ccccc32)cc(-n2c3ncncc3c3cccc(-n4c5ccccc5c5cc(-n6c7ccccc7c7ccccc76)ccc54)c32)c1]

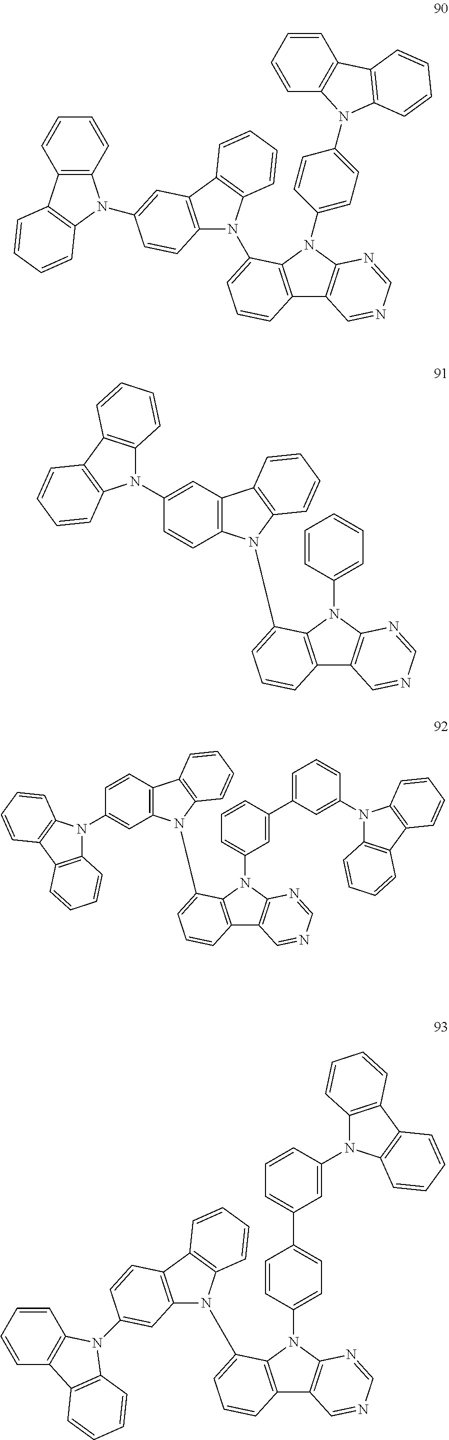 [SMILES: c1ccc2c(c1)c1ccccc1n2-c1ccc(-n2c3ncncc3c3cccc(-n4c5ccccc5c5cc(-n6c7ccccc7c7ccccc76)ccc54)c32)cc1 ; c1ccc(-n2c3ncncc3c3cccc(-n4c5ccccc5c5cc(-n6c7ccccc7c7ccccc76)ccc54)c32)cc1 ; c1cc(-c2cccc(-n3c4ncncc4c4cccc(-n5c6ccccc6c6ccc(-n7c8ccccc8c8ccccc87)cc65)c43)c2)cc(-n2c3ccccc3c3ccccc32)c1 ; c1cc(-c2ccc(-n3c4ncncc4c4cccc(-n5c6ccccc6c6ccc(-n7c8ccccc8c8ccccc87)cc65)c43)cc2)cc(-n2c3ccccc3c3ccccc32)c1]

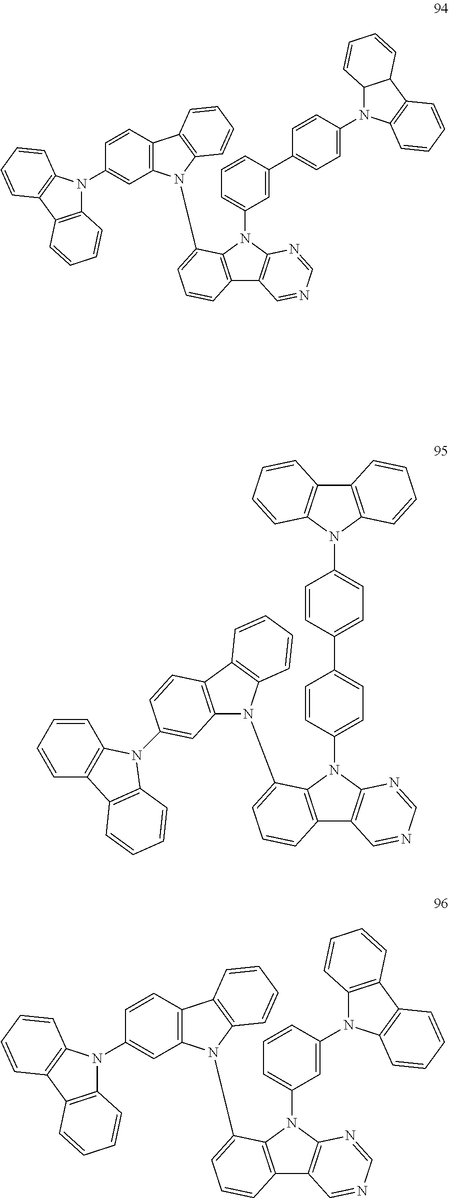 [SMILES: C1=CC2c3ccccc3N(c3ccc(-c4cccc(-n5c6ncncc6c6cccc(-n7c8ccccc8c8ccc(-n9c%10ccccc%10c%10ccccc%109)cc87)c65)c4)cc3)C2C=C1 ; c1ccc2c(c1)c1ccccc1n2-c1ccc(-c2ccc(-n3c4ncncc4c4cccc(-n5c6ccccc6c6ccc(-n7c8ccccc8c8ccccc87)cc65)c43)cc2)cc1 ; c1cc(-n2c3ccccc3c3ccccc32)cc(-n2c3ncncc3c3cccc(-n4c5ccccc5c5ccc(-n6c7ccccc7c7ccccc76)cc54)c32)c1]

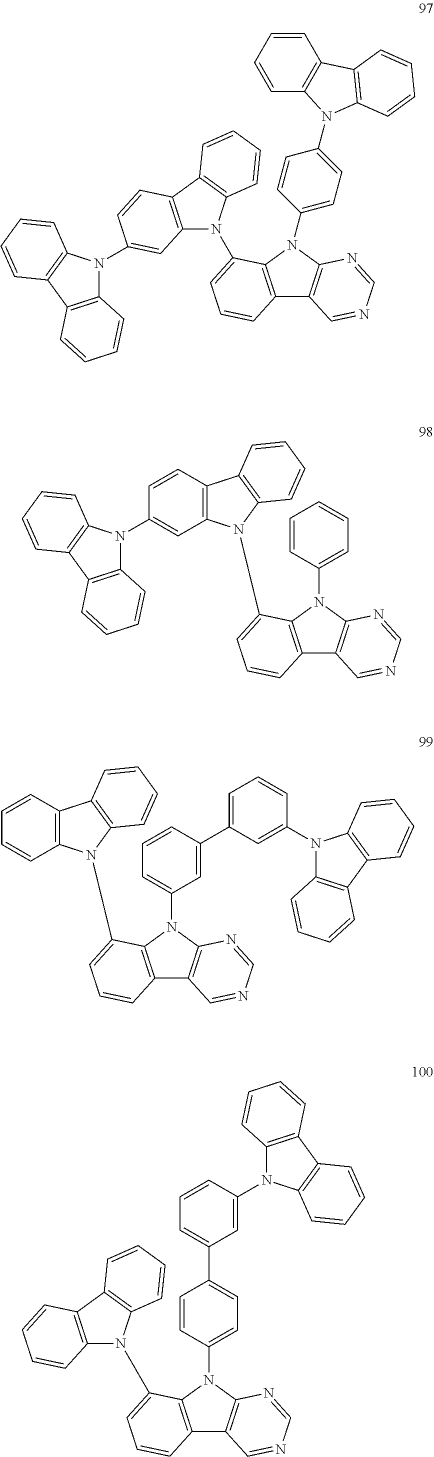 [SMILES: c1ccc2c(c1)c1ccccc1n2-c1ccc(-n2c3ncncc3c3cccc(-n4c5ccccc5c5ccc(-n6c7ccccc7c7ccccc76)cc54)c32)cc1 ; c1ccc(-n2c3ncncc3c3cccc(-n4c5ccccc5c5ccc(-n6c7ccccc7c7ccccc76)cc54)c32)cc1 ; c1cc(-c2cccc(-n3c4ncncc4c4cccc(-n5c6ccccc6c6ccccc65)c43)c2)cc(-n2c3ccccc3c3ccccc32)c1 ; c1cc(-c2ccc(-n3c4ncncc4c4cccc(-n5c6ccccc6c6ccccc65)c43)cc2)cc(-n2c3ccccc3c3ccccc32)c1]

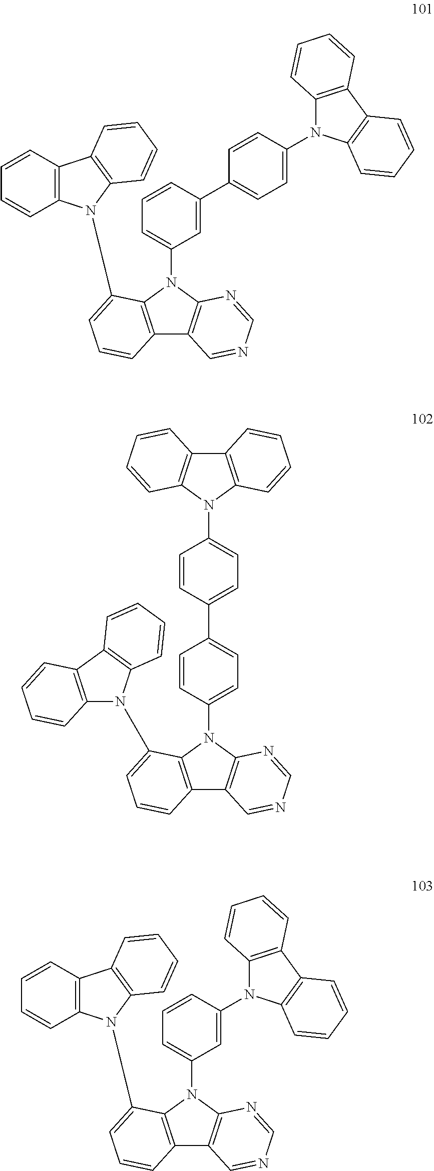 [SMILES: c1cc(-c2ccc(-n3c4ccccc4c4ccccc43)cc2)cc(-n2c3ncncc3c3cccc(-n4c5ccccc5c5ccccc54)c32)c1 ; c1ccc2c(c1)c1ccccc1n2-c1ccc(-c2ccc(-n3c4ncncc4c4cccc(-n5c6ccccc6c6ccccc65)c43)cc2)cc1 ; c1cc(-n2c3ccccc3c3ccccc32)cc(-n2c3ncncc3c3cccc(-n4c5ccccc5c5ccccc54)c32)c1]

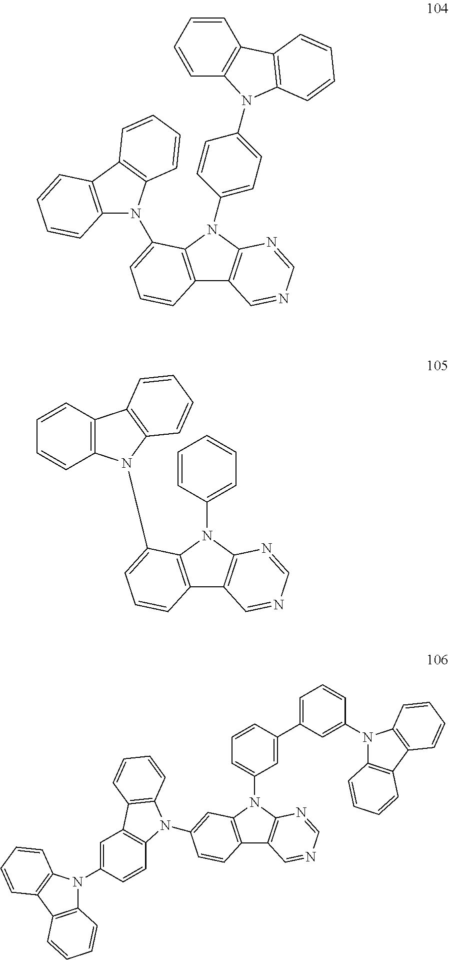 [SMILES: c1ccc2c(c1)c1ccccc1n2-c1ccc(-n2c3ncncc3c3cccc(-n4c5ccccc5c5ccccc54)c32)cc1 ; c1ccc(-n2c3ncncc3c3cccc(-n4c5ccccc5c5ccccc54)c32)cc1 ; c1cc(-c2cccc(-n3c4cc(-n5c6ccccc6c6cc(-n7c8ccccc8c8ccccc87)ccc65)ccc4c4cncnc43)c2)cc(-n2c3ccccc3c3ccccc32)c1]

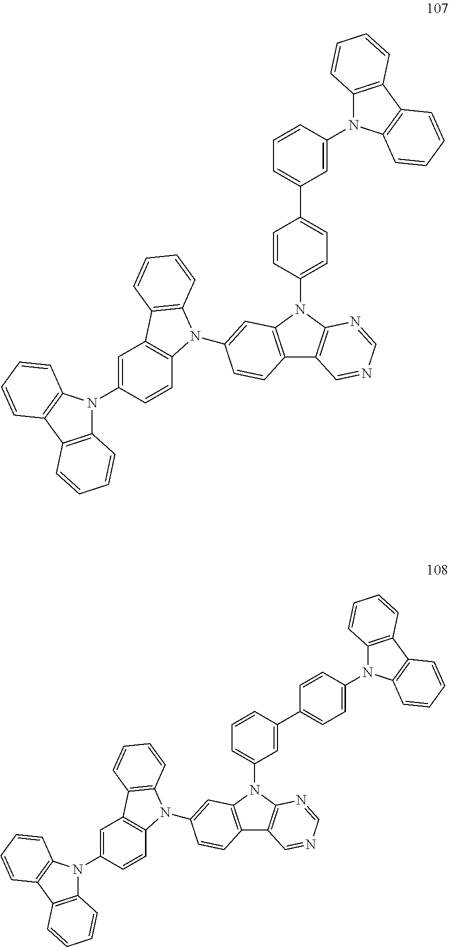 [SMILES: c1cc(-c2ccc(-n3c4cc(-n5c6ccccc6c6cc(-n7c8ccccc8c8ccccc87)ccc65)ccc4c4cncnc43)cc2)cc(-n2c3ccccc3c3ccccc32)c1 ; c1cc(-c2ccc(-n3c4ccccc4c4ccccc43)cc2)cc(-n2c3cc(-n4c5ccccc5c5cc(-n6c7ccccc7c7ccccc76)ccc54)ccc3c3cncnc32)c1]

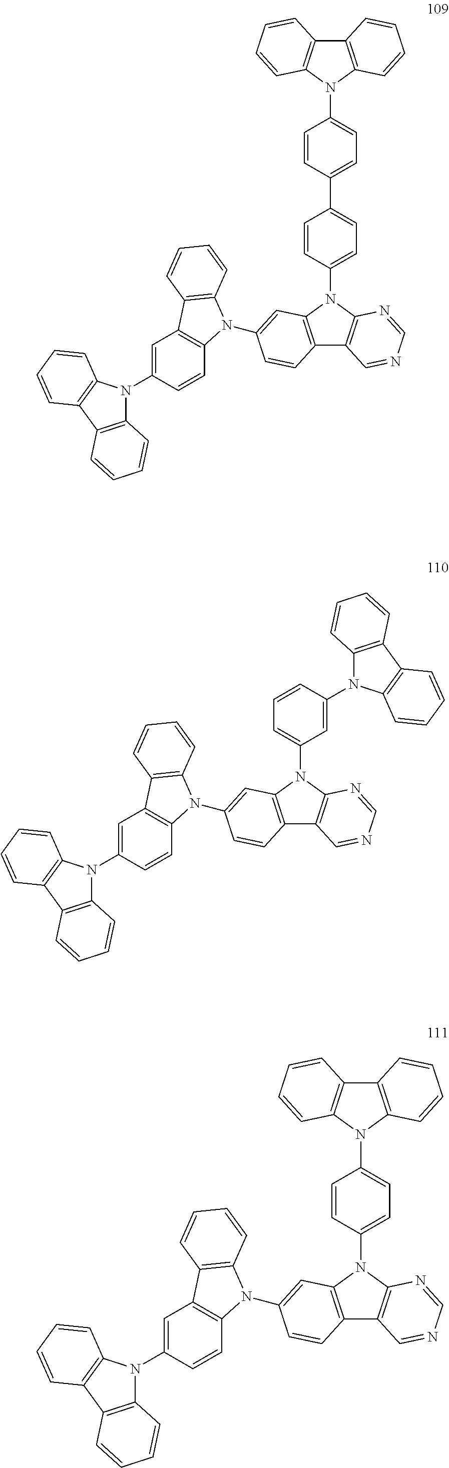 [SMILES: c1ccc2c(c1)c1ccccc1n2-c1ccc(-c2ccc(-n3c4cc(-n5c6ccccc6c6cc(-n7c8ccccc8c8ccccc87)ccc65)ccc4c4cncnc43)cc2)cc1 ; c1cc(-n2c3ccccc3c3ccccc32)cc(-n2c3cc(-n4c5ccccc5c5cc(-n6c7ccccc7c7ccccc76)ccc54)ccc3c3cncnc32)c1 ; c1ccc2c(c1)c1ccccc1n2-c1ccc(-n2c3cc(-n4c5ccccc5c5cc(-n6c7ccccc7c7ccccc76)ccc54)ccc3c3cncnc32)cc1]

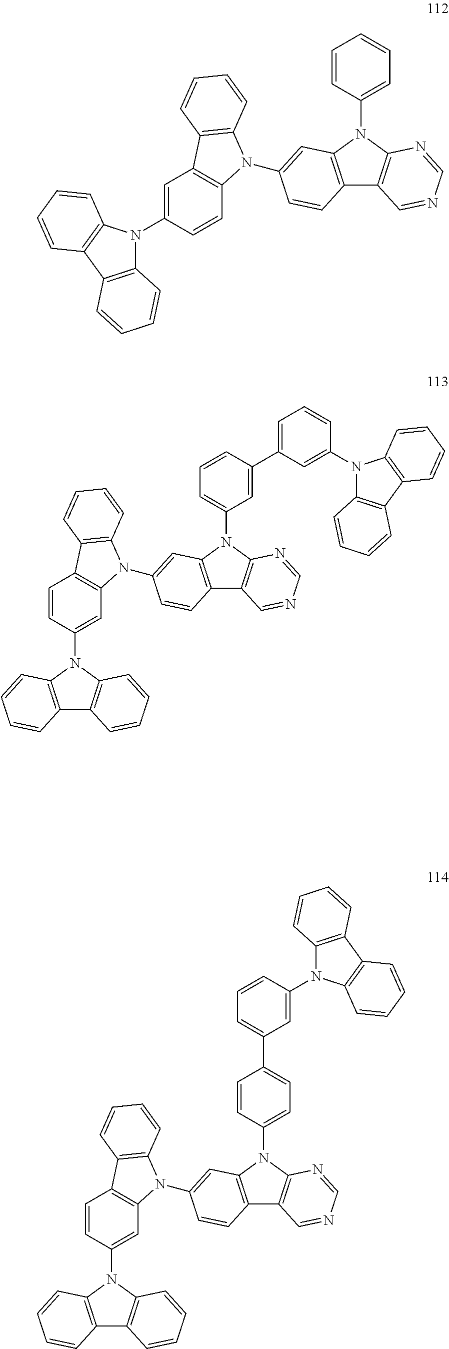 [SMILES: c1ccc(-n2c3cc(-n4c5ccccc5c5cc(-n6c7ccccc7c7ccccc76)ccc54)ccc3c3cncnc32)cc1 ; c1cc(-c2cccc(-n3c4cc(-n5c6ccccc6c6ccc(-n7c8ccccc8c8ccccc87)cc65)ccc4c4cncnc43)c2)cc(-n2c3ccccc3c3ccccc32)c1 ; c1cc(-c2ccc(-n3c4cc(-n5c6ccccc6c6ccc(-n7c8ccccc8c8ccccc87)cc65)ccc4c4cncnc43)cc2)cc(-n2c3ccccc3c3ccccc32)c1]

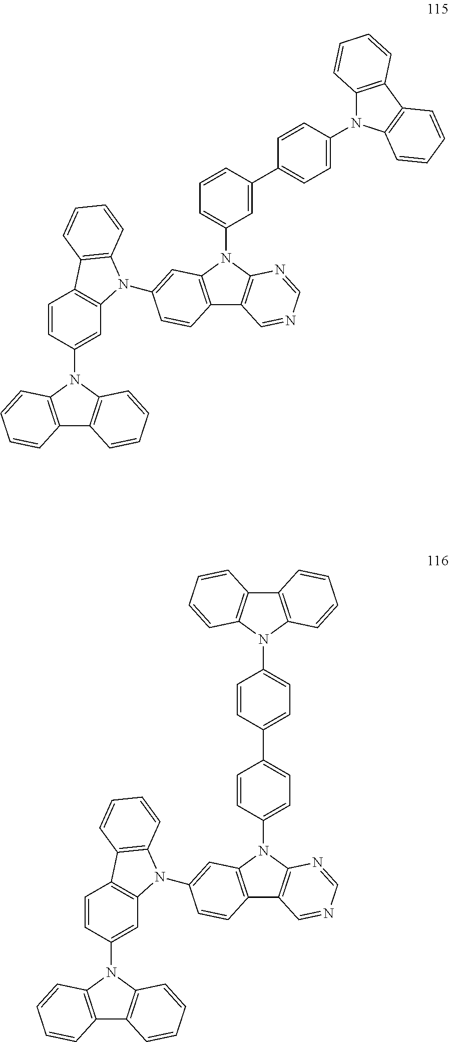 [SMILES: c1cc(-c2ccc(-n3c4ccccc4c4ccccc43)cc2)cc(-n2c3cc(-n4c5ccccc5c5ccc(-n6c7ccccc7c7ccccc76)cc54)ccc3c3cncnc32)c1 ; c1ccc2c(c1)c1ccccc1n2-c1ccc(-c2ccc(-n3c4cc(-n5c6ccccc6c6ccc(-n7c8ccccc8c8ccccc87)cc65)ccc4c4cncnc43)cc2)cc1]

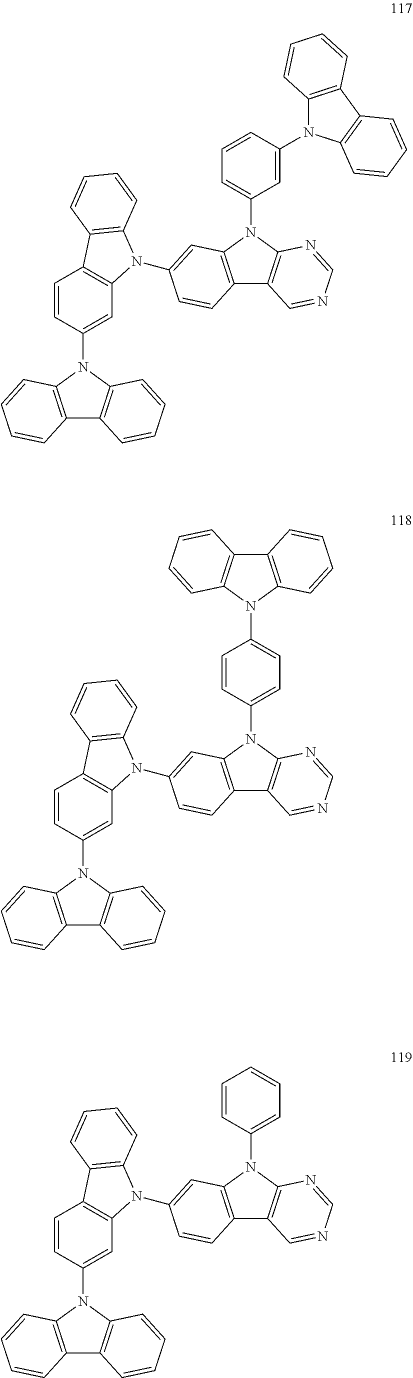 [SMILES: c1cc(-n2c3ccccc3c3ccccc32)cc(-n2c3cc(-n4c5ccccc5c5ccc(-n6c7ccccc7c7ccccc76)cc54)ccc3c3cncnc32)c1 ; c1ccc2c(c1)c1ccccc1n2-c1ccc(-n2c3cc(-n4c5ccccc5c5ccc(-n6c7ccccc7c7ccccc76)cc54)ccc3c3cncnc32)cc1 ; c1ccc(-n2c3cc(-n4c5ccccc5c5ccc(-n6c7ccccc7c7ccccc76)cc54)ccc3c3cncnc32)cc1]

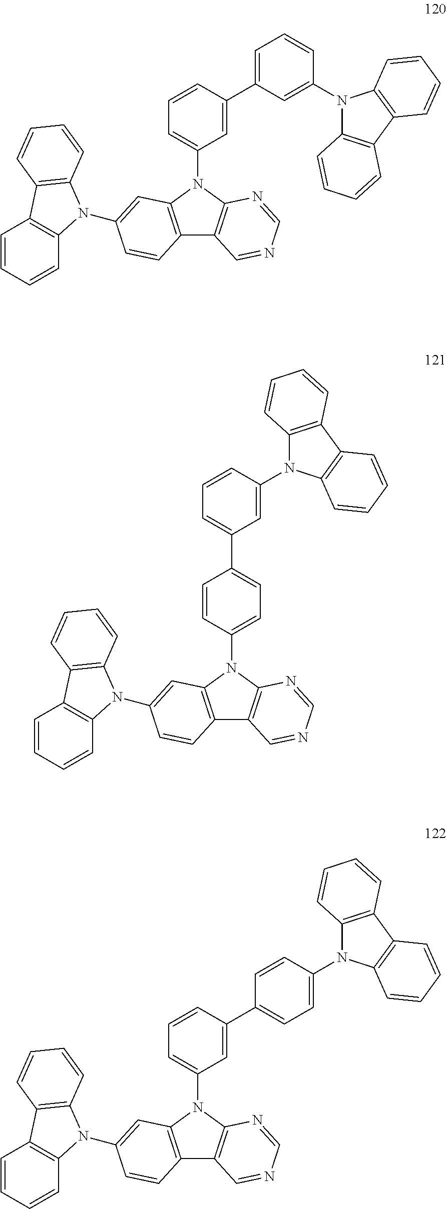 [SMILES: c1cc(-c2cccc(-n3c4cc(-n5c6ccccc6c6ccccc65)ccc4c4cncnc43)c2)cc(-n2c3ccccc3c3ccccc32)c1 ; c1cc(-c2ccc(-n3c4cc(-n5c6ccccc6c6ccccc65)ccc4c4cncnc43)cc2)cc(-n2c3ccccc3c3ccccc32)c1 ; c1cc(-c2ccc(-n3c4ccccc4c4ccccc43)cc2)cc(-n2c3cc(-n4c5ccccc5c5ccccc54)ccc3c3cncnc32)c1]

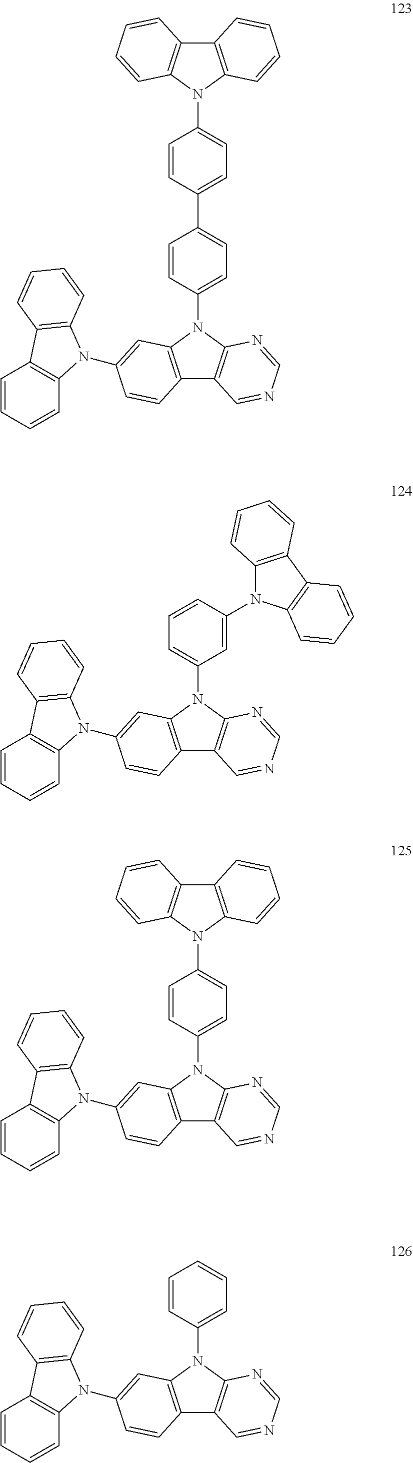 [SMILES: c1ccc2c(c1)c1ccccc1n2-c1ccc(-c2ccc(-n3c4cc(-n5c6ccccc6c6ccccc65)ccc4c4cncnc43)cc2)cc1 ; c1cc(-n2c3ccccc3c3ccccc32)cc(-n2c3cc(-n4c5ccccc5c5ccccc54)ccc3c3cncnc32)c1 ; c1ccc2c(c1)c1ccccc1n2-c1ccc(-n2c3cc(-n4c5ccccc5c5ccccc54)ccc3c3cncnc32)cc1 ; c1ccc(-n2c3cc(-n4c5ccccc5c5ccccc54)ccc3c3cncnc32)cc1]

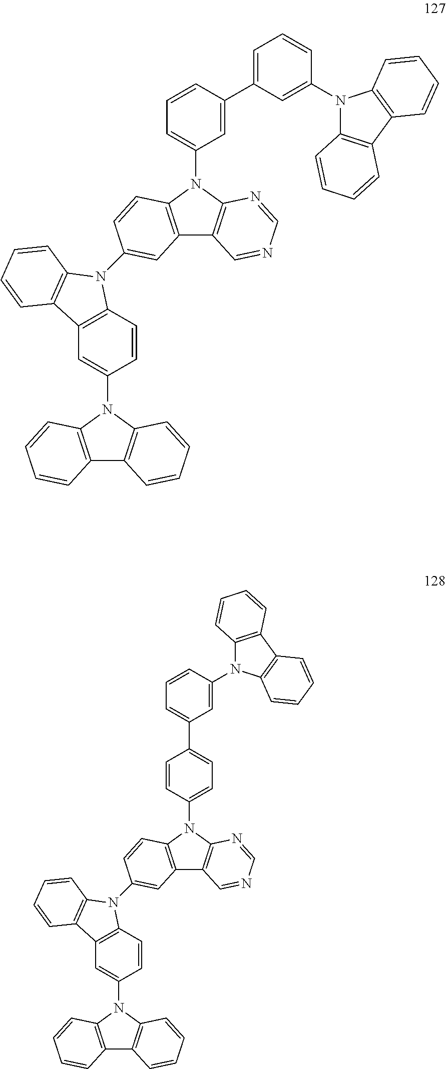 [SMILES: c1cc(-c2cccc(-n3c4ccc(-n5c6ccccc6c6cc(-n7c8ccccc8c8ccccc87)ccc65)cc4c4cncnc43)c2)cc(-n2c3ccccc3c3ccccc32)c1 ; c1cc(-c2ccc(-n3c4ccc(-n5c6ccccc6c6cc(-n7c8ccccc8c8ccccc87)ccc65)cc4c4cncnc43)cc2)cc(-n2c3ccccc3c3ccccc32)c1]

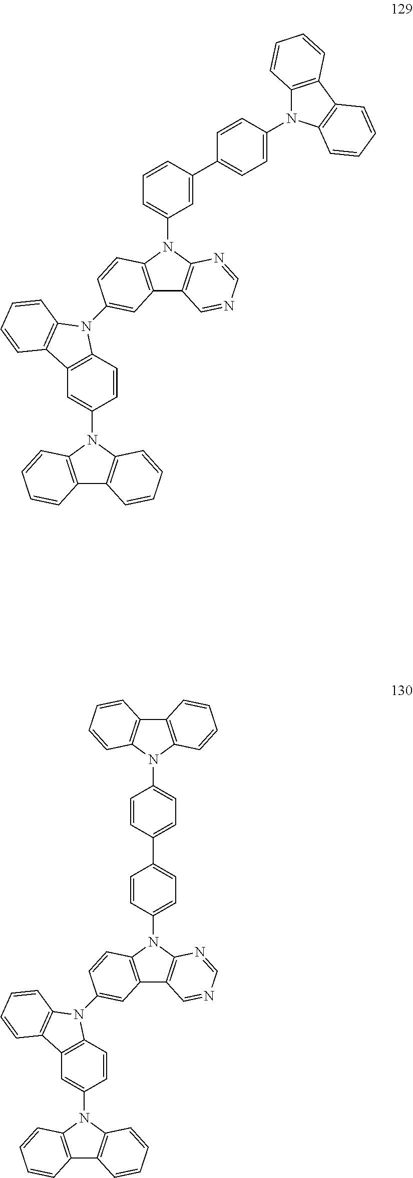 [SMILES: c1cc(-c2ccc(-n3c4ccccc4c4ccccc43)cc2)cc(-n2c3ccc(-n4c5ccccc5c5cc(-n6c7ccccc7c7ccccc76)ccc54)cc3c3cncnc32)c1 ; c1ccc2c(c1)c1ccccc1n2-c1ccc(-c2ccc(-n3c4ccc(-n5c6ccccc6c6cc(-n7c8ccccc8c8ccccc87)ccc65)cc4c4cncnc43)cc2)cc1]

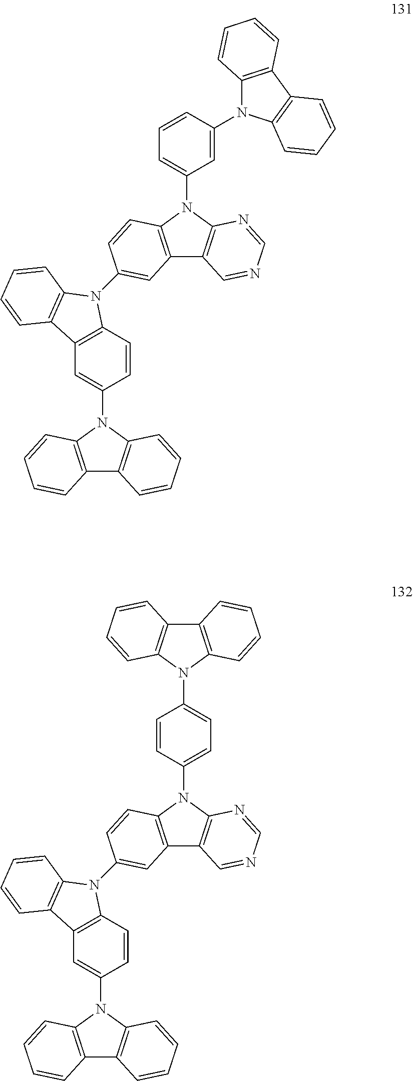 [SMILES: c1cc(-n2c3ccccc3c3ccccc32)cc(-n2c3ccc(-n4c5ccccc5c5cc(-n6c7ccccc7c7ccccc76)ccc54)cc3c3cncnc32)c1 ; c1ccc2c(c1)c1ccccc1n2-c1ccc(-n2c3ccc(-n4c5ccccc5c5cc(-n6c7ccccc7c7ccccc76)ccc54)cc3c3cncnc32)cc1]

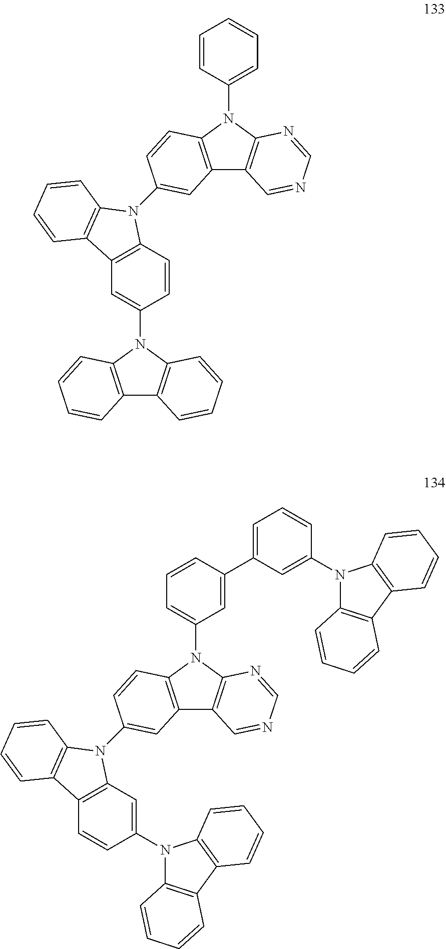 [SMILES: c1ccc(-n2c3ccc(-n4c5ccccc5c5cc(-n6c7ccccc7c7ccccc76)ccc54)cc3c3cncnc32)cc1 ; c1cc(-c2cccc(-n3c4ccc(-n5c6ccccc6c6ccc(-n7c8ccccc8c8ccccc87)cc65)cc4c4cncnc43)c2)cc(-n2c3ccccc3c3ccccc32)c1]

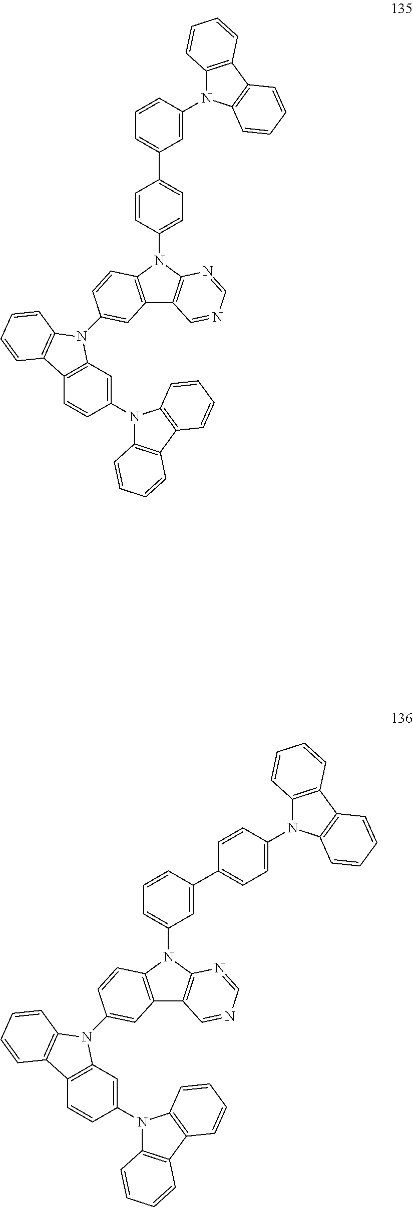 [SMILES: c1cc(-c2ccc(-n3c4ccc(-n5c6ccccc6c6ccc(-n7c8ccccc8c8ccccc87)cc65)cc4c4cncnc43)cc2)cc(-n2c3ccccc3c3ccccc32)c1 ; c1cc(-c2ccc(-n3c4ccccc4c4ccccc43)cc2)cc(-n2c3ccc(-n4c5ccccc5c5ccc(-n6c7ccccc7c7ccccc76)cc54)cc3c3cncnc32)c1]

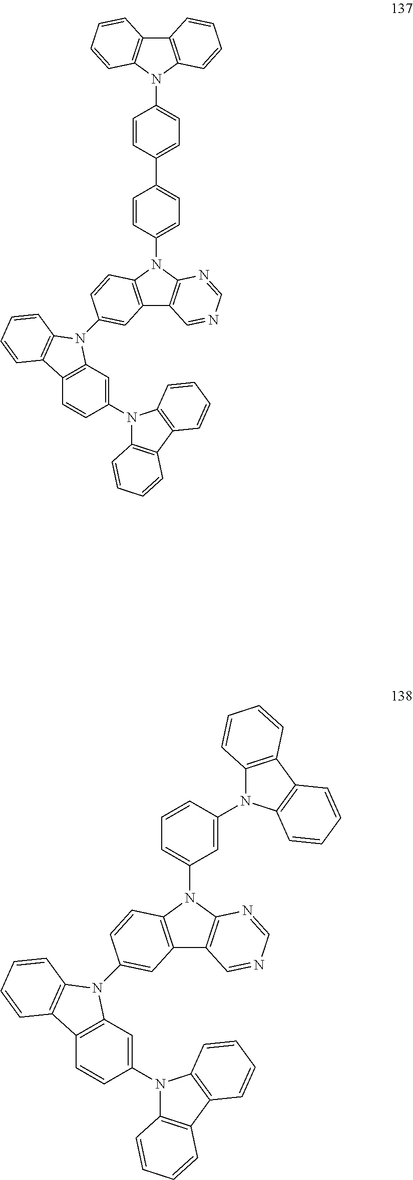 [SMILES: c1ccc2c(c1)c1ccccc1n2-c1ccc(-c2ccc(-n3c4ccc(-n5c6ccccc6c6ccc(-n7c8ccccc8c8ccccc87)cc65)cc4c4cncnc43)cc2)cc1 ; c1cc(-n2c3ccccc3c3ccccc32)cc(-n2c3ccc(-n4c5ccccc5c5ccc(-n6c7ccccc7c7ccccc76)cc54)cc3c3cncnc32)c1]

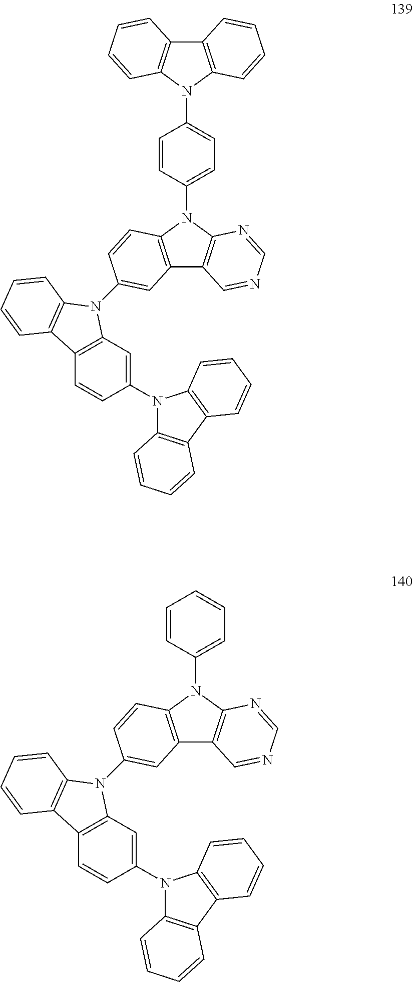 [SMILES: c1ccc2c(c1)c1ccccc1n2-c1ccc(-n2c3ccc(-n4c5ccccc5c5ccc(-n6c7ccccc7c7ccccc76)cc54)cc3c3cncnc32)cc1 ; c1ccc(-n2c3ccc(-n4c5ccccc5c5ccc(-n6c7ccccc7c7ccccc76)cc54)cc3c3cncnc32)cc1]

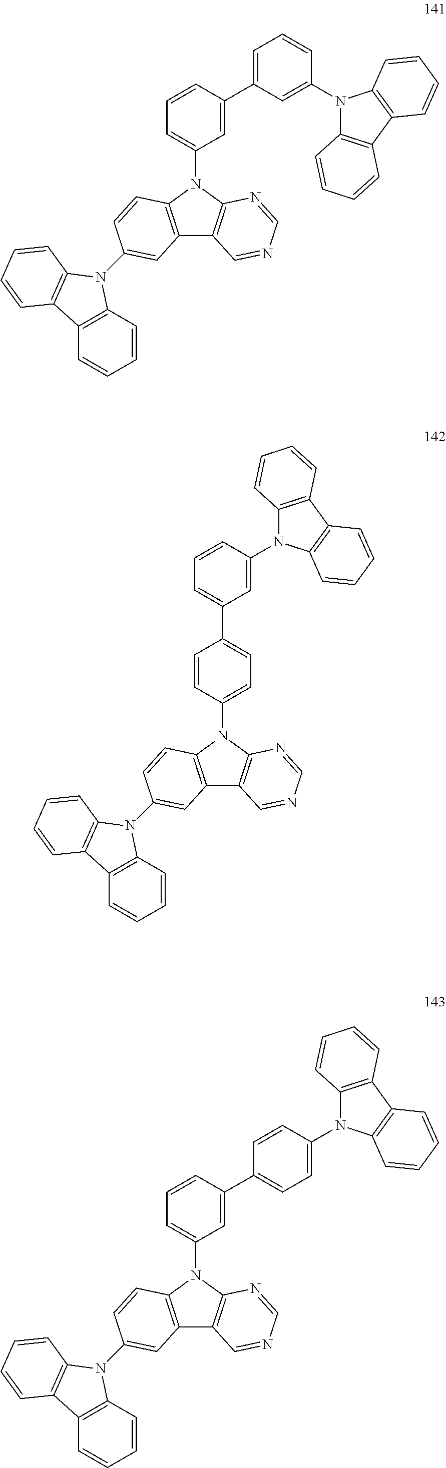 [SMILES: c1cc(-c2cccc(-n3c4ccc(-n5c6ccccc6c6ccccc65)cc4c4cncnc43)c2)cc(-n2c3ccccc3c3ccccc32)c1 ; c1cc(-c2ccc(-n3c4ccc(-n5c6ccccc6c6ccccc65)cc4c4cncnc43)cc2)cc(-n2c3ccccc3c3ccccc32)c1 ; c1cc(-c2ccc(-n3c4ccccc4c4ccccc43)cc2)cc(-n2c3ccc(-n4c5ccccc5c5ccccc54)cc3c3cncnc32)c1]

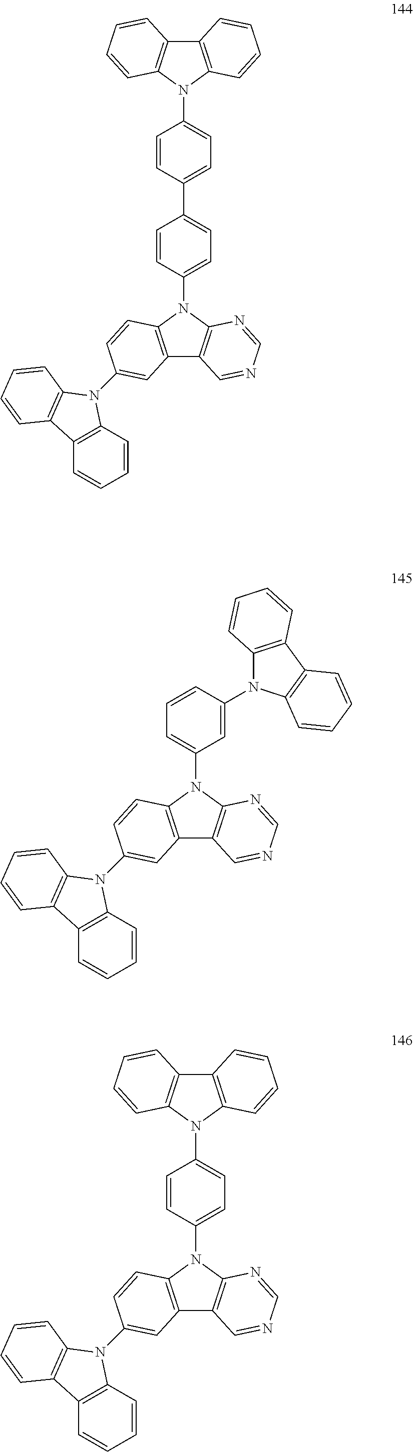 [SMILES: c1ccc2c(c1)c1ccccc1n2-c1ccc(-c2ccc(-n3c4ccc(-n5c6ccccc6c6ccccc65)cc4c4cncnc43)cc2)cc1 ; c1cc(-n2c3ccccc3c3ccccc32)cc(-n2c3ccc(-n4c5ccccc5c5ccccc54)cc3c3cncnc32)c1 ; c1ccc2c(c1)c1ccccc1n2-c1ccc(-n2c3ccc(-n4c5ccccc5c5ccccc54)cc3c3cncnc32)cc1]

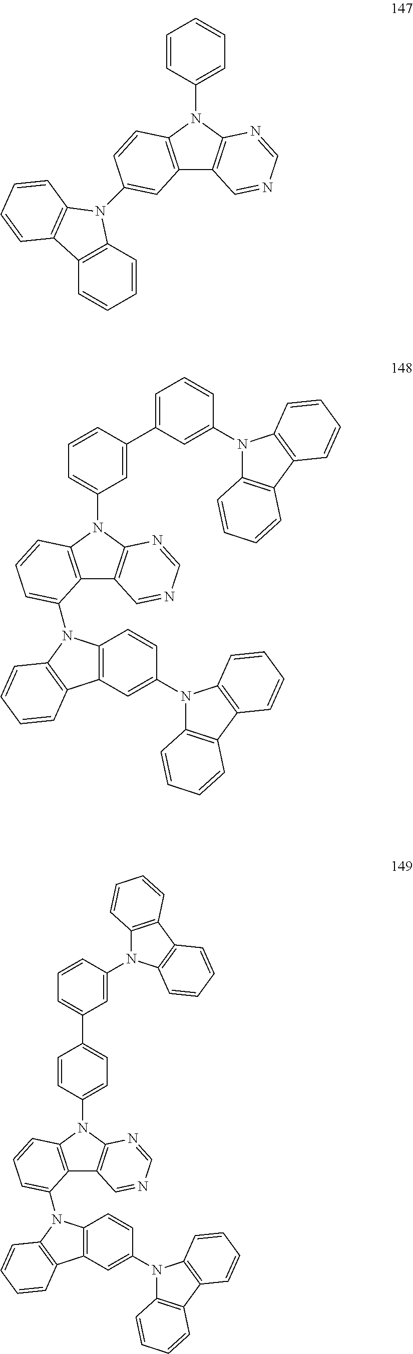 [SMILES: c1ccc(-n2c3ccc(-n4c5ccccc5c5ccccc54)cc3c3cncnc32)cc1 ; c1cc(-c2cccc(-n3c4cccc(-n5c6ccccc6c6cc(-n7c8ccccc8c8ccccc87)ccc65)c4c4cncnc43)c2)cc(-n2c3ccccc3c3ccccc32)c1 ; c1cc(-c2ccc(-n3c4cccc(-n5c6ccccc6c6cc(-n7c8ccccc8c8ccccc87)ccc65)c4c4cncnc43)cc2)cc(-n2c3ccccc3c3ccccc32)c1]

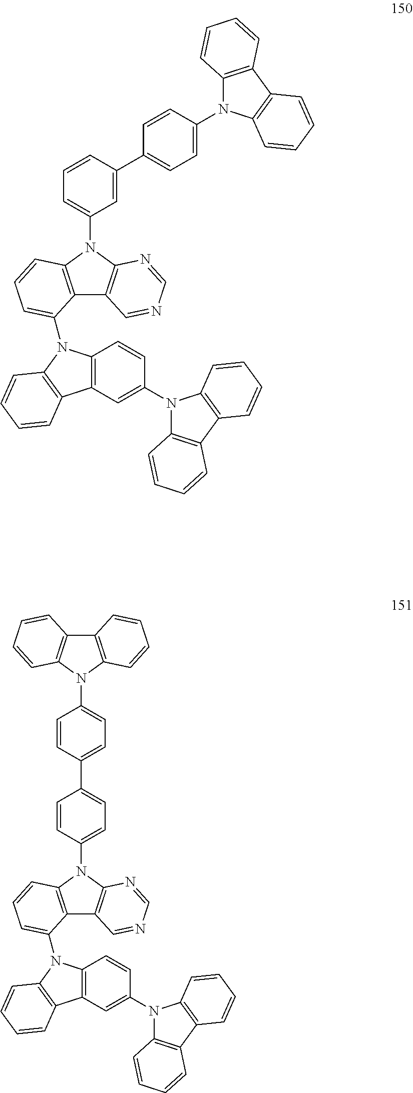 [SMILES: c1cc(-c2ccc(-n3c4ccccc4c4ccccc43)cc2)cc(-n2c3cccc(-n4c5ccccc5c5cc(-n6c7ccccc7c7ccccc76)ccc54)c3c3cncnc32)c1 ; c1ccc2c(c1)c1ccccc1n2-c1ccc(-c2ccc(-n3c4cccc(-n5c6ccccc6c6cc(-n7c8ccccc8c8ccccc87)ccc65)c4c4cncnc43)cc2)cc1]

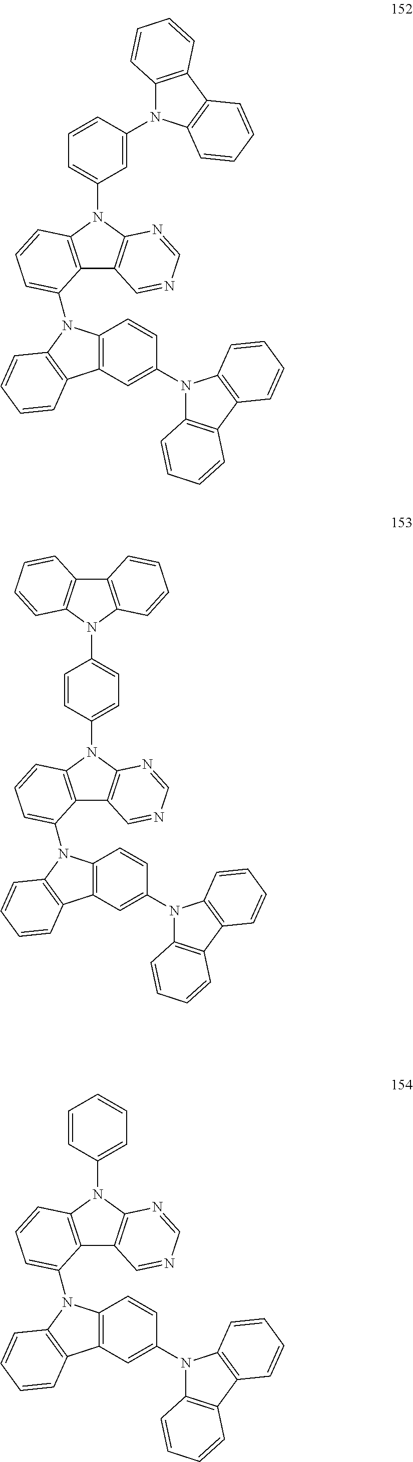

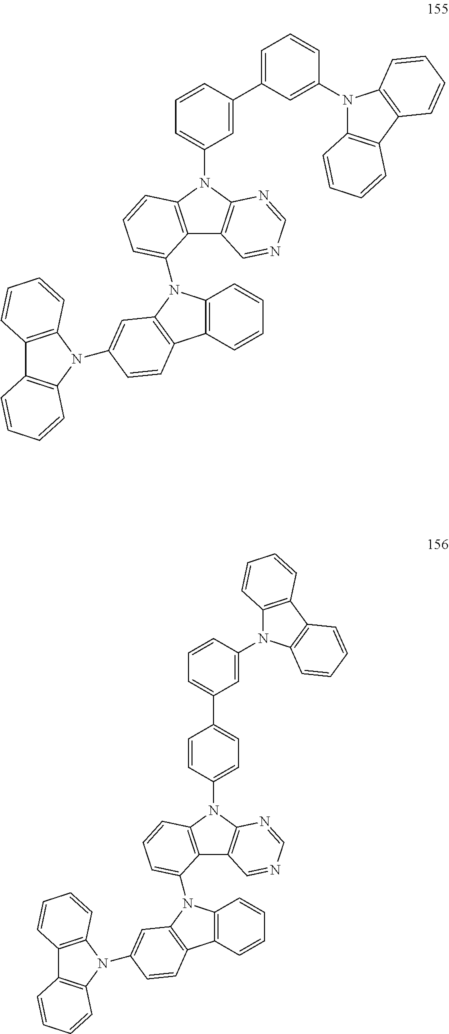 [SMILES: c1cc(-c2cccc(-n3c4cccc(-n5c6ccccc6c6ccc(-n7c8ccccc8c8ccccc87)cc65)c4c4cncnc43)c2)cc(-n2c3ccccc3c3ccccc32)c1 ; c1cc(-c2ccc(-n3c4cccc(-n5c6ccccc6c6ccc(-n7c8ccccc8c8ccccc87)cc65)c4c4cncnc43)cc2)cc(-n2c3ccccc3c3ccccc32)c1]

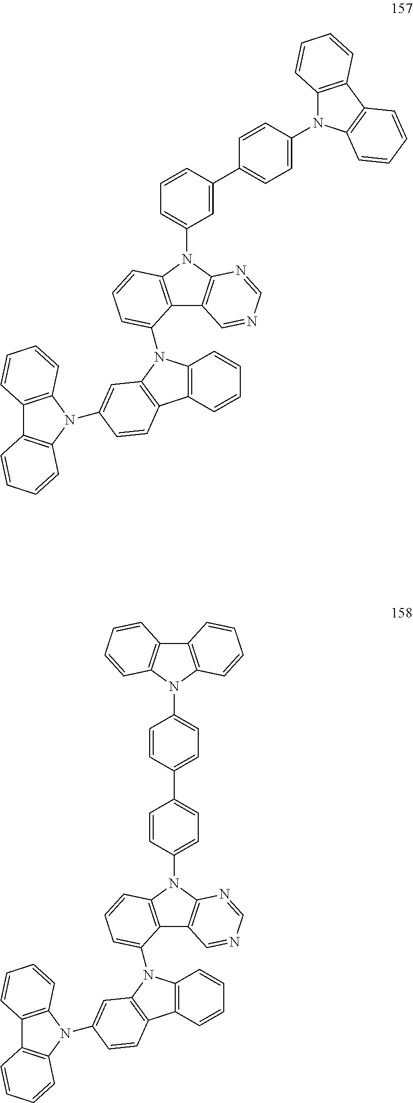 [SMILES: c1cc(-c2ccc(-n3c4ccccc4c4ccccc43)cc2)cc(-n2c3cccc(-n4c5ccccc5c5ccc(-n6c7ccccc7c7ccccc76)cc54)c3c3cncnc32)c1 ; c1ccc2c(c1)c1ccccc1n2-c1ccc(-c2ccc(-n3c4cccc(-n5c6ccccc6c6ccc(-n7c8ccccc8c8ccccc87)cc65)c4c4cncnc43)cc2)cc1]

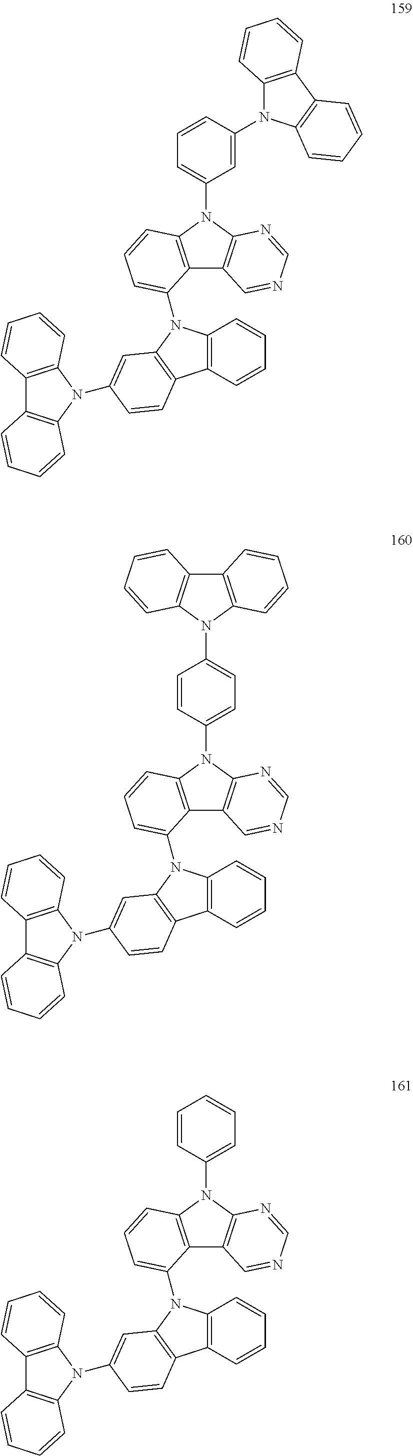 [SMILES: c1cc(-n2c3ccccc3c3ccccc32)cc(-n2c3cccc(-n4c5ccccc5c5ccc(-n6c7ccccc7c7ccccc76)cc54)c3c3cncnc32)c1 ; c1ccc2c(c1)c1ccccc1n2-c1ccc(-n2c3cccc(-n4c5ccccc5c5ccc(-n6c7ccccc7c7ccccc76)cc54)c3c3cncnc32)cc1 ; c1ccc(-n2c3cccc(-n4c5ccccc5c5ccc(-n6c7ccccc7c7ccccc76)cc54)c3c3cncnc32)cc1]

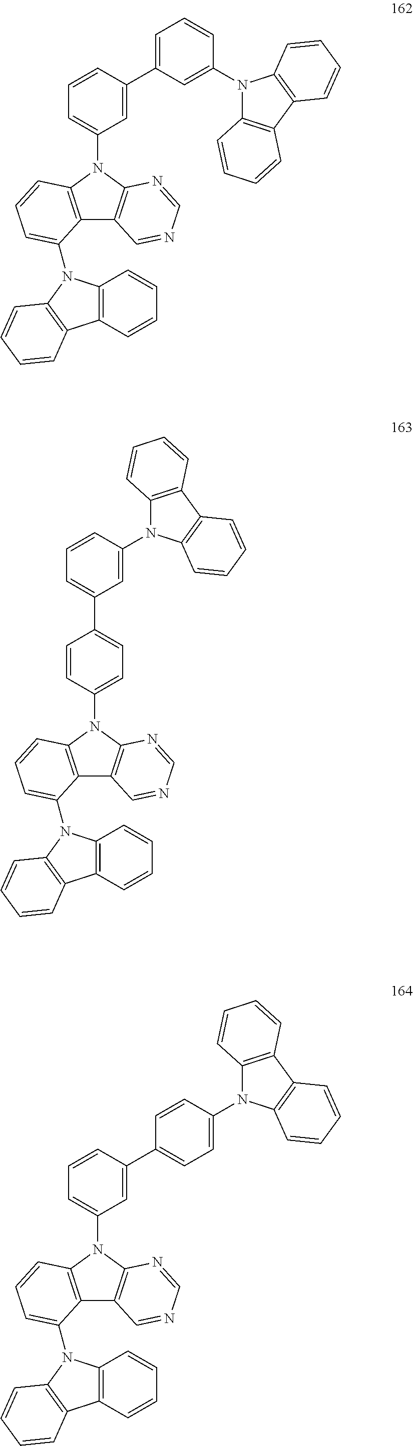 [SMILES: c1cc(-c2cccc(-n3c4cccc(-n5c6ccccc6c6ccccc65)c4c4cncnc43)c2)cc(-n2c3ccccc3c3ccccc32)c1 ; c1cc(-c2ccc(-n3c4cccc(-n5c6ccccc6c6ccccc65)c4c4cncnc43)cc2)cc(-n2c3ccccc3c3ccccc32)c1 ; c1cc(-c2ccc(-n3c4ccccc4c4ccccc43)cc2)cc(-n2c3cccc(-n4c5ccccc5c5ccccc54)c3c3cncnc32)c1]

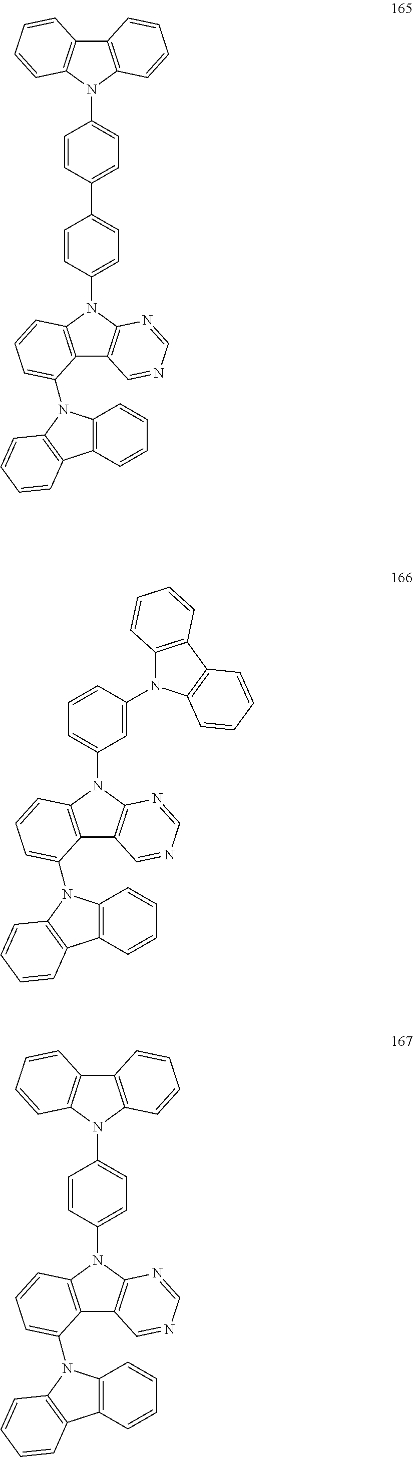 [SMILES: c1ccc2c(c1)c1ccccc1n2-c1ccc(-c2ccc(-n3c4cccc(-n5c6ccccc6c6ccccc65)c4c4cncnc43)cc2)cc1 ; c1cc(-n2c3ccccc3c3ccccc32)cc(-n2c3cccc(-n4c5ccccc5c5ccccc54)c3c3cncnc32)c1 ; c1ccc2c(c1)c1ccccc1n2-c1ccc(-n2c3cccc(-n4c5ccccc5c5ccccc54)c3c3cncnc32)cc1]

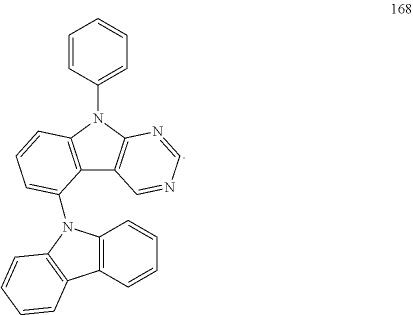 [SMILES: c1ccc(-n2c3cccc(-n4c5ccccc5c5ccccc54)c3c3cncnc32)cc1]

15. The organic light-emitting device of claim 1, wherein
the first electrode is an anode,
the second electrode is a cathode,
the organic layer comprises a hole transport region disposed between the first electrode and the emission layer and an electron transport region disposed between the emission layer and the second electrode,
the hole transport region comprises at least one selected from a hole injection layer, a hole transport layer, and an electron blocking layer, and
the electron transport region comprises at least one selected from a hole blocking layer, an electron transport layer, and an electron injection layer.

16. The organic light-emitting device of claim 1, wherein
the emission layer emits blue light having a maximum emission wavelength of about 380 nanometers to about 475 nanometers.

17. The organic light-emitting device of claim 1, wherein
the condensed cyclic compound comprised in the emission layer is a delayed fluorescence emitter.

18. The organic light-emitting device of claim 1, wherein
the emission layer consists of the condensed cyclic compound only.

19. The organic light-emitting device of claim 1, wherein
the emission layer further comprises a host, and an amount of the host is larger than an amount of the condensed cyclic compound.

20. The organic light-emitting device of claim 1, wherein
the emission layer does not comprise an organometallic compound.
